(19) United States
(12) Patent Application Publication
(10) Pub. No.: US 2026/0075930 A1
(43) Pub. Date: Mar. 12, 2026

(54) MULTILAYER ELECTRODE DEVICES AND METHOD OF MAKING THE SAME

(71) Applicant: Sandisk Technologies, Inc., Milpitas, CA (US)

(72) Inventors: Hokuto KODATE, Yokkaichi (JP); Ryo KAGAWA, Yokkaichi (JP); Kazutaka YOSHIZAWA, Yokkaichi (JP); Eiichi FUJIKURA, Yokkaichi (JP)

(21) Appl. No.: 18/882,360

(22) Filed: Sep. 11, 2024

(51) Int. Cl. H01L 27/088; H01L 21/28; H01L 21/8238; H01L 29/423; H01L 29/49

(52) U.S. Cl. CPC H10D 84/83; H10D 64/01308; H10D 64/518; H10D 64/662; H10D 84/0179; H10D 84/038

(57) ABSTRACT

Semiconductor devices that include a replacement metallic gate electrode and a gate-level semiconductor structure can be formed on a seme semiconductor substrate by providing an etch-stop structure that prevents replacement of the gate-level semiconductor structure, and by replacing a sacrificial semiconductor gate electrode with the replacement metallic gate electrode. The gate-level semiconductor structure may include a semiconductor gate electrode of a field effect transistor, or a semiconductor material strip that can be employed as a resistor. In one embodiment, the etch-stop structure and an overlying sacrificial structure may be replaced with another replacement metallic gate electrode. In another embodiment, a silicide region may be formed on the semiconductor gate electrode.

### FIELD

The present disclosure relates generally to the field of semiconductor devices and specifically to semiconductor devices containing multilayer gate and resistor structures and methods of making the same.

### BACKGROUND

Field effect transistors include source and drain regions separated by a semiconductor channel. A gate dielectric is located between the semiconductor channel and a gate electrode.

### SUMMARY

According to first and second embodiments of the present disclosure, a semiconductor structure comprises: a first field effect transistor comprising first source/drain regions located in a first portion of a semiconductor substrate, a first gate dielectric comprising a first metal oxide gate dielectric that comprises a first portion of a dielectric metal oxide material, and a first gate electrode consisting essentially of a first metallic gate electrode contacting a top surface of the first gate dielectric; and a second field effect transistor comprising second source/drain regions located in a second portion of the semiconductor substrate, a second gate dielectric comprising a silicon oxide gate dielectric, and a second gate electrode comprising a vertical stack of a doped semiconductor gate electrode and a second metallic gate electrode.

According to first and second embodiments of the present disclosure, a method of forming a semiconductor structure comprises forming a silicon oxide gate dielectric on a top surface segment of a semiconductor substrate, wherein the silicon oxide gate dielectric is not present in a first device region and is present in a second device region; forming a gate dielectric metal oxide layer directly on an additional top surface segment of the semiconductor substrate in the first device region and over the silicon oxide gate dielectric in the second device region; forming a lower gate semiconductor layer over the silicon oxide gate dielectric in the second device region and over gate dielectric metal oxide layer in the first device region; forming an etch-stop layer over the lower gate semiconductor layer in the second device region; forming an upper gate semiconductor layer over the gate dielectric metal oxide layer in the first device region and over the etch-stop layer and the lower gate semiconductor layer in the second device region; patterning the upper gate semiconductor layer, the etch-stop layer, and the lower gate semiconductor layer into a first gate structure that is formed in the first device region and into a second gate structure that is formed in the second device region; replacing a first patterned portion of the upper gate semiconductor layer and a patterned portion of the lower gate semiconductor layer in the first gate structure with a first metallic gate electrode; and replacing a second patterned portion of the upper gate semiconductor layer and a patterned portion of the etch-stop layer with a second metallic gate electrode.

According to the second embodiment of the present disclosure, a method of forming a semiconductor structure comprises forming a silicon oxide gate dielectric on a top surface segment of a semiconductor substrate, wherein the silicon oxide gate dielectric is not present in a first device region and is present in a second device region; forming a lower gate semiconductor layer over the silicon oxide gate dielectric; forming a gate dielectric metal oxide layer directly on an additional top surface segment of the semiconductor substrate in the first device region; forming an intermediate gate semiconductor layer over the gate dielectric metal oxide layer; forming an upper gate semiconductor layer over the intermediate gate semiconductor layer; patterning the upper gate semiconductor layer, the intermediate gate semiconductor layer, and the lower gate semiconductor layer into a first gate structure that is formed in the first device region and into a second gate structure that is formed in the second device region; replacing a first patterned portion of the upper gate semiconductor layer and a patterned portion of the intermediate gate semiconductor layer in the first gate structure with a first metallic gate electrode; and replacing at least a second patterned portion of the upper gate semiconductor layer with a second metallic gate electrode.

According to a third embodiment of the present disclosure, a semiconductor structure comprises a resistor, wherein the resistor comprises: an isolation dielectric layer located on a top surface of a first portion of a semiconductor substrate; a semiconductor material strip overlying the isolation dielectric layer; a first metallic contact structure located on a first end portion of the semiconductor material strip; and a second metallic contact structure located on a second end portion of the semiconductor material strip, wherein the first metallic contact structure comprises at least one first metallic liner each having a respective first horizontally-extending portion and a respective first tubular portion that vertically extends upward from a periphery of the respective first horizontally-extending portion.

According to the third embodiment of the present disclosure, a method of forming a semiconductor structure comprises: forming an isolation dielectric layer on a top surface of a first portion of a semiconductor substrate; forming a layer stack including a lower gate semiconductor layer, an etch-stop layer, and an upper gate semiconductor layer over the isolation dielectric layer; patterning the layer stack, wherein patterned portions of the layer stack comprise, from bottom to top, a semiconductor material strip that is a patterned portion of the lower gate semiconductor layer, an etch-stop strip that is a patterned portion of the etch-stop layer, and a pair of semiconductor pillars that are patterned portions of the upper gate semiconductor layer; forming a planarization dielectric layer around the semiconductor material strip, the etch-stop strip, and the pair of semiconductor pillars by depositing and planarizing a planarization dielectric material, wherein top surfaces of the pair of semiconductor pillars are exposed; and replacing the pair of semiconductor pillars and underlying portions of the etch-stop strip with a first metallic contact structure and a second metallic contact structure.

According to fourth and fifth embodiments of the present disclosure, a semiconductor structure comprises: a first field effect transistor comprising first source/drain regions located in a first portion of a semiconductor substrate, a first gate dielectric comprising a first metal oxide gate dielectric that comprises a first portion of a dielectric metal oxide material, and a first gate electrode comprising a metallic gate electrode contacting a top surface of the first gate dielectric; and a second field effect transistor comprising second source/drain regions located in a second portion of the semiconductor substrate, a second gate dielectric, a second gate electrode comprising a doped semiconductor gate electrode, and a gate metal-semiconductor alloy region comprising an alloy of a first elemental metal and a semiconductor material of the doped semiconductor gate electrode.

According to a fourth embodiment of the present disclosure, a method of forming a semiconductor structure comprises: forming a first gate structure over a first portion of a semiconductor substrate and a second gate structure over a second portion of the semiconductor substrate, wherein the first gate structure comprises a first gate dielectric, a first semiconductor gate electrode, and a first sacrificial gate cap structure, and the second gate structure comprises a second gate dielectric, a second semiconductor gate electrode, and a second sacrificial gate cap structure; forming a planarization dielectric layer around the first gate structure and the second gate structure; forming a gate cavity by removing the first sacrificial gate cap structure and the first semiconductor gate electrode; depositing at least one metallic material in the gate cavity and over the planarization dielectric layer; and removing portions of the at least one metallic material, the second sacrificial gate cap structure, and an upper portion of the planarization dielectric layer from above a horizontal plane including a top surface of the second semiconductor gate electrode by performing a planarization process, wherein a remaining portion of the at least one metallic material in a lower portion of the gate cavity comprises a metallic gate electrode.

According to a fifth embodiment of the present disclosure, a method of forming a semiconductor structure comprises: forming a first gate structure over a first portion of a semiconductor substrate and a second gate structure over a second portion of the semiconductor substrate, wherein the first gate structure comprises a first gate dielectric, a first semiconductor gate electrode, and a first sacrificial gate cap structure, and the second gate structure comprises a second gate dielectric, a second semiconductor gate electrode, a gate cap dielectric, and a second sacrificial gate cap structure; forming an opening through the second sacrificial gate cap structure and the gate cap dielectric; forming a gate metal-semiconductor alloy region on the second semiconductor gate electrode in the opening in the gate cap dielectric; forming a planarization dielectric layer around the first gate structure and the second gate structure; forming a gate cavity by removing the first sacrificial gate cap structure and the first semiconductor gate electrode; depositing at least one metallic material in the gate cavity and over the planarization dielectric layer; and removing portions of the at least one metallic material and the second sacrificial gate cap structure from above a horizontal plane including a top surface of the gate cap dielectric by performing a planarization process, wherein a remaining portion of the at least one metallic material in a lower portion of the gate cavity comprises a metallic gate electrode.

### BRIEF DESCRIPTION OF THE DRAWINGS

FIG. 1A is a vertical cross-sectional view of a first exemplary structure after formation of various shallow trench isolation structures according to a first embodiment of the present disclosure. FIG. 1B is a top-down view of the first exemplary structure of FIG. 1A. The vertical plane A-A′ is the cut plane of the vertical cross-sectional view of FIG. 1A.

FIG. 2A is a vertical cross-sectional view of the first exemplary structure after formation of silicon oxide gate dielectrics according to the first embodiment of the present disclosure. FIG. 2B is a top-down view of the first exemplary structure of FIG. 2A. The vertical plane A-A′ is the cut plane of the vertical cross-sectional view of FIG. 2A.

FIG. 3A is a vertical cross-sectional view of the first exemplary structure after formation of a gate dielectric metal oxide layer and a lower gate semiconductor layer according to the first embodiment of the present disclosure. FIG. 3B is a top-down view of the first exemplary structure of FIG. 3A. The vertical plane A-A′ is the cut plane of the vertical cross-sectional view of FIG. 3A.

FIG. 4A is a vertical cross-sectional view of the first exemplary structure after converting a portion of the lower gate semiconductor layer into a doped semiconductor material layer according to the first embodiment of the present disclosure. FIG. 4B is a top-down view of the first exemplary structure of FIG. 4A. The vertical plane A-A′ is the cut plane of the vertical cross-sectional view of FIG. 4A.

FIG. 5A is a vertical cross-sectional view of the first exemplary structure after formation of an etch-stop layer according to the first embodiment of the present disclosure. FIG. 5B is a top-down view of the first exemplary structure of FIG. 5A. The vertical plane A-A′ is the cut plane of the vertical cross-sectional view of FIG. 5A.

FIG. 6A is a vertical cross-sectional view of the first exemplary structure after formation of an upper gate semiconductor layer, a lower sacrificial gate cap layer, and an upper sacrificial gate cap layer according to the first embodiment of the present disclosure. FIG. 6B is a top-down view of the first exemplary structure of FIG. 6A. The vertical plane A-A′ is the cut plane of the vertical cross-sectional view of FIG. 6A.

FIG. 7A is a vertical cross-sectional view of the first exemplary structure after formation of gate structures according to the first embodiment of the present disclosure. FIG. 7B is a top-down view of the first exemplary structure of FIG. 7A. The vertical plane A-A′ is the cut plane of the vertical cross-sectional view of FIG. 7A.

FIG. 8A is a vertical cross-sectional view of the first exemplary structure after formation of inner dielectric gate spacers and source/drain extension regions according to the first embodiment of the present disclosure. FIG. 8B is a top-down view of the first exemplary structure of FIG. 8A. The vertical plane A-A′ is the cut plane of the vertical cross-sectional view of FIG. 8A.

FIG. 9A is a vertical cross-sectional view of the first exemplary structure after formation of an outer dielectric gate spacer material layer according to the first embodiment of the present disclosure. FIG. 9B is a top-down view of the first exemplary structure of FIG. 9A. The vertical plane A-A′ is the cut plane of the vertical cross-sectional view of FIG. 9A.

FIG. 10A is a vertical cross-sectional view of the first exemplary structure after formation of outer dielectric gate spacers according to the first embodiment of the present disclosure. FIG. 10B is a top-down view of the first exemplary structure of FIG. 10A. The vertical plane A-A′ is the cut plane of the vertical cross-sectional view of FIG. 10A.

FIG. 11A is a vertical cross-sectional view of the first exemplary structure after formation of deep source/drain regions according to the first embodiment of the present disclosure. FIG. 11B is a top-down view of the first exemplary structure of FIG. 11A. The vertical plane A-A′ is the cut plane of the vertical cross-sectional view of FIG. 11A.

FIG. 12A is a vertical cross-sectional view of the first exemplary structure after formation of metal-semiconductor alloy regions, a dielectric diffusion barrier layer, and a planarization dielectric layer according to the first embodiment of the present disclosure. FIG. 12B is a top-down view of the first exemplary structure of FIG. 12A. The vertical plane A-A′ is the cut plane of the vertical cross-sectional view of FIG. 12A.

FIG. 13A is a vertical cross-sectional view of the first exemplary structure after performing a planarization process that planarizes the planarization dielectric layer according to the first embodiment of the present disclosure. FIG. 13B is a top-down view of the first exemplary structure of FIG. 13A. The vertical plane A-A′ is the cut plane of the vertical cross-sectional view of FIG. 13A.

FIG. 14A is a vertical cross-sectional view of the first exemplary structure after formation of gate cavities according to the first embodiment of the present disclosure. FIG. 14B is a top-down view of the first exemplary structure of FIG. 14A. The vertical plane A-A′ is the cut plane of the vertical cross-sectional view of FIG. 14A.

FIG. 15A is a vertical cross-sectional view of the first exemplary structure after removal of an etch-stop strip according to the first embodiment of the present disclosure. FIG. 15B is a top-down view of the first exemplary structure of FIG. 15A. The vertical plane A-A′ is the cut plane of the vertical cross-sectional view of FIG. 15A.

FIG. 16A is a vertical cross-sectional view of the first exemplary structure after deposition of a replacement metallic material layer according to the first embodiment of the present disclosure. FIG. 16B is a top-down view of the first exemplary structure of FIG. 16A. The vertical plane A-A′ is the cut plane of the vertical cross-sectional view of FIG. 16A.

FIG. 17A is a vertical cross-sectional view of the first exemplary structure after formation of metallic gate electrodes according to the first embodiment of the present disclosure. FIG. 17B is a top-down view of the first exemplary structure of FIG. 17A. The vertical plane A-A′ is the cut plane of the vertical cross-sectional view of FIG. 17A.

FIG. 18A is a vertical cross-sectional view of the first exemplary structure after formation of a cover dielectric layer and various contact via structures according to the first embodiment of the present disclosure. FIG. 18B is a top-down view of the first exemplary structure of FIG. 18A. The vertical plane A-A′ is the cut plane of the vertical cross-sectional view of FIG. 18A.

FIG. 19A is a vertical cross-sectional view of a second exemplary structure after formation of a silicon oxide gate dielectric and sacrificial silicon oxide layers according to a second embodiment of the present disclosure. FIG. 19B is a top-down view of the second exemplary structure of FIG. 19A. The vertical plane A-A′ is the cut plane of the vertical cross-sectional view of FIG. 19A.

FIG. 20A is a vertical cross-sectional view of the second exemplary structure after formation of a lower gate semiconductor layer according to the second embodiment of the present disclosure. FIG. 20B is a top-down view of the second exemplary structure of FIG. 20A. The vertical plane A-A′ is the cut plane of the vertical cross-sectional view of FIG. 20A.

FIG. 21A is a vertical cross-sectional view of the second exemplary structure after patterning the lower gate semiconductor layer according to the second embodiment of the present disclosure. FIG. 21B is a top-down view of the second exemplary structure of FIG. 21A. The vertical plane A-A′ is the cut plane of the vertical cross-sectional view of FIG. 21A.

FIG. 22A is a vertical cross-sectional view of the second exemplary structure after formation of additional silicon oxide gate dielectrics and an etch-stop layer according to the second embodiment of the present disclosure. FIG. 22B is a top-down view of the second exemplary structure of FIG. 22A. The vertical plane A-A′ is the cut plane of the vertical cross-sectional view of FIG. 22A.

FIG. 23A is a vertical cross-sectional view of the second exemplary structure after formation of a gate dielectric metal oxide layer and an intermediate gate semiconductor layer according to the second embodiment of the present disclosure. FIG. 23B is a top-down view of the second exemplary structure of FIG. 23A. The vertical plane A-A′ is the cut plane of the vertical cross-sectional view of FIG. 23A.

FIG. 24A is a vertical cross-sectional view of the second exemplary structure after patterning the intermediate gate semiconductor layer and the gate dielectric metal oxide layer according to the second embodiment of the present disclosure. FIG. 24B is a top-down view of the second exemplary structure of FIG. 24A. The vertical plane A-A′ is the cut plane of the vertical cross-sectional view of FIG. 24A. FIG. 24C is a vertical cross-sectional view of an alternative configuration of the second exemplary structure after patterning the intermediate gate semiconductor layer and the gate dielectric metal oxide layer according to the second embodiment of the present disclosure.

FIG. 25A is a vertical cross-sectional view of the second exemplary structure after formation of an upper gate semiconductor layer, a lower sacrificial gate cap layer, and an upper sacrificial gate cap layer according to the second embodiment of the present disclosure. FIG. 25B is a top-down view of the second exemplary structure of FIG. 25A. The vertical plane A-A′ is the cut plane of the vertical cross-sectional view of FIG. 25A.

FIG. 26A is a vertical cross-sectional view of the second exemplary structure after patterning a second gate structure according to the second embodiment of the present disclosure. FIG. 26B is a top-down view of the second exemplary structure of FIG. 26A. The vertical plane A-A′ is the cut plane of the vertical cross-sectional view of FIG. 26A.

FIG. 27A is a vertical cross-sectional view of the second exemplary structure after patterning a first gate structure and a third gate structure according to the second embodiment of the present disclosure. FIG. 27B is a top-down view of the second exemplary structure of FIG. 27A. The vertical plane A-A′ is the cut plane of the vertical cross-sectional view of FIG. 27A.

FIG. 28A is a vertical cross-sectional view of the second exemplary structure after formation of inner dielectric gate spacers and source/drain extension regions according to the second embodiment of the present disclosure. FIG. 28B is a top-down view of the second exemplary structure of FIG. 28A. The vertical plane A-A′ is the cut plane of the vertical cross-sectional view of FIG. 28A.

FIG. 29A is a vertical cross-sectional view of the second exemplary structure after formation of an outer dielectric gate spacer material layer according to the second embodiment of the present disclosure. FIG. 29B is a top-down view of the second exemplary structure of FIG. 29A. The vertical plane A-A′ is the cut plane of the vertical cross-sectional view of FIG. 29A.

FIG. 30A is a vertical cross-sectional view of the second exemplary structure after formation of outer dielectric gate spacers according to the second embodiment of the present disclosure. FIG. 30B is a top-down view of the second exemplary structure of FIG. 30A. The vertical plane A-A′ is the cut plane of the vertical cross-sectional view of FIG. 30A.

FIG. 31A is a vertical cross-sectional view of the second exemplary structure after formation of deep source/drain regions according to the second embodiment of the present disclosure. FIG. 31B is a top-down view of the second exemplary structure of FIG. 31A. The vertical plane A-A′ is the cut plane of the vertical cross-sectional view of FIG. 31A.

FIG. 32A is a vertical cross-sectional view of the second exemplary structure after formation of metal-semiconductor alloy regions, a dielectric diffusion barrier layer, and a planarization dielectric layer according to the second embodiment of the present disclosure. FIG. 32B is a top-down view of the second exemplary structure of FIG. 32A. The vertical plane A-A′ is the cut plane of the vertical cross-sectional view of FIG. 32A.

FIG. 33A is a vertical cross-sectional view of the second exemplary structure after performing a planarization process that planarizes the planarization dielectric layer according to the second embodiment of the present disclosure. FIG. 33B is a top-down view of the second exemplary structure of FIG. 33A. The vertical plane A-A′ is the cut plane of the vertical cross-sectional view of FIG. 33A.

FIG. 34A is a vertical cross-sectional view of the second exemplary structure after removal of the first sacrificial gate caps according to the second embodiment of the present disclosure. FIG. 34B is a top-down view of the second exemplary structure of FIG. 34A. The vertical plane A-A′ is the cut plane of the vertical cross-sectional view of FIG. 34A.

FIG. 35A is a vertical cross-sectional view of the second exemplary structure after removal of sacrificial semiconductor gate electrodes selectively to an etch-stop strip according to the second embodiment of the present disclosure. FIG. 35B is a top-down view of the second exemplary structure of FIG. 35A. The vertical plane A-A′ is the cut plane of the vertical cross-sectional view of FIG. 35A.

FIG. 36A is a vertical cross-sectional view of the second exemplary structure after removal of the etch-stop strip according to the second embodiment of the present disclosure. FIG. 36B is a top-down view of the second exemplary structure of FIG. 36A. The vertical plane A-A′ is the cut plane of the vertical cross-sectional view of FIG. 36A.

FIG. 37A is a vertical cross-sectional view of the second exemplary structure after deposition of a replacement metallic material layer according to the second embodiment of the present disclosure. FIG. 37B is a top-down view of the second exemplary structure of FIG. 37A. The vertical plane A-A′ is the cut plane of the vertical cross-sectional view of FIG. 37A.

FIG. 38A is a vertical cross-sectional view of the second exemplary structure after formation of metallic gate electrodes according to the second embodiment of the present disclosure. FIG. 38B is a top-down view of the second exemplary structure of FIG. 38A. The vertical plane A-A′ is the cut plane of the vertical cross-sectional view of FIG. 38A.

FIG. 39A is a vertical cross-sectional view of the second exemplary structure after formation of a cover dielectric layer and various contact via structures according to the second embodiment of the present disclosure. FIG. 39B is a top-down view of the second exemplary structure of FIG. 39A. The vertical plane A-A′ is the cut plane of the vertical cross-sectional view of FIG. 39A.

FIG. 40A is a vertical cross-sectional view of a third exemplary structure after formation of a semiconductor oxide gate dielectric and an isolation dielectric layer according to a third embodiment of the present disclosure. FIG. 40B is a top-down view of the third exemplary structure of FIG. 40A. The vertical plane A-A′ is the cut plane of the vertical cross-sectional view of FIG. 40A. FIG. 40C is a vertical cross-sectional view of the third exemplary structure along the vertical plane C-C′ of FIG. 40A.

FIG. 41A is a vertical cross-sectional view of the third exemplary structure after formation of a gate dielectric metal oxide layer and a lower gate semiconductor layer according to the third embodiment of the present disclosure. FIG. 41B is a top-down view of the third exemplary structure of FIG. 41A. The vertical plane A-A′ is the cut plane of the vertical cross-sectional view of FIG. 41A. FIG. 41C is a vertical cross-sectional view of the third exemplary structure along the vertical plane C-C′ of FIG. 41A.

FIG. 42A is a vertical cross-sectional view of the third exemplary structure after doping the lower gate semiconductor layer according to the third embodiment of the present disclosure. FIG. 42B is a top-down view of the third exemplary structure of FIG. 42A. The vertical plane A-A′ is the cut plane of the vertical cross-sectional view of FIG. 42A. FIG. 42C is a vertical cross-sectional view of the third exemplary structure along the vertical plane C-C′ of FIG. 42A.

FIG. 43A is a vertical cross-sectional view of the third exemplary structure after formation of an etch-stop layer, an upper gate semiconductor layer, a lower sacrificial gate cap layer, and an upper sacrificial gate cap layer according to the third embodiment of the present disclosure. FIG. 43B is a top-down view of the third exemplary structure of FIG. 43A. The vertical plane A-A′ is the cut plane of the vertical cross-sectional view of FIG. 43A. FIG. 43C is a vertical cross-sectional view of the third exemplary structure along the vertical plane C-C′ of FIG. 43A.

FIG. 44A is a vertical cross-sectional view of the third exemplary structure after patterning the upper sacrificial gate cap layer, the lower sacrificial gate cap layer, and the upper gate semiconductor layer according to the third embodiment of the present disclosure. FIG. 44B is a top-down view of the third exemplary structure of FIG. 44A. The vertical plane A-A′ is the cut plane of the vertical cross-sectional view of FIG. 44A. FIG. 44C is a vertical cross-sectional view of the third exemplary structure along the vertical plane C-C′ of FIG. 44A.

FIG. 45A is a vertical cross-sectional view of the third exemplary structure after formation of a patterned photoresist layer according to the third embodiment of the present disclosure. FIG. 45B is a top-down view of the third exemplary structure of FIG. 45A. The vertical plane A-A′ is the cut plane of the vertical cross-sectional view of FIG. 45A. FIG. 45C is a vertical cross-sectional view of the third exemplary structure along the vertical plane C-C′ of FIG. 45A.

FIG. 46A is a vertical cross-sectional view of the third exemplary structure after formation of a gate structure and a semiconductor material strip according to the third embodiment of the present disclosure. FIG. 46B is a top-down view of the third exemplary structure of FIG. 46A. The vertical plane A-A′ is the cut plane of the vertical cross-sectional view of FIG. 46A. FIG. 46C is a vertical cross-sectional view of the third exemplary structure along the vertical plane C-C′ of FIG. 46A.

FIG. 47A is a vertical cross-sectional view of the third exemplary structure after formation of an inner dielectric gate spacer and an inner dielectric resistor spacer according to the third embodiment of the present disclosure. FIG. 47B is a top-down view of the third exemplary structure of FIG. 47A. The vertical plane A-A′ is the cut plane of the vertical cross-sectional view of FIG. 47A. FIG. 47C is a vertical cross-sectional view of the third exemplary structure along the vertical plane C-C′ of FIG. 47A.

FIG. 48A is a vertical cross-sectional view of the third exemplary structure after formation of source/drain extension regions according to the third embodiment of the present disclosure. FIG. 48B is a top-down view of the third exemplary structure of FIG. 48A. The vertical plane A-A′ is the cut plane of the vertical cross-sectional view of FIG. 48A. FIG. 48C is a vertical cross-sectional view of the third exemplary structure along the vertical plane C-C′ of FIG. 48A.

FIG. 49A is a vertical cross-sectional view of the third exemplary structure after formation of an outer dielectric gate spacer material layer according to the third embodiment of the present disclosure. FIG. 49B is a top-down view of the third exemplary structure of FIG. 49A. The vertical plane A-A′ is the cut plane of the vertical cross-sectional view of FIG. 49A. FIG. 49C is a vertical cross-sectional view of the third exemplary structure along the vertical plane C-C′ of FIG. 49A.

FIG. 50A is a vertical cross-sectional view of the third exemplary structure after patterning the outer dielectric gate spacer material layer according to the third embodiment of the present disclosure. FIG. 50B is a top-down view of the third exemplary structure of FIG. 50A. The vertical plane A-A′ is the cut plane of the vertical cross-sectional view of FIG. 50A. FIG. 50C is a vertical cross-sectional view of the third exemplary structure along the vertical plane C-C′ of FIG. 50A.

FIG. 51A is a vertical cross-sectional view of the third exemplary structure after formation of deep source/drain regions according to the third embodiment of the present disclosure. FIG. 51B is a top-down view of the third exemplary structure of FIG. 51A. The vertical plane A-A′ is the cut plane of the vertical cross-sectional view of FIG. 51A. FIG. 51C is a vertical cross-sectional view of the third exemplary structure along the vertical plane C-C′ of FIG. 51A.

FIG. 52A is a vertical cross-sectional view of the third exemplary structure after formation of a dielectric diffusion barrier layer and a planarization dielectric layer according to the third embodiment of the present disclosure. FIG. 52B is a top-down view of the third exemplary structure of FIG. 52A. The vertical plane A-A′ is the cut plane of the vertical cross-sectional view of FIG. 52A. FIG. 52C is a vertical cross-sectional view of the third exemplary structure along the vertical plane C-C′ of FIG. 52A.

FIG. 53A is a vertical cross-sectional view of the third exemplary structure after planarizing the planarization dielectric layer according to the third embodiment of the present disclosure. FIG. 53B is a top-down view of the third exemplary structure of FIG. 53A. The vertical plane A-A′ is the cut plane of the vertical cross-sectional view of FIG. 53A. FIG. 53C is a vertical cross-sectional view of the third exemplary structure along the vertical plane C-C′ of FIG. 53A.

FIG. 54A is a vertical cross-sectional view of the third exemplary structure after removal of a sacrificial gate cap and sacrificial resistor contact caps according to the third embodiment of the present disclosure. FIG. 54B is a top-down view of the third exemplary structure of FIG. 54A. The vertical plane A-A′ is the cut plane of the vertical cross-sectional view of FIG. 54A.

FIG. 55A is a vertical cross-sectional view of the third exemplary structure after removal of sacrificial semiconductor structures selectively to etch-stop strips according to the third embodiment of the present disclosure. FIG. 55B is a top-down view of the third exemplary structure of FIG. 55A. The vertical plane A-A′ is the cut plane of the vertical cross-sectional view of FIG. 55A.

FIG. 56A is a vertical cross-sectional view of the third exemplary structure after removing unmasked portions of the etch-stop strips according to the third embodiment of the present disclosure. FIG. 56B is a top-down view of the third exemplary structure of FIG. 56A. The vertical plane A-A′ is the cut plane of the vertical cross-sectional view of FIG. 56A.

FIG. 57A is a vertical cross-sectional view of the third exemplary structure after deposition of a replacement metallic material layer according to the third embodiment of the present disclosure. FIG. 57B is a top-down view of the third exemplary structure of FIG. 57A. The vertical plane A-A′ is the cut plane of the vertical cross-sectional view of FIG. 57A.

FIG. 58A is a vertical cross-sectional view of the third exemplary structure after formation of a metallic gate electrode and metallic contact structures according to the third embodiment of the present disclosure. FIG. 58B is a top-down view of the third exemplary structure of FIG. 58A. The vertical plane A-A′ is the cut plane of the vertical cross-sectional view of FIG. 58A.

FIG. 59A is a vertical cross-sectional view of the third exemplary structure after formation of a cover dielectric layer and various contact via structures according to the third embodiment of the present disclosure. FIG. 59B is a top-down view of the third exemplary structure of FIG. 59A. The vertical plane A-A′ is the cut plane of the vertical cross-sectional view of FIG. 59A.

FIG. 60A is a vertical cross-sectional view of a fourth exemplary structure after formation of silicon oxide gate dielectrics according to a fourth embodiment of the present disclosure. FIG. 60B is a top-down view of the fourth exemplary structure of FIG. 60A. The vertical plane A-A′ is the cut plane of the vertical cross-sectional view of FIG. 60A.

FIG. 61A is a vertical cross-sectional view of the fourth exemplary structure after formation of a gate dielectric metal oxide layer, a gate semiconductor layer, and a sacrificial gate cap layer according to the fourth embodiment of the present disclosure. FIG. 61B is a top-down view of the fourth exemplary structure of FIG. 61A. The vertical plane A-A′ is the cut plane of the vertical cross-sectional view of FIG. 61A.

FIG. 62A is a vertical cross-sectional view of the fourth exemplary structure after formation of gate structures according to the fourth embodiment of the present disclosure. FIG. 62B is a top-down view of the fourth exemplary structure of FIG. 62A. The vertical plane A-A′ is the cut plane of the vertical cross-sectional view of FIG. 62A.

FIG. 63A is a vertical cross-sectional view of the fourth exemplary structure after formation of inner dielectric gate spacers and source/drain extension regions according to the fourth embodiment of the present disclosure. FIG. 63B is a top-down view of the fourth exemplary structure of FIG. 63A. The vertical plane A-A′ is the cut plane of the vertical cross-sectional view of FIG. 63A.

FIG. 64A is a vertical cross-sectional view of the fourth exemplary structure after formation of an intermediate dielectric gate spacer material layer and an outer dielectric gate spacer material layer according to the fourth embodiment of the present disclosure. FIG. 64B is a top-down view of the fourth exemplary structure of FIG. 64A. The vertical plane A-A′ is the cut plane of the vertical cross-sectional view of FIG. 64A.

FIG. 65A is a vertical cross-sectional view of the fourth exemplary structure after formation of intermediate dielectric gate spacers and outer dielectric gate spacers according to the fourth embodiment of the present disclosure. FIG. 65B is a top-down view of the fourth exemplary structure of FIG. 65A. The vertical plane A-A′ is the cut plane of the vertical cross-sectional view of FIG. 65A.

FIG. 66A is a vertical cross-sectional view of the fourth exemplary structure after formation of deep source/drain regions and metal-semiconductor alloy regions according to the fourth embodiment of the present disclosure. FIG. 66B is a top-down view of the fourth exemplary structure of FIG. 66A. The vertical plane A-A′ is the cut plane of the vertical cross-sectional view of FIG. 66A.

FIG. 67A is a vertical cross-sectional view of the fourth exemplary structure after formation of a dielectric diffusion barrier layer and a planarization dielectric layer according to the fourth embodiment of the present disclosure. FIG. 67B is a top-down view of the fourth exemplary structure of FIG. 67A. The vertical plane A-A′ is the cut plane of the vertical cross-sectional view of FIG. 67A.

FIG. 68A is a vertical cross-sectional view of the fourth exemplary structure after planarizing the planarization dielectric layer according to the fourth embodiment of the present disclosure. FIG. 68B is a top-down view of the fourth exemplary structure of FIG. 68A. The vertical plane A-A′ is the cut plane of the vertical cross-sectional view of FIG. 68A.

FIG. 69A is a vertical cross-sectional view of the fourth exemplary structure after formation of a patterned photoresist layer according to the fourth embodiment of the present disclosure. FIG. 69B is a top-down view of the fourth exemplary structure of FIG. 69A. The vertical plane A-A′ is the cut plane of the vertical cross-sectional view of FIG. 69A.

FIG. 70A is a vertical cross-sectional view of the fourth exemplary structure after formation of gate cavities according to the fourth embodiment of the present disclosure. FIG. 70B is a top-down view of the fourth exemplary structure of FIG. 70A. The vertical plane A-A′ is the cut plane of the vertical cross-sectional view of FIG. 70A.

FIG. 71A is a vertical cross-sectional view of the fourth exemplary structure after formation of a replacement metallic material layer according to the fourth embodiment of the present disclosure. FIG. 71B is a top-down view of the fourth exemplary structure of FIG. 71A. The vertical plane A-A′ is the cut plane of the vertical cross-sectional view of FIG. 71A.

FIG. 72A is a vertical cross-sectional view of the fourth exemplary structure after formation of metallic gate electrodes according to the fourth embodiment of the present disclosure. FIG. 72B is a top-down view of the fourth exemplary structure of FIG. 72A. The vertical plane A-A′ is the cut plane of the vertical cross-sectional view of FIG. 72A.

FIG. 73A is a vertical cross-sectional view of the fourth exemplary structure after formation of a dielectric capping layer and a gate metal-semiconductor alloy region according to the fourth embodiment of the present disclosure. FIG. 73B is a top-down view of the fourth exemplary structure of FIG. 73A. The vertical plane A-A′ is the cut plane of the vertical cross-sectional view of FIG. 73A.

FIG. 74A is a vertical cross-sectional view of the fourth exemplary structure after formation of a cover dielectric layer and various contact via structures according to the fourth embodiment of the present disclosure. FIG. 74B is a top-down view of the fourth exemplary structure of FIG. 74A. The vertical plane A-A′ is the cut plane of the vertical cross-sectional view of FIG. 74A.

FIG. 75A is a vertical cross-sectional view of a first portion of a fifth exemplary structure after formation of silicon oxide gate dielectrics, a gate dielectric metal oxide layer, a gate semiconductor layer, and a sacrificial gate cap layer according to a fifth embodiment of the present disclosure. FIG. 75B is a top-down view of the first portion of the fifth exemplary structure of FIG. 75A. The vertical plane A-A′ is the cut plane of the vertical cross-sectional view of FIG. 75A.

FIG. 76A is a vertical cross-sectional view of a first portion of the fifth exemplary structure after local thinning of the gate semiconductor layer according to the fifth embodiment of the present disclosure. FIG. 76B is a top-down view of the first portion of the fifth exemplary structure of FIG. 76A. The vertical plane A-A′ is the cut plane of the vertical cross-sectional view of FIG. 76A.

FIG. 77A is a vertical cross-sectional view of a portion of the fifth exemplary structure after deposition and patterning of a gate cap dielectric layer according to the fifth embodiment of the present disclosure. FIG. 77B is a top-down view of the portion of the fifth exemplary structure of FIG. 77A. The vertical plane A-A′ is the cut plane of the vertical cross-sectional view of FIG. 77A.

FIG. 78A is a vertical cross-sectional view of a portion of the fifth exemplary structure after formation of a sacrificial gate cap dielectric layer according to the fifth embodiment of the present disclosure. FIG. 78B is a top-down view of the portion of the fifth exemplary structure of FIG. 78A. The vertical plane A-A′ is the cut plane of the vertical cross-sectional view of FIG. 78A.

FIG. 79A is a vertical cross-sectional view of a first portion of the fifth exemplary structure after formation of gate structures and stacks of a semiconductor material strip and a dielectric resistor cap strip according to the fifth embodiment of the present disclosure. FIG. 79B is a top-down view of the first portion of the fifth exemplary structure of FIG. 79A. The vertical plane A-A′ is the cut plane of the vertical cross-sectional view of FIG. 79A. FIG. 79C is a vertical cross-sectional view of a second portion of the fifth exemplary structure at the processing steps of FIGS. 79A and 79B. FIG. 79D is a top-down view of the second portion of the fifth exemplary structure of FIG. 79C. The vertical plane C-C′ is the cut plane of the vertical cross-sectional view of FIG. 79C.

FIG. 80A is a vertical cross-sectional view of a portion of the fifth exemplary structure after formation of inner gate spacers and source/drain extension regions according to the fifth embodiment of the present disclosure. FIG. 80B is a top-down view of the portion of the fifth exemplary structure of FIG. 80A. The vertical plane A-A′ is the cut plane of the vertical cross-sectional view of FIG. 80A. FIG. 80C is a vertical cross-sectional view of a second portion of the fifth exemplary structure at the processing steps of FIGS. 80A and 80B. FIG. 80D is a top-down view of the second portion of the fifth exemplary structure of FIG. 80C. The vertical plane C-C′ is the cut plane of the vertical cross-sectional view of FIG. 80C.

FIG. 81A is a vertical cross-sectional view of a first portion of the fifth exemplary structure after formation of an intermediate dielectric gate spacer material layer and an outer dielectric gate spacer material layer according to the fifth embodiment of the present disclosure. FIG. 81B is a top-down view of the first portion of the fifth exemplary structure of FIG. 81A. The vertical plane A-A′ is the cut plane of the vertical cross-sectional view of FIG. 81A. FIG. 81C is a vertical cross-sectional view of a second portion of the fifth exemplary structure at the processing steps of FIGS. 81A and 81B. FIG. 81D is a top-down view of the second portion of the fifth exemplary structure of FIG. 81C. The vertical plane C-C′ is the cut plane of the vertical cross-sectional view of FIG. 81C.

FIG. 82A is a vertical cross-sectional view of a first portion of the fifth exemplary structure after formation of a patterned photoresist layer according to the fifth embodiment of the present disclosure. FIG. 82B is a top-down view of the first portion of the fifth exemplary structure of FIG. 82A. The vertical plane A-A′ is the cut plane of the vertical cross-sectional view of FIG. 82A. FIG. 82C is a vertical cross-sectional view of a second portion of the fifth exemplary structure at the processing steps of FIGS. 82A and 82B. FIG. 82D is a top-down view of the second portion of the fifth exemplary structure of FIG. 82C. The vertical plane C-C′ is the cut plane of the vertical cross-sectional view of FIG. 82C.

FIG. 83A is a vertical cross-sectional view of a first portion of the fifth exemplary structure after formation of openings through a gate cap structure and dielectric resistor cap strips according to the fifth embodiment of the present disclosure. FIG. 83B is a top-down view of the first portion of the fifth exemplary structure of FIG. 83A. The vertical plane A-A′ is the cut plane of the vertical cross-sectional view of FIG. 83A. FIG. 83C is a vertical cross-sectional view of a second portion of the fifth exemplary structure at the processing steps of FIGS. 83A and 83B. FIG. 83D is a top-down view of the second portion of the fifth exemplary structure of FIG. 83C. The vertical plane C-C′ is the cut plane of the vertical cross-sectional view of FIG. 83C.

FIG. 84A is a vertical cross-sectional view of a first portion of the fifth exemplary structure after formation of metal-semiconductor alloy regions according to the fifth embodiment of the present disclosure. FIG. 84B is a top-down view of the first portion of the fifth exemplary structure of FIG. 84A. The vertical plane A-A′ is the cut plane of the vertical cross-sectional view of FIG. 84A. FIG. 84C is a vertical cross-sectional view of a second portion of the fifth exemplary structure at the processing steps of FIGS. 84A and 84B. FIG. 84D is a top-down view of the second portion of the fifth exemplary structure of FIG. 84C. The vertical plane C-C′ is the cut plane of the vertical cross-sectional view of FIG. 84C.

FIG. 85A is a vertical cross-sectional view of a first portion of the fifth exemplary structure after formation of a dielectric diffusion barrier layer and a planarization dielectric layer according to the fifth embodiment of the present disclosure. FIG. 85B is a top-down view of the first portion of the fifth exemplary structure of FIG. 85A. The vertical plane A-A′ is the cut plane of the vertical cross-sectional view of FIG. 85A. FIG. 85C is a vertical cross-sectional view of a second portion of the fifth exemplary structure at the processing steps of FIGS. 85A and 85B. FIG. 85D is a top-down view of the second portion of the fifth exemplary structure of FIG. 85C. The vertical plane C-C′ is the cut plane of the vertical cross-sectional view of FIG. 85C.

FIG. 86A is a vertical cross-sectional view of a first portion of the fifth exemplary structure after planarizing the planarization dielectric layer according to the fifth embodiment of the present disclosure. FIG. 86B is a top-down view of the first portion of the fifth exemplary structure of FIG. 86A. The vertical plane A-A′ is the cut plane of the vertical cross-sectional view of FIG. 86A. FIG. 86C is a vertical cross-sectional view of a second portion of the fifth exemplary structure at the processing steps of FIGS. 86A and 86B. FIG. 86D is a top-down view of the second portion of the fifth exemplary structure of FIG. 86C. The vertical plane C-C′ is the cut plane of the vertical cross-sectional view of FIG. 86C.

FIG. 87A is a vertical cross-sectional view of a first portion of the fifth exemplary structure after formation of gate cavities according to the fifth embodiment of the present disclosure. FIG. 87B is a top-down view of the first portion of the fifth exemplary structure of FIG. 87A. The vertical plane A-A′ is the cut plane of the vertical cross-sectional view of FIG. 87A. FIG. 87C is a vertical cross-sectional view of a second portion of the fifth exemplary structure at the processing steps of FIGS. 87A and 87B. FIG. 87D is a top-down view of the second portion of the fifth exemplary structure of FIG. 87C. The vertical plane C-C′ is the cut plane of the vertical cross-sectional view of FIG. 87C.

FIG. 88A is a vertical cross-sectional view of a first portion of the fifth exemplary structure after formation of a replacement metallic material layer according to the fifth embodiment of the present disclosure. FIG. 88B is a top-down view of the first portion of the fifth exemplary structure of FIG. 88A. The vertical plane A-A′ is the cut plane of the vertical cross-sectional view of FIG. 88A. FIG. 88C is a vertical cross-sectional view of a second portion of the fifth exemplary structure at the processing steps of FIGS. 88A and 88B. FIG. 88D is a top-down view of the second portion of the fifth exemplary structure of FIG. 88C. The vertical plane C-C′ is the cut plane of the vertical cross-sectional view of FIG. 88C.

FIG. 89A is a vertical cross-sectional view of a first portion of the fifth exemplary structure after formation of metallic gate electrodes according to the fifth embodiment of the present disclosure. FIG. 89B is a top-down view of the first portion of the fifth exemplary structure of FIG. 89A. The vertical plane A-A′ is the cut plane of the vertical cross-sectional view of FIG. 89A. FIG. 89C is a vertical cross-sectional view of a second portion of the fifth exemplary structure at the processing steps of FIGS. 89A and 89B. FIG. 89D is a top-down view of the second portion of the fifth exemplary structure of FIG. 89C. The vertical plane C-C′ is the cut plane of the vertical cross-sectional view of FIG. 89C.

FIG. 90A is a vertical cross-sectional view of a first portion of the fifth exemplary structure after formation of a cover dielectric layer and various contact via structures according to the fifth embodiment of the present disclosure. FIG. 90B is a top-down view of the first portion of the fifth exemplary structure of FIG. 90A. The vertical plane A-A′ is the cut plane of the vertical cross-sectional view of FIG. 90A. FIG. 90C is a vertical cross-sectional view of a second portion of the fifth exemplary structure at the processing steps of FIGS. 90A and 90B. FIG. 90D is a top-down view of the second portion of the fifth exemplary structure of FIG. 90C. The vertical plane C-C′ is the cut plane of the vertical cross-sectional view of FIG. 90C.

### DETAILED DESCRIPTION

Embodiments of the present disclosure are directed to semiconductor devices such as field effect transistors containing multilayer gate electrodes and multilayer resistors and methods of making the same using a gate replacement process or a silicidation process, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element.

As used herein, a “layer” refers to a material portion including a region having a thickness. A layer may extend over the entirety of an underlying or overlying structure, or may have an extent less than the extent of an underlying or overlying structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which mobility of charge carriers is affected by an applied electrical field. A “gate electrode” refers to a conductive material portion that controls electron mobility in the channel region by application of an electrical field. A “source region” refers to a doped semiconductor region that supplies charge carriers that flow through the channel region. A “drain region” refers to a doped semiconductor region that receives charge carriers supplied by the source region and passes through the channel region. A “source/drain region” may be a source region or a drain region. An “active region” collectively refers to a source region, a drain region, and a channel region of a field effect transistor. A “source extension region” refers to a doped semiconductor region that is a portion of a source region and having a lesser dopant concentration than the rest of the source region. A “drain extension region” refers to a doped semiconductor region that is a portion of a drain region and having a lesser dopant concentration than the rest of the drain region. A “deep source region” refers to a doped semiconductor region that is a portion of a source region and having a greater depth than the rest of the source region. A “deep drain region” refers to a doped semiconductor region that is a portion of a drain region and having a greater depth than the rest of the drain region. A source/drain extension region may be a source extension region or a drain extension region. A deep source/drain region may be a deep source region or a deep drain region.

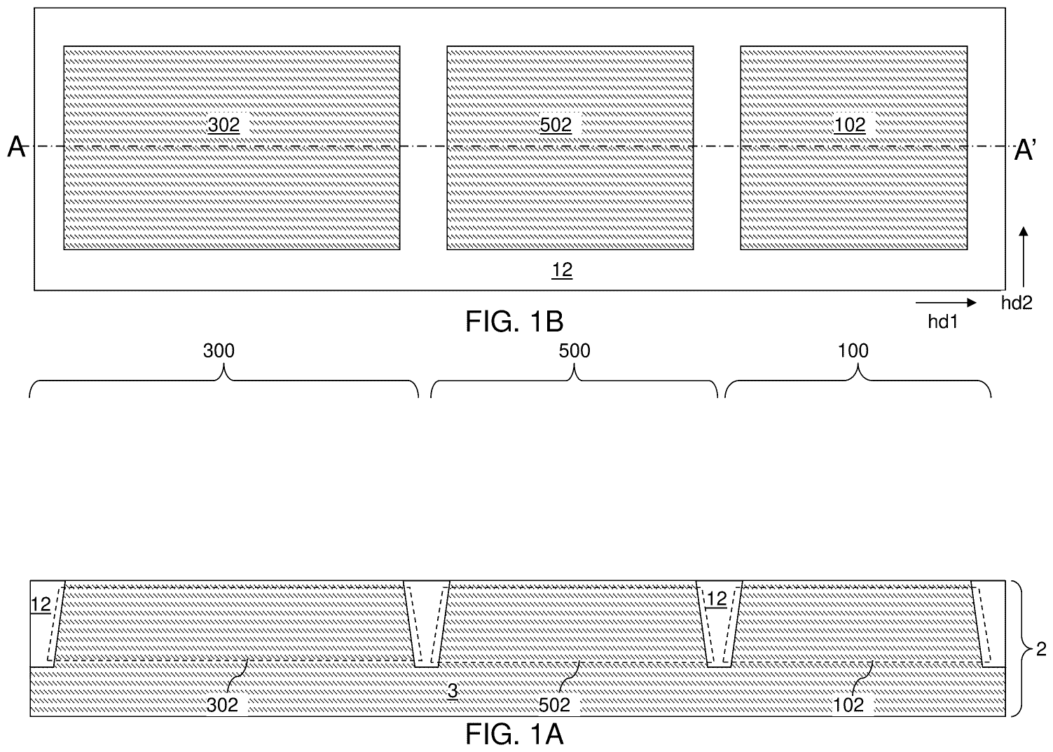

Referring to FIGS. 1A and 1B, a first exemplary structure according to a first embodiment of the present disclosure is illustrated. The first exemplary structure comprises a semiconductor substrate 2, which may be any semiconductor substrate known in the art. For example, the semiconductor substrate 2 may comprise a commercially available single crystalline silicon wafer. The substrate 2 may include a single crystalline semiconductor layer 3 at least in an upper portion thereof. The single crystalline semiconductor layer 3 may comprise an epitaxial single crystalline silicon layer or a p-type or n-type doped well in an upper portion of the silicon wafer. The first exemplary structure may comprise multiple device regions, such as a first device region 100, a second device region 300, and a third device region 500. The first device region 100 may comprise a very low voltage transistor region, the second device region 300 may comprise a low voltage transistor region, and the third device region 500 may comprise a high voltage transistor region.

Shallow trench isolation structures 12 can be formed in the upper portion of the semiconductor substrate 2 such that the shallow trench isolation structures 12 laterally surround a center portion of each device region (100, 300, 500). Each portion of the single crystalline semiconductor layer 3 that is laterally surrounded by a respective shallow trench isolation structure 12 comprises an active region (102, 302, 502). For example, a first active region 102 may be provided in the first device region 100, a second active region 302 may be provided in the second device region 300, and a third active region 502 may be provided in the third device region 500.

Semiconductor devices, such as field effect transistors, may be formed in the device regions (100, 300, 500). The various active regions (102, 302, 502) may be independently doped with p-type dopants or n-type dopants to provide a suitable doping level for the channel region of the field effect transistors to be subsequently formed. If a field effect transistor is formed in a device region (100, 300, 500), the active region (102, 302, 502) may have a rectangular physically exposed top surface. A pair of sidewalls of the rectangular physically exposed top surface may be parallel to a first horizontal direction hd1, and may be perpendicular to a second horizontal direction hd2. While an embodiment is described in which each channel direction (i.e., the direction of the electrical current between a source region and a drain region) is parallel to the first horizontal direction hd1, the channel directions of the various transistors may be parallel or perpendicular to each other. Embodiments are expressly contemplated herein in which different field effect transistors in different regions have different channel directions.

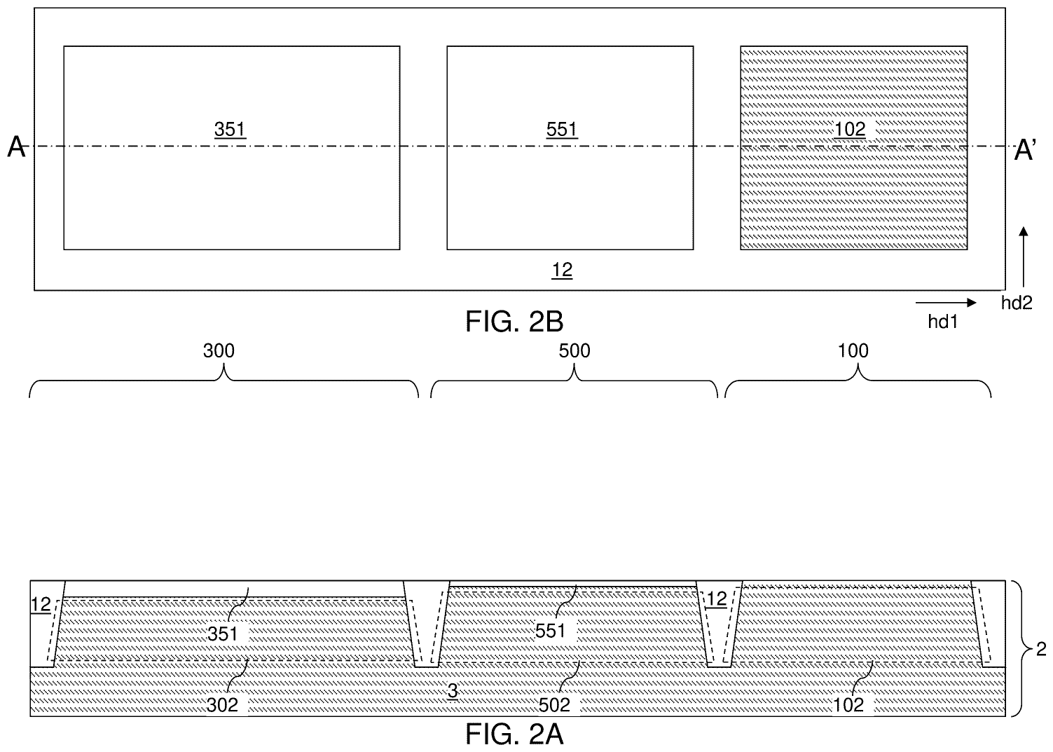

Referring to FIGS. 2A and 2B, silicon oxide gate dielectrics (351, 551) can be formed on top surfaces of a subset of the active regions (102, 302, 502). In an illustrative example, a first silicon oxide gate dielectric 351 can be formed on a top surface of the second active region 302, and a second silicon oxide gate dielectric 551 can be formed on a top surface of the third active region 502. For example, a first thermal oxidation process can be performed to convert surface portions of the active regions (102, 302, 502) into silicon oxide plates, and a first patterned photoresist layer may be formed to cover the second active region 302 without covering the first active region 102 or the third active region 502. An etch process, such as a wet etch process employing dilute hydrofluoric acid can be performed to remove the silicon oxide plates from above the first active region 102 and the third active region 502. The first patterned photoresist layer can be subsequently removed, for example, by ashing. A second thermal oxidation process can be performed to convert surface portions of the first active region 102 and the third active region 502 into silicon oxide plates, and a second patterned photoresist layer may be formed to cover the second active region 302 and the third active region 502 without covering the first active region 102. An etch process, such as a wet etch process employing dilute hydrofluoric acid, can be performed to remove the silicon oxide plate from above the first active region 102. The second patterned photoresist layer can be subsequently removed, for example, by ashing. The remaining silicon oxide plates comprise the first silicon oxide gate dielectric 351 and the second silicon oxide gate dielectric 551.

Alternatively, the first active region 102 may be masked, and the second silicon oxide gate dielectric 551 is formed on the second active region 302 and the third active region 502. The first and third active regions (102, 502) may then be masked, and the thickness of the second silicon oxide gate dielectric 551 may be increased in the unmasked second active region 302 by performing an additional oxidation to form the first silicon oxide gate dielectric 351 in the second active region 302.

The first silicon oxide gate dielectric 351 may thicker than the second silicon oxide gate dielectric 551. The thickness of the first silicon oxide gate dielectric 351 may be in a range from 6 nm to 60 nm, such as from 10 nm to 30 nm, although lesser and greater thicknesses may also be employed. The thickness of the second silicon oxide gate dielectric 551 may be in a range from 2 nm to 20 nm, such as from 4 nm to 10 nm, although lesser and greater thicknesses may also be employed. In one embodiment, no silicon oxide gate dielectric is present in the first device region 100, i.e., on the first active region 102, after the above oxidation step(s).

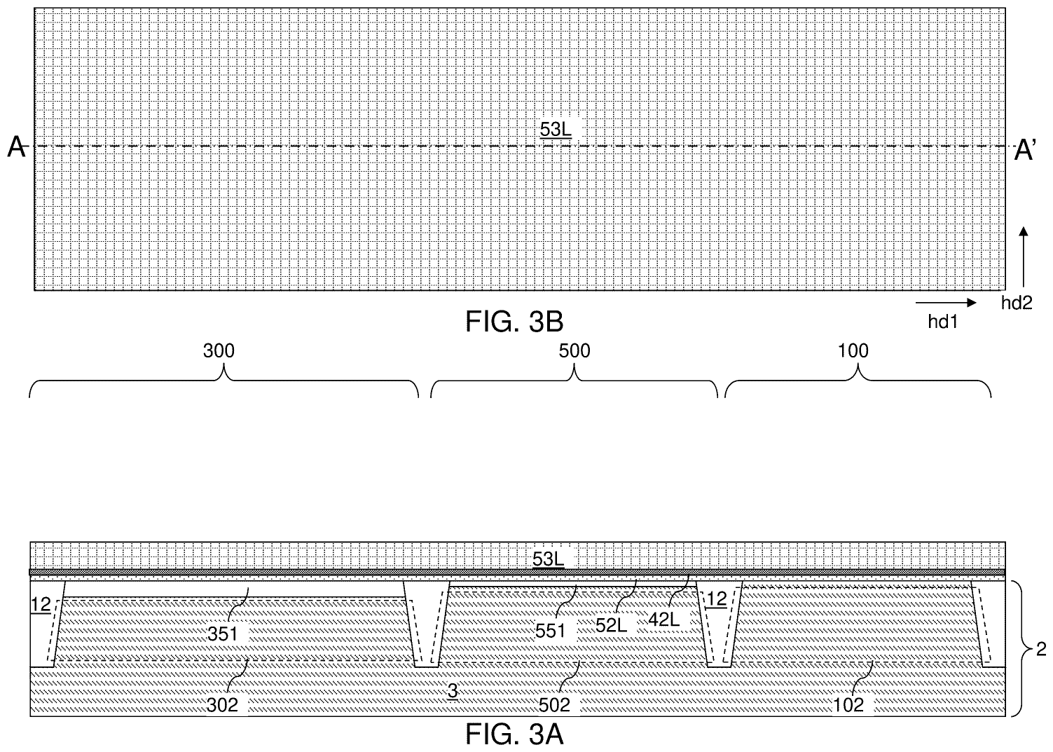

Referring to FIGS. 3A and 3B, a gate dielectric metal oxide layer 52L, an optional metallic barrier liner layer 42L, and a lower gate semiconductor layer 53L can be sequentially deposited. The gate dielectric metal oxide layer 52L may comprise a high dielectric constant (“high-k”) dielectric material having a dielectric constant above 3.9, such as above 7. The dielectric material may comprise any suitable high-k metal oxide gate dielectric material, such as aluminum oxide, at least one transition metal oxide (e.g., tantalum oxide, hafnium oxide, zirconium oxide, lanthanum zirconium oxide, barium strontium titanate, etc.), a metal silicate (e.g., zirconium silicate, hafnium silicate, etc.) or a combination thereof. The gate dielectric metal oxide layer 52L can be formed on the silicon oxide gate dielectrics (351, 551) and directly on a top surface segment of the semiconductor substrate 2 in the first device region 100. The effective oxide thickness (EOT) of the gate dielectric metal oxide layer 52L may be in a range from 0.8 nm to 5 nm, such as from 1 nm to 3 nm, although lesser and greater thicknesses may also be employed.

The optional metallic barrier liner layer 42L, if present, may comprise a conductive metallic nitride material such as TiN, TaN, WN, or MoN. The thickness of the metallic barrier liner layer 42L may be in a range from 0.5 nm to 10 nm, such as from 1 nm to 5 nm, although lesser and greater thicknesses may also be employed. The optional metallic barrier liner layer 42L, if present, can function as an etch stop material that protects the material of the gate dielectric metal oxide layer 52L in subsequent processing steps.

The lower gate semiconductor layer 53L comprises a semiconductor material that is doped with or may be subsequently doped with an electrical dopant, which may comprise a p-type dopant or an n-type dopant. For example, the lower gate semiconductor layer 53L may comprise amorphous silicon or polysilicon. The thickness of the lower gate semiconductor layer 53L may be in a range from 40 nm to 100 nm, such as from 60 nm to 80 nm, although lesser and greater thicknesses may also be employed.

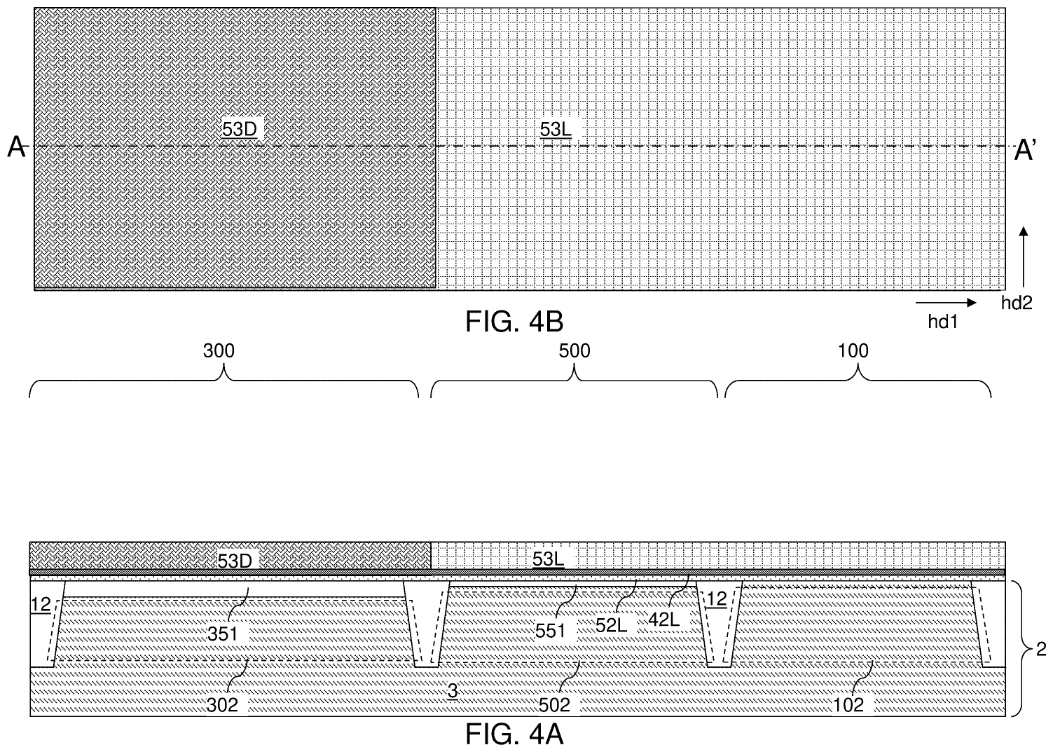

Referring to FIGS. 4A and 4B, in case the lower gate semiconductor layer 53L is deposited without suitable doping for forming a semiconductor gate electrode, a masked ion implantation process can be performed to convert a portion of the lower gate semiconductor layer 53L into a doped semiconductor material layer 53D. For example, a photoresist layer (not shown) can be applied and patterned to cover the first device region 100 and the third device region 500 without covering the second device region 300. P-type dopants or n-type dopants can be implanted into a portion of the lower gate semiconductor layer 53L in the second device region 300 to convert a portion of the lower gate semiconductor layer 53L into the doped semiconductor material layer 53D. The patterned photoresist layer can be subsequently removed, for example, by ashing.

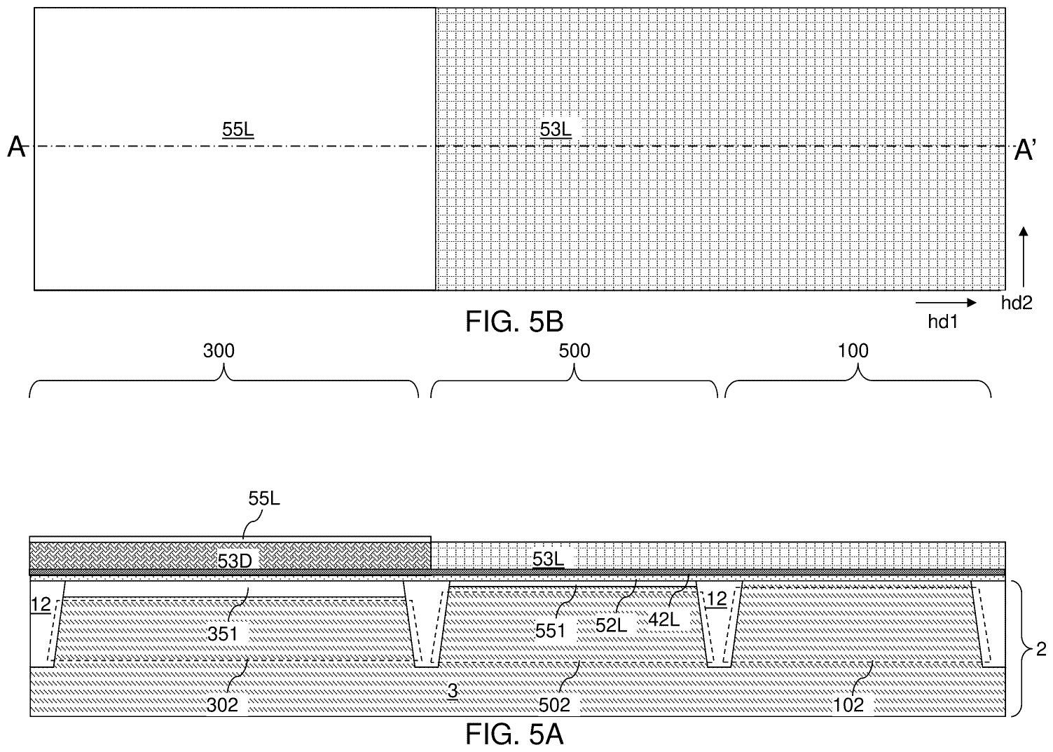

Referring to FIGS. 5A and 5B, an etch-stop layer 55L can be formed over the doped semiconductor material layer 53D (or on a portion of the lower gate semiconductor layer 53L located in the second device region 300 in case the doped semiconductor material layer 53D is not formed). The etch-stop layer 55L may comprise silicon oxide, silicon nitride, or another inter-polysilicon dielectric. In one embodiment, the etch-stop layer 55L may comprise a semiconductor oxide layer (such as a silicon oxide layer) that is formed by oxidation of a top surface portion of the doped semiconductor (e.g., silicon) material layer 53D (or the lower gate semiconductor layer 53L). The etch-stop layer 55L can be removed from outside the area of the second device region 300. For example, a photoresist layer can be applied over the etch-stop layer 55L, and can be lithographically patterned to cover the second device region 300 without covering the first device region 100 or the third device region 500. A selective etch process can be performed to remove the material of the etch-stop layer 55L selectively to the material of the lower gate semiconductor layer 53L. If the etch-stop layer 55L comprises silicon oxide, a wet etch process employing dilute hydrofluoric acid can be performed to remove portions of the etch-stop layer 55L selectively to the material of the lower gate semiconductor layer 53L. The patterned photoresist layer can be subsequently removed, for example, by ashing.

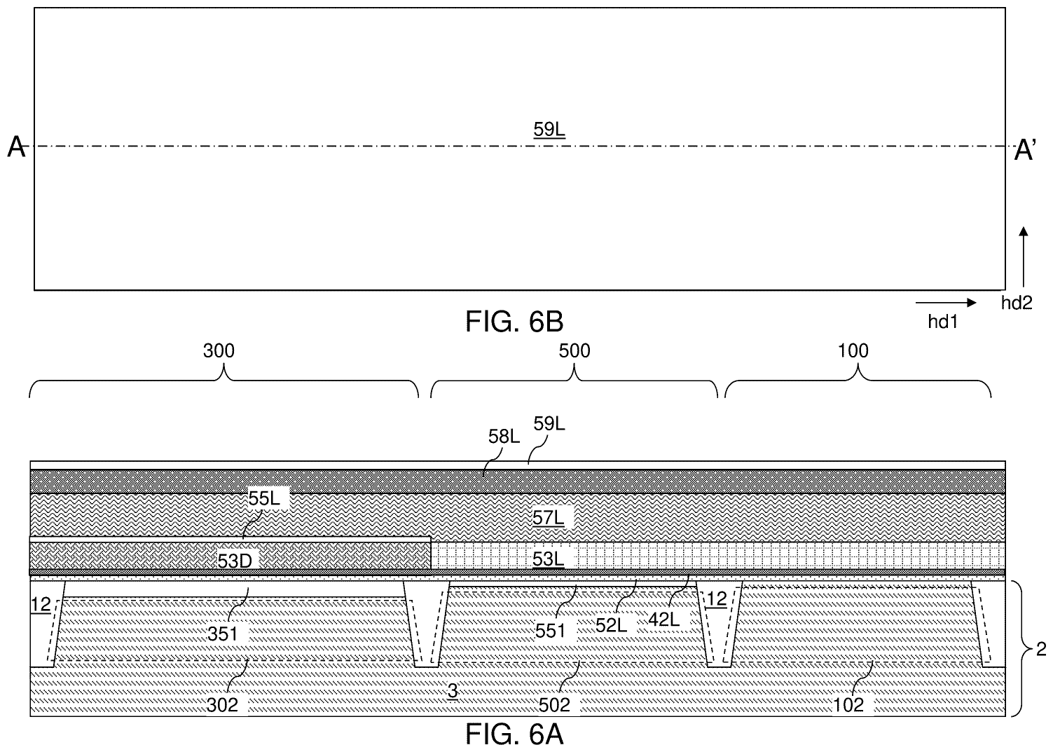

Referring to FIGS. 6A and 6B, an upper gate semiconductor layer 57L and at least one sacrificial gate cap layer (58L, 59L) can be sequentially formed. The upper gate semiconductor layer 57L comprises a semiconductor material. The semiconductor material of the upper gate semiconductor layer 57L may optionally be doped with electrical dopants. In one embodiment, the upper gate semiconductor layer 57L may comprise amorphous silicon or polysilicon. The thickness of the upper gate semiconductor layer 57L may be in a range from 40 nm to 100 nm, such as from 60 nm to 80 nm, although lesser and greater thicknesses may also be employed.

The at least one sacrificial gate cap layer (58L, 59L) comprises at least one sacrificial material that can be employed as a temporary gate capping material. The at least one sacrificial gate cap layer (58L, 59L) may comprise, for example, silicon oxide, silicon nitride, silicon carbonitride, etc. In one embodiment, the at least one sacrificial gate cap layer (58L, 59L) may comprise a lower sacrificial gate cap layer 58L and an upper sacrificial gate cap layer 59L. In an illustrative example, the lower sacrificial gate cap layer 58L may comprise a silicon nitride layer, and the upper sacrificial gate cap layer 59L may comprise a silicon oxide layer. The lower sacrificial gate cap layer 58L may have a thickness in a range from 15 nm to 40 nm, such as from 20 to 30 nm, although lesser and greater thicknesses may also be employed. The upper sacrificial gate cap layer 59L may have a thickness in a range from 5 nm to 20 nm, although lesser and greater thicknesses may also be employed.

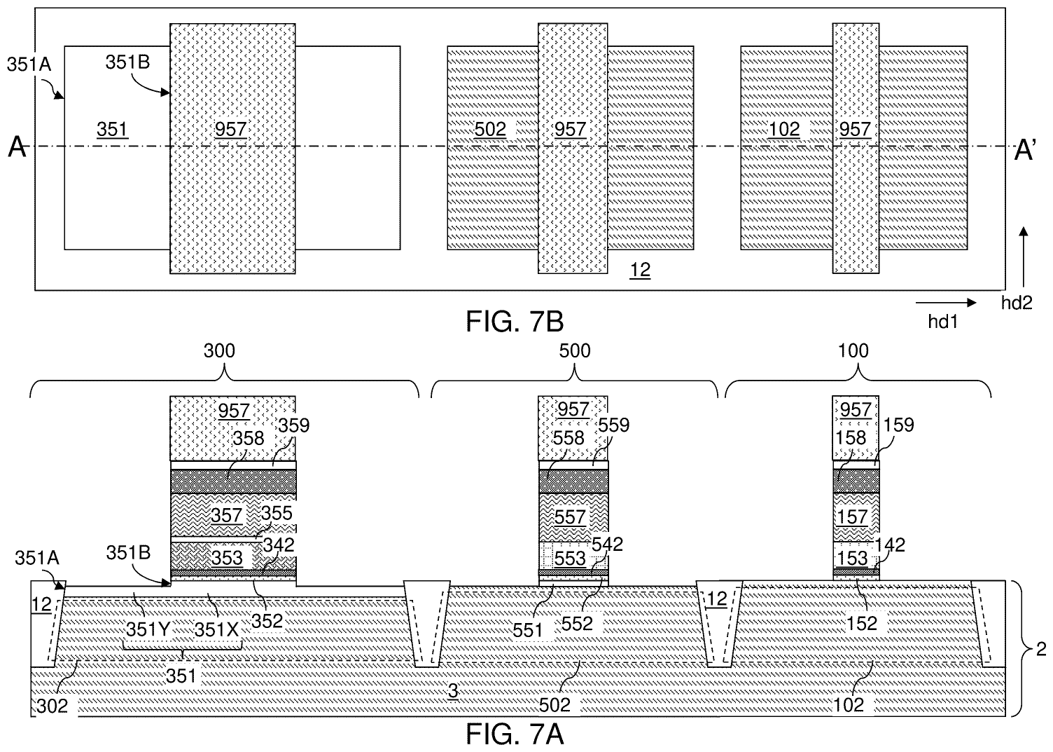

Referring to FIGS. 7A and 7B, a photoresist layer 957 can be applied over the at least one sacrificial gate cap layer (58L, 59L), and can be lithographically patterned into gate electrode patterns, i.e., the patterns of gate electrodes to be subsequently formed. An anisotropic etch process including a sequence of anisotropic etch steps can be performed to transfer the pattern in the photoresist layer 957 through the at least one sacrificial gate cap layer (58L, 59L), the upper gate semiconductor layer 57L, the etch-stop layer 55L, the lower gate semiconductor layer 53L and the optional doped semiconductor material layer 53D, the optional metallic barrier liner layer 42L, and the gate dielectric metal oxide layer 52L. Further, the anisotropic etch process may comprise a terminal etch step that etches the second silicon oxide gate dielectric 551 and an upper portion of the first silicon oxide gate dielectric 351 selectively to the material of the single crystalline semiconductor layer 3. The duration of the terminal etch step may be selected such that the unmasked portions of the second silicon oxide gate dielectric 551 are etched through, but the unmasked portions of the first silicon oxide gate dielectric 351 are only partially etched. The photoresist layer 957 can be subsequently removed by ashing.

Thus, the least one sacrificial gate cap layer (58L, 59L), the upper gate semiconductor layer 57L, the etch-stop layer 55L, the lower gate semiconductor layer 53L and the optional the doped semiconductor material layer 53D, the optional metallic barrier liner layer 42L, and the gate dielectric metal oxide layer 52L are patterned into a first gate structure (152, 142, 153, 157, 158, 159) that is formed in the first device region 100, into a second gate structure (351, 352, 342, 353, 355, 357, 358, 359) that is formed in the second device region 300, and a third gate structure (551, 552, 542, 553, 557, 558, 559) that is formed in the third device region 500. The first gate structure (152, 142, 154, 157, 158, 159) may comprise, from bottom to top, a first metal oxide gate dielectric 152, an optional first metallic barrier liner 142, a first lower semiconductor gate electrode 153, a first upper semiconductor gate electrode 157, a first lower sacrificial gate cap 158, and a first upper sacrificial gate cap 159. The second gate structure (351, 352, 342, 353, 355, 357, 358, 359) may comprise, from bottom to top, a first silicon oxide gate dielectric 351, a second metal oxide gate dielectric 352, an optional second metallic barrier liner 342, a second lower semiconductor gate electrode 353, an etch stop layer 355, a second upper semiconductor gate electrode 357, a second lower sacrificial gate cap 358, and a second upper sacrificial gate cap 359. The third gate structure (551, 552, 542, 553, 557, 558, 559) may comprise, from bottom to top, a second silicon oxide gate dielectric 551, a third metal oxide gate dielectric 552, an optional third metallic barrier liner 542, a third lower semiconductor gate electrode 553, a third upper semiconductor gate electrode 557, a third lower sacrificial gate cap 558, and a third upper sacrificial gate cap 559.

The first gate structure (152, 142, 154, 157, 158, 159) comprises a first gate dielectric 152, which may consist of the first metal oxide gate dielectric 152. The second gate structure (351, 352, 342, 353, 355, 357, 358, 359) comprises a second gate dielectric (351, 352), which comprises a dielectric stack of a first silicon oxide gate dielectric 351 and a second metal oxide gate dielectric 352. Further, the second gate structure (351, 352, 342, 353, 355, 357, 358, 359) comprises the etch-stop layer 355 which is a patterned portion of the etch-stop layer 55L. The third gate structure (551, 552, 542, 553, 557, 558, 559) comprises a third gate dielectric (551, 552), which comprises a dielectric stack of a second silicon oxide gate dielectric 551 and a third metal oxide gate dielectric 552.

In one embodiment, sidewalls of the first gate dielectric 152 are vertically coincident with sidewalls of the first lower semiconductor gate electrode 153; and sidewalls of the second metal oxide gate dielectric 352 are vertically coincident with sidewalls of the second lower semiconductor gate electrode 353 (which is a doped semiconductor gate electrode). The second lower semiconductor gate electrode 353 is a patterned portion of the doped semiconductor material layer 53D. In one embodiment, a bottom surface of the first metal oxide gate dielectric 152 is in direct contact with a channel region of a first field effect transistor to be formed in the first device region 100.

In one embodiment, the first silicon oxide gate dielectric 351 comprises: first sidewalls 351A that are laterally offset outward relative to the sidewalls of the second metal oxide gate dielectric 352; and second sidewalls 351B that are vertically coincident with and are adjoined to the sidewalls of the second metal oxide gate dielectric 352. In one embodiment, the first silicon oxide gate dielectric 351 comprises: a first portion 351X located within an area of the second metal oxide gate dielectric 352 in a plan view and having a first thickness; and a second portion 351Y that does not have any areal overlap in the plan view and having a second thickness that is less than the first thickness.

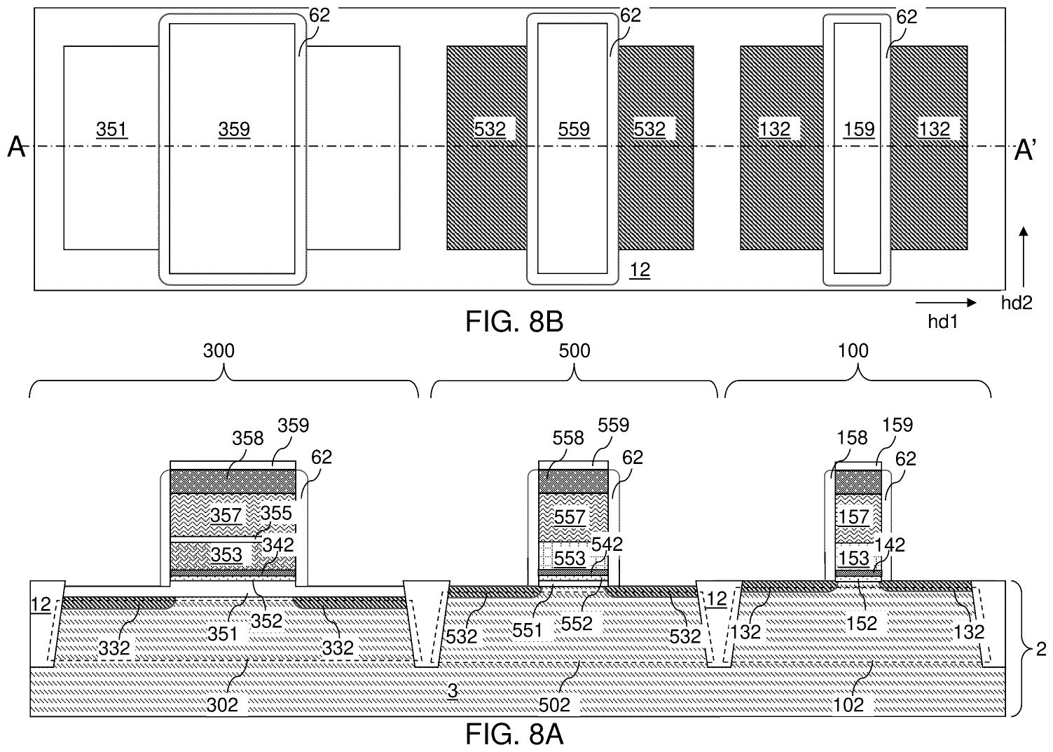

Referring to FIGS. 8A and 8B, an inner dielectric gate spacer material layer may be conformally deposited, and may be subsequently anisotropically etched. The inner dielectric gate spacer material layer comprises a dielectric material, such as silicon nitride. Each remaining vertically-extending portion of the inner dielectric gate spacer material layer constitutes an inner dielectric gate spacer 62. Ion implantation processes may be performed to form source/drain extension regions (132, 332, 532). The source/drain extension regions (132, 332, 532) may comprise first source/drain extension regions 132 that are formed in the first device region 100, second source/drain extension regions 332 that are formed in the second device region 300, and third source/drain extension regions 532 that are formed in the third device region 500.

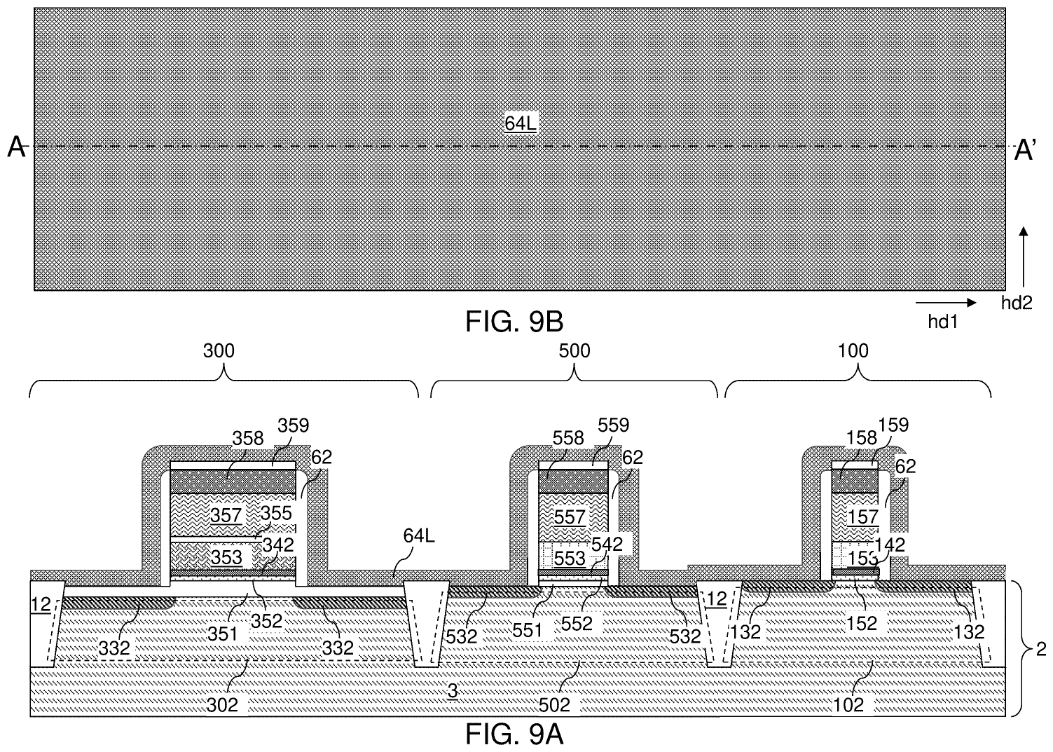

Referring to FIGS. 9A and 9B, an outer dielectric gate spacer material layer 64L may be conformally deposited. The outer dielectric gate spacer material layer 64L comprises at least one dielectric material, such as silicon nitride, silicon oxide or a combination thereof.

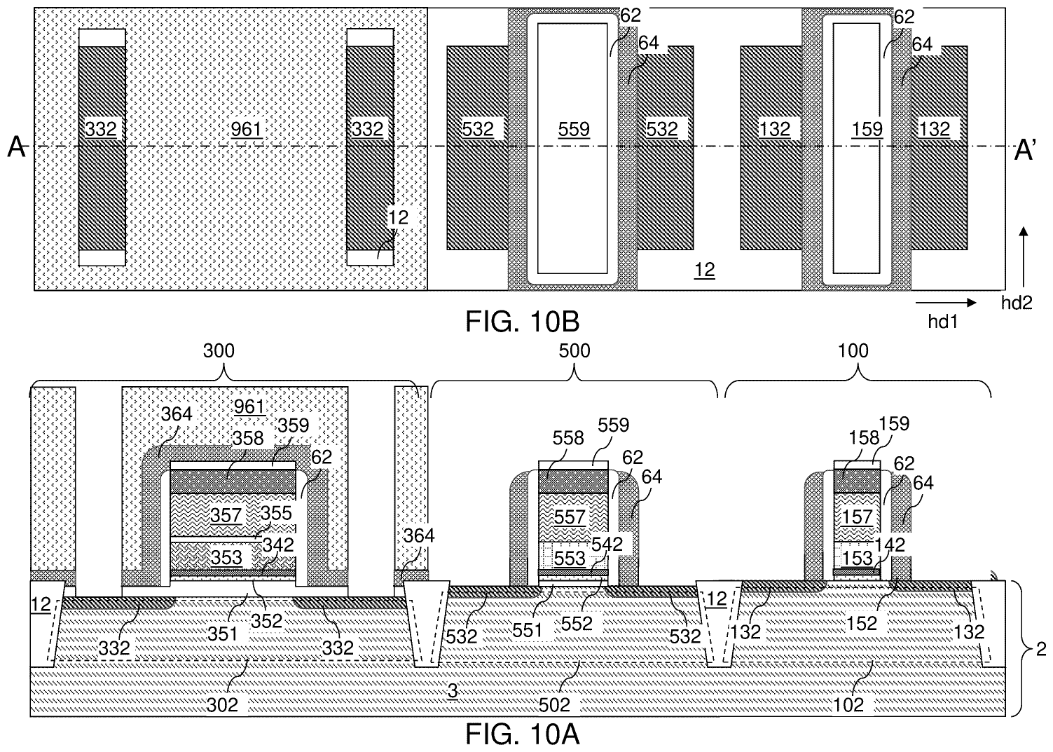

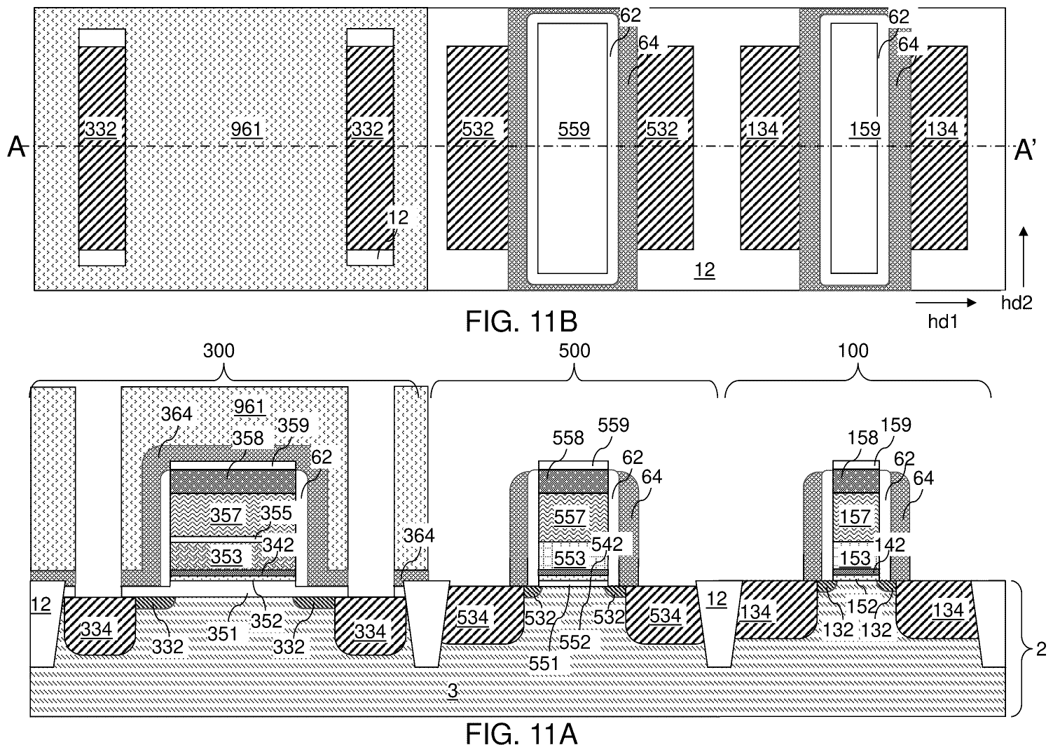

Referring to FIGS. 10A and 10B, a photoresist layer 961 can be applied over the first exemplary structure, and can be lithographically patterned so that the first device region 100 and the third device region 500 are not covered by the photoresist layer 961, and a pair of openings is formed in the photoresist layer 961 in the second device region 300. An anisotropic etch process can be performed to etch unmasked horizontally-extending portions of the outer dielectric gate spacer material layer 64L and the first silicon oxide gate dielectric 351. Each remaining vertically-extending portion of the outer dielectric gate spacer material layer 64L in the first device region 100 and in the third device region 500 constitutes an outer dielectric gate spacer 64. A remaining masked portion of the outer dielectric gate spacer material layer 64L located in the second device region 300 and underlies the photoresist layer 961 comprises an outer dielectric gate spacer layer 364.

Referring to FIGS. 11A and 11B, ion implantation processes may be performed to form deep source/drain regions (134, 334, 534). The deep source/drain regions may have a higher doping concentration than the source/drain extension regions to form the LDD structure. The deep source/drain regions (134, 334, 534) may comprise first deep source/drain regions 134 that are formed in the first device region 100, second deep source/drain regions 334 that are formed in the second device region 300, and third deep source/drain regions 534 that are formed in the third device region 500. Each contiguous combination of a first source/drain extension region 132 and a first deep source/drain region 134 constitutes a first source/drain region (132, 134). Each contiguous combination of a second source/drain extension region 332 and a second deep source/drain region 334 constitutes a second source/drain region (332, 334). Each contiguous combination of a third source/drain extension region 532 and a third deep source/drain region 534 constitutes a third source/drain region (532, 534). The photoresist layer 961 can be subsequently removed, for example, by ashing.

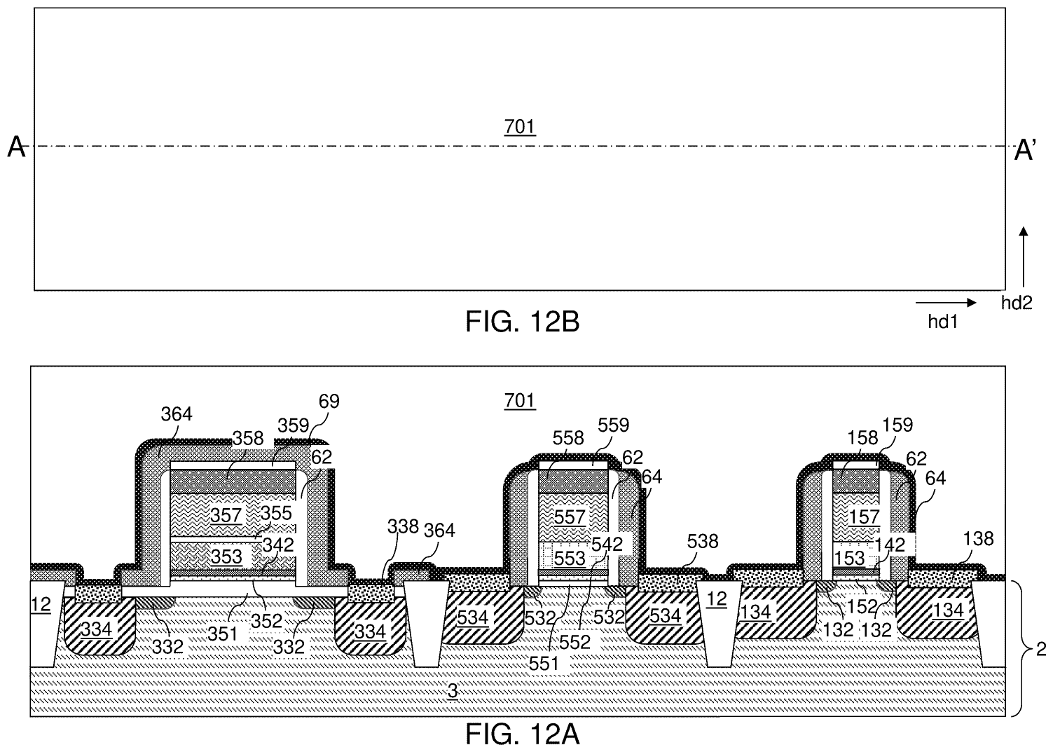

Referring to FIGS. 12A and 12B, a metal layer can be deposited over the first exemplary structure. The metal layer comprises, and/or consists essentially of, at least one elemental metal, such as Ti, W, Ta, Ni, Pt, Mo or an alloy thereof, that forms a metal-semiconductor alloy (such as a metal silicide) with the semiconductor material of the various deep source/drain regions (134, 334, 534). An anneal can be performed to form various metal-semiconductor alloy regions (138, 338, 538) that includes a metal-semiconductor alloy (such as a metal silicide, for example a silicide of Ti, W, Ta, Ni, Pt, Mo or a combination thereof) of the at least one elemental metal and the semiconductor material in the upper portions of the various deep source/drain regions (134, 334, 534). Unreacted portions of the metal layer can be removed selectively to the various metal-semiconductor alloy regions (138, 338, 538), for example, by performing a selective wet etch process. The metal-semiconductor alloy regions (138, 338, 538) may comprise first metal-semiconductor alloy regions 138 that are formed on the first deep source/drain regions 134, second metal-semiconductor alloy regions 338 that are formed on the second deep source/drain regions 334, and third metal-semiconductor alloy regions 538 that are formed on the third deep source/drain regions 534.

A dielectric diffusion barrier layer 69 may be deposited over the various gate structures and the various metal-semiconductor alloy regions (138, 338, 538). The dielectric diffusion barrier layer 69 may comprise a dielectric diffusion barrier material, such as silicon nitride or silicon carbonitride. A planarization dielectric layer 701 can be formed over the dielectric diffusion barrier layer 69. The planarization dielectric layer 701 comprises a planarizable dielectric material, such as undoped silicate glass or a doped silicate glass.

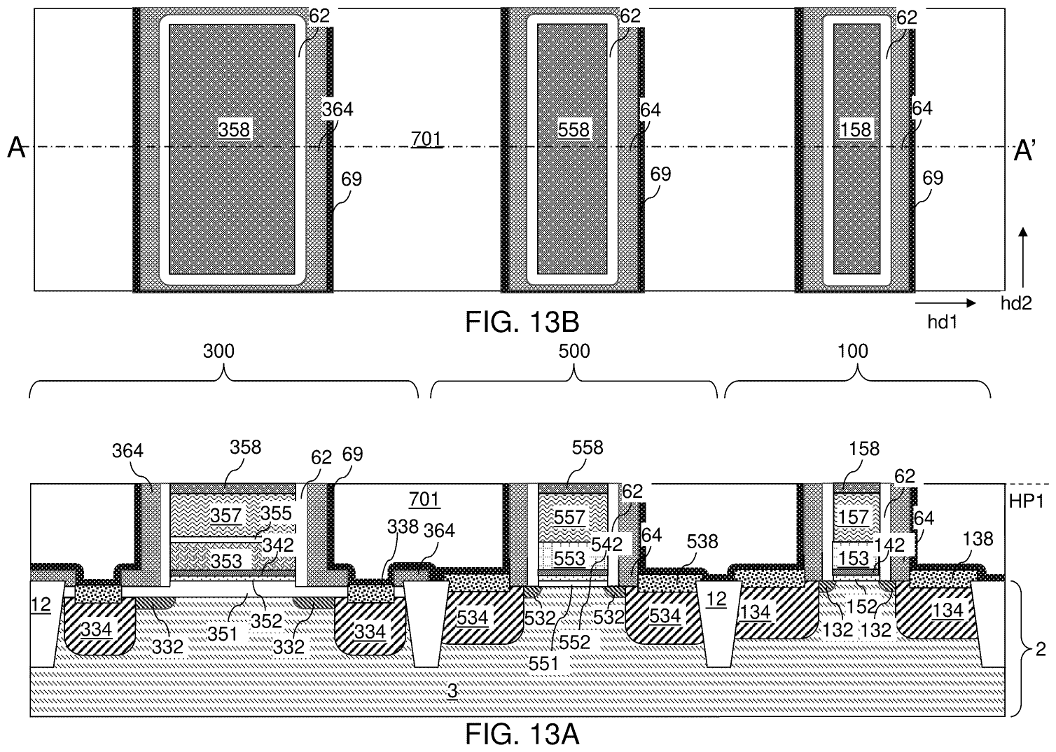

Referring to FIGS. 13A and 13B, a planarization process, such as a chemical mechanical polishing (CMP) process, can be performed to remove portions of the planarization dielectric layer 701 and portions of the sacrificial gate caps (158, 159, 358, 359, 558, 559) from above a first horizontal plane HP1 that overlies the top surfaces of the upper semiconductor gate electrodes (157, 357, 557). The lower sacrificial gate caps (158, 358, 558) may act as a polish stop during the CMP. In one embodiment, the first horizontal plane HP1 may be located below the horizontal plane including interfaces between the lower sacrificial gate caps (158, 358, 558) and the upper sacrificial gate caps (159, 359, 559). The planarization process may remove the entirety of all upper sacrificial gate caps (159, 359, 559) and remove upper portions of all lower sacrificial gate caps (158, 358, 558).

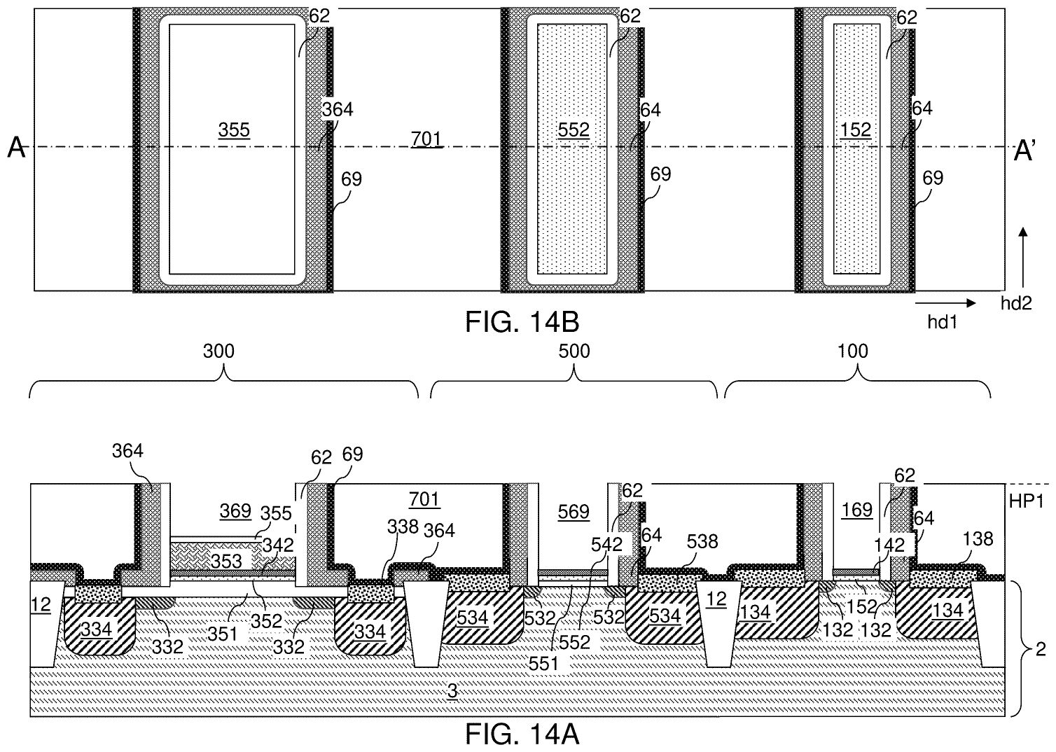

Referring to FIGS. 14A and 14B, a selective etch process can be performed to remove the lower sacrificial gate caps (158, 358, 558). For example, if the lower sacrificial gate caps (158, 358, 558) comprise silicon nitride, a wet etch process employing hot phosphoric acid may be performed to remove the lower sacrificial gate caps (158, 358, 558) without removing the upper semiconductor gate electrodes (157, 357, 557).

A first selective etch process can be subsequently performed to remove the first upper semiconductor gate electrode 157, the second upper semiconductor gate electrode 357, the third upper semiconductor gate electrode 557, the first lower semiconductor gate electrode 153, and the third lower semiconductor gate electrode 553 selectively to the materials of the metallic barrier liners (142, 342, 542) and the etch-stop layer 355. For example, the first selective etch process may comprise a wet etch process using hot trimethyl-2 hydroxyethyl ammonium hydroxide (“hot TMY”) or tetramethyl ammonium hydroxide (TMAH).

In summary, a first selective etch process can be performed which etches materials of the upper gate semiconductor layer 57L and the lower gate semiconductor layer 53L selectively to the material of the metallic barrier liners (142, 342, 542) and selectively to the material of the etch-stop layer 355. A first gate cavity 169 is formed over the first metal oxide gate dielectric 152 in the first device region 100, a second gate cavity 369 is formed over the etch-stop layer 355 in the second device region 300, and a third gate cavity 569 is formed over the third metal oxide gate dielectric 552 in the third device region 500.

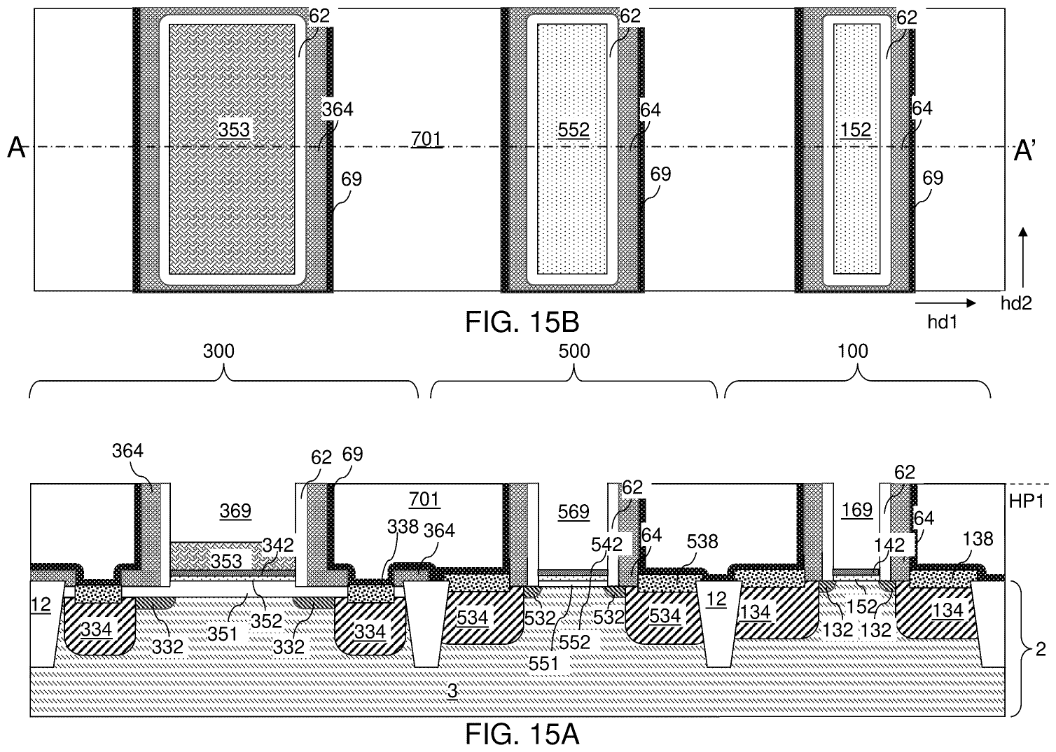

Referring to FIGS. 15A and 15B, a second selective etch process can be performed to remove the etch-stop layer 355 selectively to the material of the second lower semiconductor gate electrode 353 and selectively to the materials of the metallic barrier liners (142, 342, 542).

Gate cavities (169, 369, 569) are formed in the volumes from which the materials of the lower sacrificial gate caps (158, 358, 558), the first upper semiconductor gate electrode 157, the second upper semiconductor gate electrode 357, the third upper semiconductor gate electrode 557, the first lower semiconductor gate electrode 153, the third lower semiconductor gate electrode 553, and the etch-stop layer 355 are removed. The gate cavities (169, 369, 569) comprise a first gate cavity 169 that is formed within a fraction of the volume of the first gate structure in the first device region 100, a second gate cavity 169 that is formed within a fraction of the volume of the second gate structure in the second device region 300, and a third gate cavity 569 that is formed within a fraction of the volume of the third gate structure in the third device region 500. The first metallic barrier liner 142 and the third metallic barrier liner 542 may protect the first metal oxide gate dielectric 152 and the third metal oxide gate dielectric 552 during formation of the gate cavities (169, 369, 569).

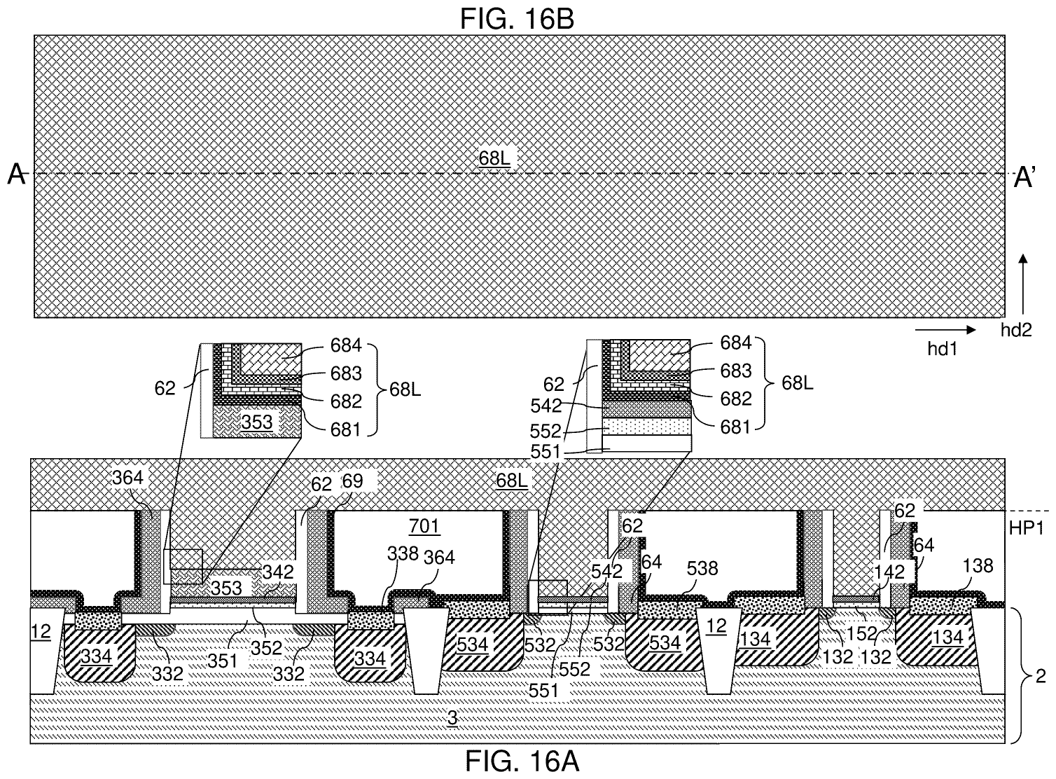

Referring to FIGS. 16A and 16B, a replacement metallic material layer 68L can be deposited in the gate cavities (169, 369, 569) and over the planarization dielectric layer 701. The replacement metallic material layer 68L comprises and/or consist of at least one metallic material. For example, the replacement metallic material layer 68L may comprise at least one metallic liner (681, 682, 683) and at least one metallic fill material portion 684. In one embodiment, the at least one metallic liner (681, 682, 683) may comprise a plurality of metallic liners (681, 682, 683) such as a first metallic liner 681, a second metallic liner 682, and a third metallic liner 683. In an illustrative example, the first metallic liner 681 may comprise a tantalum nitride layer, the second metallic liner 682 may comprise an alloy of titanium and aluminum (i.e., TiAl), and the third metallic liner 683 may comprise a stack of a titanium layer and a titanium nitride layer. The at least one metallic fill material portion 684 may comprise at least one refractory metal, such as tungsten, molybdenum or tantalum.

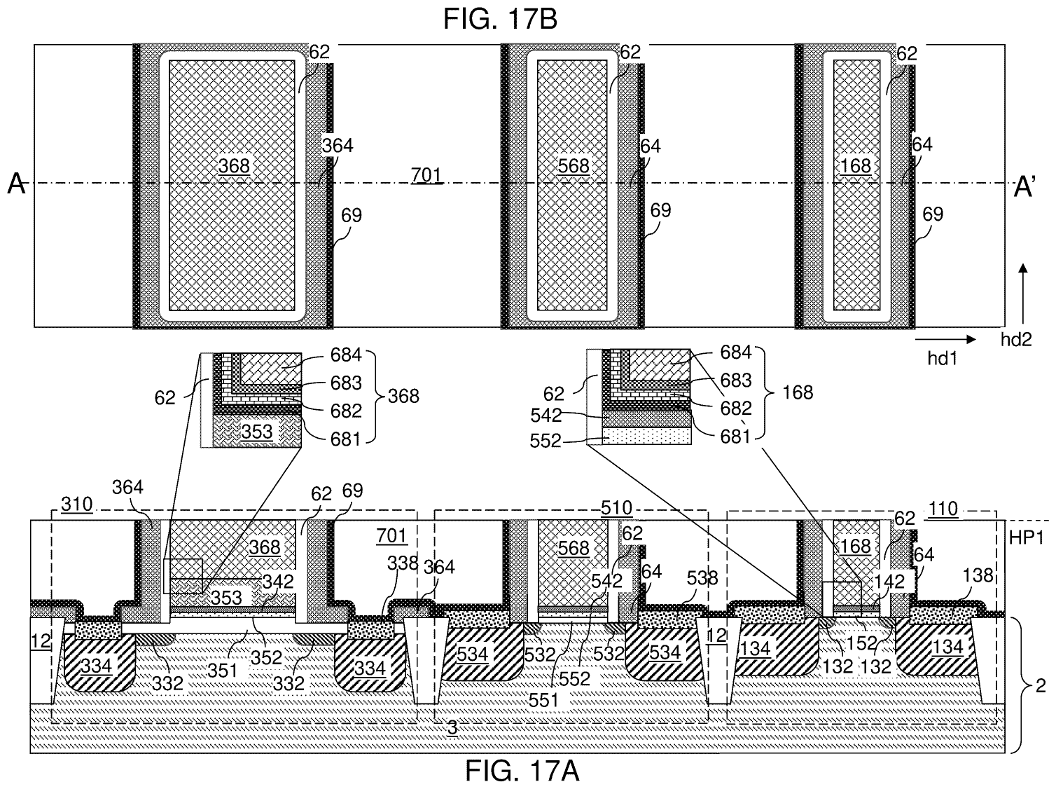

Referring to FIGS. 17A and 17B, the replacement metallic material layer 68L may be removed from above the first horizontal plane HP1 by performing a planarization process, such as a chemical mechanical polishing process. Remaining portions of the replacement metallic material layer 68L comprise a first metallic gate electrode 168 that is formed in the first device region 100, a second metallic gate electrode 368 that is formed in the second device region 300, and a third metallic gate electrode 568 that is formed in the third device region 500.

Thus, a first patterned portion of the upper gate semiconductor layer 57L and a patterned portion of the lower gate semiconductor layer 53L in the first gate structure (152, 142, 154, 157, 158, 159) is replaced with a first metallic gate electrode 168; a second patterned portion of the upper gate semiconductor layer 57L and a patterned portion of the etch-stop layer 55L in the second gate structure (351, 352, 342, 353, 355, 357, 358, 359) is replaced with a second metallic gate electrode 368; and a third patterned portion of the upper gate semiconductor layer 57L and a patterned portion of the lower gate semiconductor layer 53L in the third gate structure (551, 552, 542, 553, 557, 558, 559) is replaced with a third metallic gate electrode 568. The second metallic gate electrode 368 is formed directly on a top surface of the second lower semiconductor gate electrode 353 (which comprises a remaining patterned portion of the lower gate semiconductor layer 53L that is present within the second gate structure (351, 352, 342, 353, 355, 357, 358, 359) at the processing steps of FIGS. 7A and 7B).

A first field effect transistor 110 is formed in the first device region 100; a second field effect transistor 310 is formed in the second device region 300, and a third field effect transistor 510 is formed in the third device region 500. The first field effect transistor 110 comprises a very low voltage field effect transistor that is configured to operate at a low voltage. The second field effect transistor 310 comprises a high voltage field effect transistor that is configured to operate at a high voltage which is higher than the low voltage. The third field effect transistor 510 comprises a low voltage field effect transistor that is configured to operate at an intermedial voltage between the low voltage and the high voltage.

The first field effect transistor 110 comprises first source/drain regions (132, 134) located in a first portion of a semiconductor substrate 2, a first gate dielectric comprising that first metal oxide gate dielectric 152 that comprises a first portion of a dielectric metal oxide material, and a first gate electrode 168 comprising a first metallic gate electrode 168 contacting a top surface of the first gate dielectric 152. The second field effect transistor 310 comprises second source/drain regions (332, 334) located in a second portion of the semiconductor substrate 2, a second gate dielectric (351 and optionally 352) comprising a dielectric vertical stack of a first silicon oxide gate dielectric 351 and an optional second metal oxide gate dielectric 352 that comprises a second portion of the dielectric metal oxide material, and a second gate electrode (353, 368) comprising a vertical stack (353, 368) of a doped semiconductor (e.g., polysilicon) gate electrode 353 and a second metallic gate electrode 368.

In one embodiment, a topmost surface of the second gate electrode (353, 368) is located within a horizontal plane (such as the first horizontal plane HP1) containing a topmost surface of the first gate electrode 168. In one embodiment, the first metallic gate electrode 168 has a greater vertical extent than the second metallic gate electrode 368. In one embodiment, a vertical extent of the first metallic gate electrode 168 is not less than a total vertical extent of the vertical stack (353, 368). In one embodiment, the first metallic gate electrode 168 has a smaller lateral extent than the second metallic gate electrode 368.

In one embodiment, the first metallic gate electrode 168 comprises a first portion of at least one metallic material; and the second metallic gate electrode 368 comprises a second portion of the at least one metallic material. For each metallic material portion located within the first metallic gate electrode 168, a corresponding metallic material portion having a same material composition is present in the second metallic gate electrode 368; and for each metallic material portion located within the second metallic gate electrode 368, a corresponding metallic material portion having a same material composition is present in the first metallic gate electrode 168.

In one embodiment, the first metallic gate electrode 168 comprises at least one first metallic liner (681, 682, 683) each having a respective first horizontally-extending portion and a respective first tubular portion that vertically extends upward from a periphery of the respective first horizontally-extending portion; and the second metallic gate electrode 368 comprises at least one second metallic liner (681, 682, 683) each having a respective second horizontally-extending portion and a respective second tubular portion that vertically extends upward from a periphery of the respective second horizontally-extending portion. For each first metallic liner (681, 682, 683) located within the first metallic gate electrode 168, a corresponding second metallic liner (681, 682, 683) having a same material composition and a same thickness is present in the second metallic gate electrode 368; and for each second metallic liner (681, 682, 683) located within the second metallic gate electrode 368, a corresponding first metallic liner (681, 682, 683) having a same material composition and a same thickness is present in the first metallic gate electrode 168.

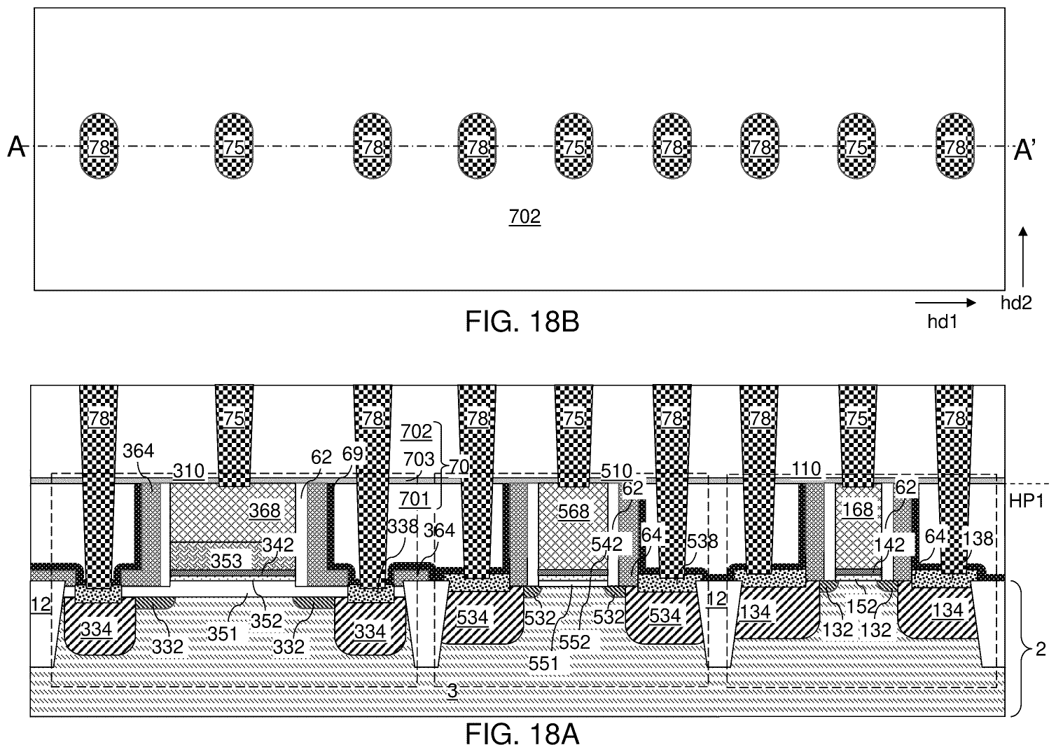

Referring to FIGS. 18A and 18B, an optional etch stop layer (e.g., silicon nitride) 703 and a cover dielectric layer 702 can be formed over the planarization dielectric layer 701. The cover dielectric layer 702 comprises a dielectric material such as undoped silicate glass or a doped silicate glass. The combination of the planarization dielectric layer 701, the etch stop layer 703 and the cover dielectric layer 702 constitutes a contact-level dielectric layer 70. Various contact via structures (75, 78) can be formed through the contact-level dielectric layer 70 on a respective one of the metallic gate electrodes (168, 358, 568) and the metal-semiconductor alloy regions (138, 338, 538). The various contact via structures (75, 78) may comprise source/drain contact via structures 78 contacting a respective one of the metal-semiconductor alloy regions (138, 338, 538), and gate contact via structures 75 contacting a respective one of the metallic gate electrodes (168, 358, 568).

In the first embodiment, the high voltage transistor 310 includes a thicker gate dielectric 351 than the low voltage transistor 510 and the very low voltage transistor 110. The use of the doped polysilicon gate electrode 353 located over the thick silicon oxide gate dielectric 351 improves the high voltage transistor reliability and provides improved control of the transistor threshold voltage. Thus, the high voltage transistor 310 includes a multilayer gate electrode (353, 368) comprising a polysilicon layer 353 and at least one metallic (i.e., metal and/or metal alloy) layer 368. The at least one metallic layer 368 acts as an etch stop to prevent etching through the polysilicon layer 353 during etching of a via cavity that is subsequently filled with the gate contact via structure 75. In contrast, the lower voltage transistor 510 and the very low voltage transistor 110 have relatively thin gate dielectrics. Therefore, these transistors (510, 110) may include only metallic gate electrodes (168, 568) without underlying polysilicon gate electrode layers. Furthermore, since the very low voltage transistor 110 operates at the lower voltage, it may include only the metal oxide gate dielectric 152, while the low voltage transistor 510 which operates at a higher voltage may include a bilayer gate dielectric including a silicon oxide layer 551 and a metal oxide layer 552.

While embodiments are described in which the metallic barrier liners (142, 342, 542) are present in the gate structures of the field effect transistors (110, 310, 510), in alternative embodiments, these metallic barrier liners (142, 342, 542) are omitted. In the second embodiment described below, the second metallic barrier liner 342 and the second metal oxide gate dielectric 352 are omitted from the final high voltage transistor 310 structure. This ensures that the doped polysilicon gate electrode 353 is located directly on the thick silicon oxide gate dielectric 351, which further improves the high voltage transistor reliability and threshold voltage control.

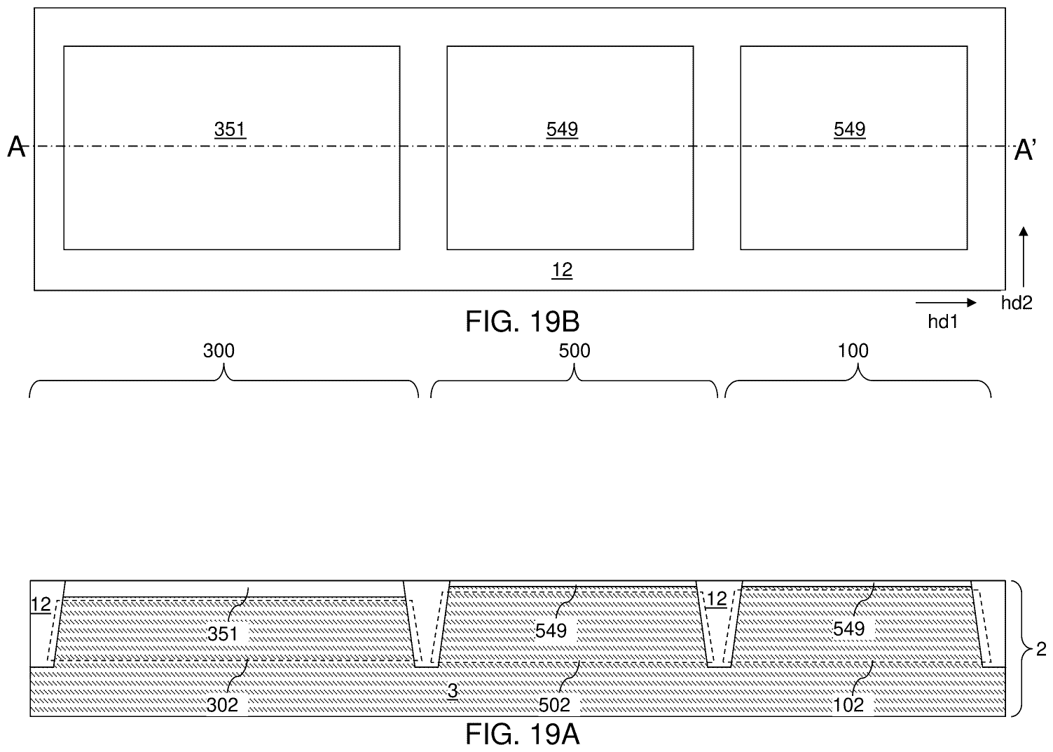

Referring to FIGS. 19A and 19B, a second exemplary structure according to the second embodiment of the present disclosure is illustrated. The second exemplary structure can be derived from the first exemplary structure illustrated in FIGS. 1A and 1B by forming a first silicon oxide gate dielectric 351 in the second device region 300 and by forming sacrificial silicon oxide layers 549 in the first device region 100 and in the third device region 500. The first silicon oxide gate dielectric 351 can be formed employing the methods described with reference to FIGS. 2A and 2B. The sacrificial silicon oxide layers 549 may be formed by performing a surface oxidation process, such as a thermal oxidation process. Generally, a first silicon oxide gate dielectric 351 can be formed on a top surface segment of a semiconductor substrate 2. The first silicon oxide gate dielectric 351 is not present in the first device region 100, and is present in the second device region 300.

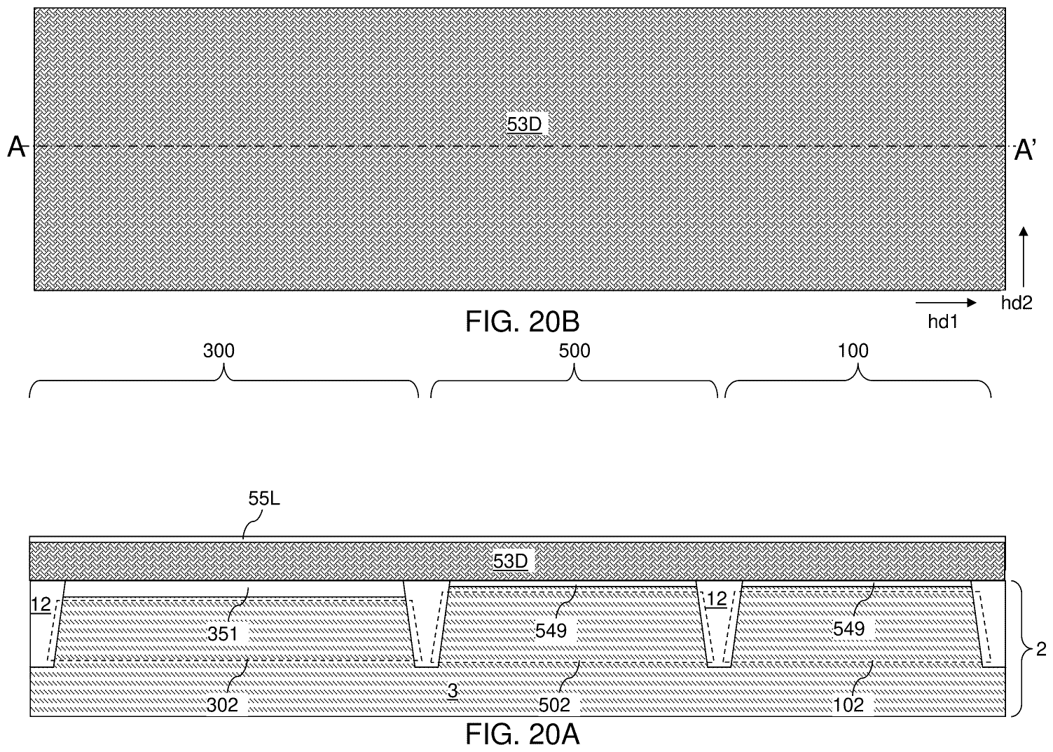

Referring to FIGS. 20A and 20B, a doped semiconductor material layer 53D can be formed over the first silicon oxide gate dielectric 351 and the sacrificial silicon oxide layers 549 by depositing a doped semiconductor material, or by depositing an undoped semiconductor material and doping the deposited semiconductor material, for example, by ion implantation. The doped semiconductor material layer 53D may have the same material composition and the same thickness as the doped semiconductor material layer 53D described with reference to FIGS. 4A and 4B.

A dielectric etch stop layer 55L is optionally formed over the doped semiconductor material layer 53D at this step by deposition (e.g., chemical vapor deposition or atomic layer deposition) or by oxidation of a surface of the doped semiconductor material layer 53D. In one embodiment, the dielectric etch stop layer 55L comprises silicon oxide.

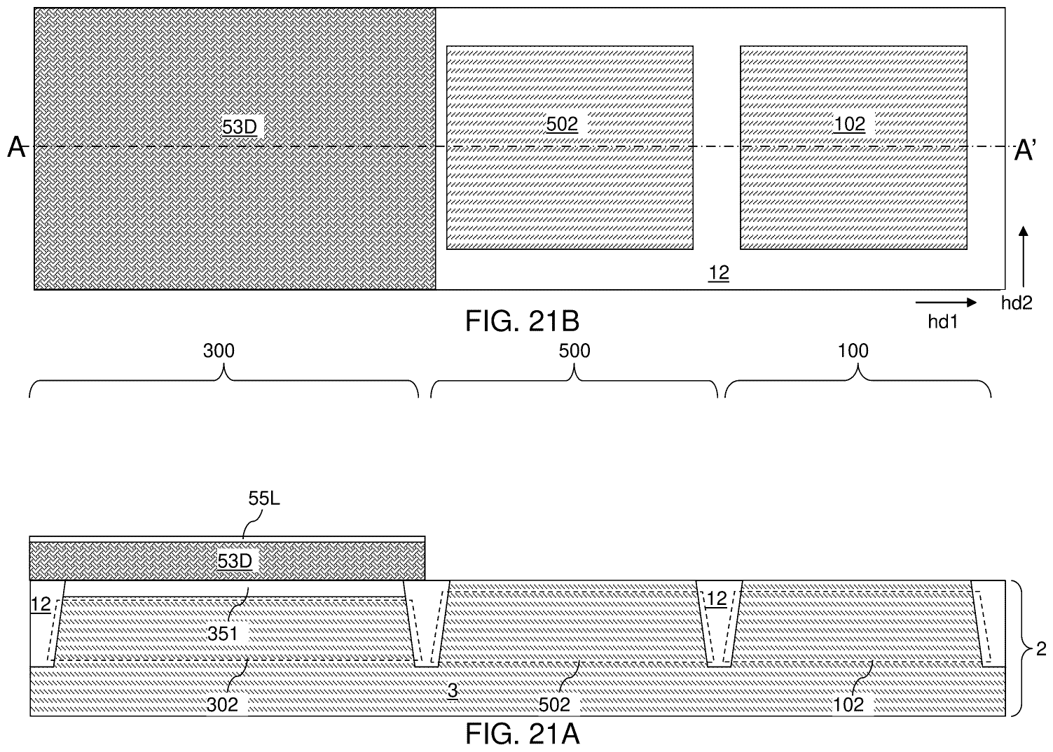

Referring to FIGS. 21A and 21B, a photoresist layer (not shown) can be applied over the doped semiconductor material layer 53D and the dielectric etch stop layer 55L, and can be lithographically patterned to cover the second device region 300 without covering the first device region 100 or the third device region 500. A selective etch process can be performed to etch the materials of the dielectric etch stop layer 55L and the doped semiconductor material layer 53D selectively to the material of the sacrificial silicon oxide layers 549. The selective etch process may comprise an anisotropic etch process (such as a reactive ion etch process) or an isotropic etch process (such as a wet etch process). Subsequently, the sacrificial silicon oxide layers 549 can be removed selectively to the material of the single crystalline semiconductor layer 3. For example, a wet etch process employing dilute hydrofluoric acid may be employed to remove the sacrificial silicon oxide layers 549.

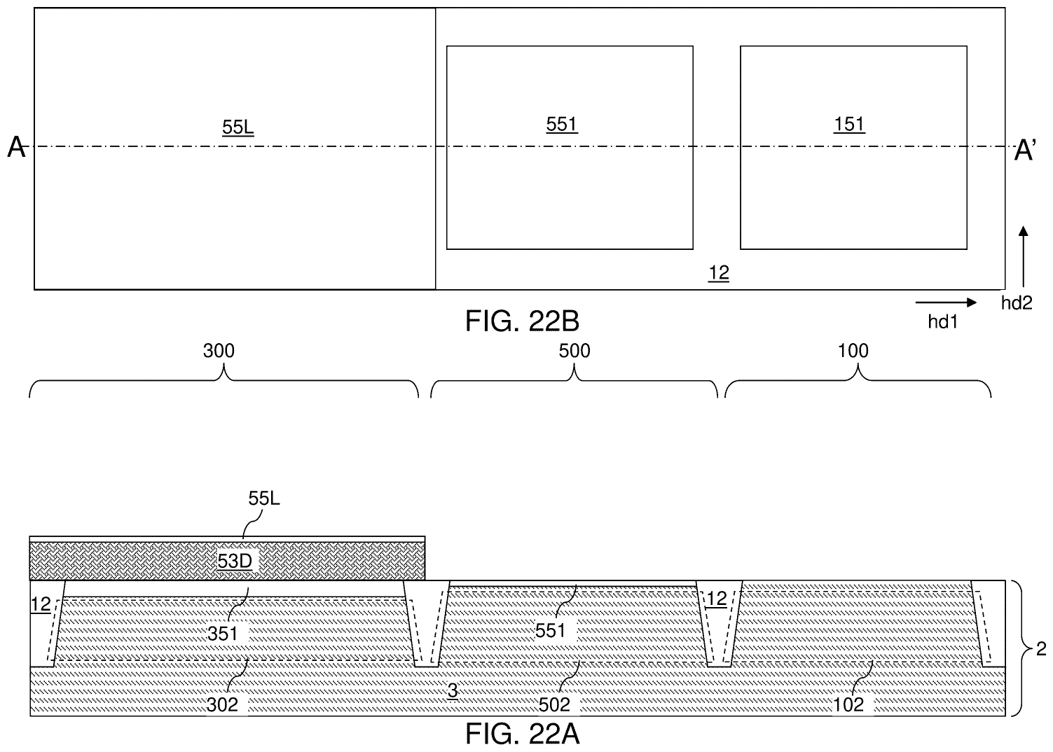

Referring to FIGS. 22A and 22B, if the dielectric etch stop layer 55L has not yet been formed, then the dielectric etch-stop layer 55L may be formed on the top surface of the doped semiconductor material layer 53D. In one embodiment, a thermal oxidation process may be performed to convert physically exposed surface portions of the doped semiconductor material layer 53D. In this case, the etch-stop layer 55L may comprise a semiconductor oxide material, such as silicon oxide. In one embodiment, at least one silicon oxide gate dielectric (such as a second silicon oxide gate dielectric 551) may be formed in at least one device region other than the second device region 300 (such as the third device region 500). In one embodiment, the thermal oxidation process may concurrently form the etch-stop layer 55L and the at least one silicon oxide gate dielectric (such as the second silicon oxide gate dielectric 551). In one embodiment, silicon oxide material layers formed in the first device region 100 may be removed, for example, by covering the second device region 300 and the third device region 500 with a patterned photoresist layer, and by performing a wet etch process that etches a silicon oxide material (such as a wet etch process employing dilute hydrofluoric acid).

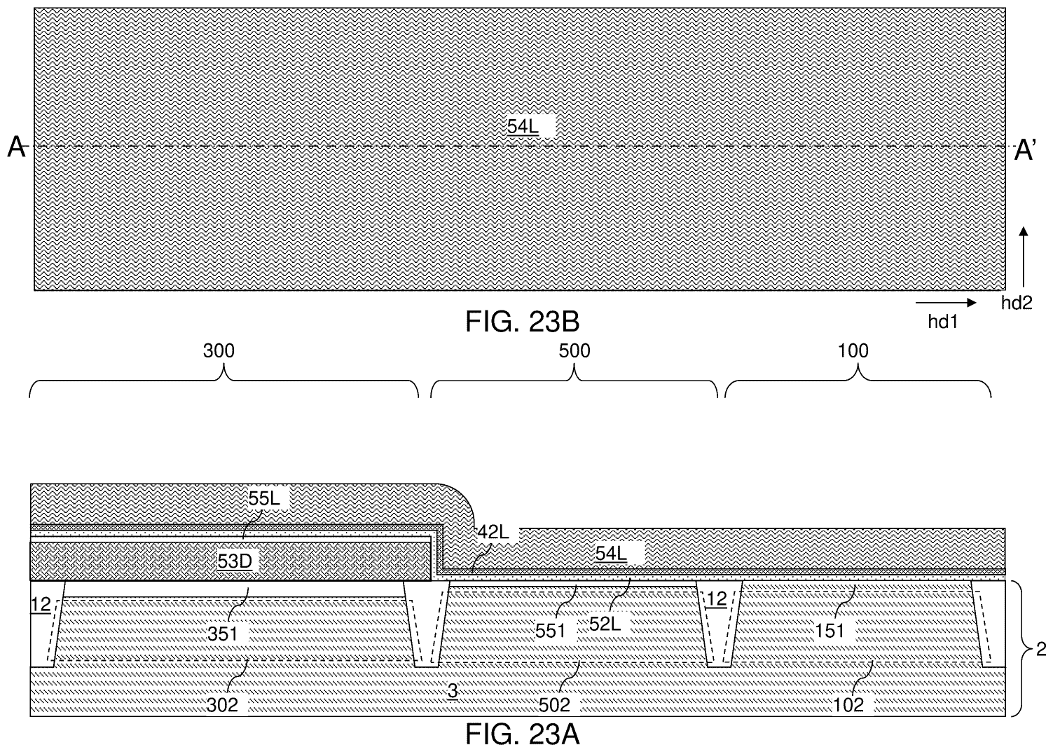

Referring to FIGS. 23A and 23B, a gate dielectric metal oxide layer 52L, an optional metallic barrier liner layer 42L, and an intermediate gate semiconductor layer 54L can be sequentially deposited. The gate dielectric metal oxide layer 52L may comprise any metal oxide gate dielectric material described above. The gate dielectric metal oxide layer 52L can be formed on the second silicon oxide gate dielectric 551 and directly on a top surface segment of the semiconductor substrate 2 in the first device region 100.

The intermediate gate semiconductor layer 54L comprises a semiconductor material, which may comprise a doped semiconductor material or an undoped semiconductor material. For example, the intermediate gate semiconductor layer 54L may comprise amorphous silicon or polysilicon. The thickness of the intermediate gate semiconductor layer 54L can be selected such that the top surface of the portion of the intermediate gate semiconductor layer 54L in the first device region 100 and in the third device region 500 is located above the horizontal plane including the top surface of the portion of the etch-stop layer 55L located in the second device region 300.

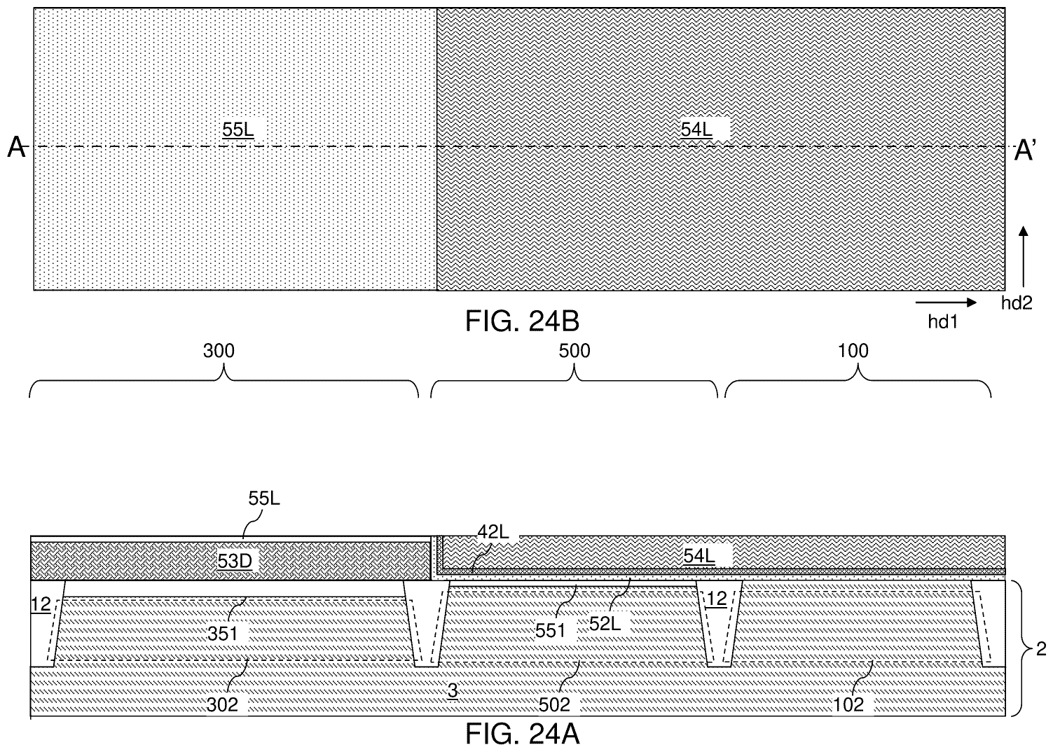

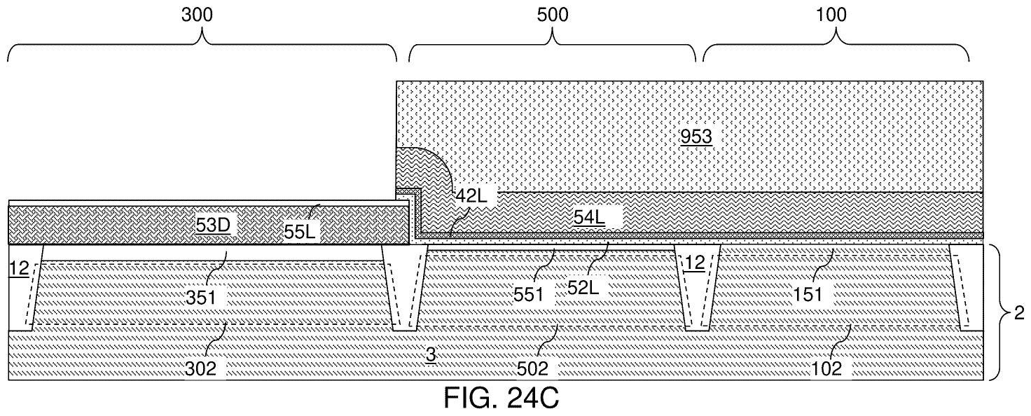

Referring to FIGS. 24A and 24B, a planarization process may be performed to remove portions of the intermediate gate semiconductor layer 54L located above the horizontal plane including the top surface of the portion of the etch-stop layer 55L located in the second device region 300. For example, a photoresist layer (not shown) may cover a portion of the second exemplary structure in which the doped semiconductor material layer 53D is not present, and a recess etch process may be performed to recess unmasked portions of the intermediate gate semiconductor layer 54L. The photoresist layer may be subsequently removed, for example, by ashing. Alternatively or additionally, a chemical mechanical polishing process may be performed to remove a portion of the intermediate gate semiconductor layer 54L that overlies the doped semiconductor material layer 53D. In this case, the portion of the metallic barrier liner layer 42L that overlies the doped semiconductor material layer 53D may be employed as a stopper layer during the chemical mechanical polishing process. The portion of the metallic barrier liner layer 42L that overlies the doped semiconductor material layer 53D can be subsequently removed by a touch-up polishing process or a selective etch process (such as a wet etch process) selectively to the material of the etch-stop layer 55L.

In the embodiment illustrated in FIG. 24A, all material portions overlying a horizontal plane including the topmost surface of the etch-stop layer 55L are removed by performing at least one planarization process, which may employ at least one etch process and/or at least one polishing process.

In an alternative embodiment illustrated in FIG. 24C, if masking and etching are used to remove the intermediate gate semiconductor layer 54L, the metallic barrier liner layer 42L and the gate dielectric metal oxide layer 52L, then portions of these layers may remain over the topmost surface of the etch-stop layer 55L. For example, the photoresist mask 953 used during the etching step may overlap the area of the etch-stop layer 55L in the second device region 300.

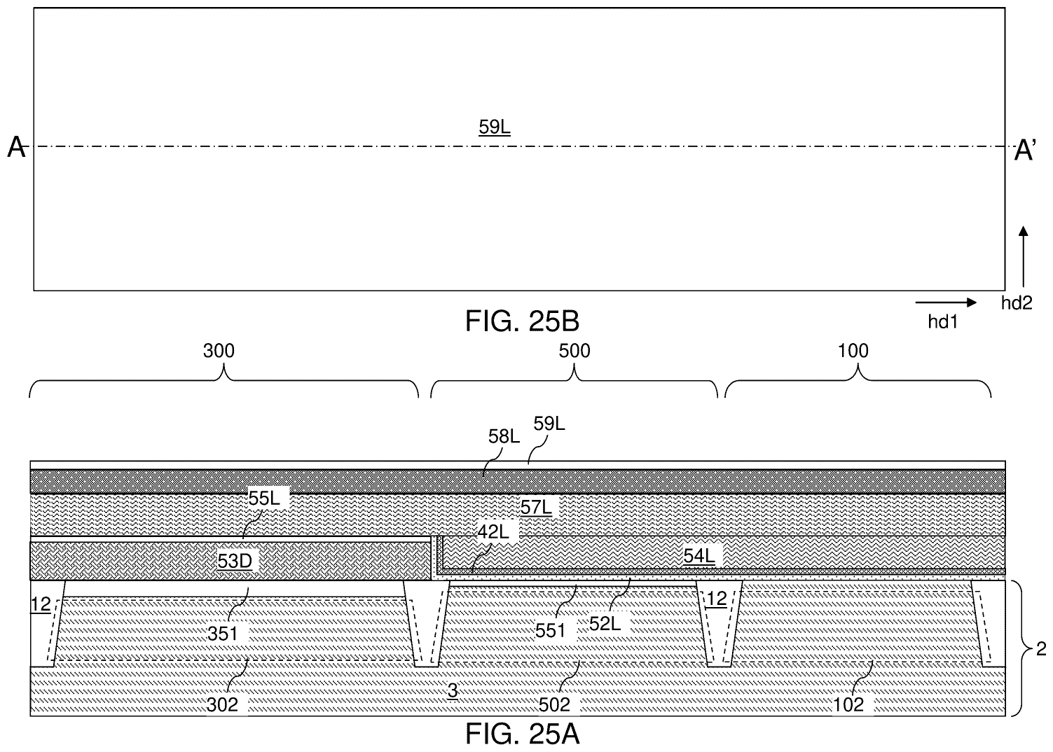

Referring to FIGS. 25A and 25B, an upper gate semiconductor layer 57L and at least one sacrificial gate cap layer (58L, 59L) that are described above can be sequentially formed.

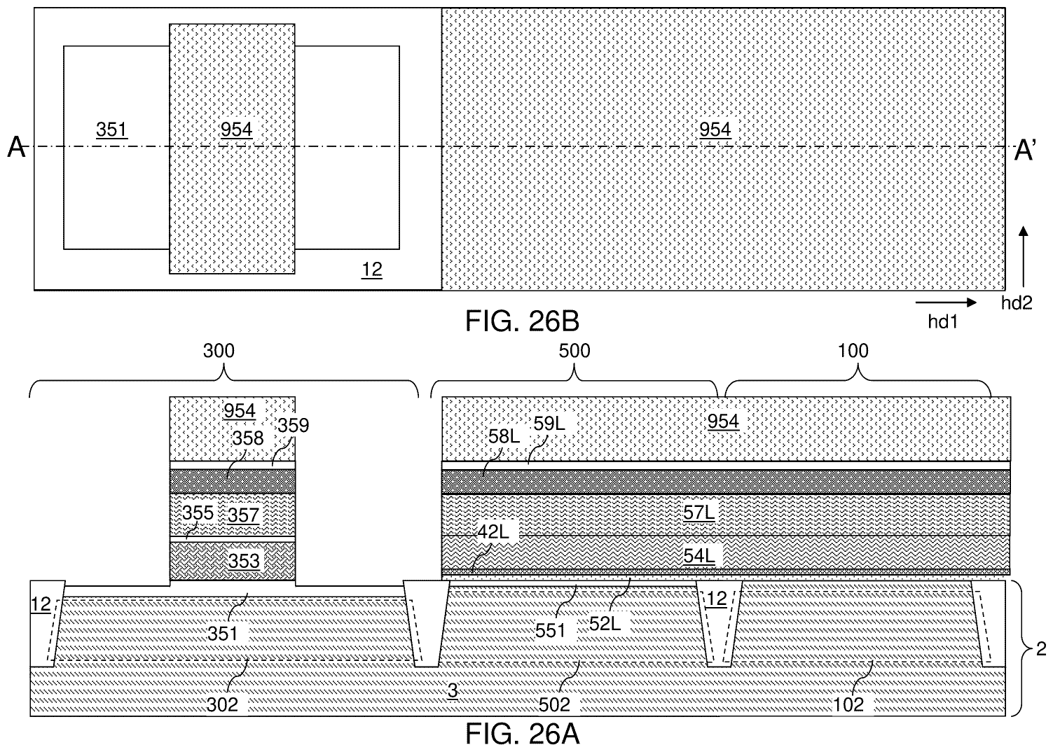

Referring to FIGS. 26A and 26B, a photoresist layer 954 can be applied over the second exemplary structure, and can be lithographically patterned to cover the first device region 100 and the third device region 500, and to cover the area of a gate electrode for a field effect transistor to be formed in the second device region 300. An anisotropic etch process including a sequence of anisotropic etch steps can be performed to transfer the pattern in the photoresist layer 954 through the at least one sacrificial gate cap layer (58L, 59L), the upper gate semiconductor layer 57L, the etch-stop layer 55L, and the doped semiconductor material layer 53D. Further, the anisotropic etch process may comprise a terminal etch step that etches an upper portion of the first silicon oxide gate dielectric 351. The duration of the terminal etch step may be selected such that the unmasked portions of the first silicon oxide gate dielectric 351 are only partially etched. The photoresist layer 954 can be subsequently removed by ashing.

A second gate structure (351, 353, 355, 357, 358, 359) is formed in the second device region 300. The second gate structure (351, 353, 355, 357, 358, 359) may comprise, from bottom to top, a first silicon oxide gate dielectric 351, a second lower semiconductor gate electrode 353, a dielectric etch stop layer 355, a second upper semiconductor gate electrode 357, a second lower sacrificial gate cap 358, and a second upper sacrificial gate cap 359.

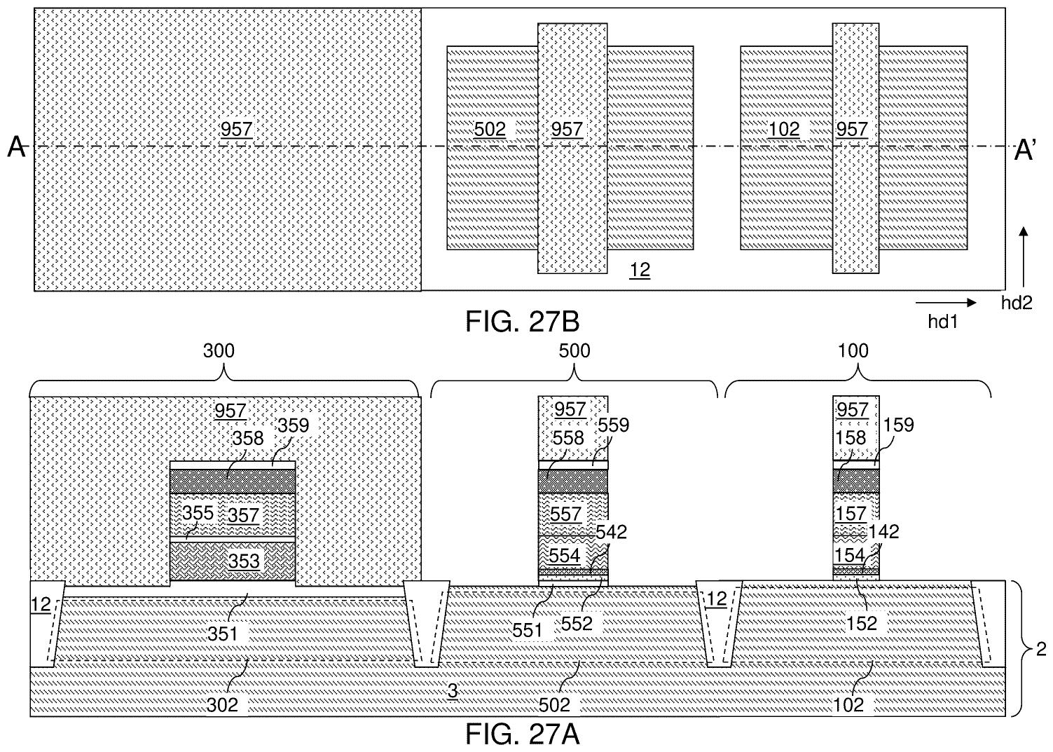

Referring to FIGS. 27A and 27B, a photoresist layer 957 can be applied over the at least one sacrificial gate cap layer (58L, 59L), and can be lithographically patterned to cover the second device region 300 and to cover areas of gate electrode patterns in the first device region 100 and in the third device region 500. An anisotropic etch process including a sequence of anisotropic etch steps can be performed to transfer the pattern in the photoresist layer 957 through the at least one sacrificial gate cap layer (58L, 59L), the upper gate semiconductor layer 57L, the intermediate gate semiconductor layer 54L, the optional metallic barrier liner layer 42L, and the gate dielectric metal oxide layer 52L. Further, the anisotropic etch process may comprise a terminal etch step that etches the second silicon oxide gate dielectric 551 selectively to the material of the single crystalline semiconductor layer 3. The duration of the terminal etch step may be selected such that the unmasked portions of the second silicon oxide gate dielectric 551 are etched through. The photoresist layer 957 can be subsequently removed by ashing.

Thus, a first gate structure (152, 142, 154, 157, 158, 159) is formed in the first device region 100, and a third gate structure (551, 552, 542, 554, 557, 558, 559) is formed in the third device region 500. The first gate structure (152, 142, 154, 157, 158, 159) may comprise, from bottom to top, a first metal oxide gate dielectric 152, an optional first metallic barrier liner 142, a first lower semiconductor gate electrode 154, a first upper semiconductor gate electrode 157, a first lower sacrificial gate cap 158, and a first upper sacrificial gate cap 159. The third gate structure (551, 552, 542, 554, 557, 558, 559) may comprise, from bottom to top, a second silicon oxide gate dielectric 551, a third metal oxide gate dielectric 552, an optional third metallic barrier liner 542, a third lower semiconductor gate electrode 554, a third upper semiconductor gate electrode 557, a third lower sacrificial gate cap 558, and a third upper sacrificial gate cap 559.

The first gate structure (152, 142, 154, 157, 158, 159) comprises a first gate dielectric 152, which may consist of the first metal oxide gate dielectric 152. The second gate structure (351, 352, 342, 353, 355, 357, 358, 359) comprises a second gate dielectric 351, which may consist of a first silicon oxide gate dielectric 351. Further, the second gate structure (351, 352, 342, 353, 355, 357, 358, 359) comprises an etch-stop layer 355 which is a patterned portion of the etch-stop layer 55L. The third gate structure (551, 552, 542, 554, 557, 558, 559) comprises a third gate dielectric (551, 552), which comprises a dielectric stack of a second silicon oxide gate dielectric 551 and a third metal oxide gate dielectric 552.

In one embodiment, sidewalls of the first gate dielectric 152 are vertically coincident with sidewalls of the first lower semiconductor gate electrode 153. The second lower semiconductor gate electrode 353 is a patterned portion of the doped semiconductor material layer 53D. In one embodiment, a bottom surface of the first metal oxide gate dielectric 152 is in direct contact with a channel region of a first field effect transistor to be formed in the first device region 100.

In the second embodiment as in the first embodiment, the first silicon oxide gate dielectric 351 comprises: first sidewalls that are laterally offset outward relative to the sidewalls of the second metal oxide gate dielectric 352; and second sidewalls that are vertically coincident with, and are adjoined to, the sidewalls of the second lower semiconductor gate electrode 353. In one embodiment, the first silicon oxide gate dielectric 351 comprises: a first portion located within an area of the second lower semiconductor gate electrode 353 in a plan view and having a first thickness; and a second portion that does not have any areal overlap with the second lower semiconductor gate electrode 353 in the plan view and having a second thickness that is less than the first thickness.

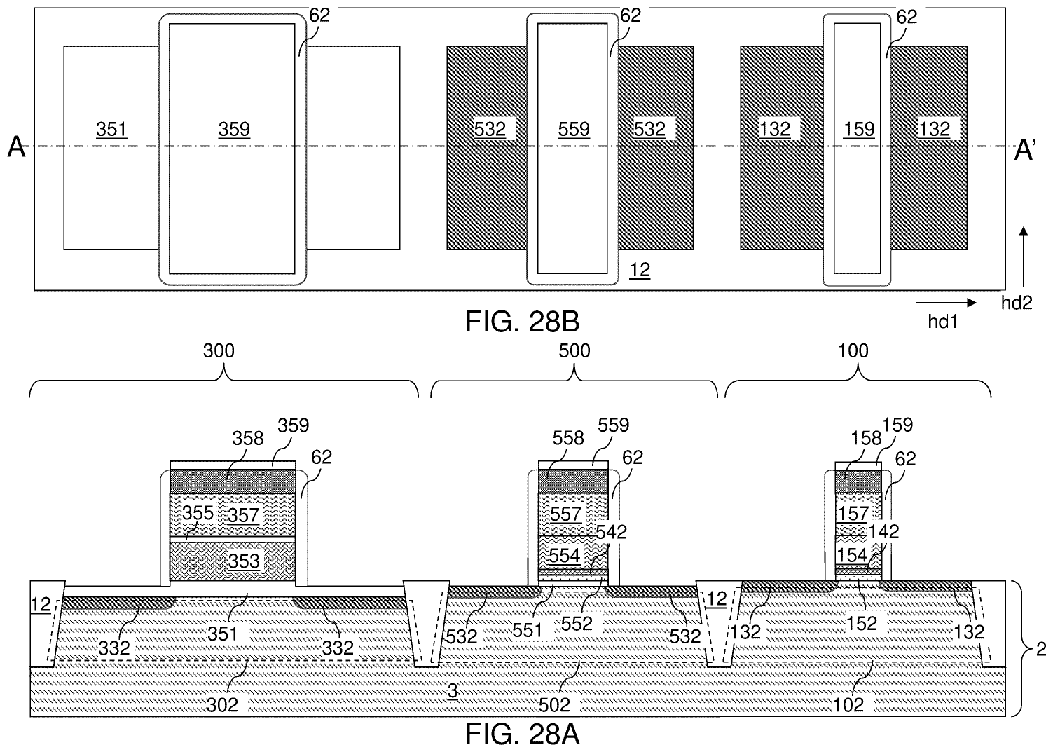

Referring to FIGS. 28A and 28B, the inner dielectric gate spacer 62 is formed on the gate structures as described above. Ion implantation processes may be performed to form the source/drain extension regions (132, 332, 532) described above.

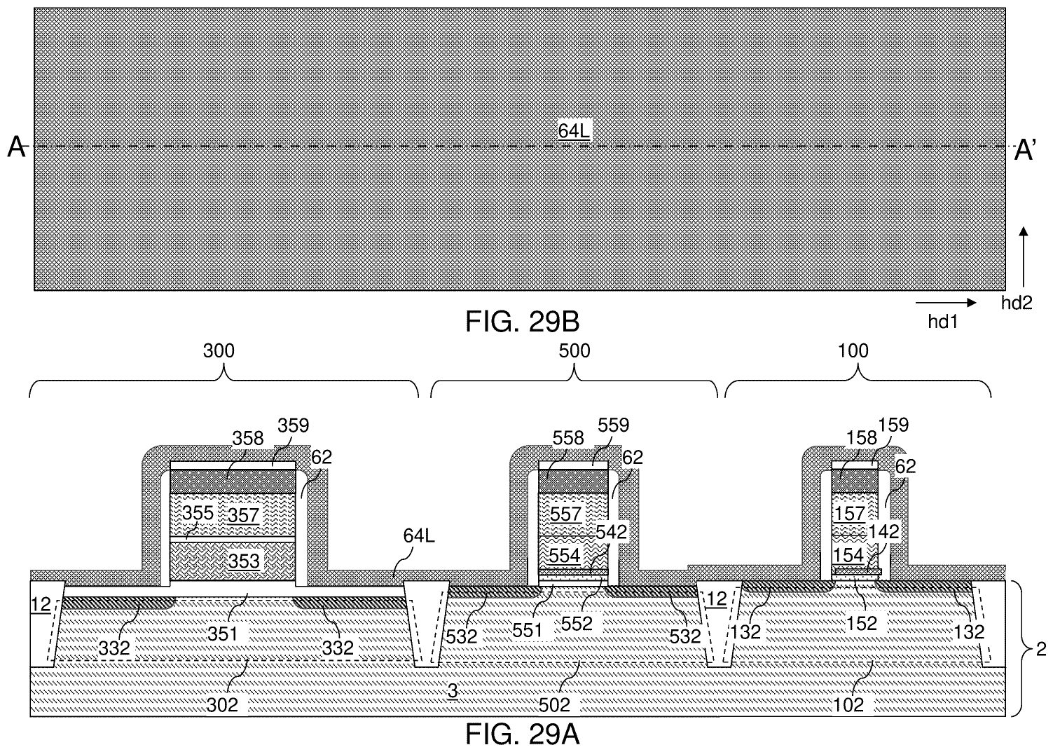

Referring to FIGS. 29A and 29B, the outer dielectric gate spacer material layer 64L may be conformally deposited, as described above.

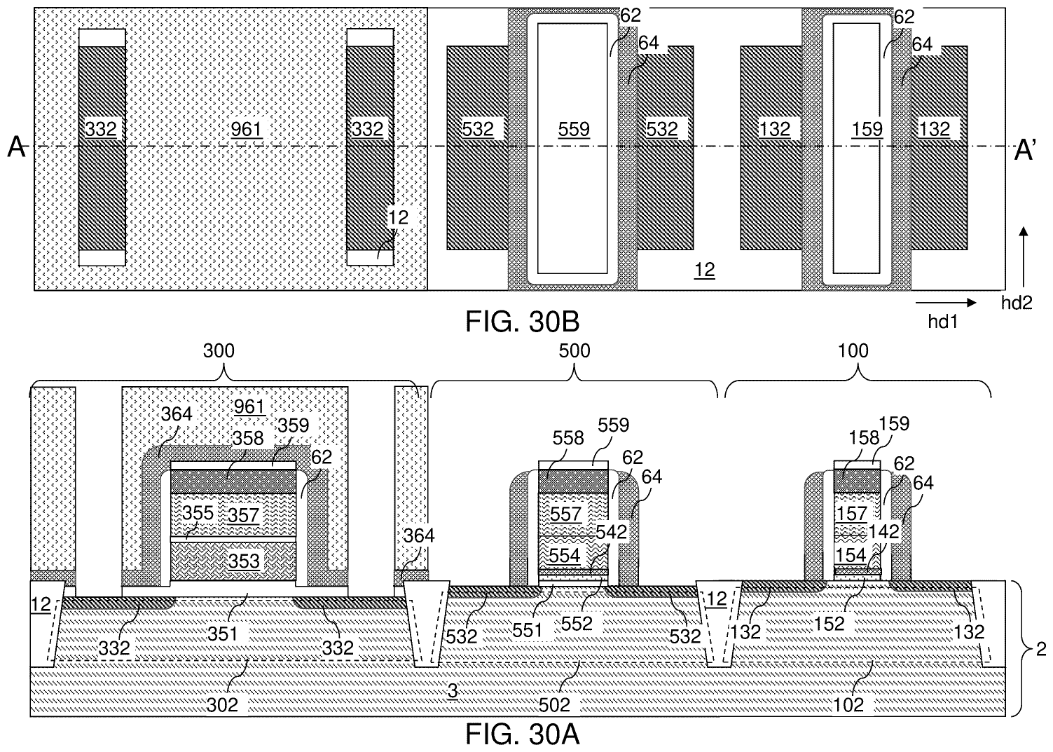

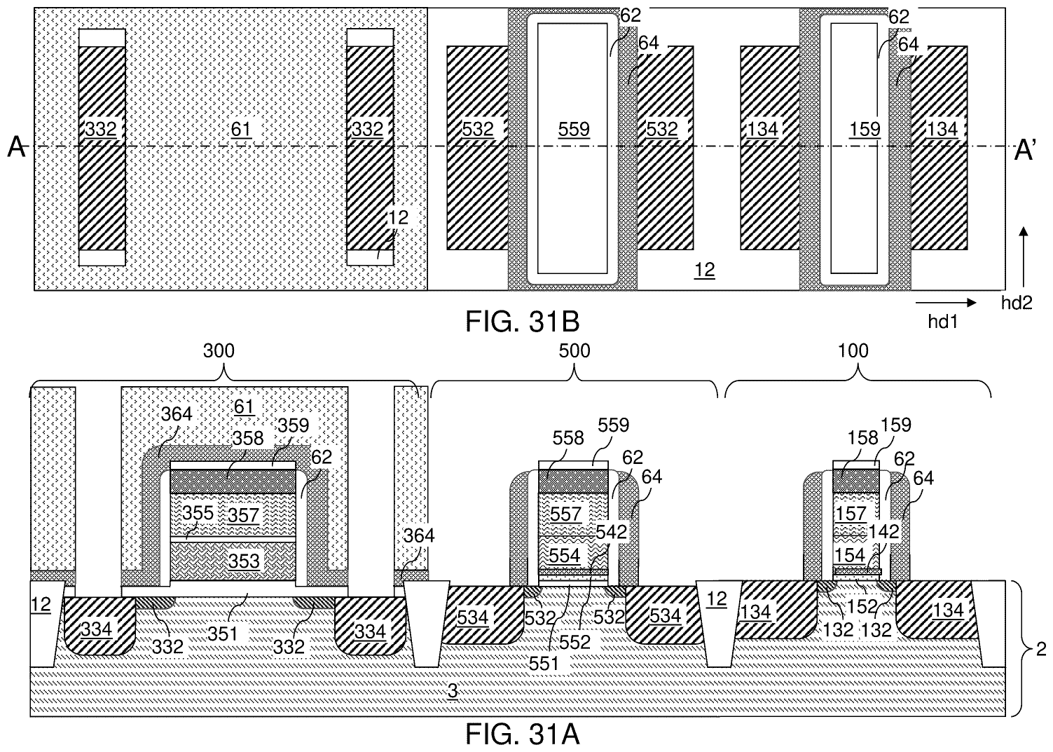

Referring to FIGS. 30A and 30B, a photoresist layer 961 can be applied over the second exemplary structure, and can be lithographically patterned so that the first device region 100 and the third device region 500 are not covered by the photoresist layer 961, and a pair of openings is formed in the photoresist layer 961 in the second device region 300. An anisotropic etch process can be performed to etch unmasked horizontally-extending portions of the outer dielectric gate spacer material layer 64L and the first silicon oxide gate dielectric 351. Each remaining vertically-extending portion of the outer dielectric gate spacer material layer 64L in the first device region 100 and in the third device region 500 constitutes an outer dielectric gate spacer 64. A remaining masked portion of the outer dielectric gate spacer material layer 64L located in the second device region 300 and underlies the photoresist layer 961 comprises an outer dielectric gate spacer layer 364.

Referring to FIGS. 31A and 31B, ion implantation processes may be performed to form the deep source/drain regions (134, 334, 534) as described above. The photoresist layer 961 can be subsequently removed, for example, by ashing.

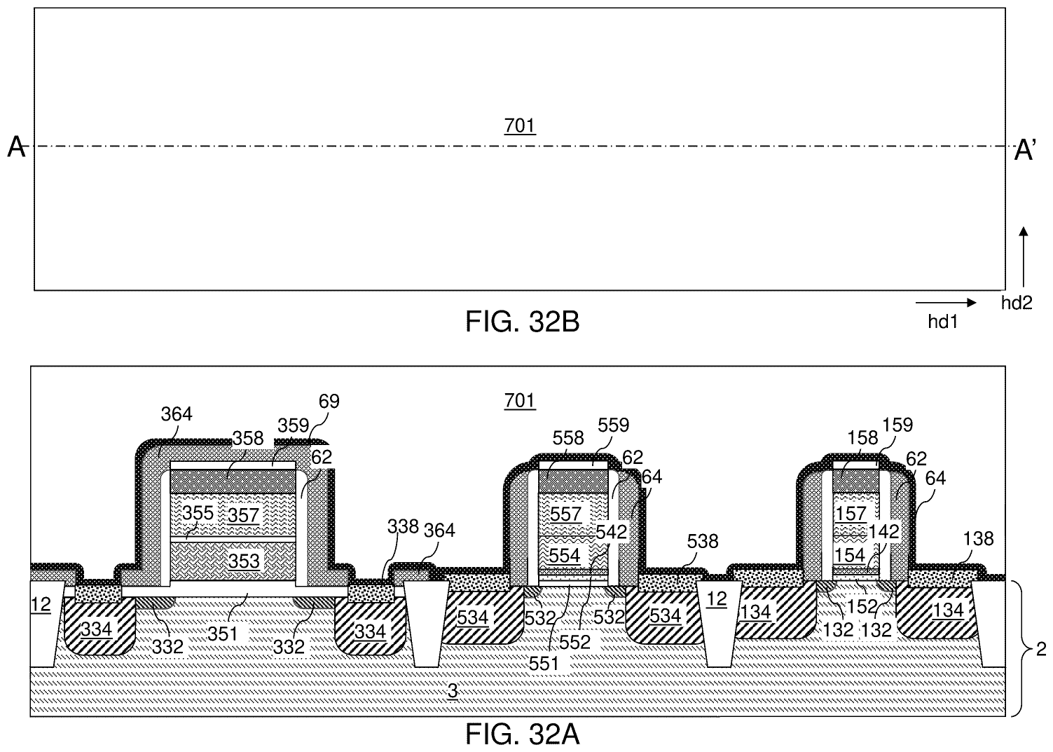

Referring to FIGS. 32A and 32B, the silicide forming metal layer can be deposited over the second exemplary structure, as described above. An anneal can be performed to form various metal-semiconductor alloy regions (138, 338, 538) that includes a metal-semiconductor alloy (such as a metal silicide) of the at least one elemental metal and the semiconductor material in the upper portions of the various deep source/drain regions (134, 334, 534). Unreacted portions of the metal layer can be removed selectively to the various metal-semiconductor alloy regions (138, 338, 538), for example, by performing a selective wet etch process. The metal-semiconductor alloy regions (138, 338, 538) may comprise first metal-semiconductor alloy regions 138 that are formed on the first deep source/drain regions 134, second metal-semiconductor alloy regions 338 that are formed on the second deep source/drain regions 334, and third metal-semiconductor alloy regions 538 that are formed on the third deep source/drain regions 534.

A dielectric diffusion barrier layer 69 may be deposited over the various gate structures and the various metal-semiconductor alloy regions (138, 338, 538). The dielectric diffusion barrier layer 69 may comprise a dielectric diffusion barrier material, such as silicon nitride or silicon carbonitride. A planarization dielectric layer 701 can be formed over the dielectric diffusion barrier layer 69. The planarization dielectric layer 701 comprises a planarizable dielectric material, such as undoped silicate glass or a doped silicate glass.

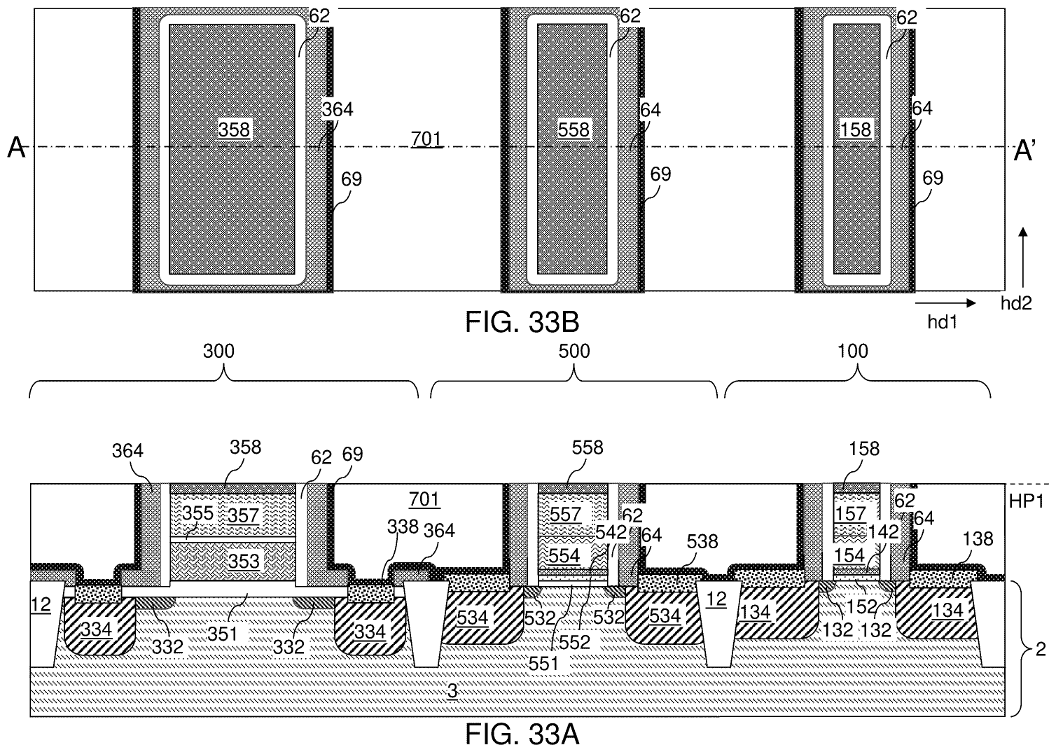

Referring to FIGS. 33A and 33B, the planarization process, such as a chemical mechanical polishing process, can be performed to remove portions of the planarization dielectric layer 701 and portions of the sacrificial gate caps (158, 159, 358, 359, 558, 559) from above a first horizontal plane HP1 that overlies the top surfaces of the upper semiconductor gate electrodes (157, 357, 557). In one embodiment, the first horizontal plane HP1 may be located below the horizontal plane including interfaces between the lower sacrificial gate caps (158, 358, 558) and the upper sacrificial gate caps (159, 359, 559). The planarization process may remove the entirety of all upper sacrificial gate caps (159, 359, 559) and remove upper portions of all lower sacrificial gate caps (158, 358, 558).

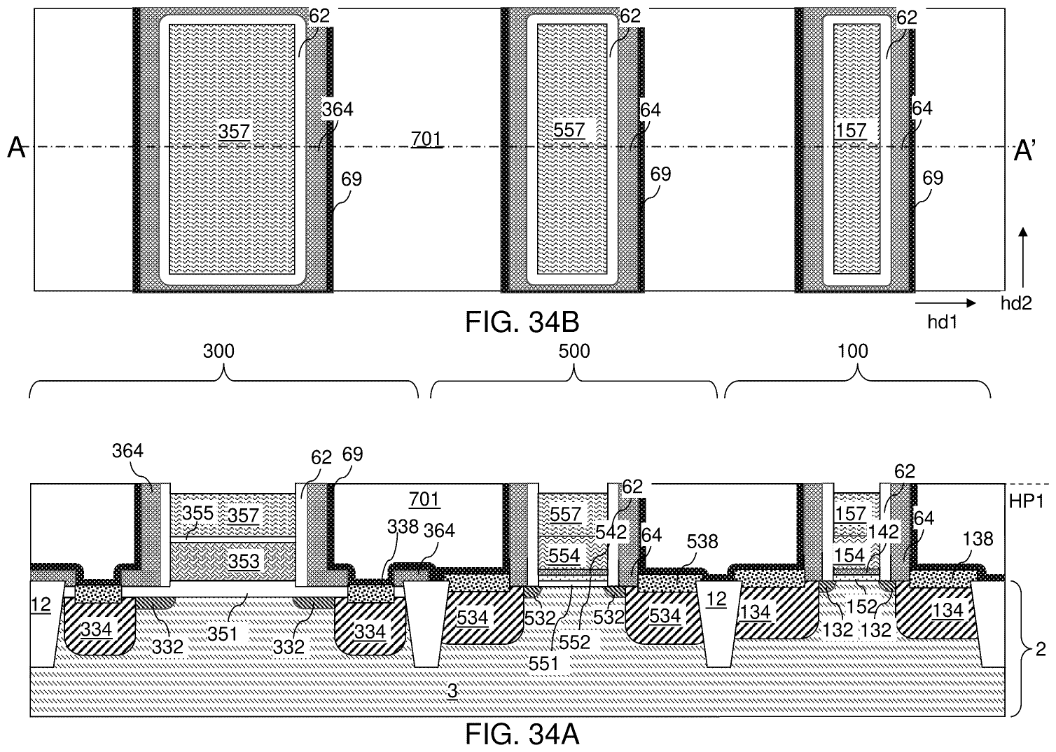

Referring to FIGS. 34A and 34B, the selective etch process can be performed to remove the lower sacrificial gate caps (158, 358, 558). For example, if the lower sacrificial gate caps (158, 358, 558) comprise silicon nitride, a wet etch process employing hot phosphoric acid may be performed to remove the lower sacrificial gate caps (158, 358, 558) without removing the upper semiconductor gate electrodes (157, 357, 557).

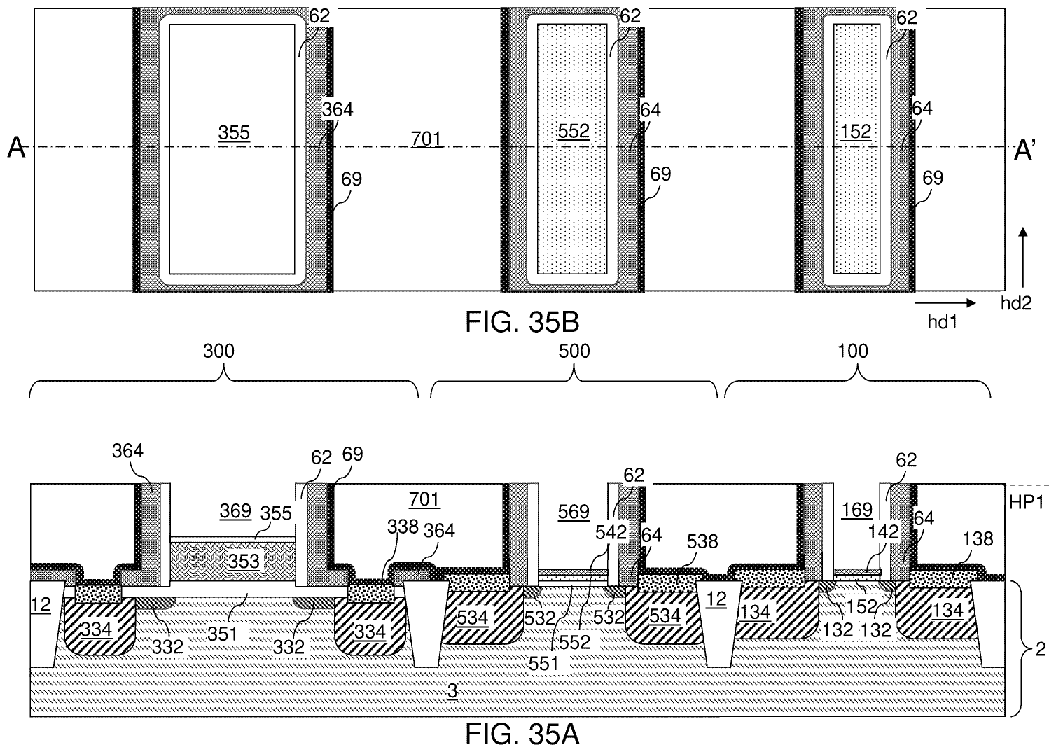

Referring to FIGS. 35A and 35B, a first selective etch process can be subsequently performed to remove the first upper semiconductor gate electrode 157, the second upper semiconductor gate electrode 357, the third upper semiconductor gate electrode 557, the first lower semiconductor gate electrode 153, and the third lower semiconductor gate electrode 553 selectively to the materials of the metallic barrier liners (142, 342, 542) and the etch-stop layer 355. For example, the first selective etch process may comprise a wet etch process using hot trimethyl-2 hydroxyethyl ammonium hydroxide (“hot TMY”) or tetramethyl ammonium hydroxide (TMAH).

The first gate cavity 169 is formed over a first remaining portion of the gate dielectric metal oxide layer 52L in the first device region 100, the second gate cavity 369 is formed over a remaining portion of the etch-stop layer 55L in the second device region 300, and the third gate cavity 569 is formed in the third device region 500.

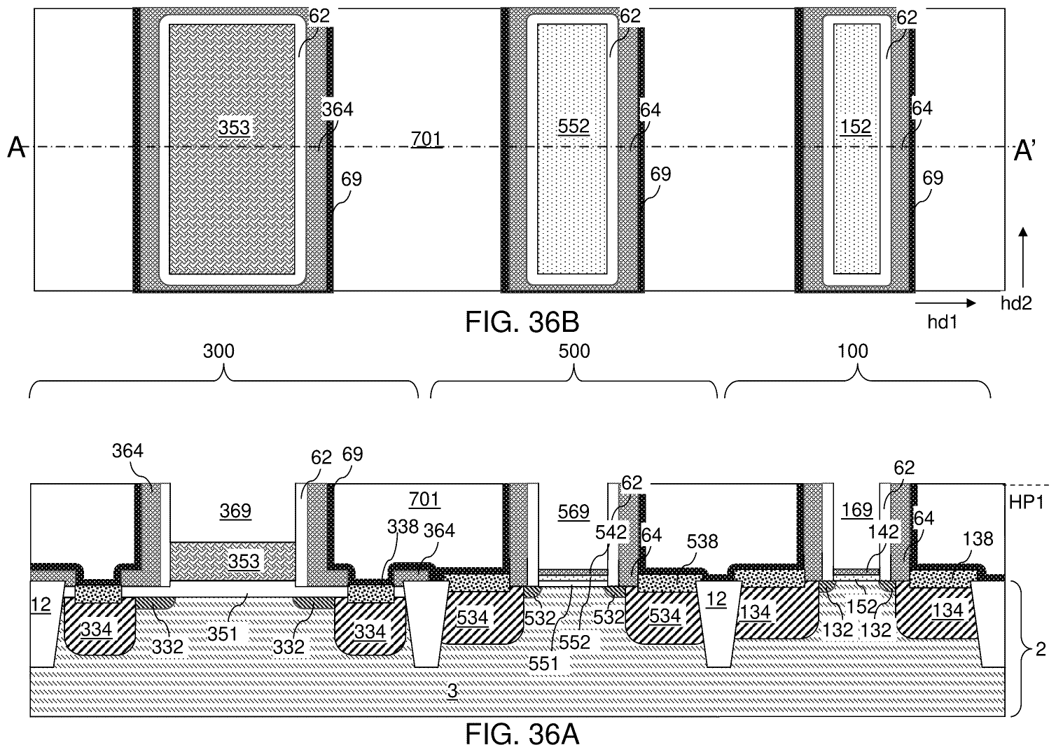

Referring to FIGS. 36A and 36B, a second selective etch process can be performed to remove the etch-stop layer 355 selectively to the material of the second lower semiconductor gate electrode 353 and selectively to the materials of the metallic barrier liners (142, 342, 542).

The gate cavities (169, 369, 569) are formed in the volumes from which the materials of the lower sacrificial gate caps (158, 358, 558), the first upper semiconductor gate electrode 157, the second upper semiconductor gate electrode 357, the third upper semiconductor gate electrode 557, the first lower semiconductor gate electrode 153, the third lower semiconductor gate electrode 553, and the etch-stop layer 355 are removed. The gate cavities (169, 369, 569) comprise a first gate cavity 169 that is formed within a fraction of the volume of the first gate structure in the first device region 100, a second gate cavity 169 that is formed within a fraction of the volume of the second gate structure in the second device region 300, and a third gate cavity 569 that is formed within a fraction of the volume of the third gate structure in the third device region 500. The first metallic barrier liner 142 and the third metallic barrier liner 542 may protect the first metal oxide gate dielectric 152 and the third metal oxide gate dielectric 552 during formation of the gate cavities (169, 369, 569).

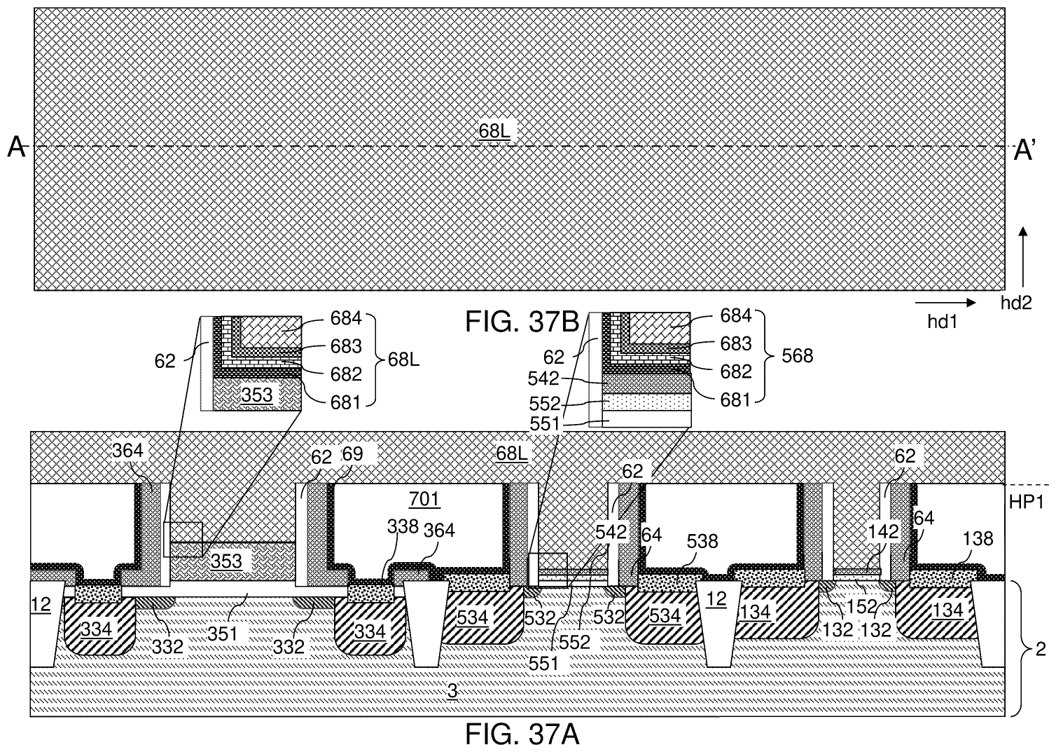

Referring to FIGS. 37A and 37B, the replacement metallic material layer 68L described above can be deposited in the gate cavities (169, 369, 569) and over the planarization dielectric layer 701.

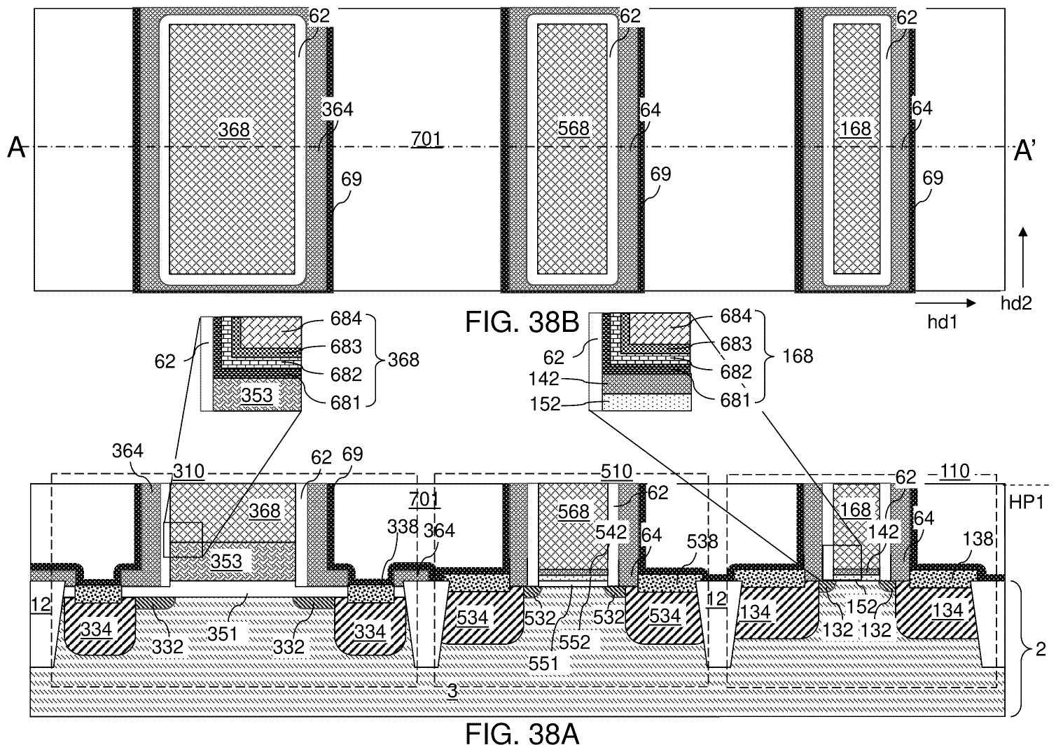

Referring to FIGS. 38A and 38B, the replacement metallic material layer 68L may be removed from above the first horizontal plane HP1 by performing the planarization process, such as a chemical mechanical polishing process. Remaining portions of the replacement metallic material layer 68L comprise a first metallic gate electrode 168 that is formed in the first device region 100, a second metallic gate electrode 368 that is formed in the second device region 300, and a third metallic gate electrode 568 that is formed in the third device region 500.

Generally, a first patterned portion of the upper gate semiconductor layer 57L and a patterned portion of the lower gate semiconductor layer 53L in the first gate structure (152, 142, 153, 157, 158, 159) is replaced with a first metallic gate electrode 168; a second patterned portion of the upper gate semiconductor layer 57L and a patterned portion of the etch-stop layer 55L in the second gate structure (351, 353, 355, 357, 358, 359) is replaced with a second metallic gate electrode 368; and a third patterned portion of the upper gate semiconductor layer 57L and a patterned portion of the lower gate semiconductor layer 53L in the third gate structure (551, 552,542, 553, 557, 558, 559) is replaced with a third metallic gate electrode 568. According to an aspect of the present disclosure, the second metallic gate electrode 368 is formed directly on a top surface of a remaining patterned portion of the lower gate semiconductor layer 53L that is present within the second gate structure (351, 353, 355, 357, 358, 359) as formed at the processing steps of FIGS. 26A and 26B.

A first field effect transistor 110 is formed in the first device region 100; a second field effect transistor 310 is formed in the second device region 300, and a third field effect transistor 510 is formed in the third device region 500. The first field effect transistor 110 comprises first source/drain regions (132, 134) located in a first portion of a semiconductor substrate 2, a first gate dielectric 152 comprising a first metal oxide gate dielectric 152 that comprises a first portion of a dielectric metal oxide material, and a first gate electrode 168 comprising a first metallic gate electrode 168 contacting a top surface of the first gate dielectric 152. The second field effect transistor 310 comprises second source/drain regions (332, 334) located in a second portion of the semiconductor substrate 2, a second gate dielectric 351 comprising a first silicon oxide gate dielectric 351, and a second gate electrode (353, 368) comprising a vertical stack (353, 368) of a doped semiconductor gate electrode 353 and a second metallic gate electrode 368.

In one embodiment, a topmost surface of the second gate electrode (353, 368) is located within a horizontal plane (such as the first horizontal plane HP1) containing a topmost surface of the first gate electrode 168. In one embodiment, the first metallic gate electrode 168 has a greater vertical extent and a lesser lateral extent than the second metallic gate electrode 368. In one embodiment, a vertical extent of the first metallic gate electrode 168 is not less than a total vertical extent of the vertical stack (353, 368).

In one embodiment, the first metallic gate electrode 168 comprises a first portion of at least one metallic material; and the second metallic gate electrode 368 comprises a second portion of the at least one metallic material. For each metallic material portion located within the first metallic gate electrode 168, a corresponding metallic material portion having a same material composition is present in the second metallic gate electrode 368; and for each metallic material portion located within the second metallic gate electrode 368, a corresponding metallic material portion having a same material composition is present in the first metallic gate electrode 168.

In one embodiment, the first metallic gate electrode 168 comprises at least one first metallic liner (681, 682, 683) each having a respective first horizontally-extending portion and a respective first tubular portion that vertically extends upward from a periphery of the respective first horizontally-extending portion; and the second metallic gate electrode 368 comprises at least one second metallic liner (681, 682, 683) each having a respective second horizontally-extending portion and a respective second tubular portion that vertically extends upward from a periphery of the respective second horizontally-extending portion. For each first metallic liner (681, 682, 683) located within the first metallic gate electrode 168, a corresponding second metallic liner (681, 682, 683) having a same material composition and a same thickness is present in the second metallic gate electrode 368; and for each second metallic liner (681, 682, 683) located within the second metallic gate electrode 368, a corresponding first metallic liner (681, 682, 683) having a same material composition and a same thickness is present in the first metallic gate electrode 168.

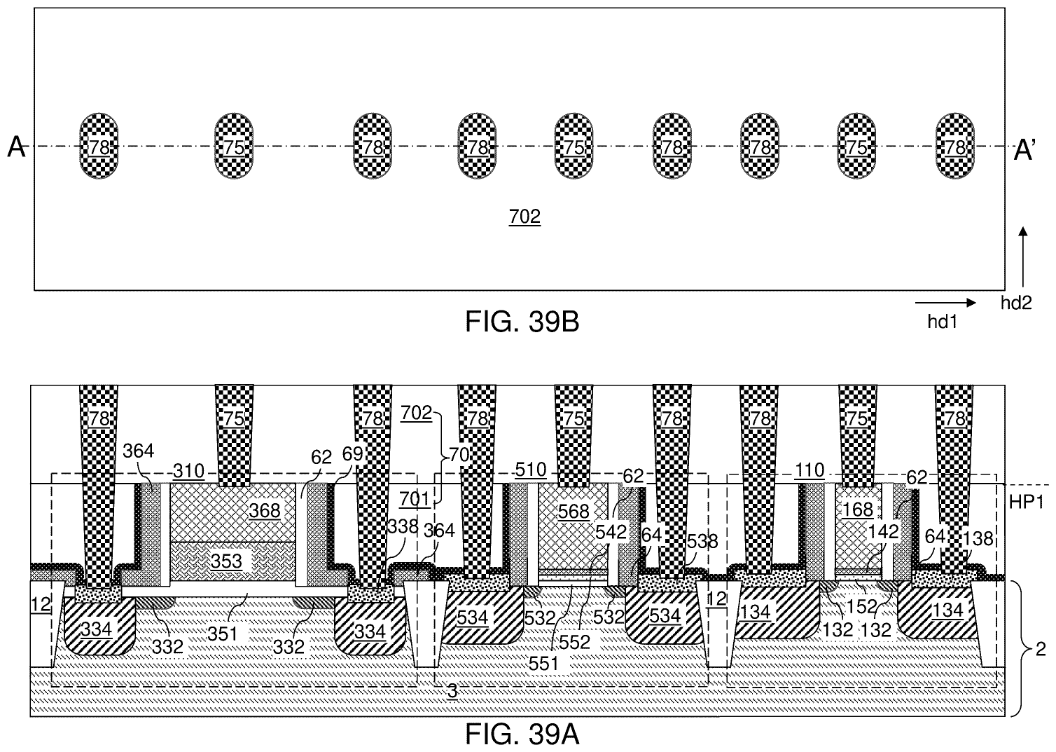

Referring to FIGS. 39A and 39B, the cover dielectric layer 702 can be formed over the planarization dielectric layer 701. The optional etch stop layer 703 described above may optionally be formed between the cover dielectric layer 702 and the planarization dielectric layer 701. The combination of the planarization dielectric layer 701 and the cover dielectric layer 702 constitutes the contact-level dielectric layer 70. Various contact via structures (75, 78) can be formed through the contact-level dielectric layer 70 on a respective one of the metallic gate electrodes (168, 358, 568) and the metal-semiconductor alloy regions (138, 338, 538). The various contact via structures (75, 78) may comprise source/drain contact via structures 78 contacting a respective one of the metal-semiconductor alloy regions (138, 338, 538), and gate contact via structures 75 contacting a respective one of the metallic gate electrodes (168, 358, 568).

Referring collectively to FIGS. 1A-39B, a semiconductor structure is provided, which comprises: a first field effect transistor 110 comprising first source/drain regions (132, 134) located in a first portion of a semiconductor substrate 2, a first gate dielectric comprising a first metal oxide gate dielectric 152 that comprises a first portion of a dielectric metal oxide material, and a first gate electrode 168 consisting essentially of a first metallic gate electrode (142, 168) (i.e., the term first gate electrode 168 includes only the electrically conductive materials and does not include insulating sidewall spacers, gate dielectric or insulating gate cap layer(s)) contacting a top surface of the first gate dielectric 152; and a second field effect transistor 310 comprising second source/drain regions (332, 334) located in a second portion of the semiconductor substrate 2, a second gate dielectric (351 and optionally 352) comprising a first silicon oxide gate dielectric 351, and a second gate electrode (353, 368) comprising a vertical stack (353, 368) of a doped semiconductor gate electrode 353 and a second metallic gate electrode 368.

In one embodiment, the first field effect transistor 110 comprises a lower voltage transistor than the second field effect transistor 310; the first field effect transistor 110 lacks any doped semiconductor gate electrode portions; and the first gate dielectric is thinner than the second gate dielectric.

In one embodiment, a topmost surface of the second gate electrode (353, 368) is located within a horizontal plane (such as the first horizontal plane HP1) containing a topmost surface of the first gate electrode 168. In one embodiment, the first metallic gate electrode 168 has a greater vertical extent and a smaller lateral extent than the second metallic gate electrode 368. In one embodiment, a vertical extent of the first metallic gate electrode 168 is not less than a total vertical extent of the vertical stack (353, 368).

In one embodiment, sidewalls of the first gate dielectric 152 are vertically coincident with sidewalls of the first gate electrode 168. In the first embodiment, the second gate dielectric (351 and optionally 352) also comprises a second metal oxide gate dielectric 352 that comprises a second portion of the dielectric metal oxide material; and sidewalls of the second metal oxide gate dielectric 352 are vertically coincident with sidewalls of the doped semiconductor gate electrode 353. In the first embodiment, the first silicon oxide gate dielectric 351 comprises: first sidewalls that are laterally offset outward relative to the sidewalls of the second metal oxide gate dielectric 352; and second sidewalls that are vertically coincident with and are adjoined to the sidewalls of the second metal oxide gate dielectric 352. In the first embodiment, the first silicon oxide gate dielectric 351 comprises: a first portion located within an area of the second metal oxide gate dielectric 352 in a plan view and having a first thickness; and a second portion that does not have any areal overlap in the plan view and having a second thickness that is less than the first thickness.

In the second embodiment, the second gate dielectric consists essentially of the silicon oxide gate dielectric 351; the doped semiconductor gate electrode 353 directly contacts the silicon oxide gate dielectric 351; and a bottom surface of the first metal oxide gate dielectric 152 is in direct contact with a channel region of the first field effect transistor 110.

In one embodiment, the first metallic gate electrode 168 comprises a first portion of at least one metallic material; and the second metallic gate electrode 368 comprises a second portion of the at least one metallic material. For each metallic material portion located within the first metallic gate electrode 168, a corresponding metallic material portion having a same material composition is present in the second metallic gate electrode 368; and for each metallic material portion located within the second metallic gate electrode 368, a corresponding metallic material portion having a same material composition is present in the first metallic gate electrode 168.

In one embodiment, the first metallic gate electrode 168 comprises at least one first metallic liner (681, 682, 683) each having a respective first horizontally-extending portion and a respective first tubular portion that vertically extends upward from a periphery of the respective first horizontally-extending portion; and the second metallic gate electrode 368 comprises at least one second metallic liner (681, 682, 683) each having a respective second horizontally-extending portion and a respective second tubular portion that vertically extends upward from a periphery of the respective second horizontally-extending portion. For each first metallic liner (681, 682, 683) located within the first metallic gate electrode 168, a corresponding second metallic liner (681, 682, 683) having a same material composition and a same thickness is present in the second metallic gate electrode 368; and for each second metallic liner (681, 682, 683) located within the second metallic gate electrode 368, a corresponding first metallic liner (681, 682, 683) having a same material composition and a same thickness is present in the first metallic gate electrode 168.

In one embodiment, the semiconductor structure also includes a third field effect transistor 510 comprising third source/drain regions (532, 534) located in a third portion of the semiconductor substrate 2, a third gate dielectric comprising a second silicon oxide gate dielectric 551 and a second metal oxide gate dielectric 552 that comprises a second portion of a dielectric metal oxide material, and a third gate electrode consisting essentially of a third metallic gate electrode 568. The third field effect transistor 510 comprises a lower voltage transistor than the second field effect transistor 310 and a higher voltage transistor than the first field effect transistor 110; the third field effect transistor lacks 510 any doped semiconductor gate electrode portions; and the third gate dielectric is thinner than the second gate dielectric and thicker than the first gate dielectric.

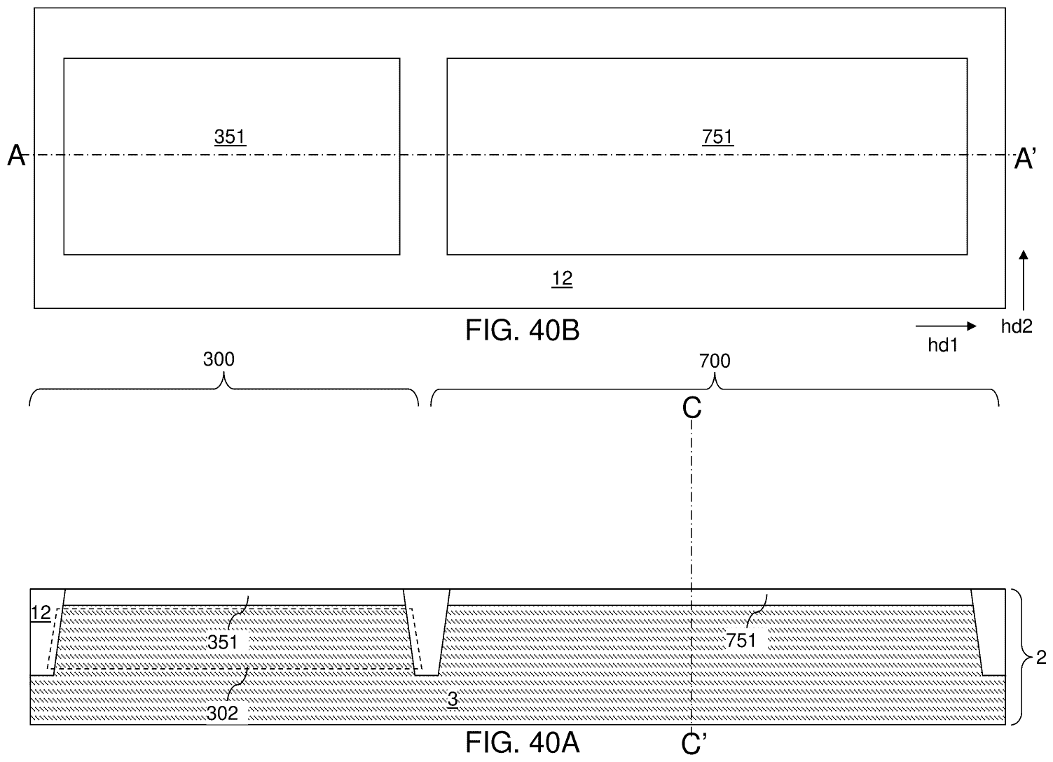

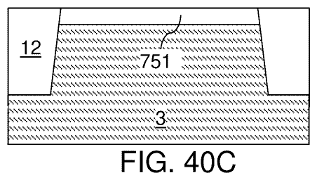

Referring to FIGS. 40A-40C, a third exemplary structure according to the third embodiment can be derived from the first exemplary structure illustrated in FIGS. 1A and 1B by providing an additional device region, which is herein referred to as a resistor region 700. While only a second device region 300 is illustrated in addition to the resistor region 700 in the third exemplary structure for simplicity, it is understood that a first device region 100 and a third device region 500 may be formed in the third exemplary structure as in the first exemplary structure and/or the second exemplary structure. Thus, the first field effect transistor 110 and/or the third field effect transistor 510 may be formed in addition to the second field effect transistor 310 in the third exemplary structure of the third embodiment.

In one embodiment, the third exemplary structure may comprise a device (e.g., transistor) region 300 that is the same as the second device region 300 described with reference to the first exemplary structure and the second exemplary structure, and the resistor region 700 in which a resistor structure is subsequently formed. The processing step that forms a first silicon oxide gate dielectric 351 can form an isolation dielectric layer 751 in the resistor region 700. In one embodiment, the isolation dielectric layer 751 may have the same material composition and the same thickness as the first silicon oxide gate dielectric 351. In one embodiment, the portion of the single crystalline semiconductor layer 3 located within the resistor region 700 may have the same material composition throughout, and may include electrical dopants at a same atomic concentration. The thickness of the isolation dielectric layer 751 may be in a range from 6 nm to 60 nm, such as from 10 nm to 30 nm, although lesser and greater thicknesses may also be employed.

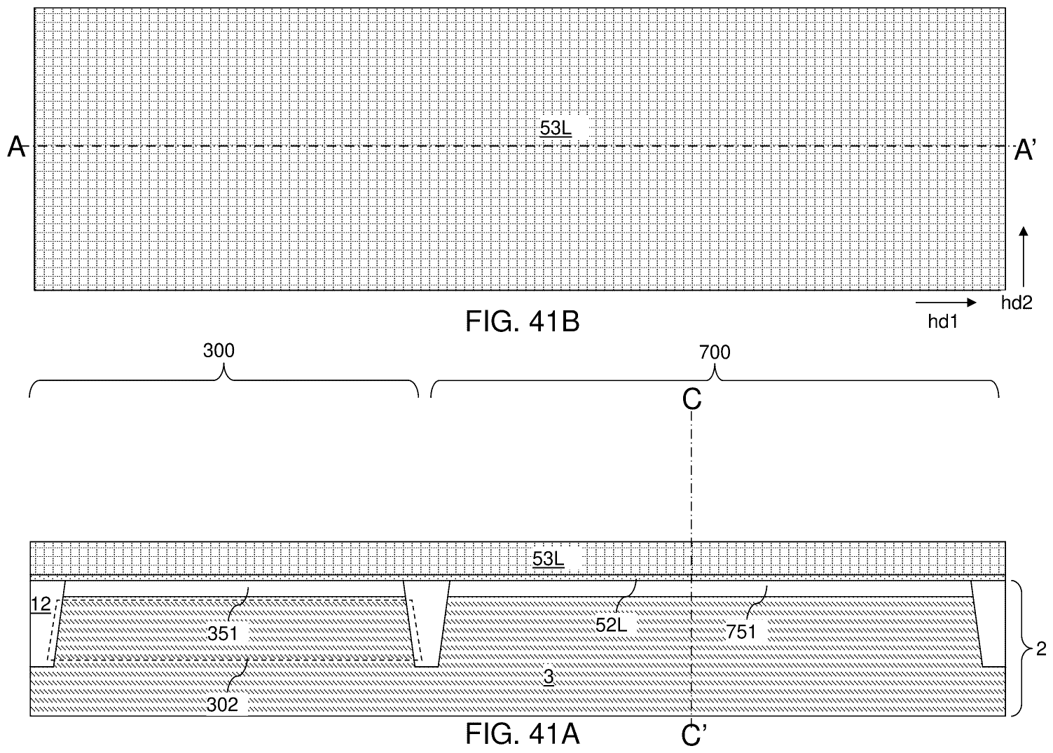

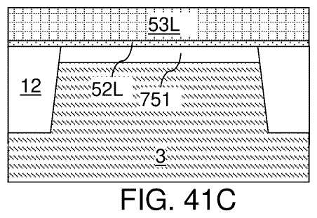

Referring to FIGS. 41A-41C, a gate dielectric metal oxide layer 52L and a lower gate semiconductor layer 53L can be sequentially deposited. The gate dielectric metal oxide layer 52L may be the same as in the first embodiment. The gate dielectric metal oxide layer 52L can be formed on the first silicon oxide gate dielectric 351 and on the isolation dielectric layer 751.

The lower gate semiconductor layer 53L comprises a semiconductor material that is doped with or may be subsequently doped with at least suitable electrical dopant, which may comprise a p-type dopant or an n-type dopant. For example, the lower gate semiconductor layer 53L may comprise amorphous silicon or polysilicon. The thickness of the lower gate semiconductor layer 53L may be in a range from 40 nm to 150 nm, such as from 60 nm to 100 nm, although lesser and greater thicknesses may also be employed.

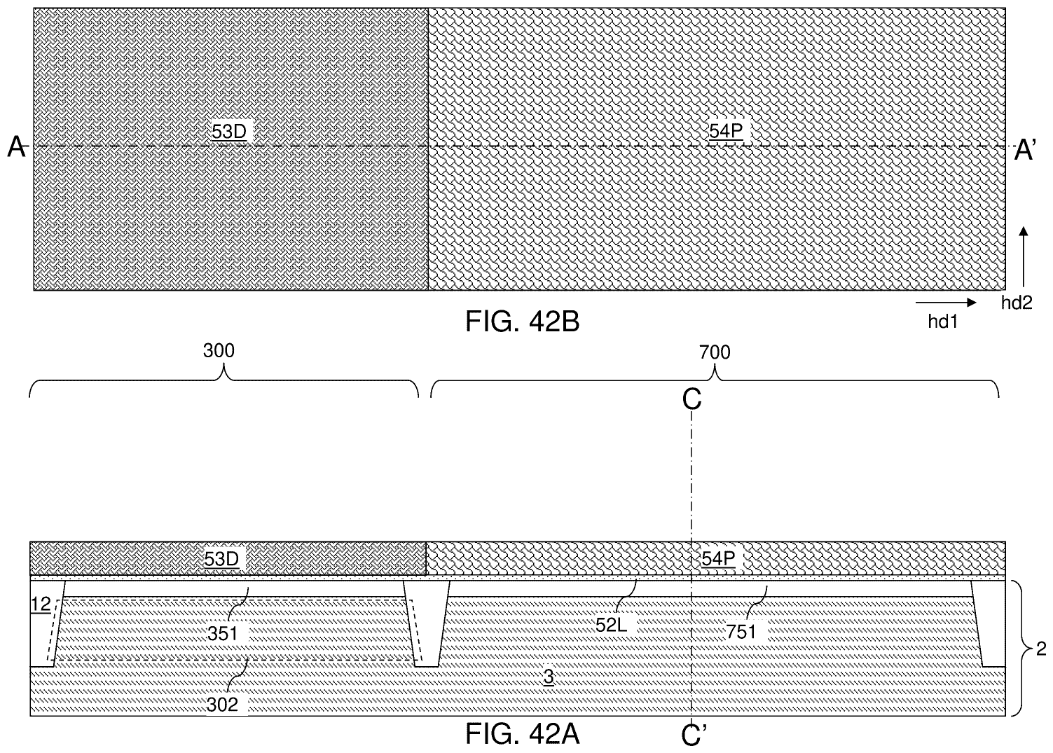

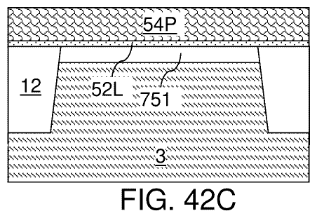

Referring to FIGS. 42A-42C, various portions of the lower gate semiconductor layer 53L may be doped with suitable electrical dopants to provide various semiconductor materials having different types of doping and/or different dopant concentrations. For example, the portion of the lower gate semiconductor layer 53L in the second device region 300 may be doped with n-type dopants, such as phosphorus or arsenic, and the portion of the lower gate semiconductor layer 53L located in the resistor region 700 may be doped with p-type dopants, such as boron at a doping level that is suitable for forming a polysilicon resistor. An n-type doped semiconductor material layer 53D is formed in the second device region 300, and a p-type doped semiconductor plate 54P is formed in the resistor region 700.

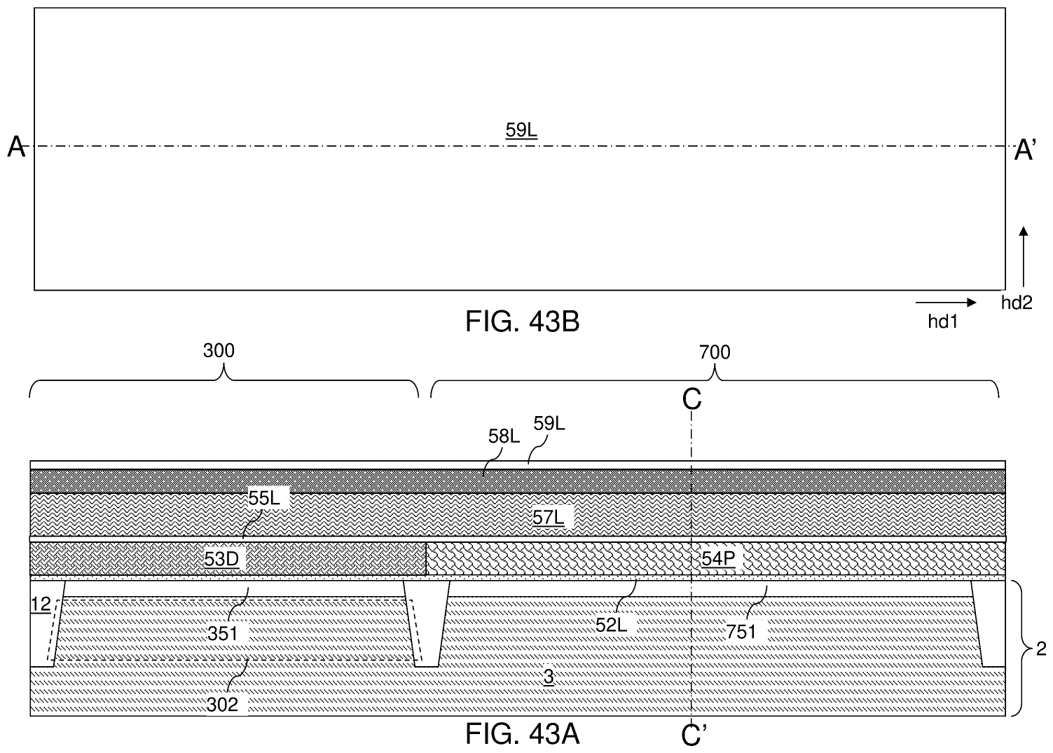

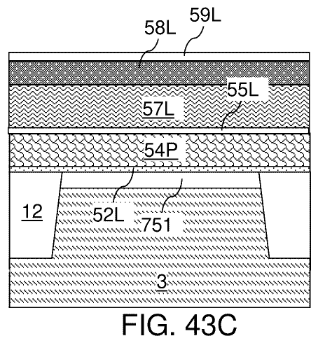

Referring to FIGS. 43A-43C, the above described etch-stop layer 55L can be formed over the doped semiconductor material layer 53D and the doped semiconductor plate 54P. The etch-stop layer 55L may comprise silicon oxide, silicon nitride, silicon carbonitride, etc. In one embodiment, the etch-stop layer 55L may comprise a semiconductor oxide layer (such as a silicon oxide layer) that is formed by oxidation of a top surface portion of the doped semiconductor material layer 53D and the doped semiconductor plate 54P (e.g., by oxidation of silicon layer 53D and silicon plate 54P). The etch-stop layer 55L may be removed from the low voltage transistor regions, such as the first and third device regions (100, 500) described with respect to the previous embodiments.

An upper gate semiconductor layer 57L and at least one sacrificial gate cap layer (58L, 59L) can be sequentially formed on the etch-stop layer 55L. The upper gate semiconductor layer 57L comprises a semiconductor material. The semiconductor material of the upper gate semiconductor layer 57L may optionally be doped with electrical dopants. In one embodiment, the upper gate semiconductor layer 57L may comprise amorphous silicon or polysilicon. The thickness of the upper gate semiconductor layer 57L may be in a range from 40 nm to 100 nm, such as from 60 nm to 80 nm, although lesser and greater thicknesses may also be employed.

The at least one sacrificial gate cap layer (58L, 59L) comprises at least one sacrificial material that can be employed as a temporary gate capping material. The at least one sacrificial gate cap layer (58L, 59L) may comprise, for example, silicon oxide, silicon nitride, silicon carbonitride, etc. In one embodiment, the at least one sacrificial gate cap layer (58L, 59L) may comprise a lower sacrificial gate cap layer 58L and an upper sacrificial gate cap layer 59L. In an illustrative example, the lower sacrificial gate cap layer 58L may comprise a silicon nitride layer, and the upper sacrificial gate cap layer 59L may comprise a silicon oxide layer. The lower sacrificial gate cap layer 58L may have a thickness in a range from 15 nm to 50 nm, such as from 20 to 40 nm, although lesser and greater thicknesses may also be employed. The upper sacrificial gate cap layer 59L may have a thickness in a range from 5 nm to 20 nm, although lesser and greater thicknesses may also be employed. Generally, a layer stack comprising a lower gate semiconductor layer 53L, an etch-stop layer 55L, and an upper gate semiconductor layer 57L can be formed over the isolation dielectric layer 751.

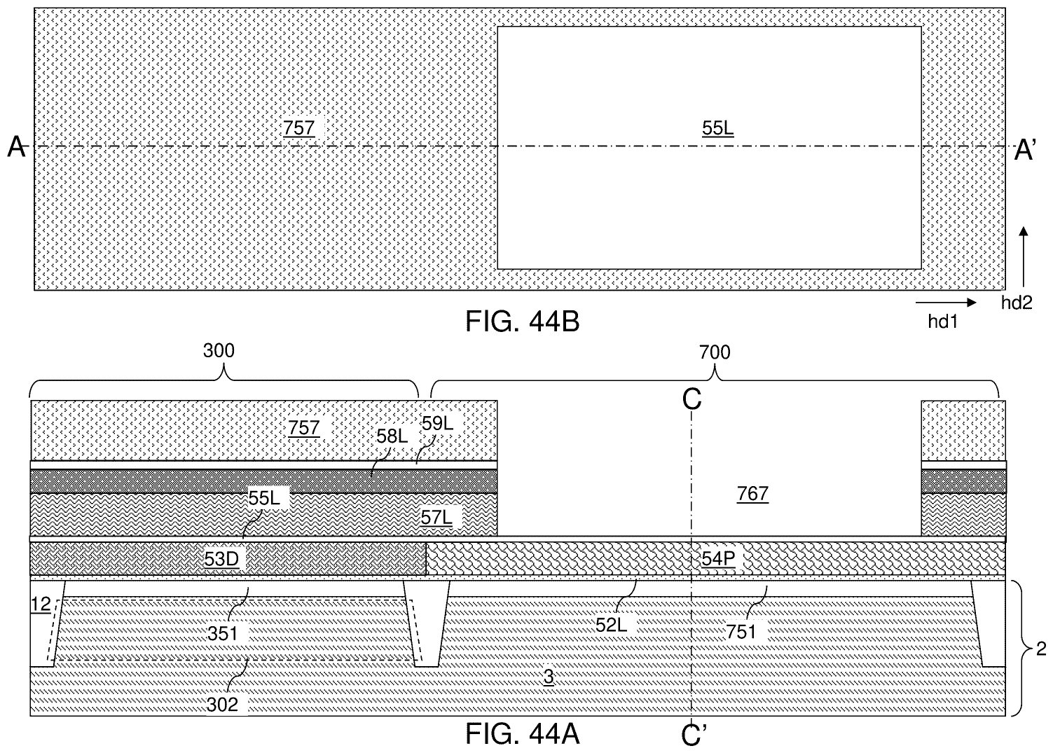

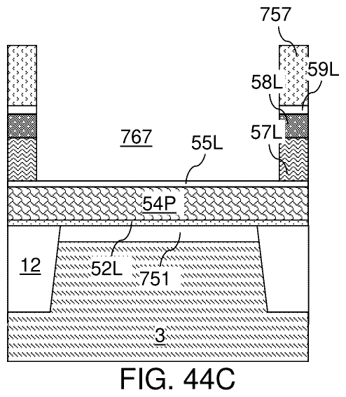

Referring to FIGS. 44A-44C, a photoresist layer 757 can be applied over the exemplary structure, and can be lithographically patterned to form an opening in the resistor region 700. Specifically, the opening in the photoresist layer 757 can be formed within an area in which portions of semiconductor resistor materials that are not contacted by an overlying contact structure are to be formed. Thus, the area of the opening in the photoresist layer 757 may correspond to areas of portions of resistor structures that do not have any areal overlap with contact structures to be subsequently formed.

An etch process may be performed to transfer the pattern of the opening in the photoresist layer 757 through the at least one sacrificial gate cap layer (58L, 59L) and the upper gate semiconductor layer 57L. For example, an anisotropic etch process including a plurality of anisotropic etch steps may be employed to etch portions of the at least one sacrificial gate cap layer (58L, 59L) and the upper gate semiconductor layer 57L that are not masked by the photoresist layer 757. The terminal step of the anisotropic etch process may etch the material of the upper gate semiconductor layer 57L selectively to the material of the etch-stop layer 55L which functions as an etch stop. An opening 767, such as a rectangular opening, may be formed through the at least one sacrificial gate cap layer (58L, 59L) and the upper gate semiconductor layer 57L. The photoresist layer 757 can be subsequently removed, for example, by ashing.

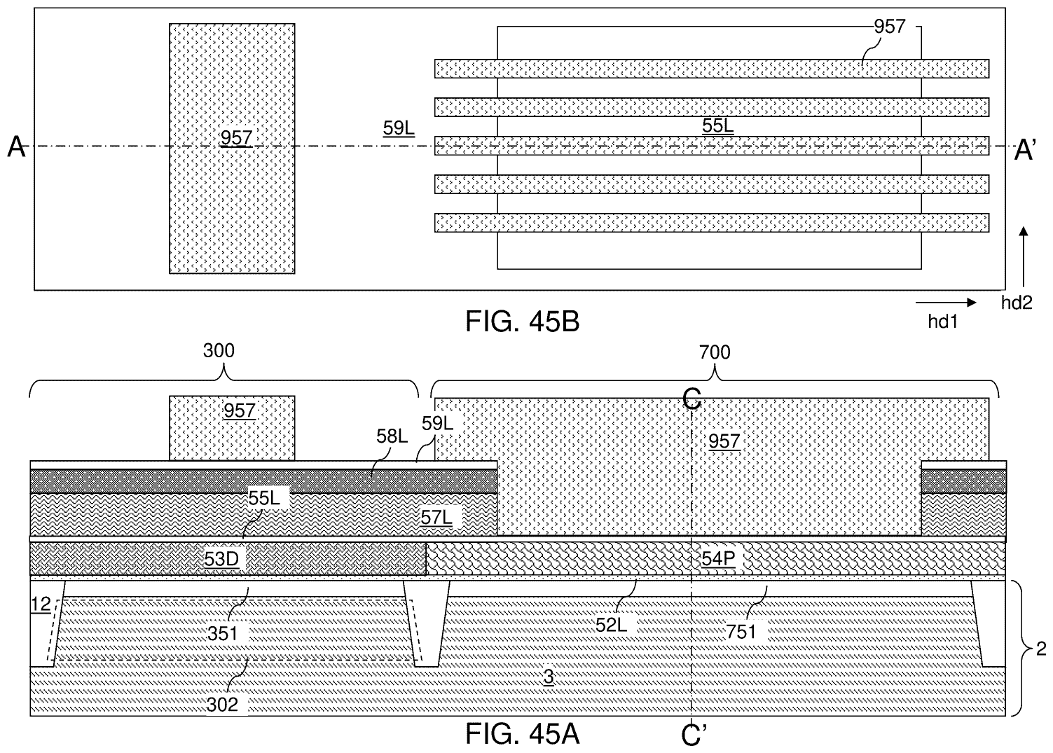

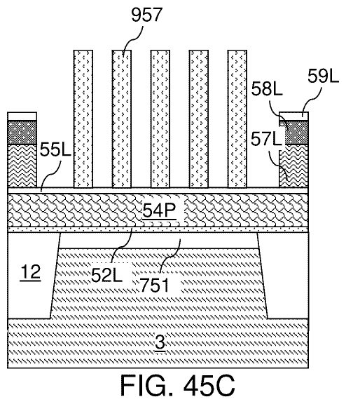

Referring to FIGS. 45A-45C, a photoresist layer 957 can be applied over the third exemplary structure, and can be lithographically patterned into a gate electrode pattern in the second device region 300 and into a pattern of at least one strip in the resistor region 700. In one embodiment, the pattern of the at least one strip may comprise a pattern of a plurality of strips having a respective elongated rectangular horizontal cross-sectional shape. In one embodiment, the plurality of strips are elongated along the first horizontal direction hd1 and laterally spaced apart from each other along the second horizontal direction hd2. Alternative patterns may be employed for the at least one strip. For example, a pattern for a strip may comprise a plurality of elongated shapes having at least two different lateral extension directions and adjoined to each other.

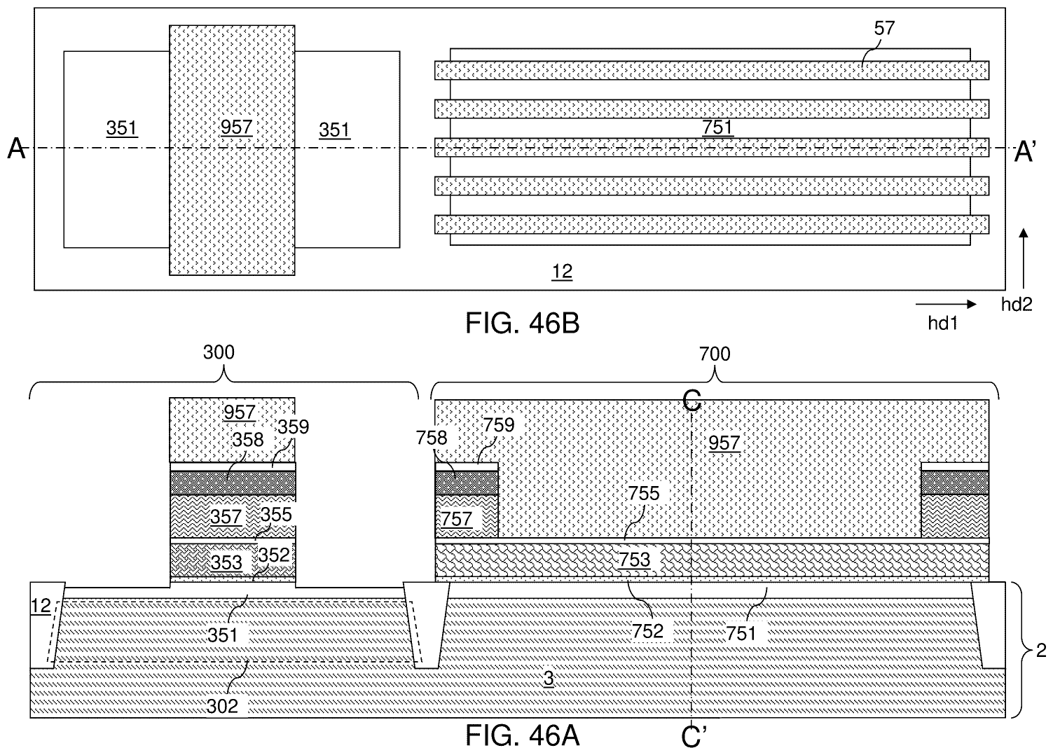

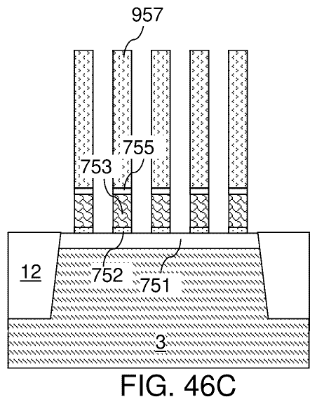

Referring to FIGS. 46A-46C, an anisotropic etch process including a sequence of anisotropic etch steps can be performed to transfer the pattern in the photoresist layer 957 through the at least one sacrificial gate cap layer (58L, 59L), the upper gate semiconductor layer 57L, the etch-stop layer 55L, the doped semiconductor material layer 53D and the doped semiconductor plate 54P, and the gate dielectric metal oxide layer 52L. Further, the anisotropic etch process may comprise a terminal etch step that etches an upper portion of the first silicon oxide gate dielectric 351 selectively to the material of the single crystalline semiconductor layer 3. The duration of the terminal etch step may be selected such that the unmasked portions of the first silicon oxide gate dielectric 351 are only partially etched. The photoresist layer 957 can be subsequently removed by ashing.

Generally, the sacrificial gate cap layers (58L, 59L), the upper gate semiconductor layer 57L, the etch-stop layer 55L, and the doped semiconductor material layer 53D and the gate dielectrics 52L and 351 may be patterned into an in-process gate structure (351, 352, 353, 355, 357, 358, 359) that is formed in the second device region 300. The sacrificial gate cap layers (58L, 59L), the upper gate semiconductor layer 57L, the etch-stop layer 55L, the doped semiconductor plate 54P and the gate dielectric layer 52L are patterned into in-process resistor structures (752, 753, 755, 757, 758, 759) in the resistor region 700. Each in-process resistor structure (752, 753, 755, 757, 758, 759) may comprise, from bottom to top, a dielectric metal oxide strip 752, a semiconductor material strip 753, an etch-stop strip 755, a pair of semiconductor pillars 757, and a pair of resistor dielectric caps (758, 759). Each resistor dielectric cap (758, 759) may comprise a stack of a lower resistor dielectric cap 758 and an upper resistor dielectric cap 759. The photoresist layer 957 can be subsequently removed, for example, by ashing.

Each dielectric metal oxide strip 752 is a patterned portion of the gate dielectric metal oxide layer 52L. Each semiconductor material strip 753 is a patterned portion of the doped semiconductor plate 54P. Each etch-stop strip 755 is a patterned portion of the etch-stop layer 55L. Each semiconductor pillar 757 is a patterned portion of the upper gate semiconductor layer 57L. Each lower resistor dielectric cap 758 is a patterned portion of the lower sacrificial gate cap layer 58L. Each upper resistor dielectric cap 759 is a patterned portion of the upper sacrificial gate cap layer 59L.

Thus, an in-process gate electrode (353, 355, 357) and at least one semiconductor material strip 753 are formed over a dielectric metal oxide layer (i.e., the gate dielectric metal oxide layer 52L) during the anisotropic etch process. The dielectric metal oxide layer (i.e., the gate dielectric metal oxide layer 52L) can be patterned to provide a metal oxide gate dielectric 352 that underlies an in-process gate electrode (353, 355, 357), and to provide each dielectric metal oxide strip 752 that underlies a respective semiconductor material strip 753. The second upper semiconductor gate electrode 357 in the third exemplary structure is herein referred to as a sacrificial semiconductor gate electrode 357.

Generally, the layer stack including the at least one sacrificial gate cap layer (58L, 59L), the upper gate semiconductor layer 57L, the etch-stop layer 55L, the doped semiconductor material layer 53D and the doped semiconductor plate 54P, and the gate dielectric metal oxide layer 52L can be patterned to provide at least one in-process resistor structure (752, 753, 755, 757, 758, 759). Each in-process resistor structure (752, 753, 755, 757, 758, 759) comprises a semiconductor material strip 753 that is a patterned portion of the lower gate semiconductor layer 53L that is formed at the processing steps of FIGS. 41A-41C, an etch-stop strip 755 that is a patterned portion of the etch-stop layer 55L, and a pair of semiconductor pillars 757 that are patterned portions of the upper gate semiconductor layer 57L.

Within each in-process resistor structure (752, 753, 755, 757, 758, 759), a sidewall of a first semiconductor pillar 757 is vertically coincident with a first end wall of the semiconductor material strip 753, and a sidewall of a second semiconductor pillar 757 is vertically coincident with a second end wall of the semiconductor material strip 753. Each dielectric metal oxide strip 752 can be located between the isolation dielectric layer 751 and a respective overlying semiconductor material strip 753. In one embodiment, sidewalls of each dielectric metal oxide strip 752 may be vertically coincident with sidewalls of a respective overlying semiconductor material strip 753.

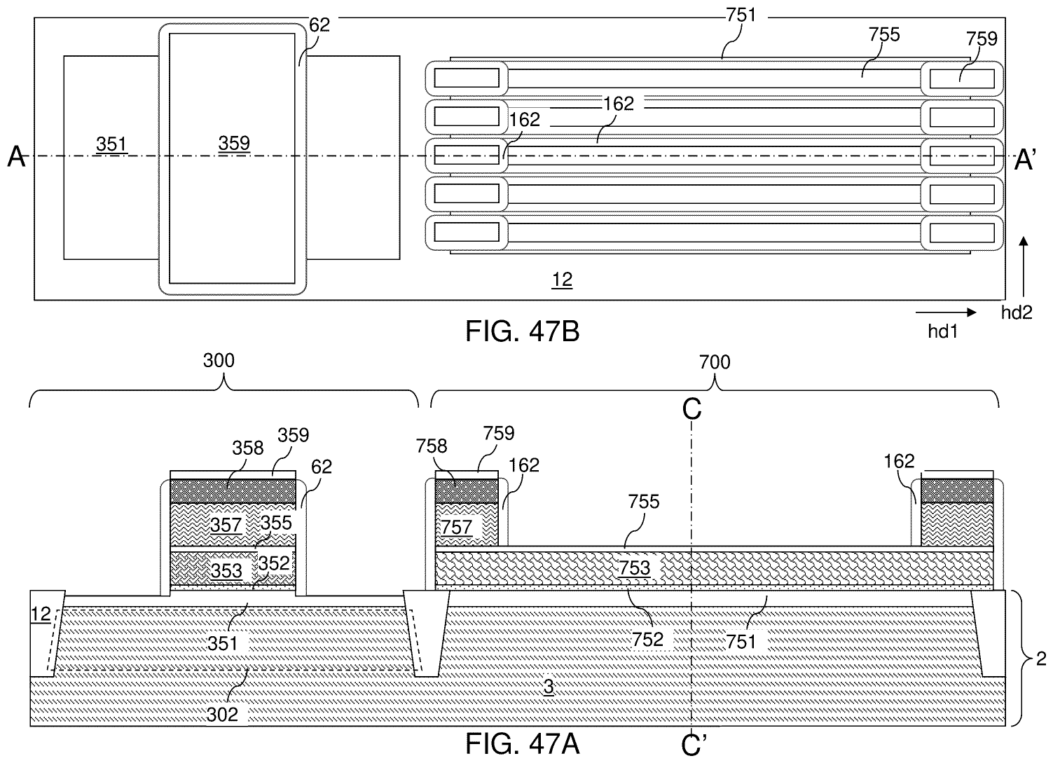

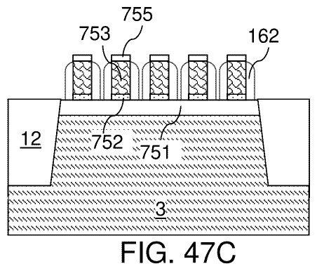

Referring to FIGS. 47A-47C, an inner dielectric gate spacer material layer may be conformally deposited, and may be subsequently anisotropically etched. The inner dielectric gate spacer material layer comprises a dielectric material such as silicon nitride or silicon oxide. A remaining vertically-extending portion of the inner dielectric gate spacer material layer that laterally surrounds the in-process gate stack (351, 352, 353, 355, 357, 358, 359) constitutes an inner dielectric gate spacer 62. Each remaining vertically-extending portion of the inner dielectric gate spacer material layer that laterally surrounds a respective in-process resistor structure (752, 753, 755, 757, 758, 759) constitutes an inner insulating spacer 162. Each inner insulating spacer 162 comprises a lower portion that laterally surrounds a respective semiconductor material strip 753, and a pair of upper portions that laterally surrounds a respective semiconductor pillar 757.

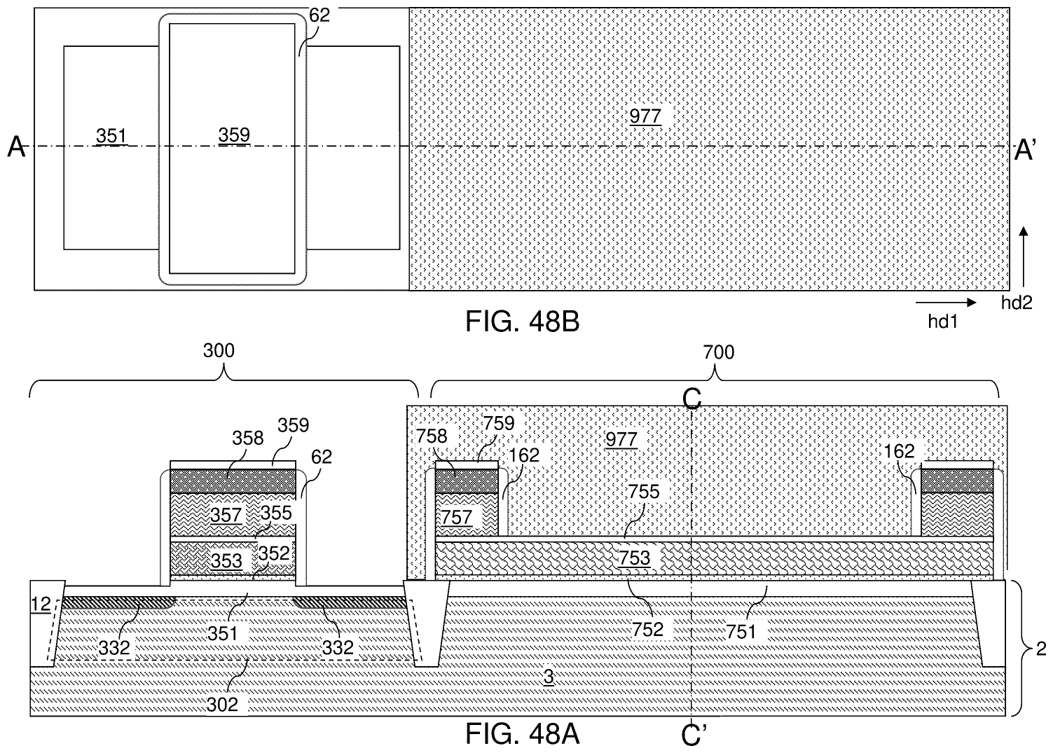

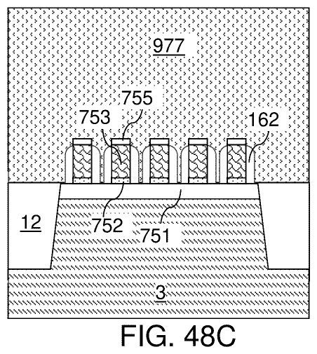

Referring to FIGS. 48A-48C, a photoresist layer 977 can be applied over the third exemplary structure, and can be lithographically patterned to cover the resistor region 700 without covering the second device region 300. Ion implantation processes may be performed to form source/drain extension regions 332.

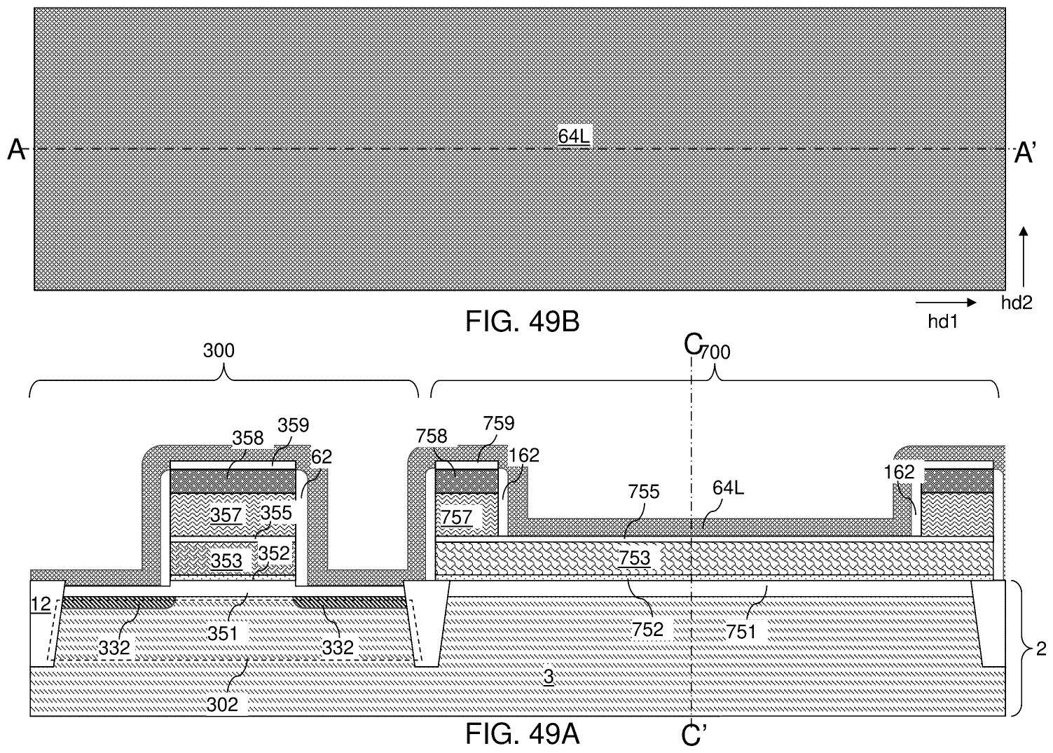

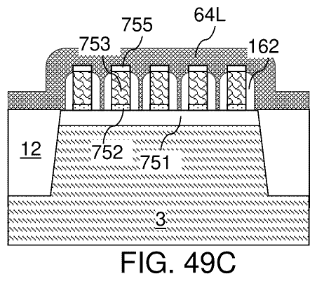

Referring to FIGS. 49A-49C, an outer dielectric gate spacer material layer 64L may be conformally deposited. The outer dielectric gate spacer material layer 64L comprises a dielectric material, such as silicon nitride, or a bilayer of silicon oxide and silicon nitride.

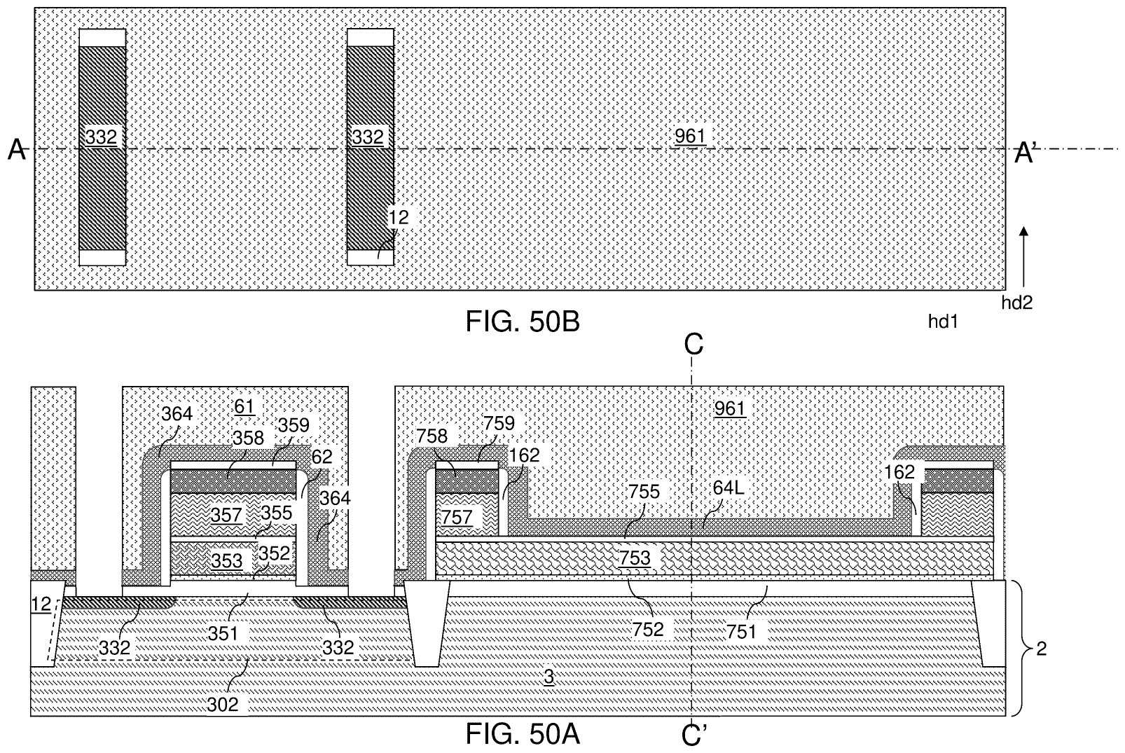

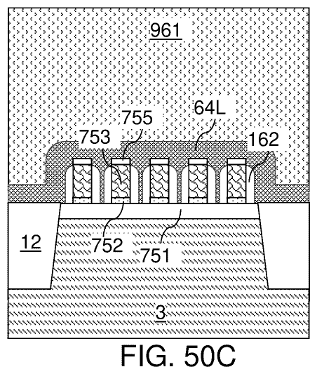

Referring to FIGS. 50A-50C, a photoresist layer 961 can be applied over the first exemplary structure, and can be lithographically patterned so that the resistor region 700 is covered with the photoresist layer 961, and a pair of openings is formed in the photoresist layer 961 in the second device region 300. If the third exemplary structure includes the first device region 100 and the third device region 500 as described with reference to the first exemplary structure and the second exemplary structure, the first device region 100 and the third device region 500 are not covered with the photoresist layer 961. An anisotropic etch process can be performed to etch unmasked horizontally-extending portions of the outer dielectric gate spacer material layer 64L and the first silicon oxide gate dielectric 351. A remaining masked portion of the outer dielectric gate spacer material layer 64L located in the second device region 300 and underlies the photoresist layer 961 comprises an outer dielectric gate spacer layer 364.

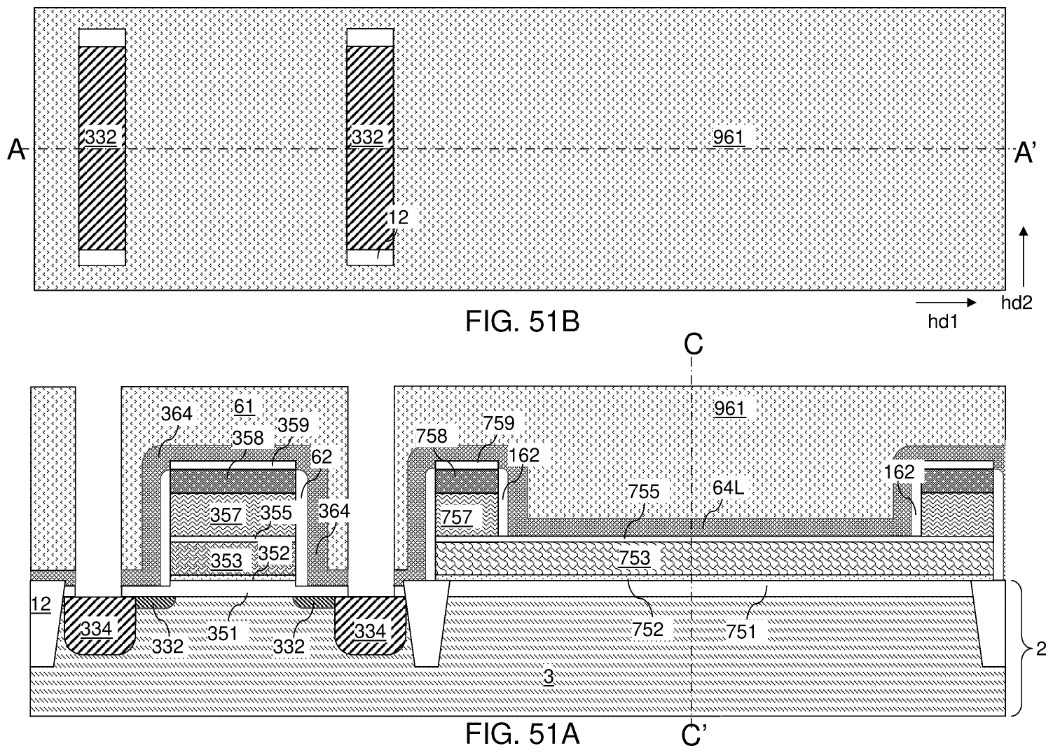

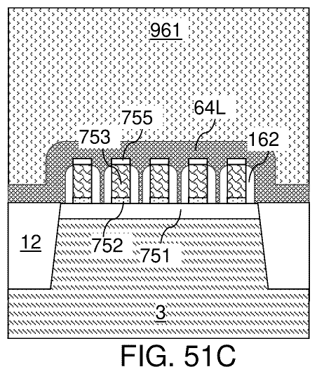

Referring to FIGS. 51A-51C, ion implantation processes may be performed to form deep source/drain regions (134, 334, 534), which include second deep source/drain regions 334 that are formed in the second device region 300. The photoresist layer 961 can be subsequently removed, for example, by ashing.

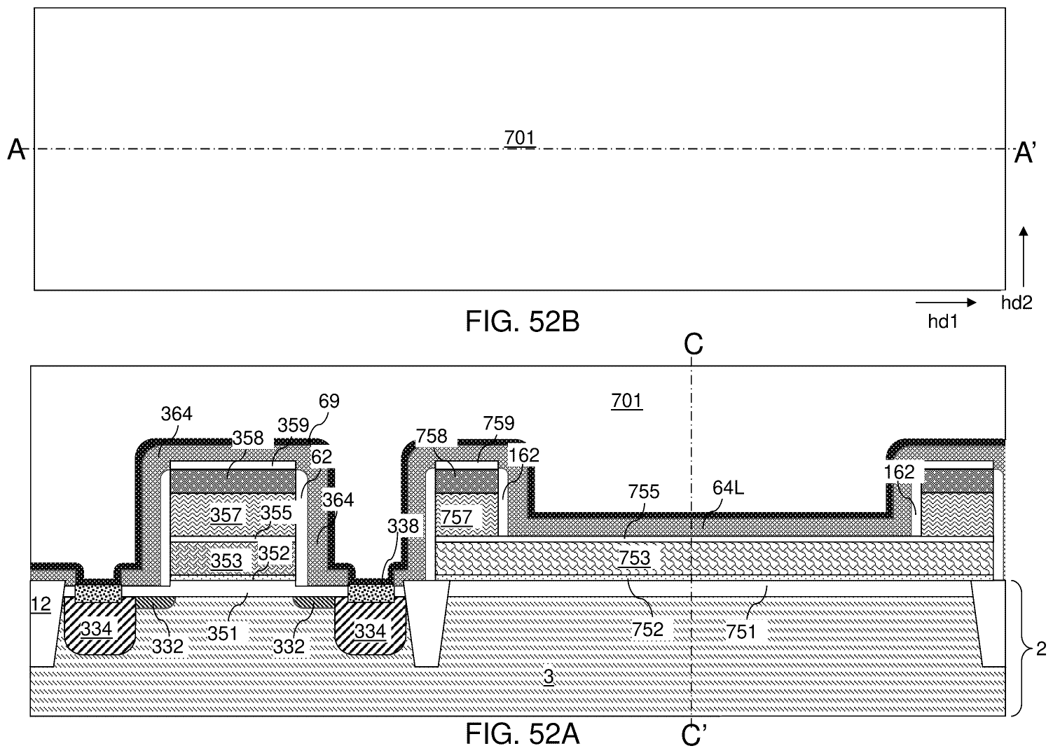

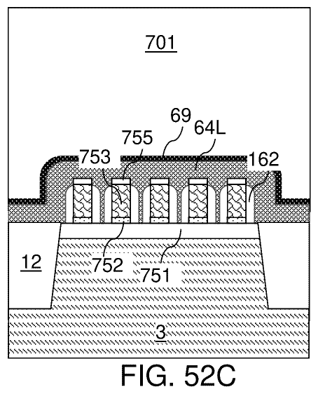

Referring to FIGS. 52A-52C, a metal layer can be deposited over the first exemplary structure. The metal layer comprises and/or consists essentially o, at least one elemental metal that forms a metal-semiconductor alloy (such as a metal silicide) with the semiconductor material of the various deep source/drain regions (134, 334, 534). An anneal can be performed to form various metal-semiconductor alloy regions (138, 338, 538) that includes a metal-semiconductor alloy (such as a metal silicide) of the at least one elemental metal and the semiconductor material in the upper portions of the various deep source/drain regions (134, 334, 534). Unreacted portions of the metal layer can be removed selectively to the various metal-semiconductor alloy regions (138, 338, 538), for example, by performing a selective wet etch process. The various metal-semiconductor alloy regions (138, 338, 538) may comprise second metal-semiconductor alloy regions 338 that are formed on the second deep source/drain regions 334 and additional metal-semiconductor alloy regions as described above with reference to the first exemplary structure and the second exemplary structure.

A dielectric diffusion barrier layer 69 may be deposited over the various gate structures and the various metal-semiconductor alloy regions (138, 338, 538). The dielectric diffusion barrier layer 69 may comprise a dielectric diffusion barrier material such as silicon nitride or silicon carbonitride. A planarization dielectric layer 701 can be formed over the dielectric diffusion barrier layer 69. The planarization dielectric layer 701 comprises a planarizable dielectric material, such as undoped silicate glass or a doped silicate glass.

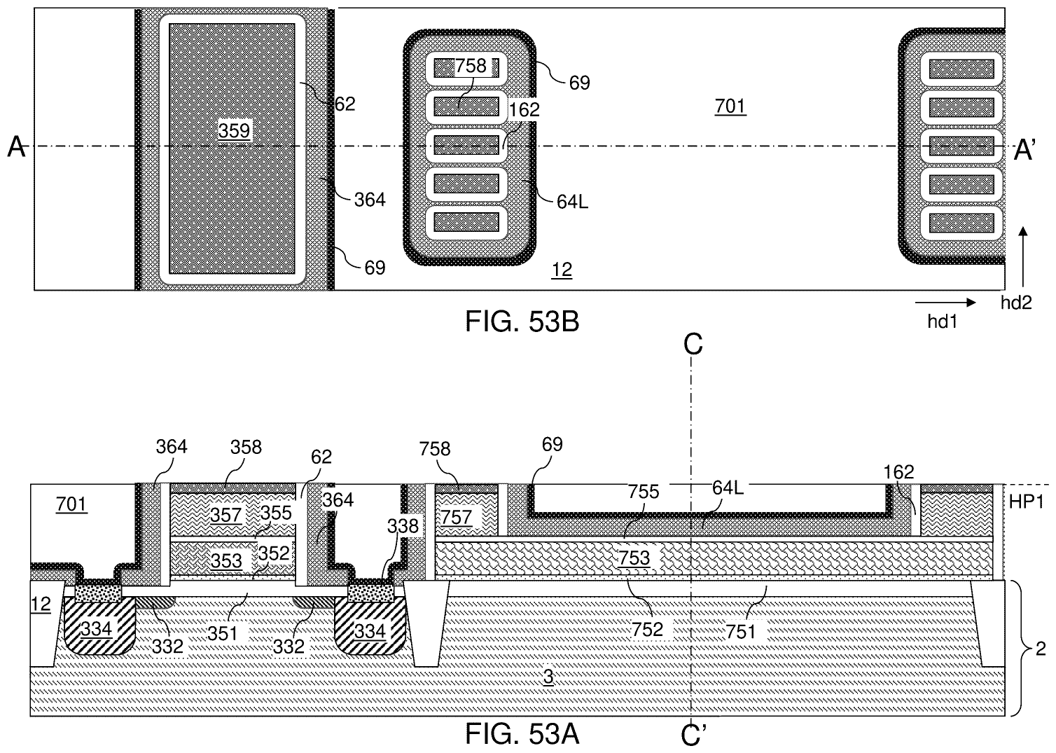

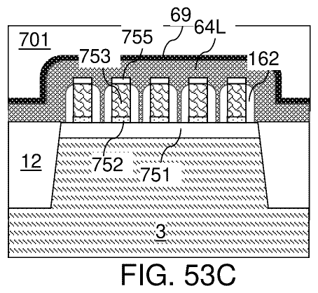

Referring to FIGS. 53A-53C, a planarization process, such as a chemical mechanical polishing process, can be performed to remove portions of the planarization dielectric layer 701 and portions of the sacrificial gate caps (358, 359) and resistor dielectric caps (758, 759) from above a first horizontal plane HP1 that overlies the top surfaces of the upper semiconductor gate electrode 357 and the semiconductor pillars 757. In one embodiment, the first horizontal plane HP1 may be located below the horizontal plane including interfaces between the lower sacrificial gate cap 358 and the upper sacrificial gate cap 359. The planarization process may remove the entirety of the upper sacrificial gate cap 359 and the upper resistor dielectric caps 759 and remove upper portions of the sacrificial gate cap 358 and the lower resistor dielectric caps 758.

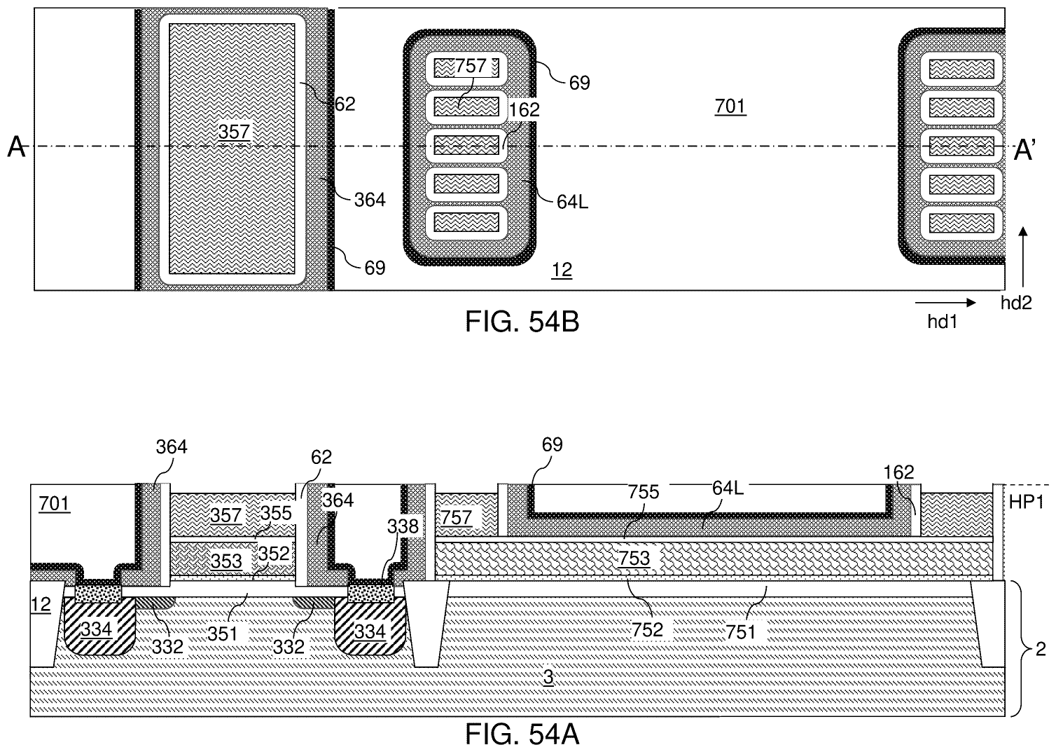

Referring to FIGS. 54A and 54B, a selective etch process can be performed to remove the lower sacrificial gate cap 358 and the lower resistor dielectric caps 758. For example, if the lower sacrificial gate cap 358 and the lower resistor dielectric caps 758 comprise silicon nitride, a wet etch process employing hot phosphoric acid may be performed to remove the lower sacrificial gate cap 358 without removing the upper semiconductor gate electrode 358 or the semiconductor pillars 757.

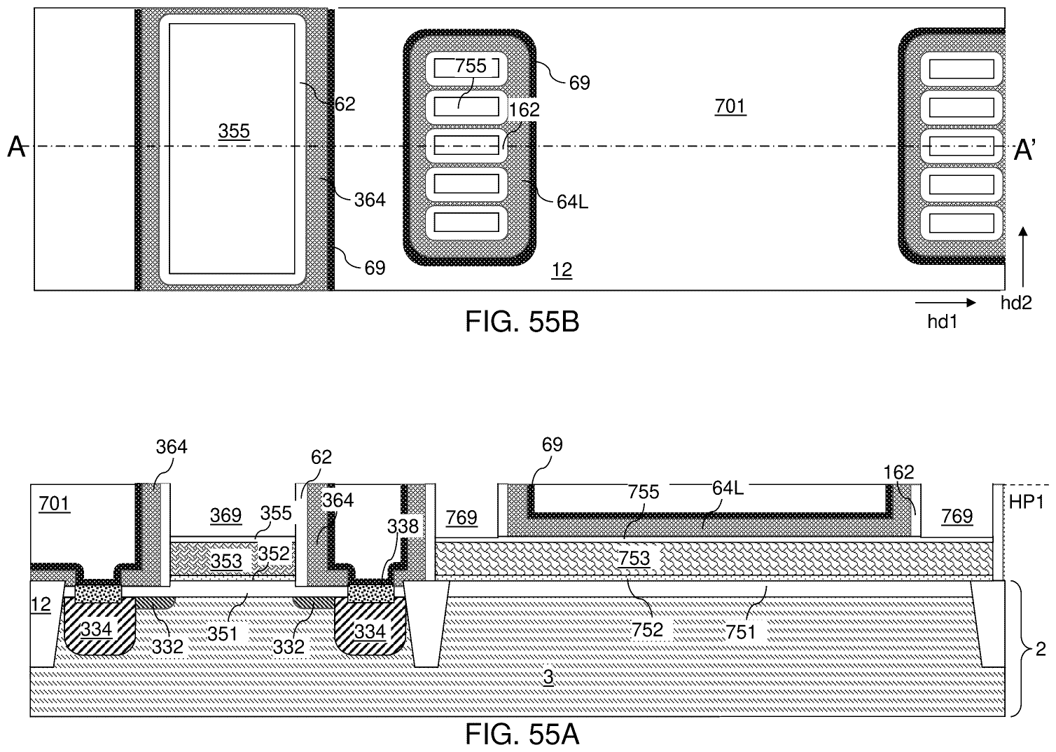

Referring to FIGS. 55A and 55B, a first selective etch process can be subsequently performed to remove the sacrificial semiconductor gate electrode 357 and the semiconductor pillars 757 selectively to the materials of the etch-stop layer 355 and the etch-stop strips 755. For example, the first selective etch process may comprise a wet etch process using hot trimethyl-2 hydroxyethyl ammonium hydroxide (“hot TMY”) or tetramethyl ammonium hydroxide (TMAH).

Generally, a first selective etch process can be performed which etches the material of the upper gate semiconductor layer 57L selectively to the material of the etch-stop layer 55L. A second gate cavity 369 is formed over a remaining portion of the etch-stop layer 55L in the second device region 300. A contact cavity 769 can be formed in each volume from which a semiconductor pillar 757 is removed.

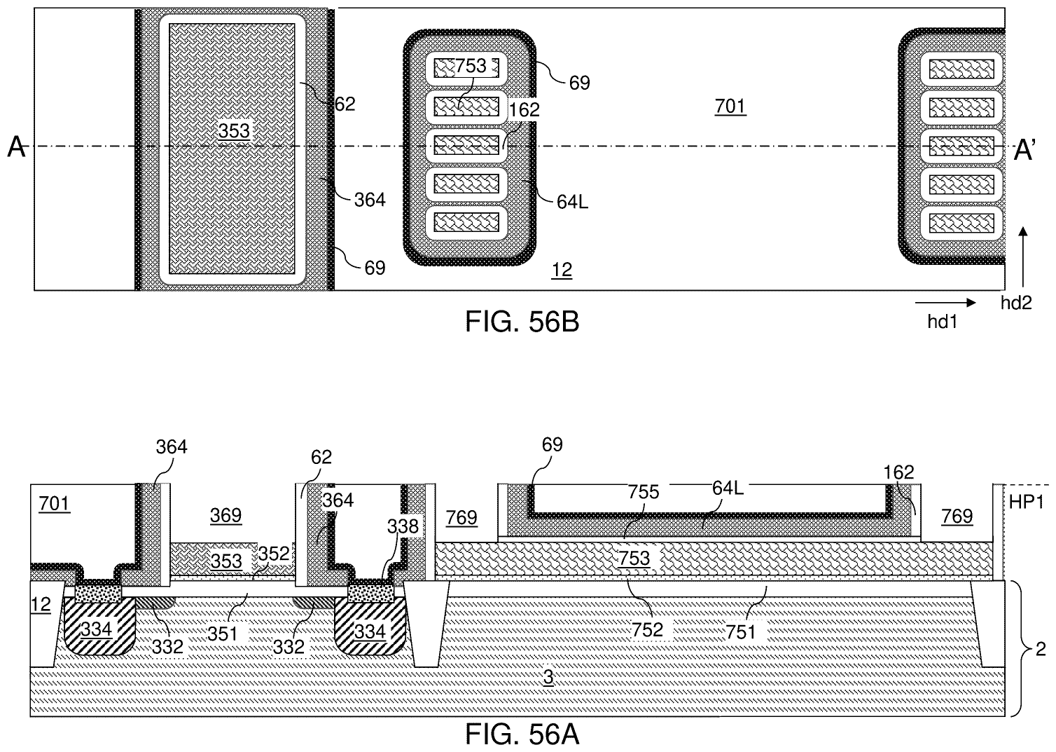

Referring to FIGS. 56A and 56B, a second selective etch process can be performed to remove the etch-stop layer 355 and unmasked portions of the etch-stop strips 755 selectively to the material of the second lower semiconductor gate electrode 353 and the semiconductor material strips 753. For example, if the etch-stop layer 355 and the etch-stop strips 755 comprise silicon oxide, an anisotropic etch process that etches silicon oxide selectively to semiconductor materials may be performed to remove the etch-stop layer 355 and unmasked portions of the etch-stop strips 755 selectively to the second lower semiconductor gate electrode 353 and the semiconductor material strips 753. Generally, the second selective etch process etches the remaining portion of the etch-stop layer 55L selectively to the material of the lower gate semiconductor layer 53L.

A gate cavity 369 is formed in the volume from which the materials of the lower sacrificial gate caps 358, the sacrificial upper semiconductor gate electrode 357, and the etch-stop layer 355 are removed. Each contact cavity 769 includes a volume from which a semiconductor pillar 757 and a portion of an etch-stop strip 755 are removed.

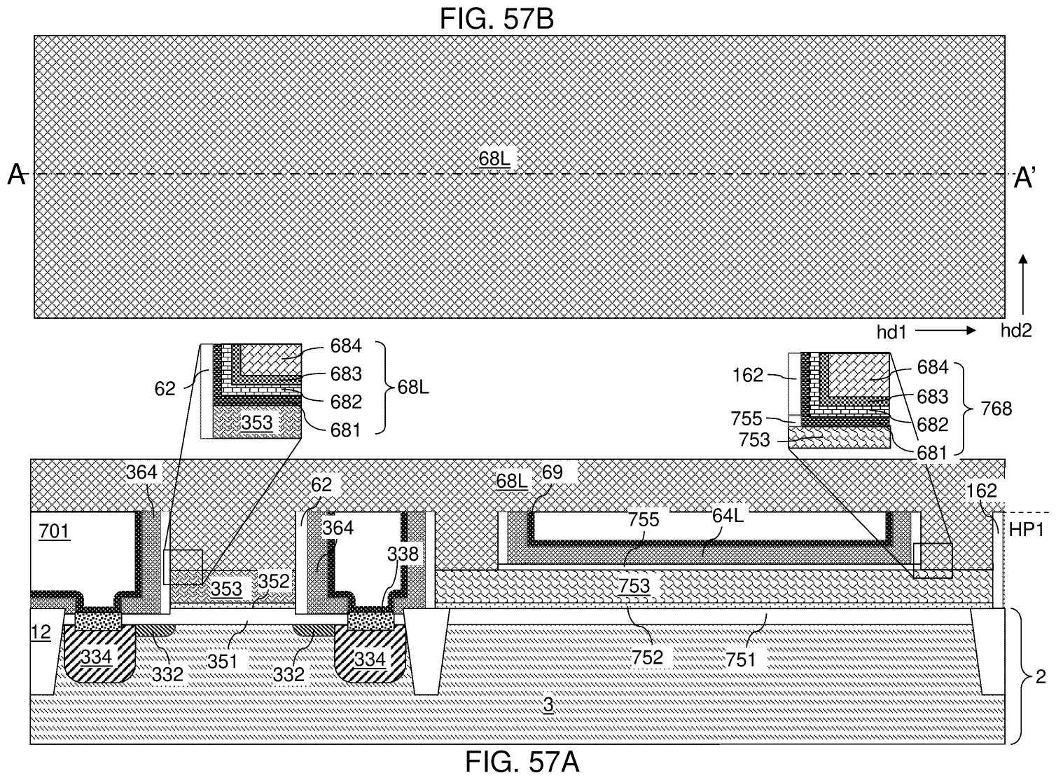

Referring to FIGS. 57A and 57B, a replacement metallic material layer 68L can be deposited in the gate cavity 369 and the contact cavities 769 and over the planarization dielectric layer 701. The replacement metallic material layer 68L comprises and/or consist of at least one metallic material. For example, the replacement metallic material layer 68L may comprise at least one metallic liner (681, 682, 683) and at least one metallic fill material portion 684. In one embodiment, the at least one metallic liner (681, 682, 683) may comprise a plurality of metallic liners (681, 682, 683) such as a first metallic liner 681, a second metallic liner 682, and a third metallic liner 683. In an illustrative example, the first metallic liner 681 may comprise a tantalum nitride layer, the second metallic liner 682 may comprise an alloy of titanium and aluminum, and the third metallic liner 683 may comprise a stack of a titanium layer and a titanium nitride layer. The at least one metallic fill material portion 684 may comprise at least one refractory metal such as tungsten, molybdenum, tantalum, etc.

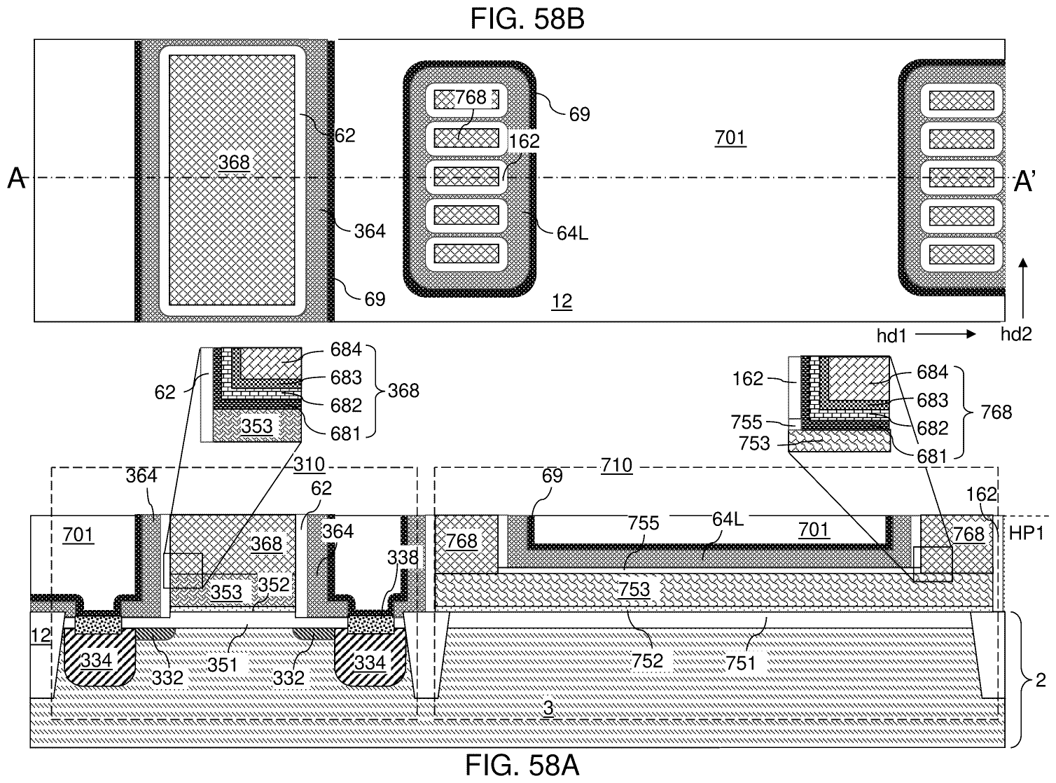

Referring to FIGS. 58A and 58B, the replacement metallic material layer 68L may be removed from above the first horizontal plane HP1 by performing a planarization process, such as a chemical mechanical polishing process. Remaining portions of the replacement metallic material layer 68L comprise a metallic gate electrode 368 that fills the gate cavity 369 and metallic contact structures 768 that are formed in the contact cavities 769.

Each in-process resistor structure (752, 753, 755, 757, 758, 759) is converted into a resistor structure (752, 753, 755, 768) by replacing a combination of a first semiconductor pillar 757 and an underlying portion of the etch-stop strip 755 with a first metallic contact structure 768 and by replacing a combination of a second semiconductor pillar 757 and an underlying portion of the etch-stop strip 755 with a second metallic contact structure 768. The first metallic contact structure 768 and the second metallic contact structure 768 comprise portions of the at least one metallic material that remain after the planarization process. Generally, a patterned portion of the upper gate semiconductor layer 57L and a patterned portion of the etch-stop layer 55L in an in-process gate structure (351, 352, 353, 355, 357, 358, 359) in the second device region 300 is replaced with a metallic gate electrode 368; and additional patterned portions of the upper gate semiconductor layer 57L and additional patterned portions of the etch-stop layer 55L in the resistor region 700 are replaced with the metallic contact structures 768.

At least one resistor structure (752, 753, 755, 768) is formed in a first portion of the semiconductor substrate 2. A field effect transistor 310 comprising a pair of source/drain regions (332, 334), a gate dielectric (351, 352), and a gate electrode (353, 368) is formed on a second portion of the semiconductor substrate 2. The metallic gate electrode 368 comprises a same set of at least one metallic material as the first metallic contact structure 768 and the second metallic contact structure 768. The gate electrode (353, 358) comprises a vertical stack of the doped semiconductor gate electrode 353 and the metallic gate electrode 368. The metallic gate electrode 368 can be formed by replacing a combination of a sacrificial semiconductor gate electrode 357 and a patterned portion of an etch-stop layer 55L with the metallic gate electrode 368.

The third exemplary structure includes a resistor 710 which comprises: an isolation dielectric layer 751 located on a top surface of a first portion of a semiconductor substrate 2; a semiconductor material strip 753 overlying the isolation dielectric layer 751; a first metallic contact structure 768 located on a first end portion of the semiconductor material strip 753; and a second metallic contact structure 768 located on a second end portion of the semiconductor material strip 753. The first metallic contact structure 768 comprises at least one first metallic liner (681, 682, 683) each having a respective first horizontally-extending portion and a respective first tubular portion that vertically extends upward from a periphery of the respective first horizontally-extending portion.

In one embodiment, the second metallic contact structure 768 comprises at least one second metallic liner (681, 682, 683) each having a respective second horizontally-extending portion and a respective second tubular portion that vertically extends upward from a periphery of the respective second horizontally-extending portion. In one embodiment, the first metallic contact structure 768 comprises a first portion of at least one metallic material; and the second metallic contact structure 768 comprises a second portion of the at least one metallic material. For each metallic material portion located within the first metallic contact structure 768, a corresponding metallic material portion having a same material composition is present in the second metallic contact structure 768; and for each metallic material portion located within the second metallic contact structure 768, a corresponding metallic material portion having a same material composition is present in the first metallic contact structure 768.

In one embodiment, the resistor 710 also comprises a planarization dielectric layer 701 laterally surrounding the semiconductor material strip 753, the first metallic contact structure 768, and the second metallic contact structure 768. Top surfaces of the first metallic contact structure 768 and the second metallic contact structure 768 are located within a horizontal plane (such as the first horizontal plane HP1) including a top surface of the planarization dielectric layer 701.

In one embodiment, the resistor 710 also comprises an inner insulating spacer 162 laterally surrounding each of the semiconductor material strip 753, the first metallic contact structure 768, and the second metallic contact structure 768, and having a topmost surface located within a horizontal plane (such as the first horizontal plane HP1) including top surfaces of the first metallic contact structure 768 and the second metallic contact structure 768. In one embodiment, the resistor 710 also comprises a dielectric diffusion barrier layer 69 laterally surrounding the inner insulating spacer 162 and comprising a horizontally-extending portion located over a middle portion of the semiconductor material strip 753 and between the first metallic contact structure 768 and the second metallic contact structure 768. A top surface of the dielectric diffusion barrier layer 69 is located within the horizontal plane (such as the first horizontal plane HP1) including top surfaces of the first metallic contact structure 768 and the second metallic contact structure 768.

In one embodiment, the planarization dielectric layer 701 laterally surrounds the dielectric diffusion barrier layer 69 comprises a portion that overlies the horizontally-extending portion of the dielectric diffusion barrier layer 69. A top surface of the planarization dielectric layer 701 is located within the horizontal plane (such as the first horizontal plane HP1) including top surfaces of the first metallic contact structure 768 and the second metallic contact structure 768. In one embodiment, the resistor 710 also comprises an etch-stop strip 755 contacting a middle portion of a top surface of the semiconductor material strip 753, a bottom segment of a sidewall of the first metallic contact structure 768, a bottom segment of a sidewall of the second metallic contact structure 768, and bottom surface segments of portions of the inner insulating spacer 162 having an areal overlap with the semiconductor material strip 753 in a plan view.

In one embodiment, a sidewall of the first metallic contact structure 768 is vertically coincident with a first end wall of the semiconductor material strip 753; and a sidewall of the second metallic contact structure 768 is vertically coincident with a second end wall of the semiconductor material strip 753. In one embodiment, the resistor 710 also comprises a dielectric metal oxide strip 752 located between the isolation dielectric layer 751 and the semiconductor material strip 753. In one embodiment, sidewalls of the dielectric metal oxide strip 752 are vertically coincident with sidewalls of the semiconductor material strip 753.

In one embodiment, in addition to the resistor, the semiconductor structure also comprises a field effect transistor 310 that comprises: a pair of source/drain regions (332, 334) embedded within a second portion of the semiconductor substrate 2; a gate dielectric (351, 352) overlying a channel region located between the pair of source/drain regions (332, 334); and a gate electrode (353, 368).

The gate electrode (353, 368) comprises a metallic gate electrode 368 and a semiconductor gate electrode portion 353 that underlies the metallic gate electrode 368 and having a same thickness as the semiconductor material strip 753. In one embodiment, the metallic gate electrode 368 comprises at least one gate metallic liner (681, 682, 683) each having a respective horizontally-extending portion and a respective tubular portion that vertically extends upward from a periphery of the respective horizontally-extending portion. In one embodiment, for each gate metallic liner (681, 682, 683) in the metallic gate electrode 368, a corresponding first metallic liner (681, 682, 683) having a same material composition and a same thickness is present in the first metallic contact structure 768; and for each first metallic liner (681, 682, 683) in the first metallic contact structure 768, a corresponding gate metallic liner (681, 682, 683) having a same material composition and a same thickness is present in the metallic gate electrode.

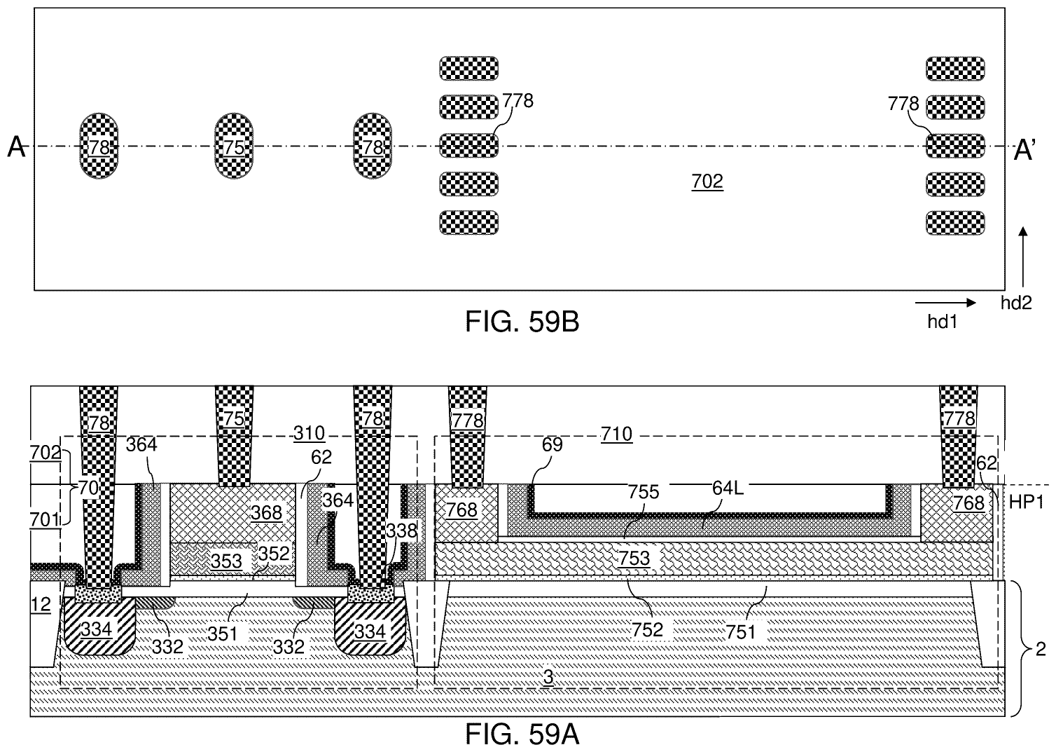

Referring to FIGS. 59A and 59B, a cover dielectric layer 702 can be formed over the planarization dielectric layer 701. The cover dielectric layer 702 comprises a dielectric material, such as undoped silicate glass or a doped silicate glass. The combination of the planarization dielectric layer 701 and the cover dielectric layer 702 constitutes a contact-level dielectric layer 70. As noted above, the third exemplary structure may comprise a first device region 100 and a third device region 500 described with reference to the first exemplary structure and the second exemplary structure. Various contact via structures (75, 78, 778) can be formed through the contact-level dielectric layer 70 on a respective one of the metallic gate electrodes (168, 358, 568), the metal-semiconductor alloy regions (138, 338, 538) and the metallic contact structures 768. The various contact via structures (75, 78, 778) may comprise source/drain contact via structures 78 contacting a respective one of the metal-semiconductor alloy regions (138, 338, 538), gate contact via structures 75 contacting a respective one of the metallic gate electrodes (168, 358, 568), and resistor contact via structures 778 contacting a respective one of the metallic contact structures 768.

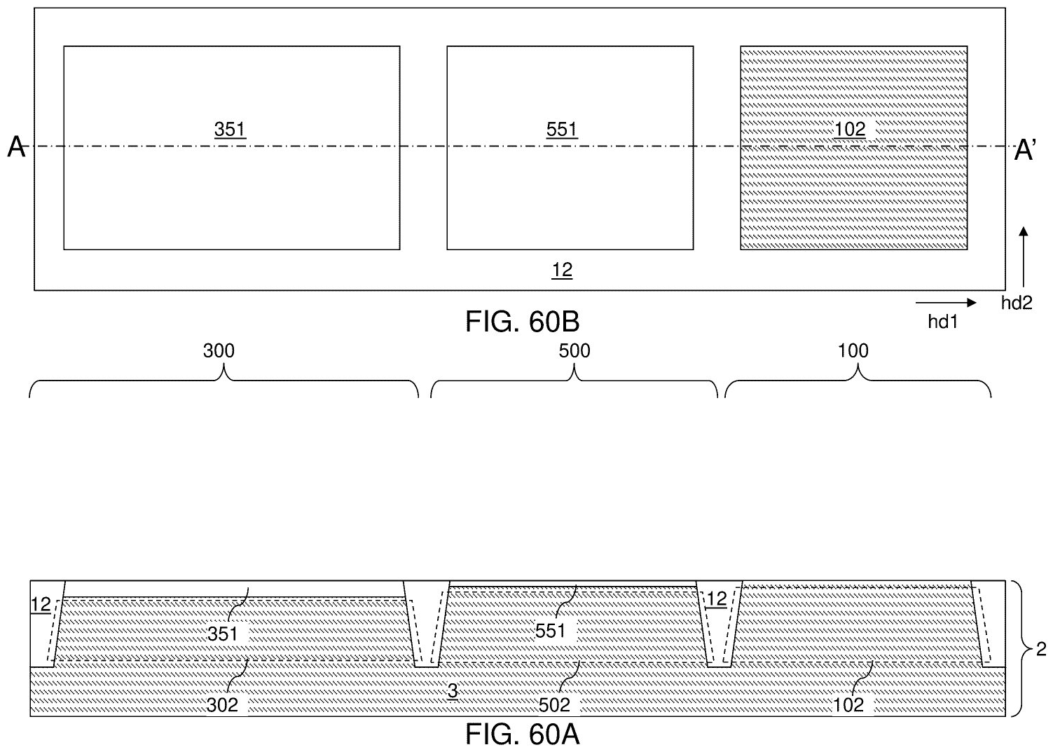

Referring to FIGS. 60A and 60B, a fourth exemplary structure is illustrated, which may be the same as the first exemplary structure described with reference to FIGS. 2A and 2B.

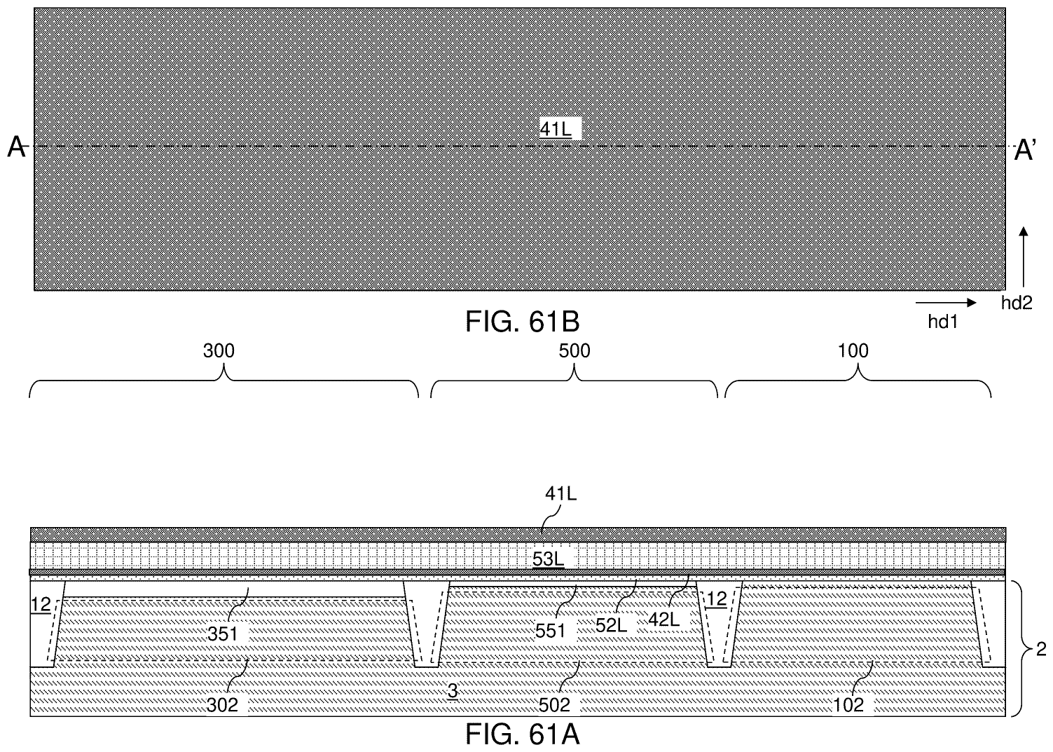

Referring to FIGS. 61A and 61B, the processing steps described with reference to FIGS. 3A and 3B can be performed to sequentially deposit a gate dielectric metal oxide layer 52L, an optional metallic barrier liner layer 42L, and a lower gate semiconductor layer 53L. In the fourth exemplary structure, the lower gate semiconductor layer 53L is the only gate semiconductor layer that is employed. As such, the lower gate semiconductor layer 53L in the fourth exemplary structure is referred to as a gate semiconductor layer 53L. The thickness of the gate semiconductor layer 53L in the fourth exemplary structure may be increased relative to the thickness of the lower gate semiconductor layer 53L in the first exemplary structure. For example, the thickness of the gate semiconductor layer 53L in the fourth exemplary structure may be in a range from 40 nm to 200 nm, such as from 60 nm to 150 nm, although lesser and greater thicknesses may also be employed. The gate semiconductor layer 53L of the fourth exemplary structure can be suitably doped with electrical dopants.

A sacrificial gate cap layer 41L can be deposited over the gate semiconductor layer 53L. The sacrificial gate cap layer 41L comprises a sacrificial material that can be employed as a temporary gate capping material. The sacrificial gate cap layer 41L may comprise, for example, silicon oxide, silicon nitride, silicon carbonitride, etc. The sacrificial gate cap layer 41L may have a thickness in a range from 15 nm to 40 nm, such as from 20 to 30 nm, although lesser and greater thicknesses may also be employed.

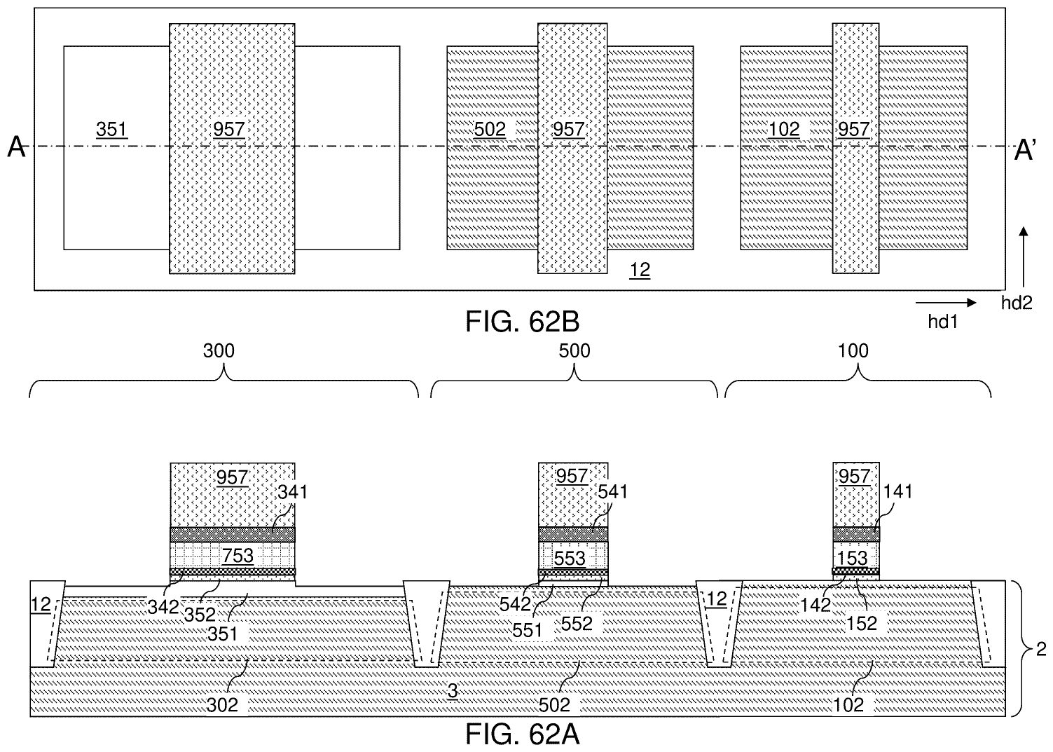

Referring to FIGS. 62A and 62B, a photoresist layer 957 can be applied over the sacrificial gate cap layer 41L, and can be lithographically patterned into gate electrode patterns, i.e., the patterns of gate electrodes to be subsequently formed. An anisotropic etch process including a sequence of anisotropic etch steps can be performed to transfer the pattern in the photoresist layer 957 through the sacrificial gate cap layer 41L, the gate semiconductor layer 53L, the optional metallic barrier liner layer 42L, and the gate dielectric metal oxide layer 52L. Further, the anisotropic etch process may comprise a terminal etch step that etches the second silicon oxide gate dielectric 551 and an upper portion of the first silicon oxide gate dielectric 351 selectively to the material of the single crystalline semiconductor layer 3. The duration of the terminal etch step may be selected such that the unmasked portions of the second silicon oxide gate dielectric 551 are etched through, but the unmasked portions of the first silicon oxide gate dielectric 351 are only partially etched. The photoresist layer 957 can be subsequently removed by ashing.

Gate structures are formed in the device regions (100, 300, 500) by the patterning step(s). The gate structures may comprise a first gate structure (152, 142, 153, 141) that is formed in the first device region 100, a second gate structure (351, 352, 342, 353, 341) that is formed in the second device region 300, and a third gate structure (551, 552, 542, 553, 541) that is formed in the third device region 500. The first gate structure (152, 142, 153, 141) may comprise, from bottom to top, a first metal oxide gate dielectric 152, an optional first metallic barrier liner 142, a first semiconductor gate electrode 153, and a first sacrificial gate cap 141. The second gate structure (351, 352, 342, 353, 341) may comprise, from bottom to top, a first silicon oxide gate dielectric 351, a second metal oxide gate dielectric 352, an optional second metallic barrier liner 342, a second semiconductor gate electrode 353, and a second sacrificial gate cap 341. The third gate structure (551, 552, 542, 553, 541) may comprise, from bottom to top, a second silicon oxide gate dielectric 551, a third metal oxide gate dielectric 552, an optional third metallic barrier liner 542, a third semiconductor gate electrode 553, and a third sacrificial gate cap 541.

The first gate structure (152, 142, 154, 141) comprises a first gate dielectric 152, which may consist of only the first metal oxide gate dielectric 152. The second gate structure (351, 352, 342, 353, 355, 341) comprises a second gate dielectric (351, 352), which comprises a dielectric stack of a first silicon oxide gate dielectric 351 and a second metal oxide gate dielectric 352. The third gate structure (551, 552, 542, 553, 541) comprises a third gate dielectric (551, 552), which comprises a dielectric stack of a second silicon oxide gate dielectric 551 and a third metal oxide gate dielectric 552. The gate structures are in-process gate structures that are subsequently modified. The first semiconductor gate electrode 153 and the third semiconductor gate electrode 553 are in-process gate electrodes which are subsequently replaced with metallic gate electrodes.

In one embodiment, sidewalls of the first gate dielectric 152 are vertically coincident with sidewalls of the first semiconductor gate electrode 153; and sidewalls of the second metal oxide gate dielectric 352 are vertically coincident with sidewalls of the second semiconductor gate electrode 353 (which is a doped semiconductor gate electrode). In one embodiment, a bottom surface of the first metal oxide gate dielectric 152 is in direct contact with a channel region of a first field effect transistor to be formed in the first device region 100.

As described above with respect to the first embodiment, the first silicon oxide gate dielectric 351 comprises: first sidewalls that are laterally offset outward relative to the sidewalls of the second metal oxide gate dielectric 352; and second sidewalls that are vertically coincident with, and are adjoined to, the sidewalls of the second metal oxide gate dielectric 352. In one embodiment, the first silicon oxide gate dielectric 351 comprises: a first portion located within an area of the second metal oxide gate dielectric 352 in a plan view and having a first thickness; and a second portion that does not have any areal overlap in the plan view and having a second thickness that is less than the first thickness. The photoresist layer 957 can be subsequently removed, for example, by ashing.

The first gate structure (152, 142, 153, 141) comprises a first gate dielectric 152, which comprises a first metal oxide gate dielectric 152 that is formed directly on a top surface of a first portion of the semiconductor substrate 2. The second gate dielectric (351, 352) comprises a first silicon oxide gate dielectric 351 that is formed directly on a top surface of the second portion of the semiconductor substrate 2, and further comprises a second metal oxide gate dielectric 352 that is formed on the first silicon oxide gate dielectric 351 and having a same material composition and a same thickness as the first metal oxide gate dielectric 152. Thus, in the fourth embodiment the second gate dielectric (351, 352) comprises: a first silicon oxide gate dielectric 351; and a second metal oxide gate dielectric 352 that comprises a second portion of the dielectric metal oxide material. In one embodiment, sidewalls of the first metal oxide gate dielectric 152 are vertically coincident with sidewalls of the first semiconductor gate electrode 153; sidewalls of the second metal oxide gate dielectric 352 are vertically coincident with sidewalls of the second semiconductor gate electrode 353; and sidewalls of the first silicon oxide gate dielectric 351 are laterally offset outward relative to the sidewalls of the second metal oxide gate dielectric 352.

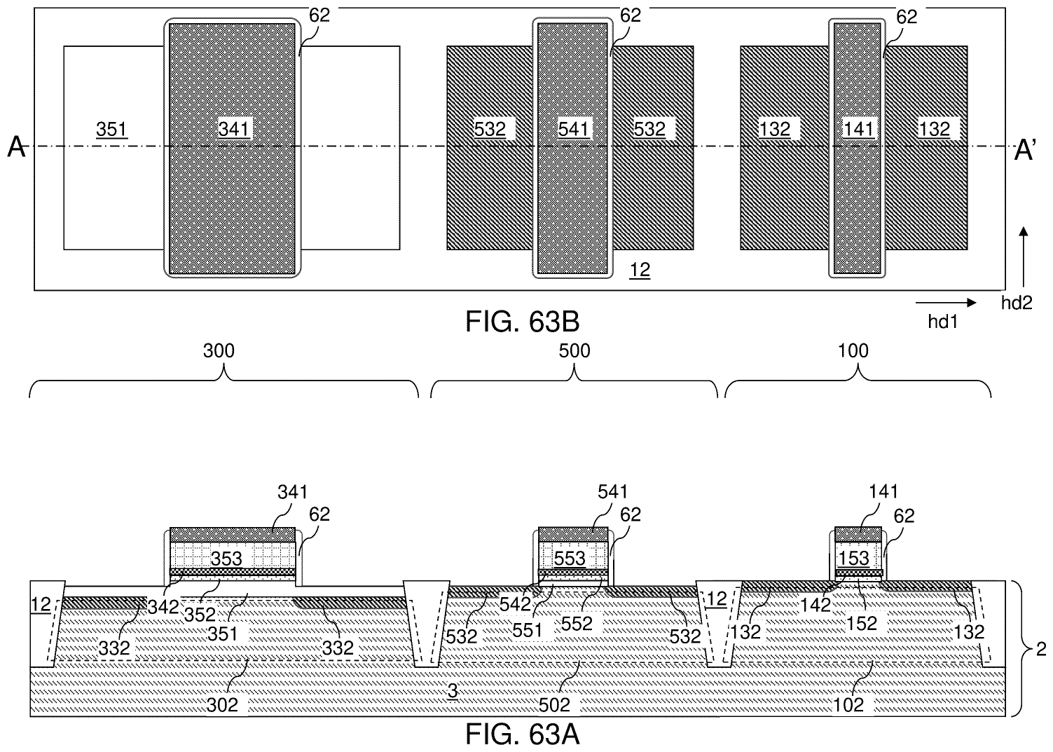

Referring to FIGS. 63A and 63B, an inner dielectric gate spacer material layer may be conformally deposited, and may be subsequently anisotropically etched. The inner dielectric gate spacer material layer comprises a dielectric material, such as silicon oxide. Each remaining vertically-extending portion of the inner dielectric gate spacer material layer constitutes an inner dielectric gate spacer 62. Ion implantation processes may be performed to form source/drain extension regions (132, 332, 532). The source/drain extension regions (132, 332, 532) may comprise first source/drain extension regions 132 that are formed in the first device region 100, second source/drain extension regions 332 that are formed in the second device region 300, and third source/drain extension regions 532 that are formed in the third device region 500. Generally, a first dielectric gate spacer (such as a first inner dielectric gate spacer 62) can be formed around the first gate structure (152, 142, 153, 141), and a second dielectric gate spacer (such as a second inner dielectric gate spacer 62) can be formed around the second gate structure (351, 352, 342, 353. 341).

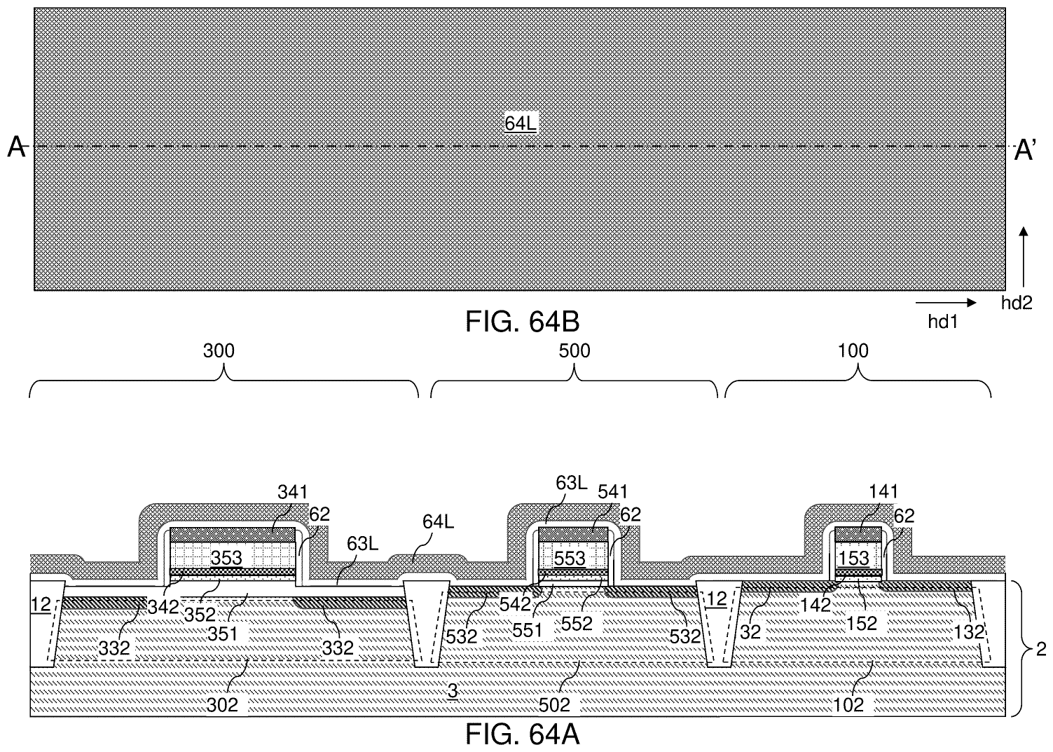

Referring to FIGS. 64A and 64B, an intermediate dielectric gate spacer material layer 63L may be conformally deposited. The intermediate dielectric gate spacer material layer 63L comprises a dielectric material, such as silicon oxide. An outer dielectric gate spacer material layer 64L may be subsequently conformally deposited. The outer dielectric gate spacer material layer 64L comprises a dielectric material, such as silicon nitride.

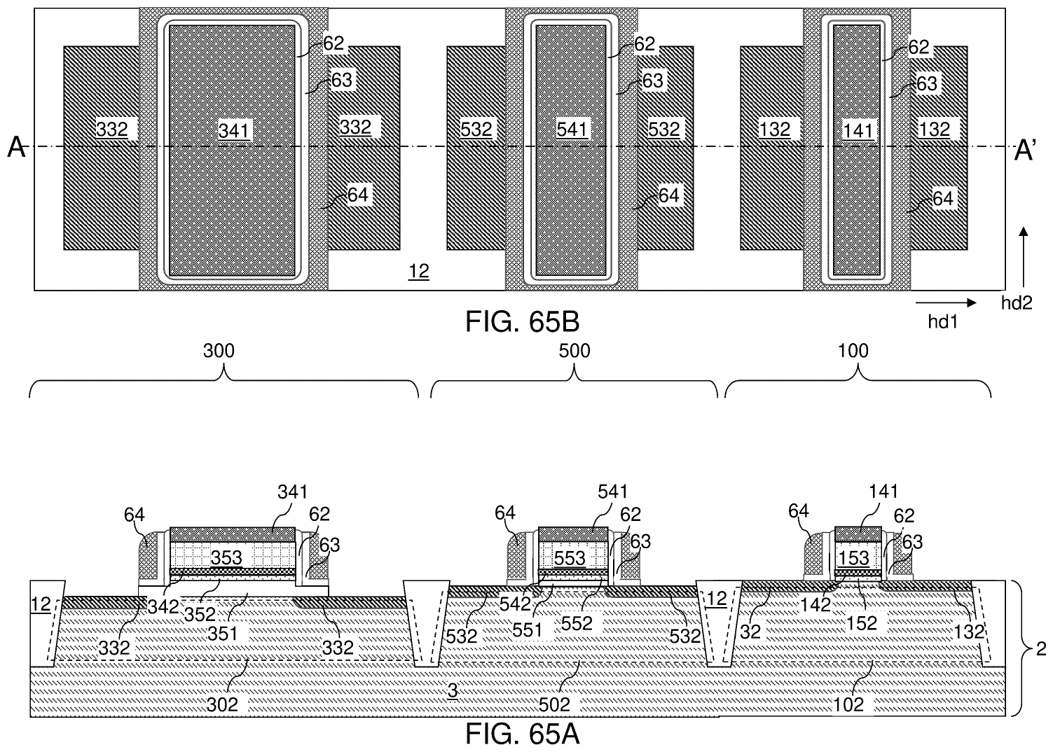

Referring to FIGS. 65A and 65B, an anisotropic etch process can be performed to etch unmasked horizontally-extending portions of the outer dielectric gate spacer material layer 64L, the intermediate dielectric gate spacer material layer 63L, and the first silicon oxide gate dielectric 351. Each remaining vertically-extending portion of the outer dielectric gate spacer material layer 64L constitutes an outer dielectric gate spacer 64. Each remaining portion of the intermediate dielectric gate spacer material layer 63L constitutes an intermediate dielectric gate spacer 63. Portions of the first silicon oxide gate dielectric 351 can be removed from outside the area defined by the outer sidewall of the outer dielectric gate spacer 64 in the second device region 300.

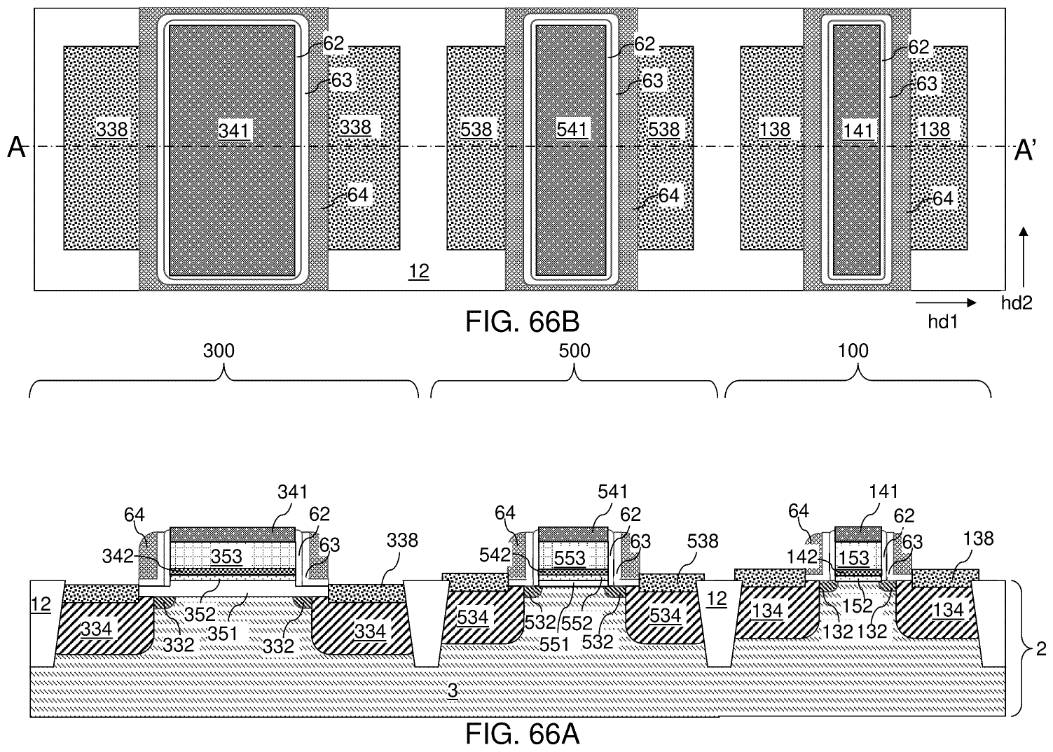

Referring to FIGS. 66A and 66B, ion implantation processes may be performed to form deep source/drain regions (134, 334, 534). The deep source/drain regions (134, 334, 534) may comprise first deep source/drain regions 134 that are formed in the first device region 100, second deep source/drain regions 334 that are formed in the second device region 300, and third deep source/drain regions 534 that are formed in the third device region 500. Each contiguous combination of a first source/drain extension region 132 and a first deep source/drain region 134 constitutes a first source/drain region (132, 134). Each contiguous combination of a second source/drain extension region 332 and a second deep source/drain region 334 constitutes a second source/drain region (332, 334). Each contiguous combination of a third source/drain extension region 532 and a third deep source/drain region 534 constitutes a third source/drain region (532, 534).

A metal layer can be deposited over the fourth exemplary structure. As described above with respect to the first embodiment, the metal layer comprises and/or consists essentially of at least one elemental metal that forms a metal-semiconductor alloy (such as a metal silicide) with the semiconductor material of the various deep source/drain regions (134, 334, 534). An anneal can be performed to form various metal-semiconductor alloy regions (138, 338, 538) that includes a metal-semiconductor alloy (such as a metal silicide) of the at least one elemental metal and the semiconductor material in the upper portions of the various deep source/drain regions (134, 334, 534). Unreacted portions of the metal layer can be removed selectively to the various metal-semiconductor alloy regions (138, 338, 538), for example, by performing a selective wet etch process. The metal-semiconductor alloy regions (138, 338, 538) may comprise first metal-semiconductor alloy regions 138 that are formed on the first deep source/drain regions 134, second metal-semiconductor alloy regions 338 that are formed on the second deep source/drain regions 334, and third metal-semiconductor alloy regions 538 that are formed on the third deep source/drain regions 534.

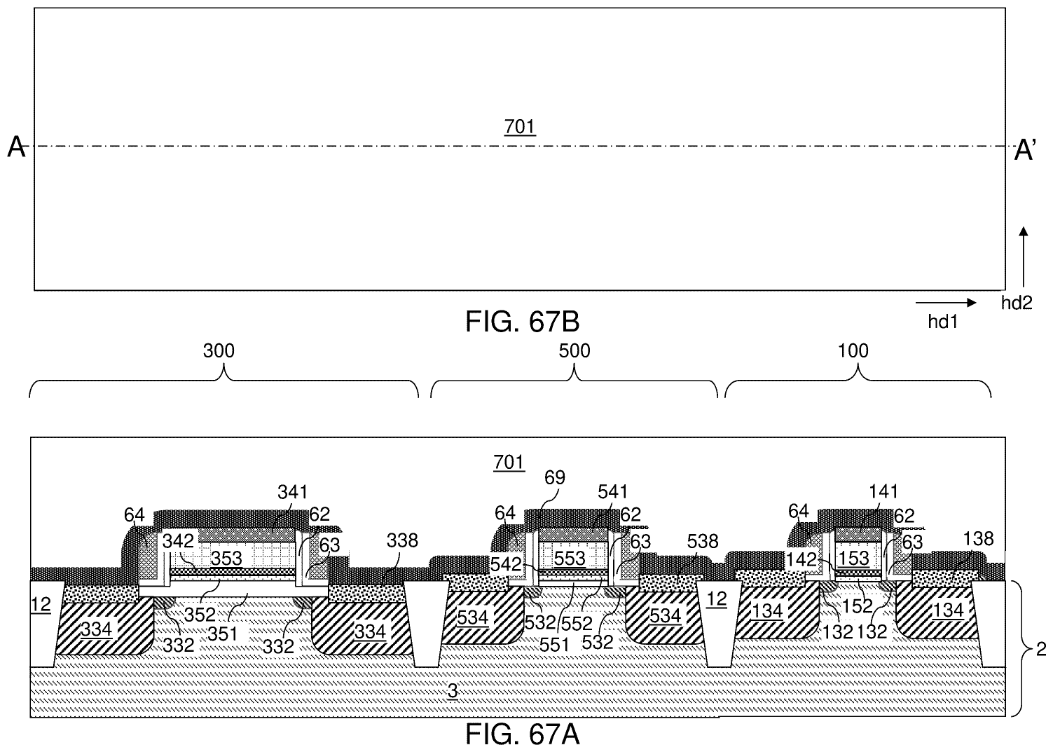

Referring to FIGS. 67A and 67B, a dielectric diffusion barrier layer 69 may be deposited over the various gate structures and the various metal-semiconductor alloy regions (138, 338, 538). The dielectric diffusion barrier layer 69 may comprise a dielectric diffusion barrier material, such as silicon nitride or silicon carbonitride. A planarization dielectric layer 701 can be formed over the dielectric diffusion barrier layer 69 around each of the gate structures. The planarization dielectric layer 701 comprises a planarizable dielectric material, such as undoped silicate glass or a doped silicate glass.

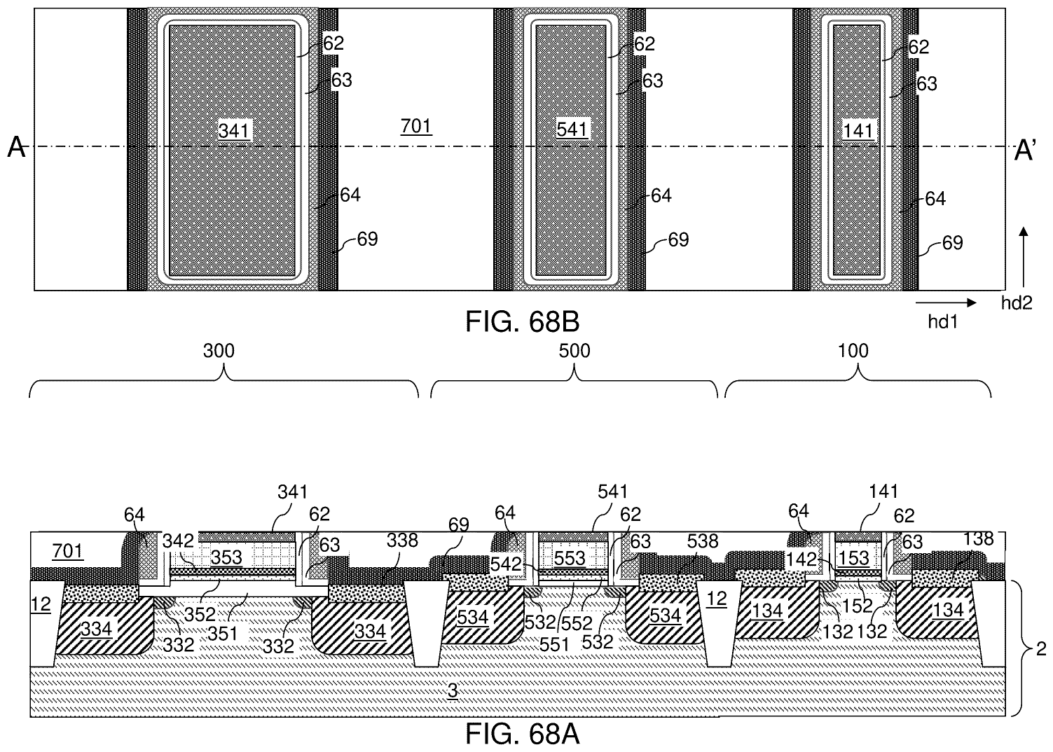

Referring to FIGS. 68A and 68B, a planarization process, such as a chemical mechanical polishing process, can be performed to remove portions of the planarization dielectric layer 701 and portions of the dielectric diffusion barrier layer 69 and the sacrificial gate caps (141, 341, 541) from above a horizontal plane that overlies the top surfaces of the semiconductor gate electrodes (153, 353, 553). The planarization process may remove upper portions of all sacrificial gate caps (141, 341, 541).

The planarization process removes top portions of the inner dielectric gate spacers 62 and the intermediate dielectric gate spacers 63 during formation of the planarization dielectric layer 701 such that remaining portions of the inner dielectric gate spacers 62 and the intermediate dielectric gate spacers 63 comprise planar top surfaces that are formed within a horizontal plane containing a top surface of the planarization dielectric layer 701. Generally, a first dielectric gate spacer (such as a first inner dielectric gate spacer 62 and/or a first intermediate dielectric gate spacer 63) having a first planar dielectric top surface laterally surrounds a first semiconductor gate electrode 153; a second dielectric gate spacer (such as a second inner dielectric gate spacer 62 and/or a second intermediate dielectric gate spacer 63) having a second planar dielectric top surface laterally surrounds a second semiconductor gate electrode 353; and a third dielectric gate spacer (such as a third inner dielectric gate spacer 62 and/or a third intermediate dielectric gate spacer 63) having a third planar dielectric top surface laterally surrounds a third semiconductor gate electrode 553. The second semiconductor gate electrode 353 is also referred to as a doped semiconductor gate electrode 353.

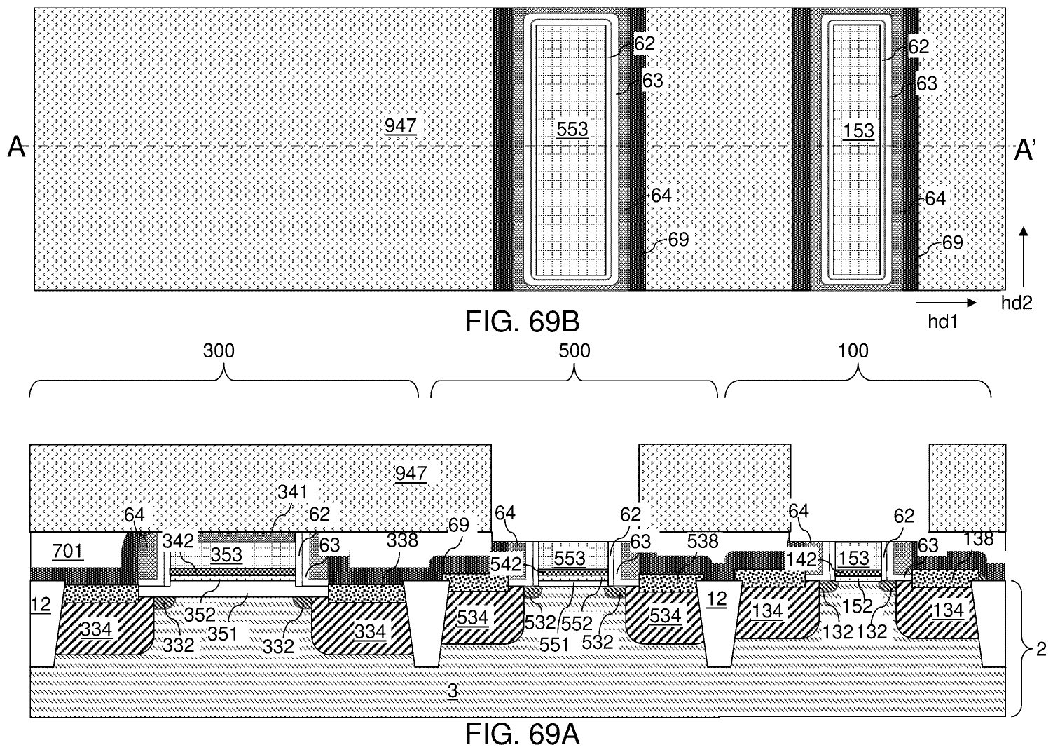

Referring to FIGS. 69A and 69B, a photoresist layer 947 can be applied over the planarization dielectric layer 701, and can be lithographically patterned to form openings over the areas of the first sacrificial gate cap 141 and the third sacrificial gate cap 541. An etch process can be performed to remove the first sacrificial gate cap 141 and the third sacrificial gate cap 541 selectively to the materials of the first semiconductor gate electrode 153 and the third semiconductor gate electrode 553. The etch process may comprise an anisotropic etch process (such as a reactive ion etch process) or an isotropic etch process (such as a wet etch process). Physically exposed portions of the various dielectric gate spacers (62, 63, 64) and the dielectric diffusion barrier layer 69 may optionally be collaterally etched.

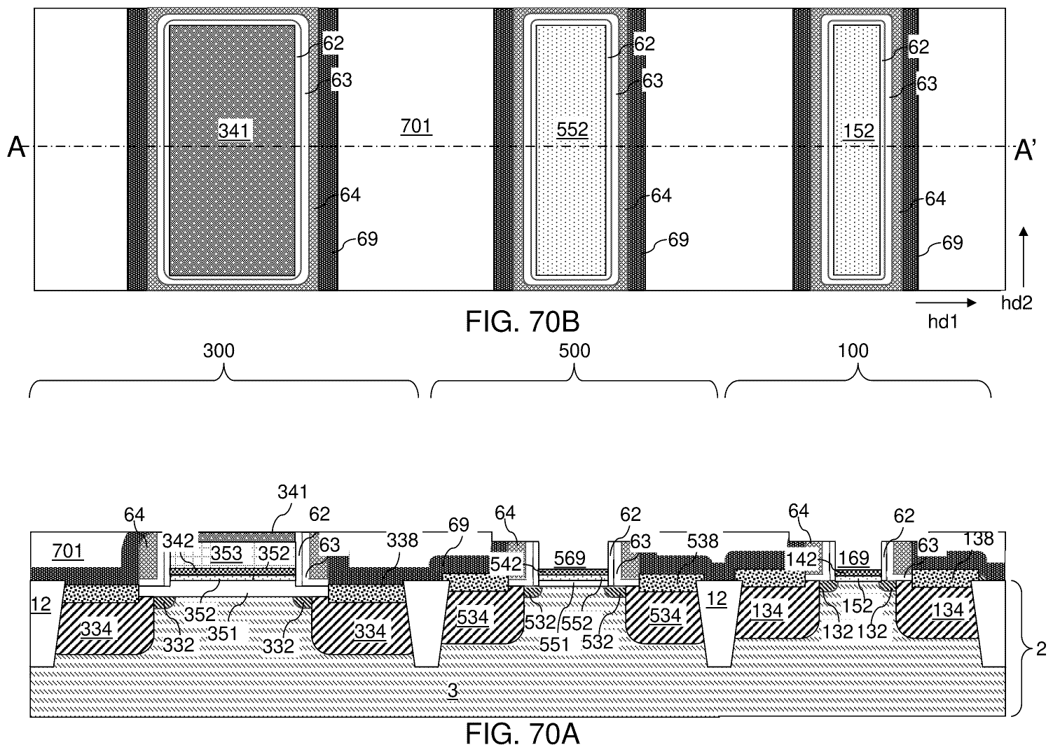

Referring to FIGS. 70A and 70B, a selective etch process can be subsequently performed to remove the first semiconductor gate electrode 153 and the third semiconductor gate electrode 553 selectively to the materials of the metallic barrier liners (142, 342, 542) and the various dielectric gate spacers (62, 63, 64) and the dielectric diffusion barrier layer 69. For example, the selective etch process may comprise a wet etch process using hot trimethyl-2 hydroxyethyl ammonium hydroxide (“hot TMY”) or tetramethyl ammonium hydroxide (TMAH).

A first gate cavity 169 is formed over a first remaining portion of the gate dielectric metal oxide layer 52L in the first device region 100, and an additional gate cavity 569 may be formed over an additional remaining portion of the gate dielectric metal oxide layer 52L in the third device region 500. The photoresist layer 947 can be subsequently removed, for example, by ashing.

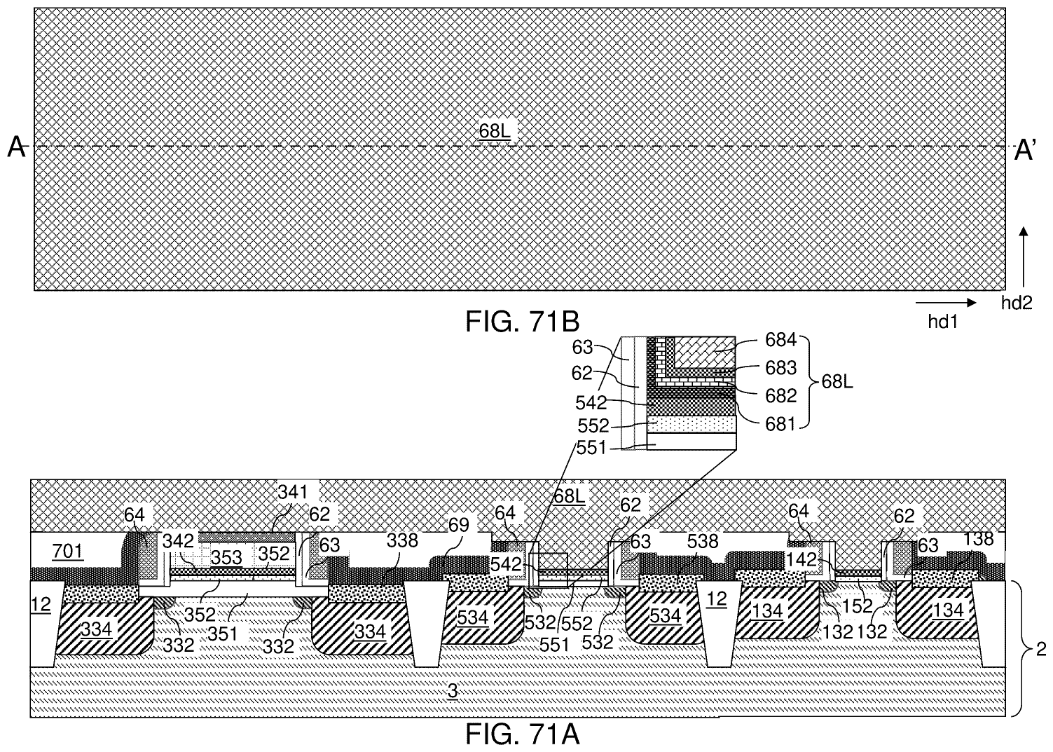

Referring to FIGS. 71A and 71B, a replacement metallic material layer 68L can be deposited in the gate cavities (169, 569) and over the planarization dielectric layer 701. The replacement metallic material layer 68L comprises and/or consist of at least one metallic material. For example, the replacement metallic material layer 68L may comprise at least one metallic liner (681, 682, 683) and at least one metallic fill material portion 684. In one embodiment, the at least one metallic liner (681, 682, 683) may comprise a plurality of metallic liners (681, 682, 683) such as a first metallic liner 681, a second metallic liner 682, and a third metallic liner 683. In one embodiment, at least one of the plurality of metallic liners (681, 682, 683) may be removed in one or more of the device regions (100, 300, 500) without removal in the rest of the device regions (100, 300, 500) such that suitable work functions are devices for metallic gate electrodes to be subsequently formed. In an illustrative example, the first metallic liner 681 may comprise a tantalum nitride layer, the second metallic liner 682 may comprise an alloy of titanium and aluminum, and the third metallic liner 683 may comprise a stack of a titanium layer and a titanium nitride layer. The at least one metallic fill material portion 684 may comprise at least one refractory metal such as tungsten, molybdenum, tantalum, etc.

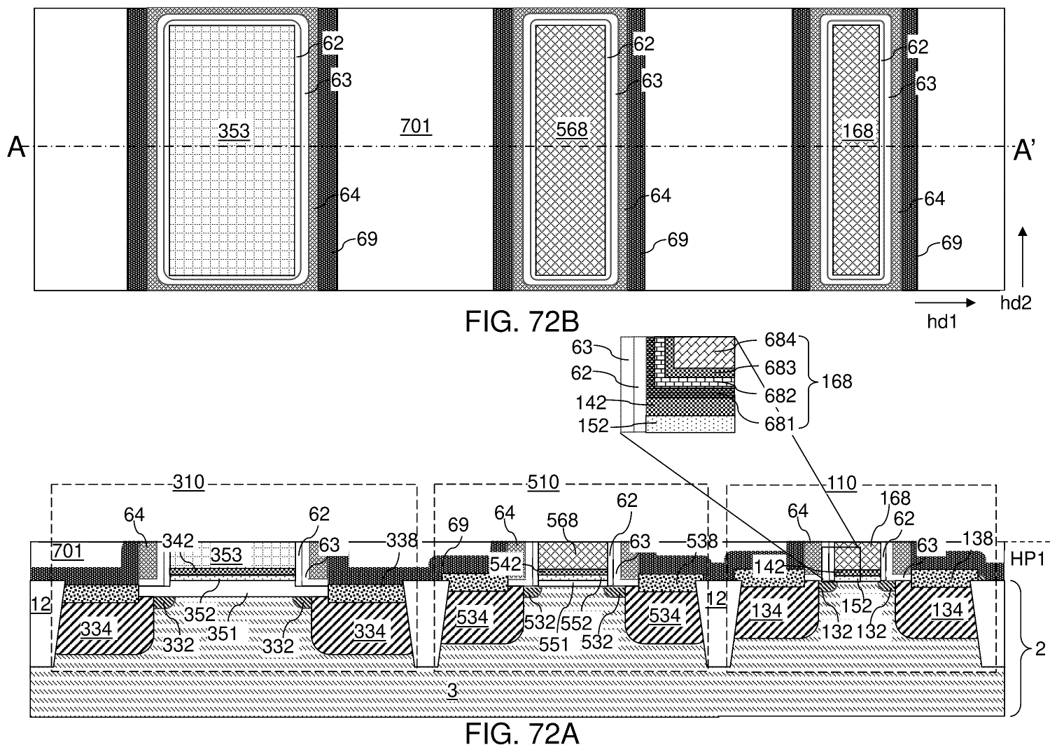

Referring to FIGS. 72A and 72B, the replacement metallic material layer 68L, an upper portion of the planarization dielectric layer 701, and the second sacrificial gate cap 341 may be removed from above a first horizontal plane HP1 including a top surface of the second semiconductor gate electrode 353 by performing a planarization process, such as a chemical mechanical polishing process. Remaining portions of the replacement metallic material layer 68L comprise a first metallic gate electrode 168 that is formed in the first device region 100, and an additional metallic gate electrode 568 that is formed in the third device region 500.

Generally, a first patterned portion of the gate semiconductor layer 53L in the first gate structure (152, 142, 153, 141) is replaced with a first metallic gate electrode 168; and an additional patterned portion of the gate semiconductor layer 53L in the third gate structure (551, 552, 542, 553, 541) is replaced with an additional metallic gate electrode 568 (which may also be referred to as a second metallic gate electrode or a third metallic gate electrode).

The fourth exemplary structure comprises a first field effect transistor 110 comprising first source/drain regions (132, 134) located in a first portion of a semiconductor substrate 2, a first gate dielectric comprising (or consisting essentially of) a first metal oxide gate dielectric 152 that comprises a first portion of a dielectric metal oxide material, and a first gate electrode 168 comprising (or consisting essentially of) a metallic gate electrode (such as the first metallic gate electrode 168) contacting a top surface of the first gate dielectric 152; and a second field effect transistor 310 comprising second source/drain regions (332, 334) located in a second portion of the semiconductor substrate 2, a second gate dielectric (351 and optionally 352), a second gate electrode comprising a doped semiconductor gate electrode 353. A pair of source/drain metal-semiconductor alloy regions (138, 338, 538) can be located on top of a pair of source/drain regions ((132, 134), (332, 334), (532, 534)) in each field effect transistor (110, 310, 510).

A planarization dielectric layer 701 laterally surrounds the first gate electrode 168 and the second gate electrode 353. The planarization dielectric layer 701 has a top surface within the horizontal plane (such as the first horizontal plane HP1) containing a top surface of the metallic gate electrode (such as the first metallic gate electrode 168). In one embodiment, metallic gate electrode comprises at least one gate metallic liner (681, 682, 683) each having a respective horizontally-extending portion and a respective tubular portion that vertically extends upward from a periphery of the respective horizontally-extending portion. In one embodiment, the topmost surface of the doped semiconductor gate electrode 353 is located within a horizontal plane (such as the first horizontal plane HP1) containing a top surface of the metallic gate electrode.

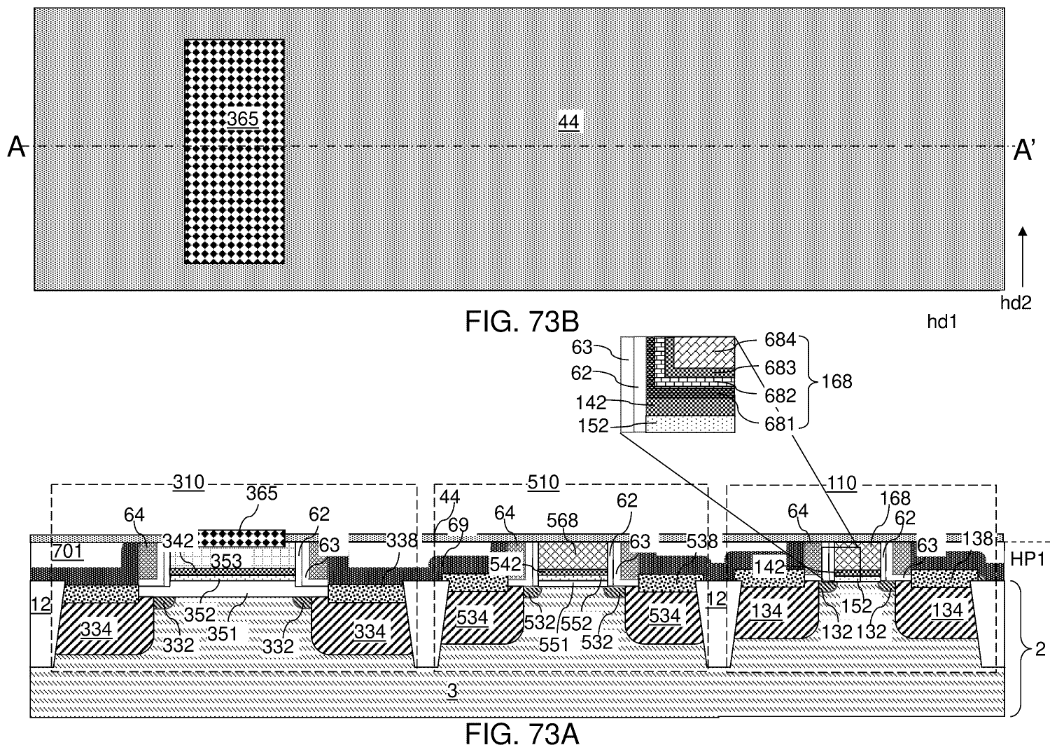

Referring to FIGS. 73A and 73B, a dielectric capping layer 44 can be deposited over the planarization dielectric layer 701. In one embodiment, the dielectric capping layer 44 may comprise a dielectric diffusion barrier material, such as silicon nitride or silicon carbonitride. The thickness of the dielectric capping layer 44 may be in a range from 5 nm to 30 nm, although lesser and greater thicknesses may also be employed.

The dielectric capping layer 44 can be formed on the second semiconductor gate electrode 353 (i.e., the doped semiconductor gate electrode 353), the metallic gate electrodes (168, 568), and a top surface of a remaining portion of the planarization dielectric layer 701 after performing the planarization process. The interfaces between the dielectric capping layer 44 and the top surface segments of the metallic gate electrodes (168, 568) are located within a same horizontal plane (such as the first horizontal plane HP1) as an interface between the dielectric capping layer 44 and the top surface segment of the doped semiconductor gate electrode 353. The dielectric capping layer 44 may be patterned to form an opening over the area of the doped semiconductor gate electrode 353 in the second device region 300. For example, a photoresist layer (not shown) can be applied over the dielectric capping layer 44 and can be lithographically patterned to form an opening over the areas of the doped semiconductor gate electrode 353, and an etch process can be performed to form the opening through the dielectric capping layer 44. The photoresist layer can be subsequently removed, for example, by ashing.

A metal layer including at least one elemental metal can be deposited over the dielectric capping layer 44. The at least one elemental metal comprises one or more metals that can form metal-semiconductor alloys, such as metal silicides. For example, the first elemental metal may be selected from Ni, Pt, Co, Ti, W, etc. An anneal can be performed to form a gate metal-semiconductor alloy region 365 that includes a metal semiconductor alloy (such as a metal silicide) of the first elemental metal and the semiconductor material in the doped semiconductor gate electrode 353. Unreacted portions of the metal layer can be removed selectively to the gate metal-semiconductor alloy region 365, for example, by performing a selective wet etch process. The gate metal-semiconductor alloy region 365 comprises an alloy of the first elemental metal and the semiconductor material of the doped semiconductor gate electrode 353 (e.g., Ni, Pt, Co, Ti and/or W silicide).

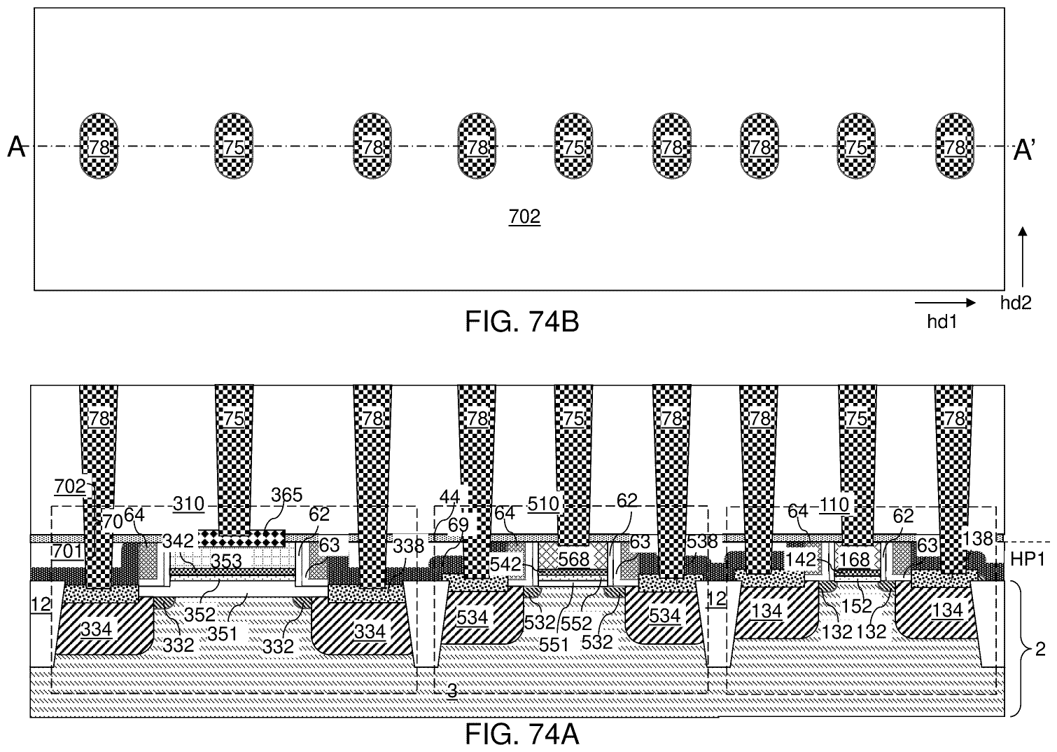

Referring to FIGS. 74A and 74B, a cover dielectric layer 702 can be formed over the dielectric capping layer 44. The cover dielectric layer 702 comprises a dielectric material, such as undoped silicate glass or a doped silicate glass. The combination of the planarization dielectric layer 701, the dielectric capping layer 44, and the cover dielectric layer 702 constitutes a contact-level dielectric layer 70. Various contact via structures (75, 78) can be formed through the contact-level dielectric layer 70 on a respective one of the metallic gate electrodes (168, 568), the gate metal-semiconductor alloy region 365, and the metal-semiconductor alloy regions (138, 338, 538). The various contact via structures (75, 78) may comprise source/drain contact via structures 78 contacting a respective one of the metal-semiconductor alloy regions (138, 338, 538), and gate contact via structures 75 contacting a respective one of the metallic gate electrodes (168, 568) and the gate metal-semiconductor alloy region 365.

In the fourth embodiment, the second gate structure (353, 365 and optionally 342) comprises a lower doped polysilicon layer 353 and an upper metal silicide layer 365, and an optional metallic nitride (e.g., TiN) barrier liner 342 between the doped polysilicon layer 353 and the gate dielectric (351, 352). The doped polysilicon layer 353 improves the performance and threshold voltage of the high voltage transistor 310. The gate metal-semiconductor alloy region 365 improves electrical contact between the second gate structure (353, 365) and its respective gate contact via structure 75, and prevents or reduces punch through during etching of a gate contact via that is subsequently filled with the gate contact via structure 75.

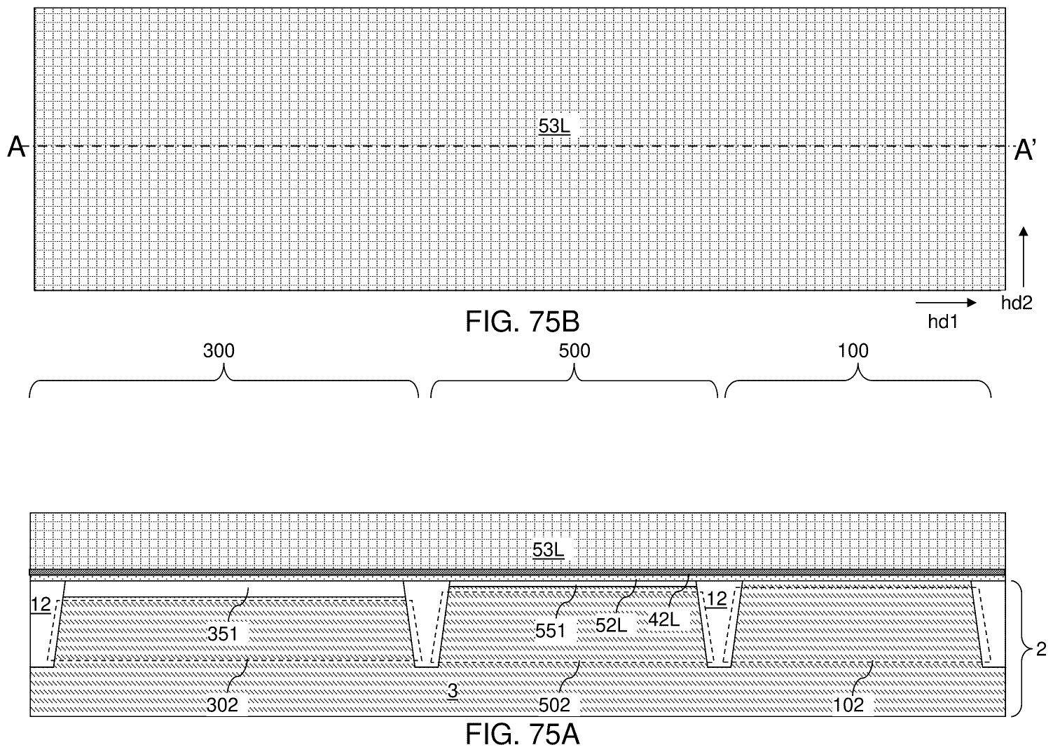

The method fourth embodiment includes separate source/drain and high voltage transistor gate silicidation steps. The method of the fifth embodiment described below includes a single common source/drain and high voltage transistor gate silicidation step. Referring to FIGS. 75A and 75B, a fifth exemplary structure according to the fifth embodiment of the present disclosure is illustrated, which comprises a first device region 100, a second device region 300, and a third device region 500. Further, the fifth exemplary structure may comprise a resistor region (not illustrated), which can be similar to the resistor region 700 illustrated in FIGS. 40A-40C. In this case, an isolation dielectric layer 751 having a same material composition and a same thickness as a first silicon oxide gate dielectric 351 may be formed in the resistor region.

The fifth exemplary structure may be derived from the fourth exemplary structure illustrated in FIGS. 61A and 61B by increasing the thickness of the gate semiconductor layer 53L. For example, the thickness of the gate semiconductor layer 53L in the fifth exemplary structure may be in a range from 80 nm to 200 nm, such as from 100 nm to 150 nm, although lesser and greater thicknesses may also be employed. The gate semiconductor layer 53L of the fifth exemplary structure can be suitably doped with electrical dopants. Formation of the sacrificial gate cap layer 41L is deferred to a subsequent processing step in the fifth embodiment.

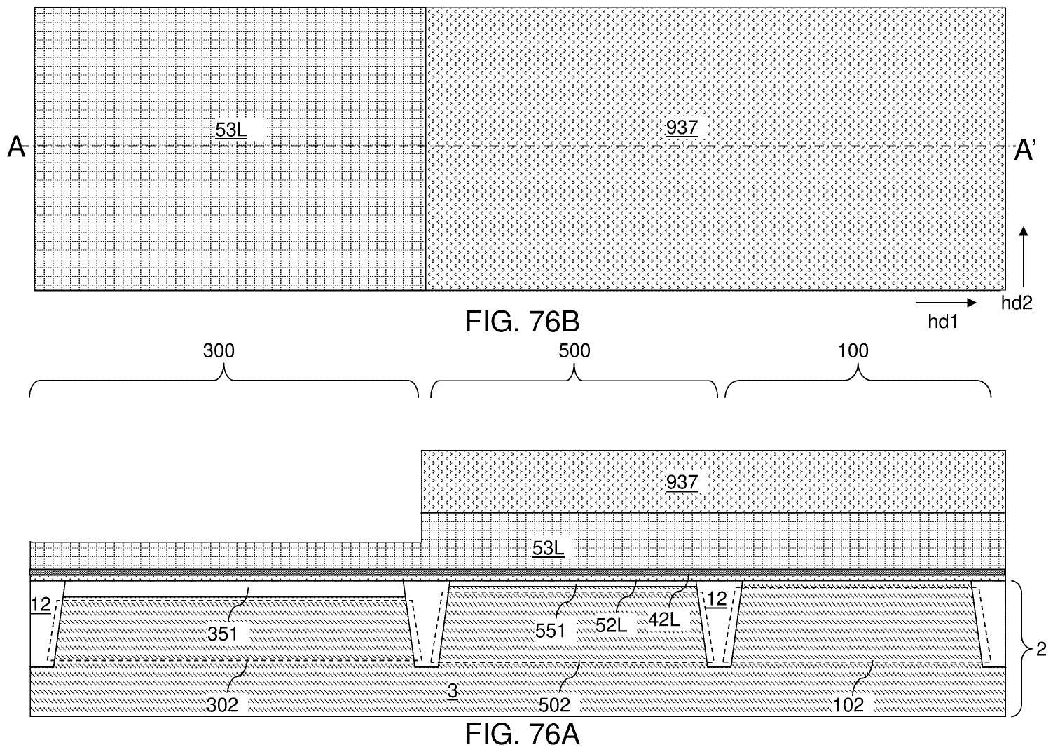

Referring to FIGS. 76A and 76B, the gate semiconductor layer 53L can be locally thinned in the second device region 300. For example, a photoresist layer 937 can be applied over the fifth exemplary structure, and can be lithographically patterned to cover the first device region 100 and the third device region 500 without covering the second device region 300 or the resistor region (not illustrated). An etch process can be performed to vertically recess the gate semiconductor layer 53L in the second device region 300 and in the resistor region without recessing the gate semiconductor layer 53L in the first device region 100 or in the third device region 500. An anisotropic etch process (such as a reactive ion etch process) or an isotropic etch process (such as a wet etch process) may be performed to recess the gate semiconductor layer 53L in the second device region 300 and in the resistor region. The thickness of the recessed portion of the gate semiconductor layer 53L in the second device region 300 and in the resistor region may be in a range from 25% to 75% of the thickness of the portions of the gate semiconductor layer 53L in the first device region 100 and in the third device region 500. For example, the thickness of the gate semiconductor layer 53L in the second device region may be in a range from 40 nm to 100 nm, such as from 50 nm to 75 nm, although lesser and greater thicknesses may also be employed. The photoresist layer 937 can be subsequently removed, for example, by ashing.

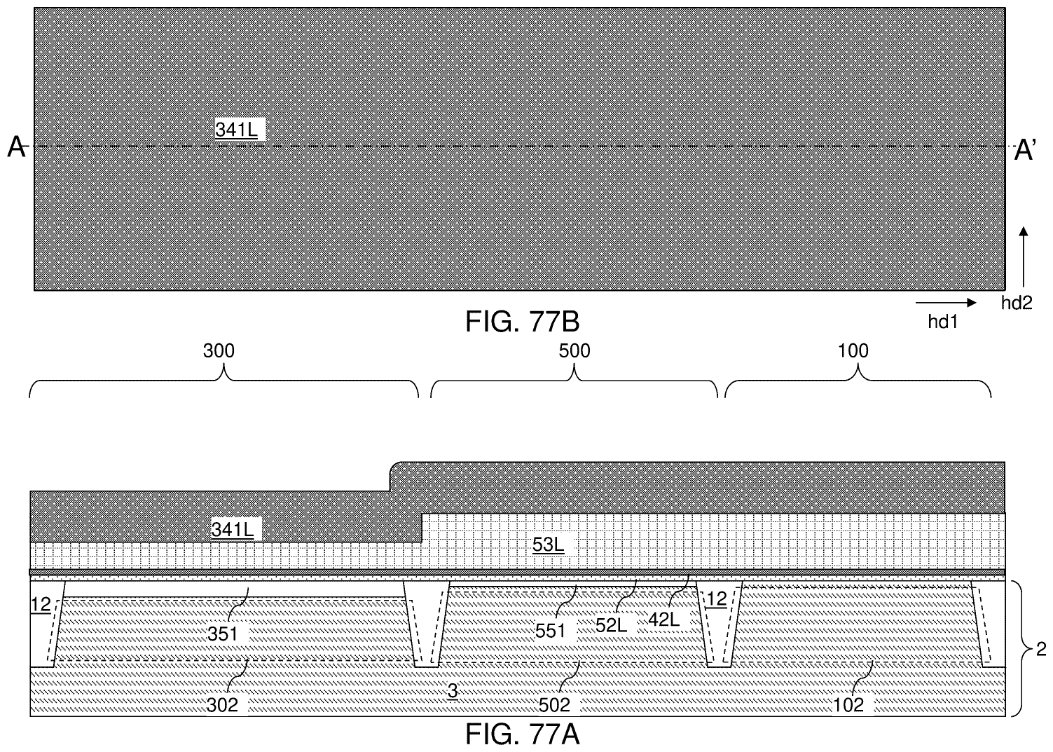

Referring to FIGS. 77A and 77B, a gate cap dielectric layer 341L can be deposited over the gate semiconductor layer 53L. The gate cap dielectric layer 341L comprises a dielectric material such as silicon nitride, silicon carbonitride, etc. The portion of the gate cap dielectric layer 341L that overlies a topmost surface of the gate semiconductor layer 53L can be removed from the first device region 100 and the third device region 500.

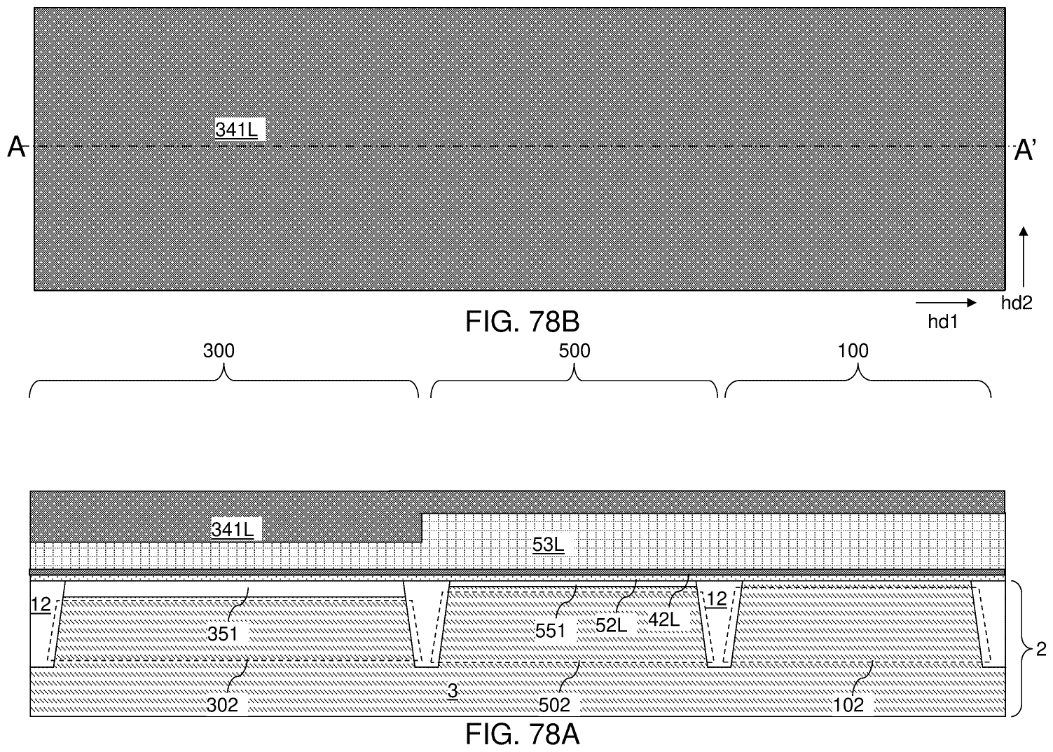

Referring to FIGS. 78A and 78B, a photoresist layer (not shown) can be applied over the gate cap dielectric layer 341L, and can be lithographically patterned to cover the second device region 300 and the resistor region without covering the first device region 100 and the third device region 500. An etch process may be performed to partially etch unmasked portions of the gate cap dielectric layer 341L. The photoresist layer can be subsequently removed, for example, by ashing. A touch-up chemical mechanical polishing process may be optionally performed to remove portions of the gate cap dielectric layer 341L in the first and third device regions (100, 500) that protrude above the top surface of the gate cap dielectric layer 341L in the second device region 300, such that the top surface of the gate cap dielectric layer 341L is in the same horizontal plane in the first, second and third device regions. The thickness of the gate cap dielectric layer 341L may be in a range from 20 nm to 60 nm, such as from 30 nm to 50 nm in the first and third device regions (100, 500) and in a range from 60 nm to 150 nm, such as from 80 nm to 120 nm in the second device region 300, although lesser and greater thicknesses may also be employed. The gate cap dielectric layer 341L is thicker in the second device region 300 than in the first and third device regions (100, 500).

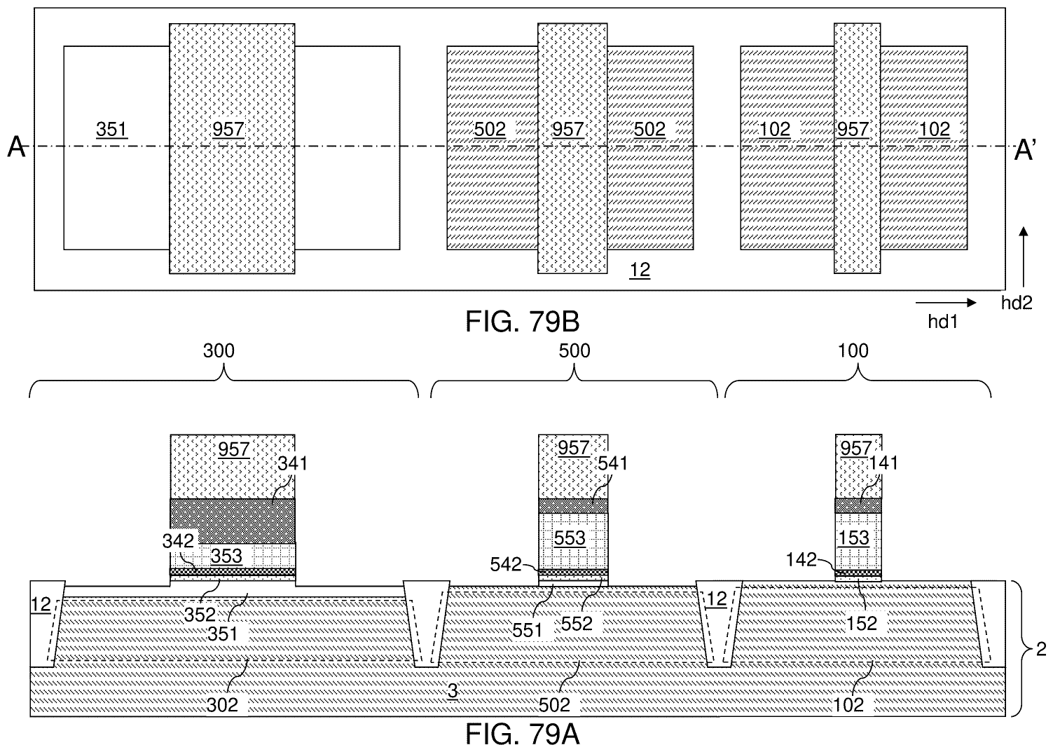

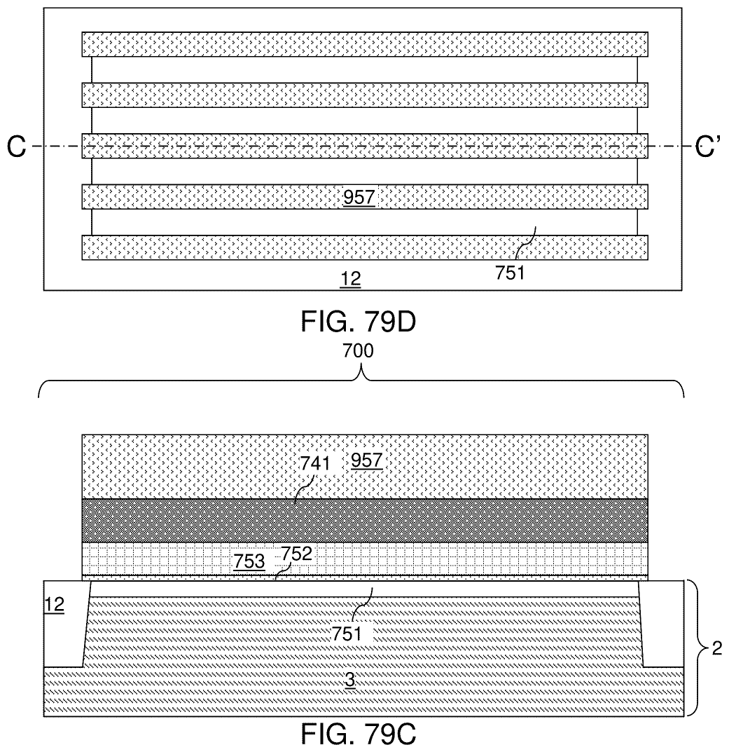

Referring to FIGS. 79A-79D, the first device region 100, the second device region 300, the third device region 500, and the resistor region 700 of the fifth exemplary structure is illustrated. A photoresist layer 957 can be applied over the gate cap dielectric layer 341L, and can be lithographically patterned into gate patterns in the first, second, and third device regions (100, 300, 500), and into strip patterns in the resistor region 700. The strip patterns of the photoresist layer 957 may be the same as the strip patterns discussed with reference to FIGS. 45A-45C.

An anisotropic etch process including a sequence of anisotropic etch steps can be performed to transfer the pattern in the photoresist layer 957 through the gate cap dielectric layer 341L, the gate semiconductor layer 53L, the optional metallic barrier liner layer 42L, and the gate dielectric metal oxide layer 52L. Further, the anisotropic etch process may comprise a terminal etch step that etches unmasked portions of the second silicon oxide gate dielectric 551 and an unmasked upper portion of the first silicon oxide gate dielectric 351 selectively to the material of the single crystalline semiconductor layer 3. The duration of the terminal etch step may be selected such that the unmasked portions of the second silicon oxide gate dielectric 551 is etched through, and the unmasked portion of the first silicon oxide gate dielectric 351 is only partially etched. The photoresist layer 957 can be subsequently removed by ashing.

Generally, the gate cap dielectric layer 341L, the gate semiconductor layer 53L, the optional metallic barrier liner layer 42L, the gate dielectric metal oxide layer 52L, the semiconductor gate dielectrics (351, 551), and the isolation dielectric layer 751 may be patterned into various in-process gate structures and in-process resistor structures. The in-process gate structures comprise a first gate structure (152, 142, 153, 151), a second gate structure (351, 352, 342, 353, 341), and a third gate structure (551, 552, 542, 553, 541). The first gate structure (152, 142, 153, 151) comprises a first metal oxide gate dielectric 152, an optional first metallic barrier liner 142, a first semiconductor gate electrode 153, and a first sacrificial gate cap 141. The second gate structure (351, 352, 342, 353, 341) comprises a first silicon oxide gate dielectric 351, a second metal oxide gate dielectric 352, an optional second metallic barrier liner 342, a second semiconductor gate electrode 353, and a second sacrificial gate cap 341. The third gate structure (551, 552, 542, 553, 541) comprises a second silicon oxide gate dielectric 551, a third metal oxide gate dielectric 542, an optional third metallic barrier liner 542, a third semiconductor gate electrode 553, and a third sacrificial gate cap 541.

Each in-process resistor structure (752, 742, 753, 741) may comprise, from bottom to top, a dielectric metal oxide strip 752, a metallic liner strip 742, a semiconductor material strip 753, and a resistor cap strip 741. Each dielectric metal oxide strip 752 is a patterned portion of the gate dielectric metal oxide layer 52L. Each semiconductor material strip 753 is a patterned portion of the doped semiconductor plate 54P. Each resistor cap strip 741 is a patterned portion of the gate cap dielectric layer 341L. The photoresist layer 957 can be subsequently removed, for example, by ashing.

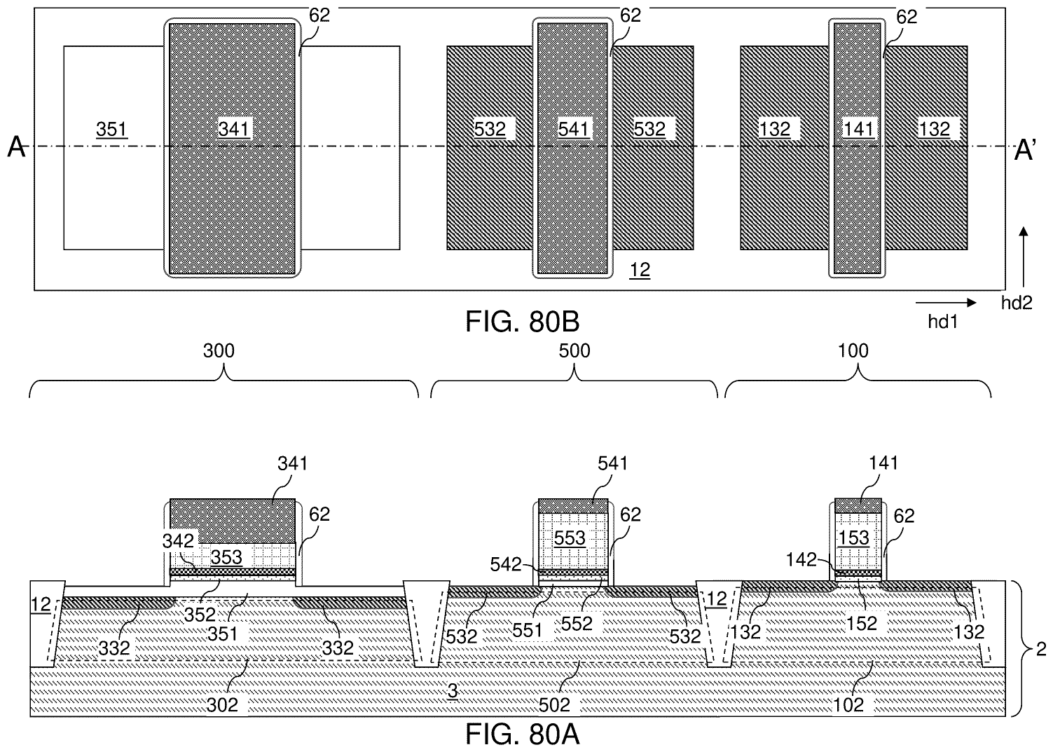

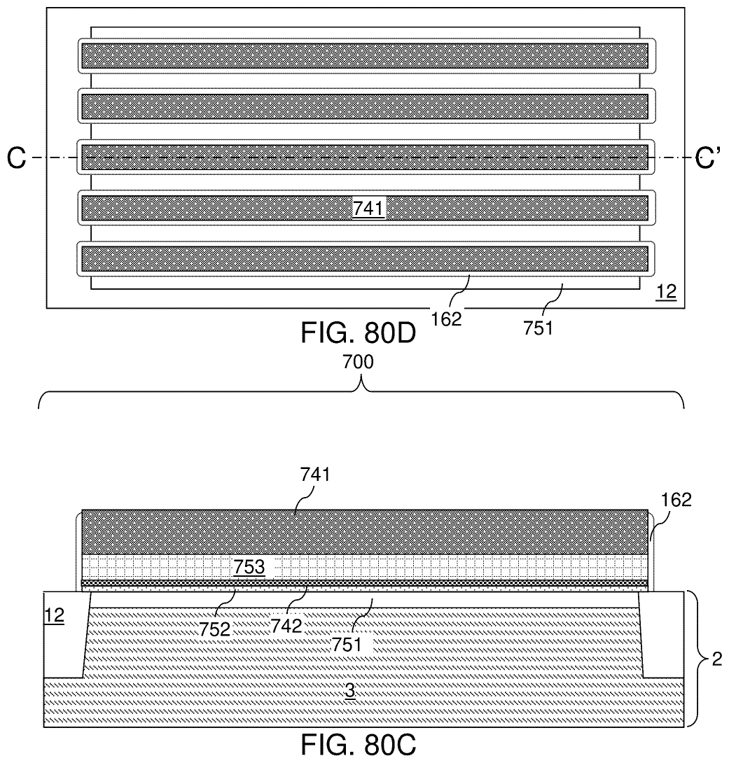

Referring to FIGS. 80A-80D, an inner dielectric gate spacer material layer may be conformally deposited, and may be subsequently anisotropically etched. The inner dielectric gate spacer material layer comprises a dielectric material such as silicon oxide. Each remaining vertically-extending portion of the inner dielectric gate spacer material layer that laterally surrounds the in-process gate stacks constitutes an inner dielectric gate spacer 62. Each remaining vertically-extending portion of the inner dielectric gate spacer material layer that laterally surrounds a respective in-process resistor (752, 753, 741) constitutes an inner insulating spacer 162.

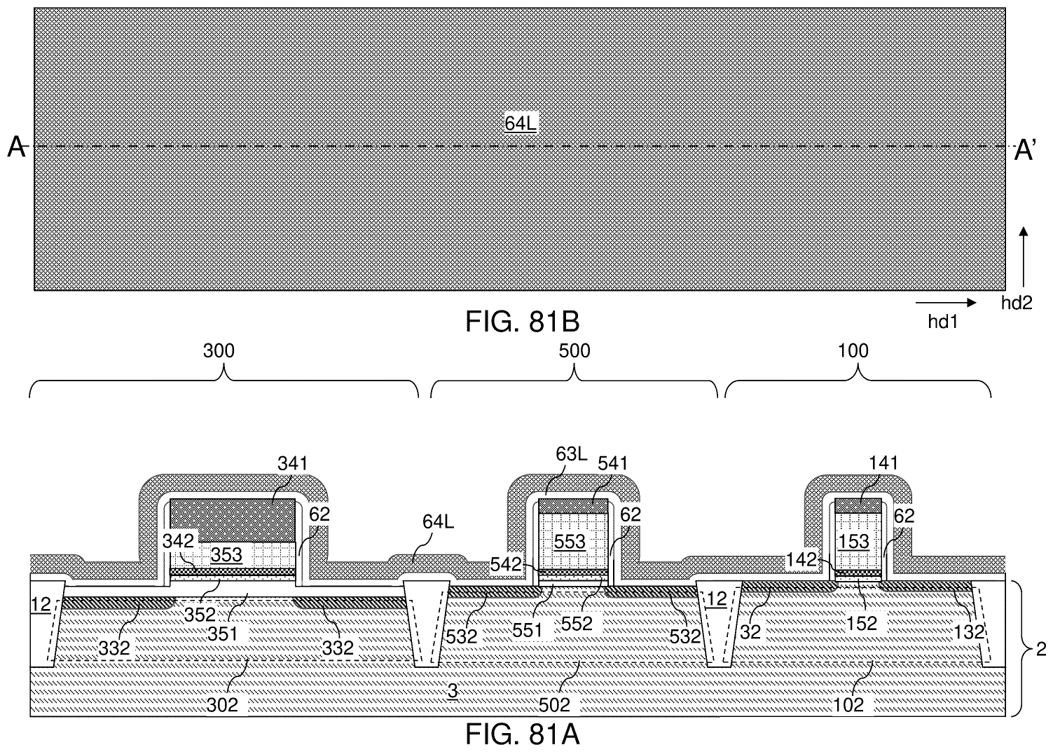

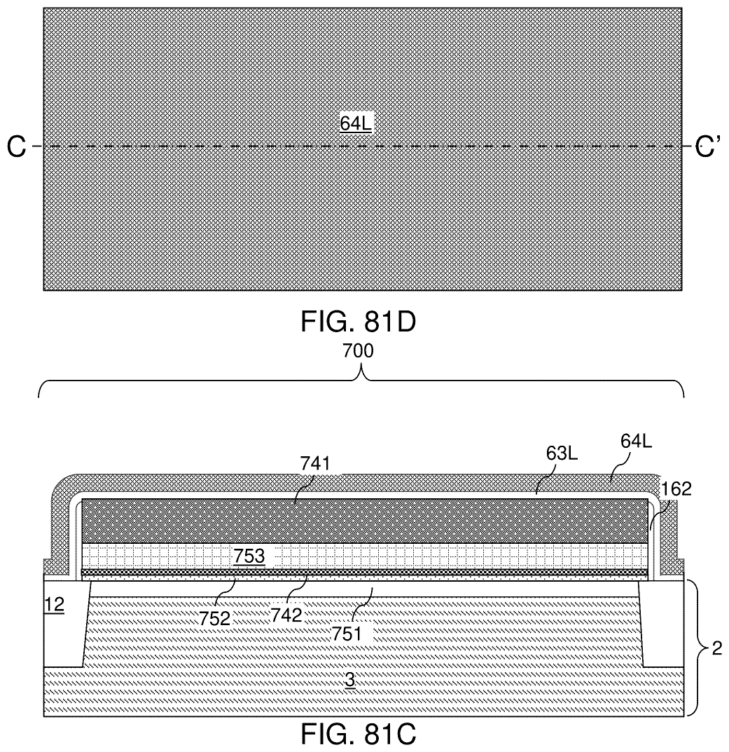

Referring to FIGS. 81A-81D, an intermediate dielectric gate spacer material layer 63L may be conformally deposited. The intermediate dielectric gate spacer material layer 63L comprises a dielectric material, such as silicon oxide. An outer dielectric gate spacer material layer 64L may be subsequently conformally deposited. The outer dielectric gate spacer material layer 64L comprises a dielectric material, such as silicon nitride.

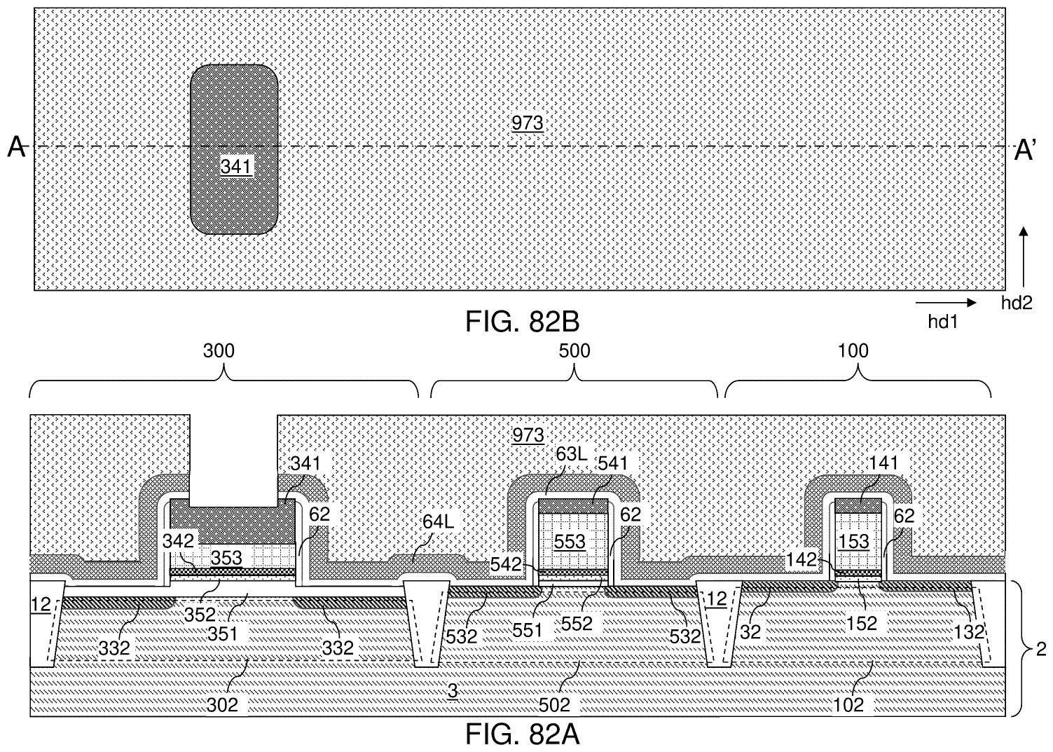

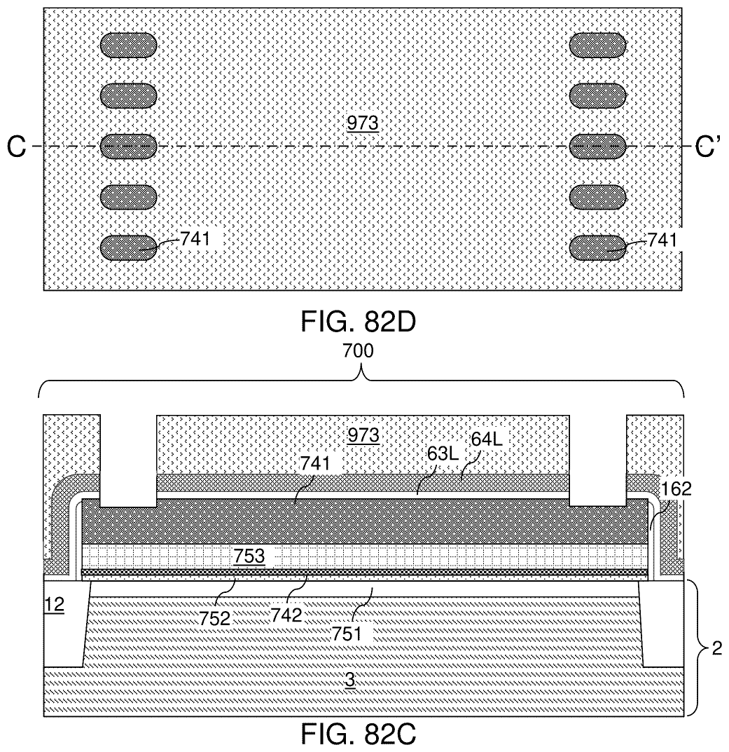

Referring to FIGS. 82A-82D, a photoresist layer 973 can be applied over the fifth exemplary structure, and can be lithographically patterned to form an opening over the second sacrificial gate cap 341 and over end portions of the sacrificial resistor cap strips 741. An anisotropic etch process can be performed to etch portions of the outer dielectric gate spacer material layer 64L, the intermediate dielectric gate spacer material layer 63L, and upper portions of the sacrificial resistor cap strips 741. The photoresist layer 973 can be subsequently removed, for example, by ashing.

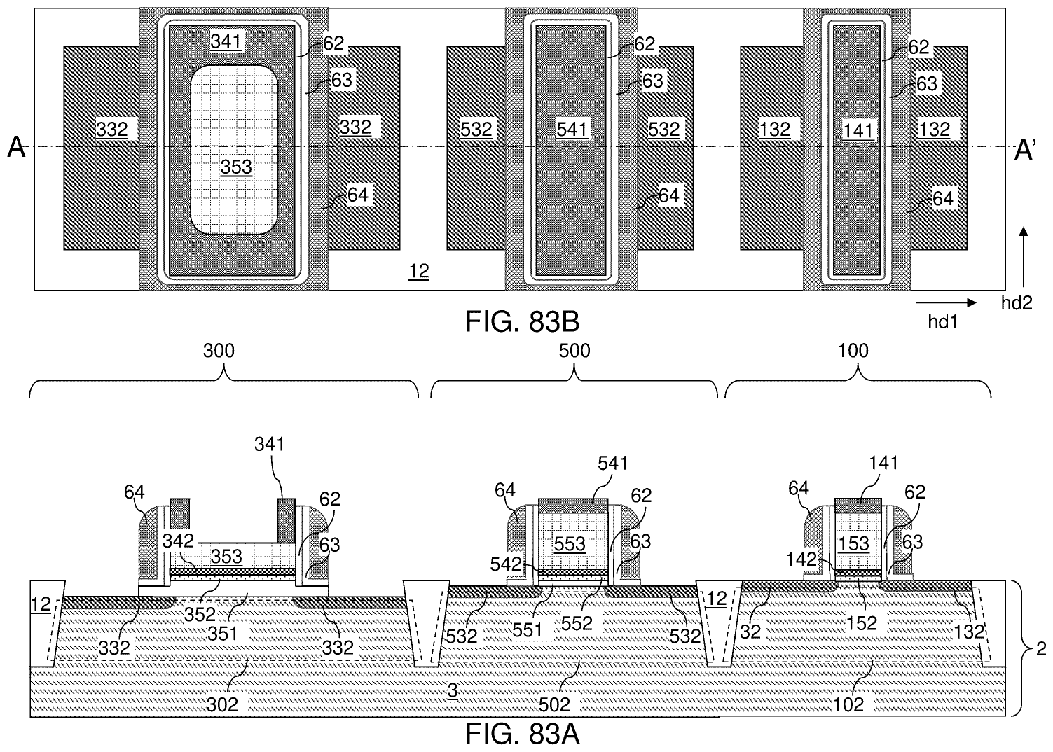

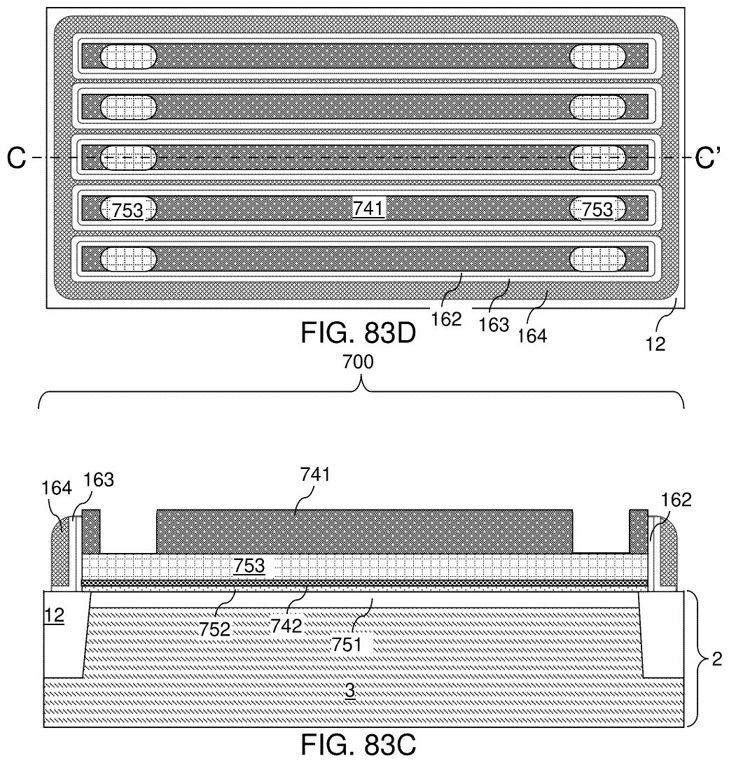

Referring to FIGS. 83A-83D, an anisotropic etch process can be performed to remove horizontally-extending unmasked portions of the outer dielectric gate spacer material layer 64L, the intermediate dielectric gate spacer material layer 63L, and the first silicon oxide gate dielectric 351 selectively to the semiconductor material of the single crystalline semiconductor layer 3. According to an aspect of the present disclosure, the anisotropic etch process collaterally etches portions of the second sacrificial gate cap 341 located underneath the opening in the outer dielectric gate spacer material layer 64L and the intermediate dielectric gate spacer material layer 63L in the second device region 300. An opening is formed through the second sacrificial gate cap 341. A top surface of the second semiconductor gate electrode 353 is physically exposed underneath an opening in the second sacrificial gate cap 341.

Further, the anisotropic etch process collaterally etches portions of the resistor cap strip 741 that are located underneath the openings in the outer dielectric gate spacer material layer 64L and the intermediate dielectric gate spacer material layer 63L in the resistor region 700. A pair of openings is formed through each resistor cap strip 741. Each semiconductor material strip 753 comprises a respective pair of horizontal surface segments that is physically exposed underneath a pair of openings through a respective resistor cap strip 741.

Each remaining portion of the intermediate dielectric gate spacer material layer 63L that remains in the first device region 100, the second device region 300, and the third device region 500 constitutes an intermediate dielectric gate spacer 63. The intermediate dielectric gate spacers 63 may have L-shaped vertical cross-sectional profiles. Each remaining portion of the outer dielectric gate spacer material layer 64L that remains in the first device region 100, the second device region 300, and the third device region 500 constitutes an outer dielectric gate spacer 64. Each remaining portion of the intermediate dielectric gate spacer material layer 63L that remains in the resistor region 700 constitutes an intermediate insulating spacer 163. The intermediate insulating spacers 163 may have L-shaped vertical cross-sectional profiles. Each remaining portion of the outer dielectric gate spacer material layer 64L that remains in the resistor region 700 constitutes an outer insulating spacer 164.

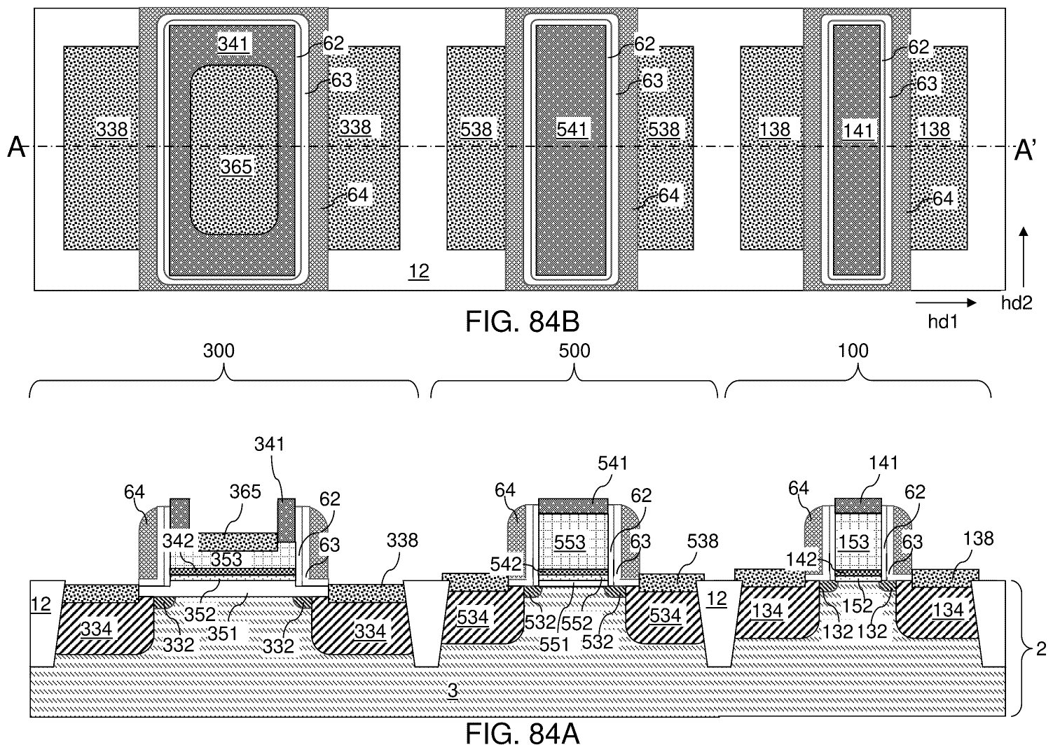

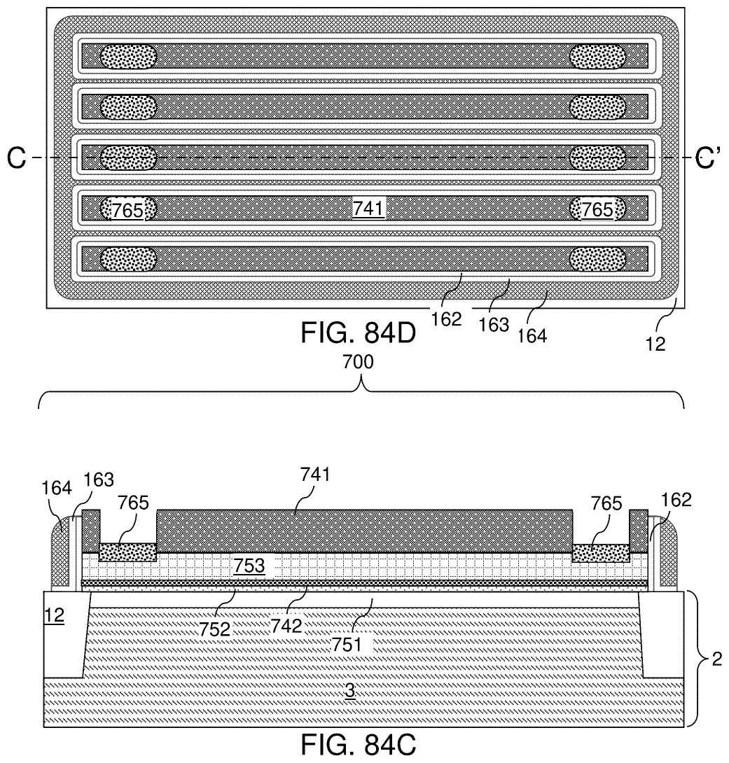

Referring to FIGS. 84A-84D, ion implantation processes may be performed to form deep source/drain regions (134, 334, 534). The deep source/drain regions (134, 334, 534) may comprise first deep source/drain regions 134 that are formed in the first device region 100, second deep source/drain regions 334 that are formed in the second device region 300, and third deep source/drain regions 534 that are formed in the third device region 500. Each contiguous combination of a first source/drain extension region 132 and a first deep source/drain region 134 constitutes a first source/drain region (132, 134). Each contiguous combination of a second source/drain extension region 332 and a second deep source/drain region 334 constitutes a second source/drain region (332, 334). Each contiguous combination of a third source/drain extension region 532 and a third deep source/drain region 534 constitutes a third source/drain region (532, 534).

A metal layer can be deposited over the fifth exemplary structure. The metal layer comprises and/or consists essentially of at least one elemental metal that forms a metal-semiconductor alloy (such as a metal silicide) with the semiconductor materials of the various deep source/drain regions (134, 334, 534), the second semiconductor gate electrode 353, and the semiconductor material strips 753. An anneal can be performed to form various metal-semiconductor alloy regions (138, 338, 538, 365, 765). The various metal-semiconductor alloy regions (138, 338, 538, 365, 765) may comprise first metal-semiconductor alloy regions 138 that are formed on the first deep source/drain regions 134, second metal-semiconductor alloy regions 338 that are formed on the second deep source/drain regions 334, third metal-semiconductor alloy regions 538 that are formed on the third deep source/drain regions 534, a gate metal-semiconductor alloy region 365 that is formed on top of the second semiconductor gate electrode 353 in a opening in the second sacrificial gate cap 341, and contact metal-semiconductor alloy regions 765 that are formed on end portions of the semiconductor material strips 753. Generally, the first, second, and third source/drain metal-semiconductor alloy regions (138, 338, 538) can be formed on portions of the semiconductor substrate 2 (such as the deep source/drain regions (134, 334, 534)) concurrently with formation of the gate metal-semiconductor alloy region 365 and the contact metal-semiconductor alloy regions 765 by depositing a metal layer on, and inducing a reaction of the metal layer with, the doped portions of the semiconductor substrate 2, a portion of the second semiconductor gate electrode 353, and portions of the semiconductor material strips 753.

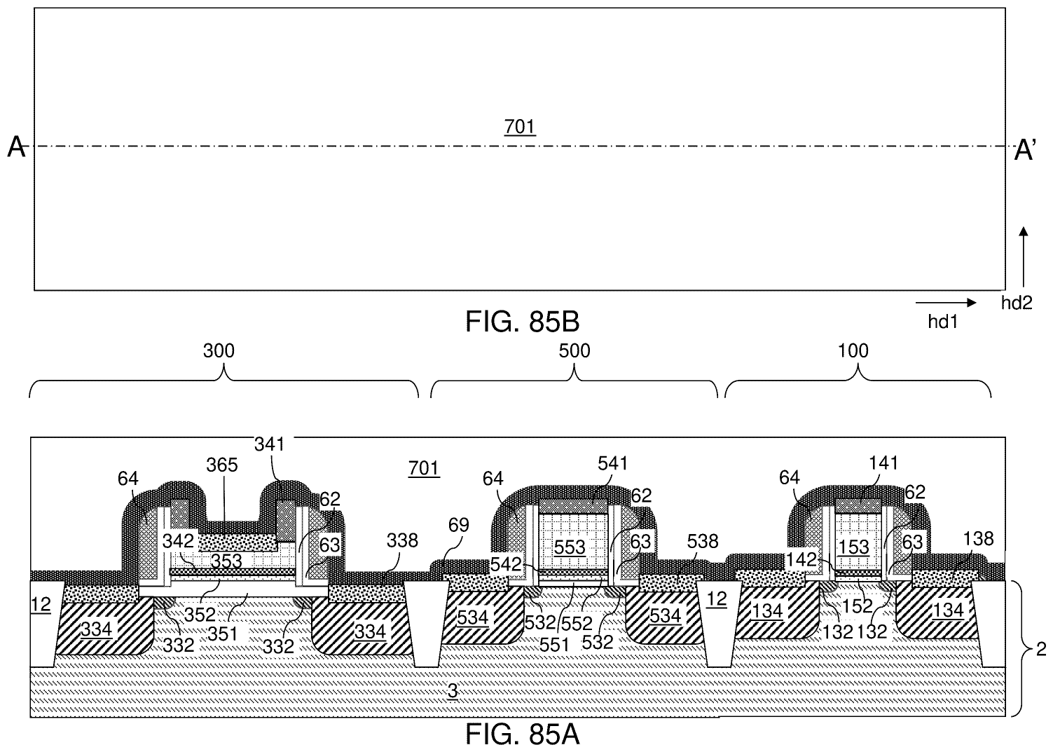

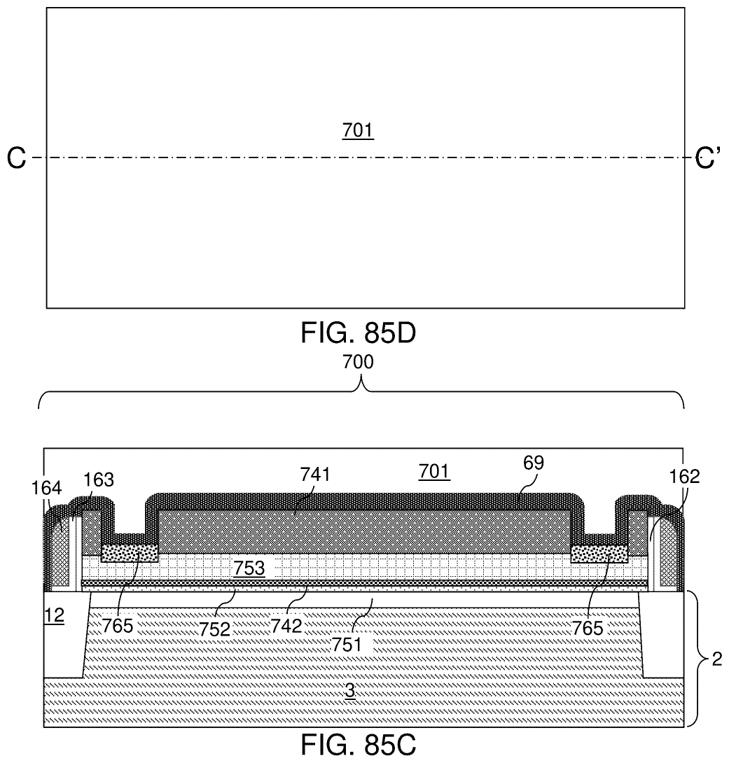

Referring to FIGS. 85A-85D, a dielectric diffusion barrier layer 69 may be deposited over the various gate structures and the various metal-semiconductor alloy regions (138, 338, 538, 365, 765). The dielectric diffusion barrier layer 69 may comprise a dielectric diffusion barrier material such as silicon nitride or silicon carbonitride. A planarization dielectric layer 701 can be formed over the dielectric diffusion barrier layer 69. The planarization dielectric layer 701 comprises a planarizable dielectric material such as undoped silicate glass or a doped silicate glass.

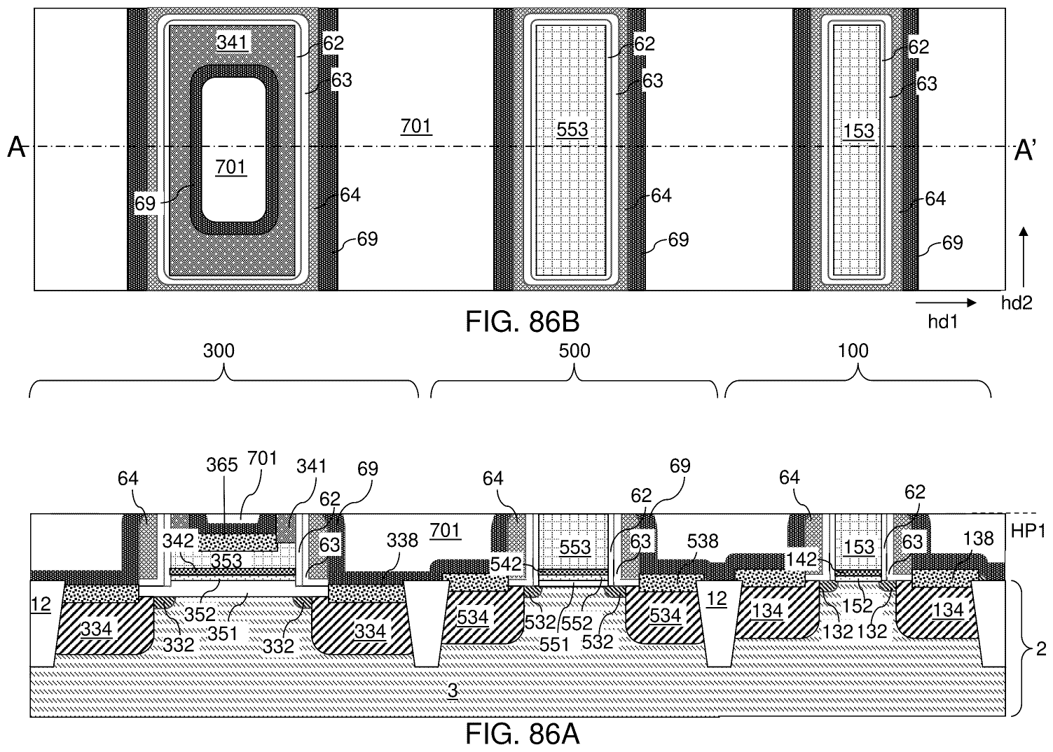

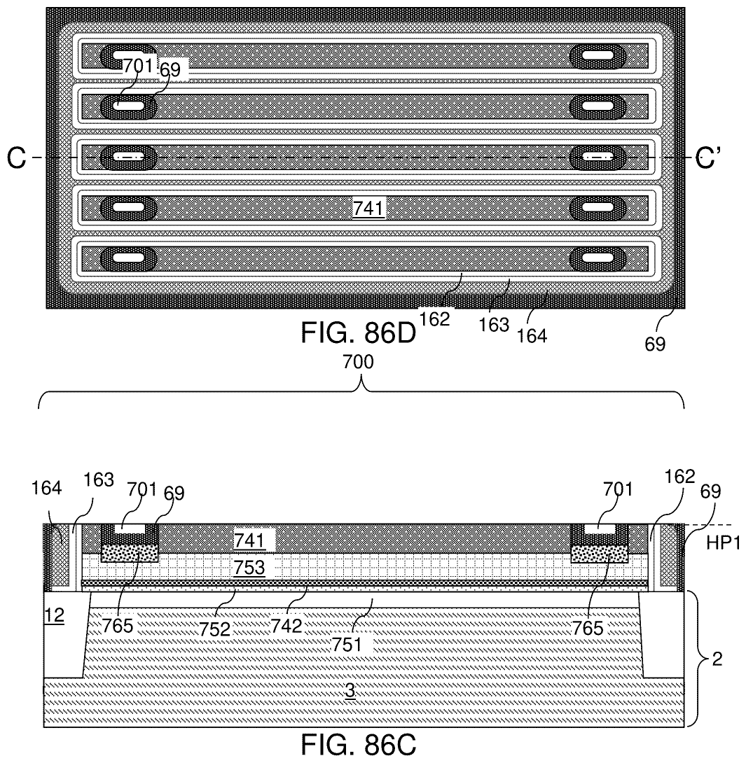

Referring to FIGS. 86A-86D, a planarization process, such as a chemical mechanical polishing process and/or a reactive ion etch back process, can be performed to remove portions of the planarization dielectric layer 701, portions of the dielectric diffusion barrier layer 69, portions of the various dielectric gate spacers (62, 63, 64), portions of the various insulating spacers (162, 163, 164), all of the sacrificial gate caps (141, 341, 541) from above a first horizontal plane HP1 including the top surfaces of the first semiconductor gate electrode 153 and the third semiconductor gate electrode 553. Remaining portions of the various dielectric gate spacers (62, 63, 64), the various insulating spacers (162, 163, 164), and the dielectric diffusion barrier layer 69 comprise planar top surfaces that are formed within the first horizontal plane HP1, which contains the planarized top surface of the planarization dielectric layer 701.

In one embodiment, the chemical mechanical polishing process may stop on the relatively thin first and third sacrificial gate caps (141, 541) and the relatively thick second sacrificial gate cap 341 and resistor cap strip 741 which are used as polish stops. The reactive ion etch back process is then used to expose the top surfaces of the first and third semiconductor gate electrodes (551, 553). The reactive ion etch back process may remove the entire first and third sacrificial gate caps (141, 541) but leave a bottom portion of the thicker second sacrificial gate cap 341 and the resistor cap strip 741.

Generally, a first dielectric gate spacer (such as a first inner dielectric gate spacer 62, a first intermediate dielectric gate spacer 63, and/or a first outer dielectric gate spacer 64) having a first planar dielectric top surface laterally surrounds a first semiconductor gate electrode 153; a second dielectric gate spacer (such as a second inner dielectric gate spacer 62, a second intermediate dielectric gate spacer 63, and/or a second outer dielectric gate spacer 64) having a second planar dielectric top surface laterally surrounds a second semiconductor gate electrode 353; and a third dielectric gate spacer (such as a third inner dielectric gate spacer 62, a third intermediate dielectric gate spacer 63, and a third outer dielectric gate spacer 64) having a third planar dielectric top surface laterally surrounds a third semiconductor gate electrode 553. The second semiconductor gate electrode 353 is also referred to as a doped semiconductor gate electrode 353.

Each contact metal-semiconductor alloy region 765 may be covered by a combination of a discrete patterned portion of the dielectric diffusion barrier layer 69 and optionally by a discrete pattered portion of the planarization dielectric layer 701. Each relatively thick resistor cap strip 741 may comprise a respective top surface that is located within the first horizontal plane HP1.

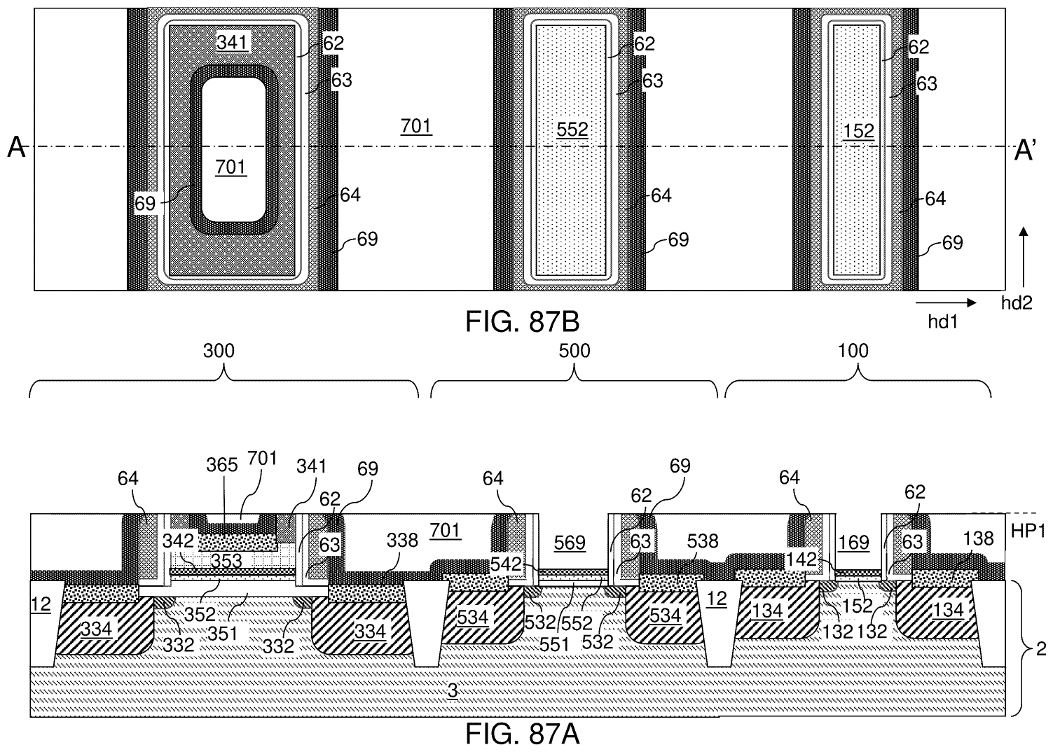

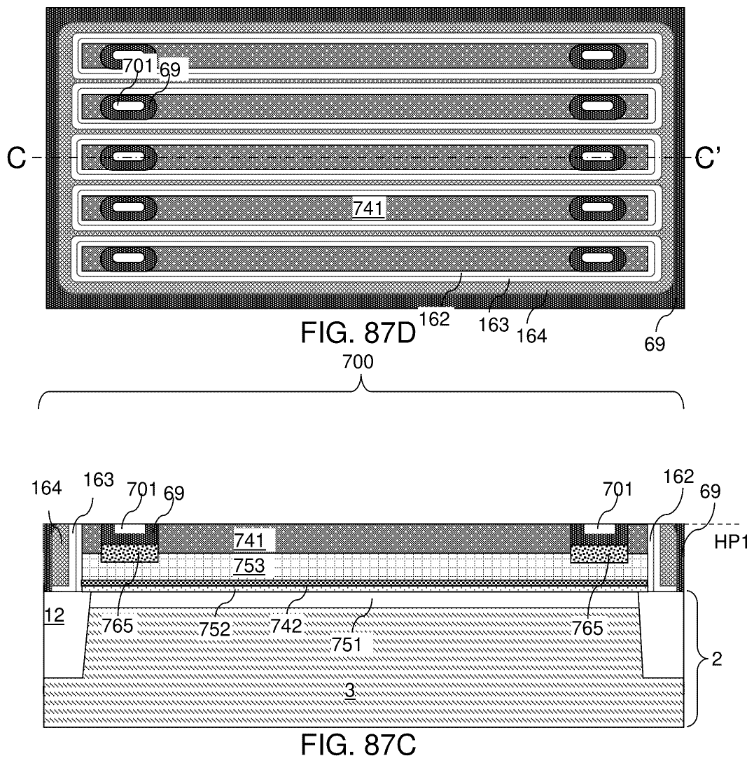

Referring to FIGS. 87A-87D, a selective etch process can be subsequently performed to remove the first semiconductor gate electrode 153 and the third semiconductor gate electrode 553 selectively to the materials of the metallic barrier liners (142, 342, 542) and the various dielectric gate spacers (62, 63, 64) and the dielectric diffusion barrier layer 69. For example, the selective etch process may comprise a wet etch process using hot trimethyl-2 hydroxyethyl ammonium hydroxide (“hot TMY”) or tetramethyl ammonium hydroxide (TMAH).

Generally, a selective etch process can be performed which etches the material of the gate semiconductor layer 53L selectively to the material of the metallic barrier liners (142, 342, 542) and selectively to the material of the various dielectric gate spacers (62, 63, 64) and the dielectric diffusion barrier layer 69. A first gate cavity 169 is formed over a first remaining portion of the gate dielectric metal oxide layer 52L in the first device region 100, and an additional gate cavity 569 may be formed over an additional remaining portion of the gate dielectric metal oxide layer 52L in the third device region 500.

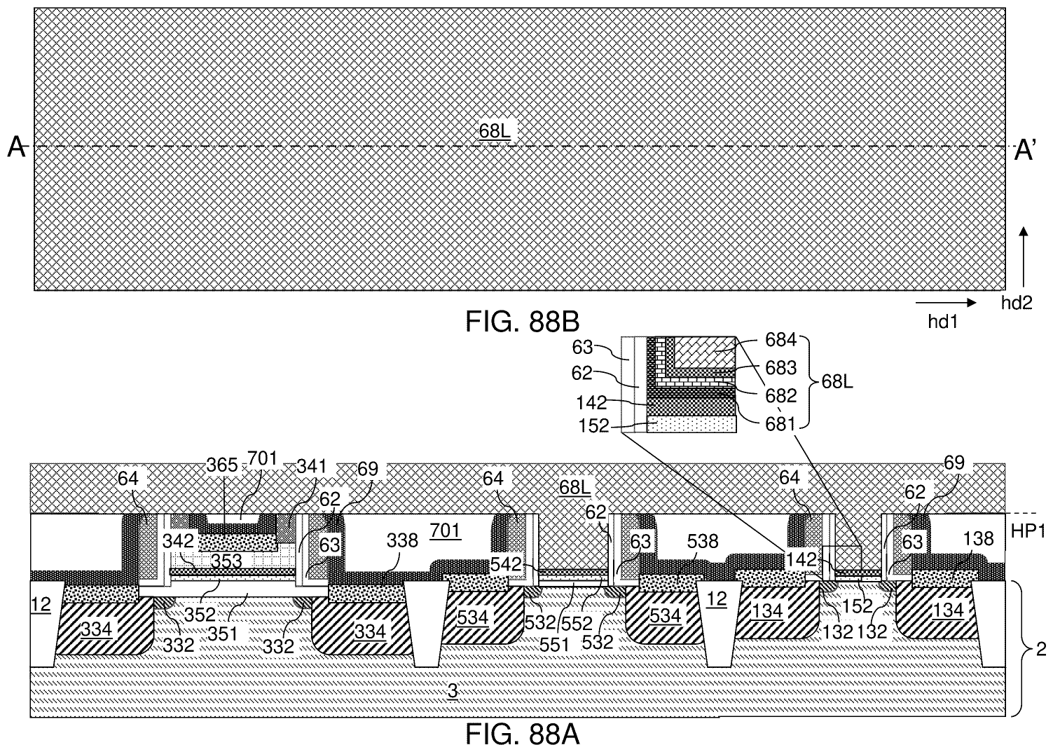

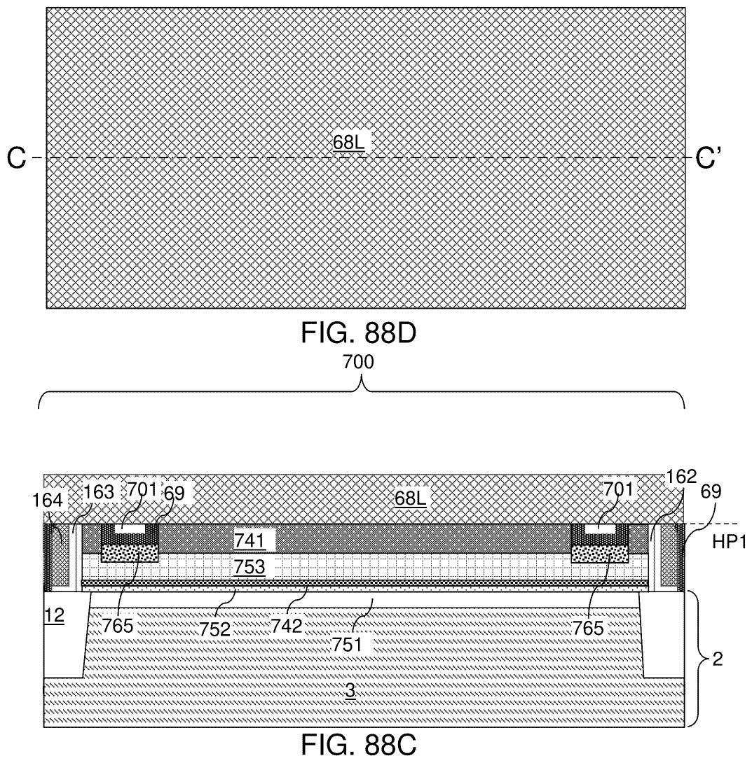

Referring to FIGS. 88A-88D, a replacement metallic material layer 68L can be deposited in the gate cavities (169, 569) and over the planarization dielectric layer 701. The replacement metallic material layer 68L comprises and/or consist of at least one metallic material. For example, the replacement metallic material layer 68L may comprise at least one metallic liner (681, 682, 683) and at least one metallic fill material portion 684. In one embodiment, the at least one metallic liner (681, 682, 683) may comprise a plurality of metallic liners (681, 682, 683) such as a first metallic liner 681, a second metallic liner 682, and a third metallic liner 683. In one embodiment, at least one of the plurality of metallic liners (681, 682, 683) may be removed in one or more of the device regions (100, 300, 500) without removal in the rest of the device regions (100, 300, 500) such that suitable work functions are devices for metallic gate electrodes to be subsequently formed. In an illustrative example, the first metallic liner 681 may comprise a tantalum nitride layer, the second metallic liner 682 may comprise an alloy of titanium and aluminum, and the third metallic liner 683 may comprise a stack of a titanium layer and a titanium nitride layer. The at least one metallic fill material portion 684 may comprise at least one refractory metal such as tungsten, molybdenum, tantalum, etc.

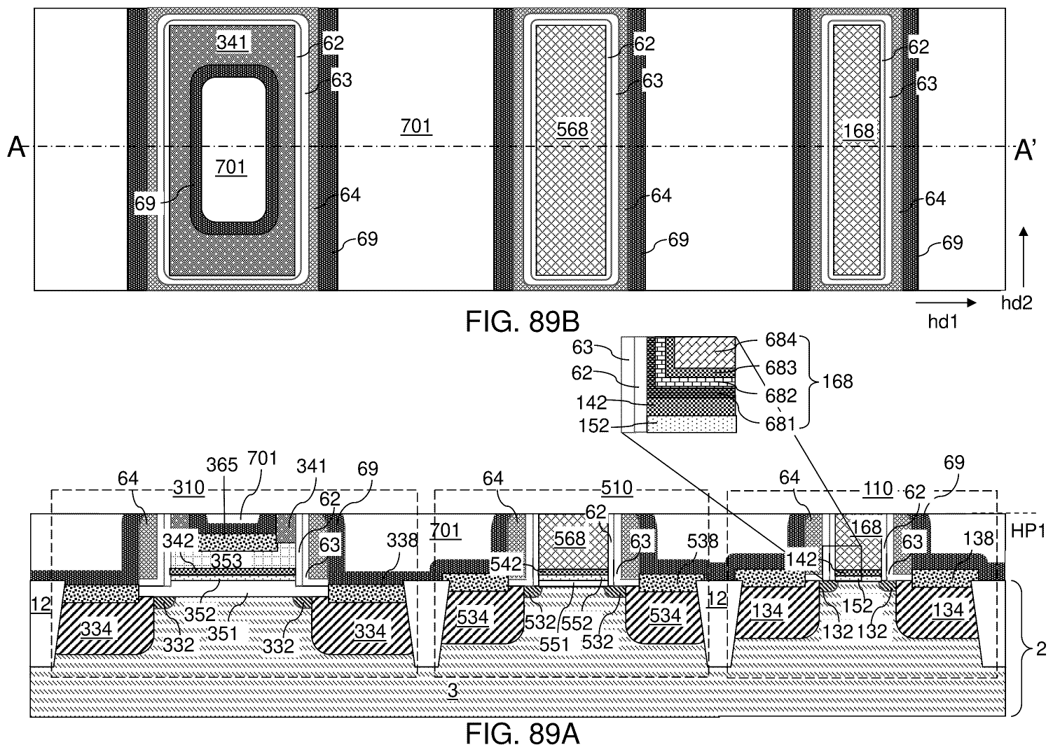

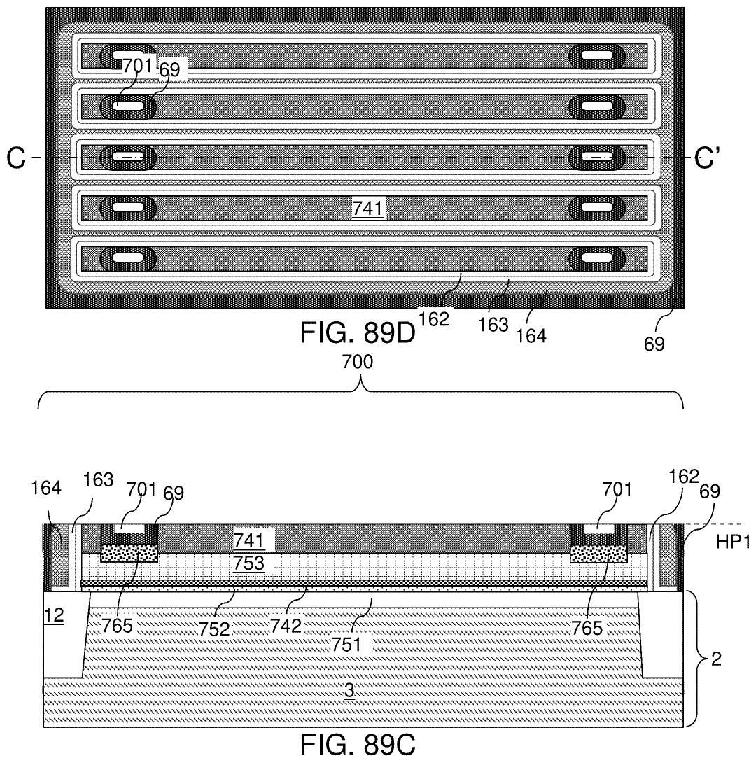

Referring to FIGS. 89A and 89B, the replacement metallic material layer 68L may be removed from above a first horizontal plane HP1 including a top surface of the second semiconductor gate electrode 353 by performing a planarization process such as a chemical mechanical polishing process. Remaining portions of the replacement metallic material layer 68L comprise a first metallic gate electrode 168 that is formed in the first device region 100, and an additional metallic gate electrode 568 that is formed in the third device region 500.

Generally, a first patterned portion of the gate semiconductor layer 53L in the first gate structure (152, 142, 153, 141) is replaced with a first metallic gate electrode 168; and an additional patterned portion of the gate semiconductor layer 53L in the third gate structure (551, 552,542, 553, 541) is replaced with an additional metallic gate electrode 568 (which may also be referred to as a second metallic gate electrode or a third metallic gate electrode).

The fifth exemplary structure comprises: a first field effect transistor 110 comprising first source/drain regions (132, 134) located in a first portion of a semiconductor substrate 2, a first gate dielectric 152 comprising a first metal oxide gate dielectric 152 that comprises a first portion of a dielectric metal oxide material, and a first gate electrode 168 comprising a metallic gate electrode (such as the first metallic gate electrode 168) contacting a top surface of the first gate dielectric 152; and a second field effect transistor 310 comprising second source/drain regions (332, 334) located in a second portion of the semiconductor substrate 2, a second gate dielectric (351 and optionally 352), a second gate electrode 353 comprising a doped semiconductor gate electrode 353. A pair of source/drain metal-semiconductor alloy regions (138, 338, 538) can be located on top of a pair of source/drain regions (332, 334) in each field effect transistor (110, 310, 510).

A planarization dielectric layer 701 laterally surrounds the first gate electrode 168 and the second gate electrode 353. The planarization dielectric layer 701 has a top surface within the horizontal plane (such as the first horizontal plane HP1) containing a top surface of the metallic gate electrode (such as the first metallic gate electrode 168). In one embodiment, metallic gate electrode comprises at least one gate metallic liner (681, 682, 683) each having a respective horizontally-extending portion and a respective tubular portion that vertically extends upward from a periphery of the respective horizontally-extending portion. In one embodiment, the topmost surface of the doped semiconductor gate electrode 353 is located below a horizontal plane (such as the first horizontal plane HP1) containing a top surface of the metallic gate electrode.

In one embodiment, the second sacrificial gate cap 341 may overlie the doped semiconductor gate electrode 353. The remaining part of the second sacrificial gate cap 341 may be referred to as a gate cap dielectric 341. A top surface of the metallic gate electrode (such as the first metallic gate electrode 168) and a top surface of an additional metallic gate electrode (such as the second metallic gate electrode 568) may be located within a horizontal plane (such as the first horizontal plane HP1) including a top surface of the gate cap dielectric 341.

The semiconductor structure may also comprise at least one resistor structure (752, 742, 753, 741, 765). Each resistor structure (752, 742, 753, 741, 765) may comprise, from bottom to top, a dielectric metal oxide strip 752, a metallic liner strip 742, a semiconductor material strip 753, a resistor cap strip 741, and a pair of contact metal-semiconductor alloy regions 765. Each resistor structure (752, 742, 753, 741, 765) overlies an isolation dielectric layer 751. Each semiconductor material strip 753 may have the same thickness as the doped semiconductor gate electrode 353, but may have different atomic concentrations and/or species of dopant atoms. The pair of contact electrode metal-semiconductor alloy regions 765 can be located on end portions of the semiconductor material strip 753.

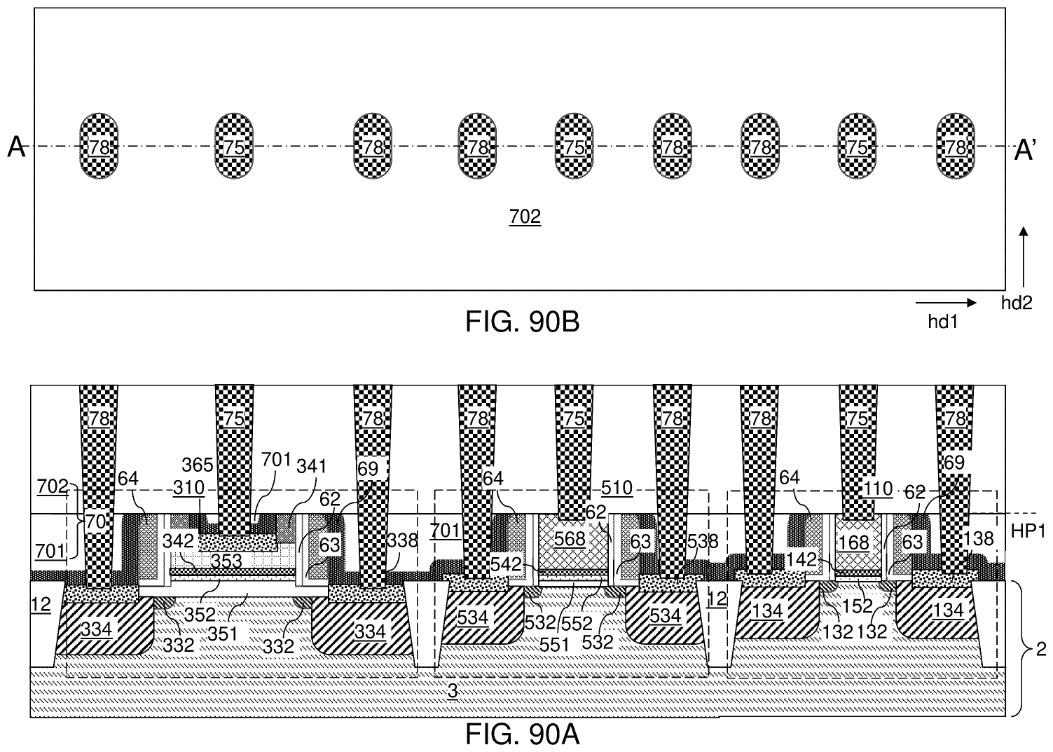

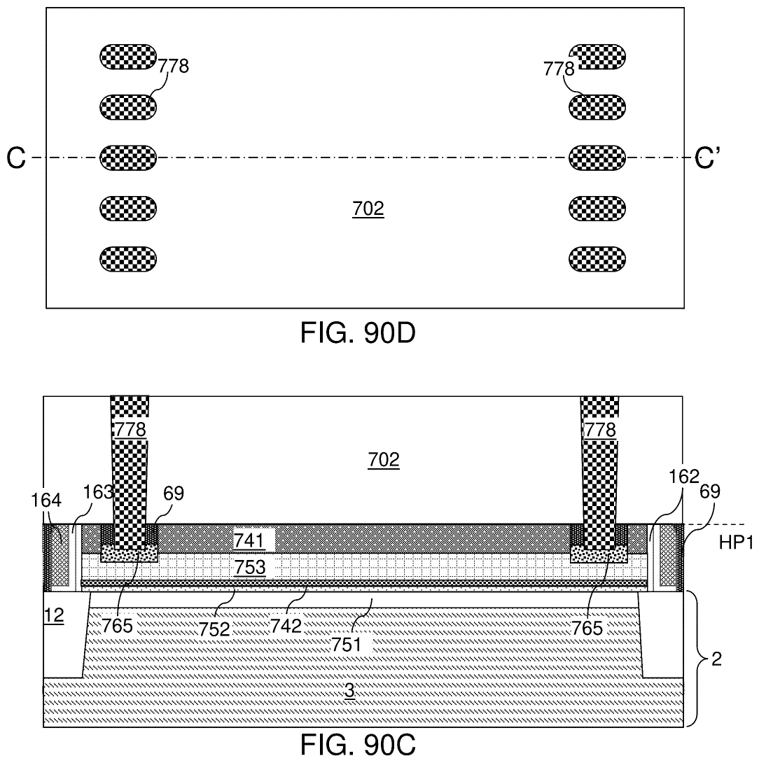

Referring to FIGS. 90A-90D, a cover dielectric layer 702 can be formed over the dielectric capping layer 44. The cover dielectric layer 702 comprises a dielectric material such as undoped silicate glass or a doped silicate glass. The combination of the planarization dielectric layer 701 and the cover dielectric layer 702 constitutes a contact-level dielectric layer 70. Various contact via structures (75, 78, 778) can be formed through the contact-level dielectric layer 70 on a respective one of the metallic gate electrodes (168, 568), the gate metal-semiconductor alloy region 365, the metal-semiconductor alloy regions (138, 338, 538), and the contact metal-semiconductor alloy regions 765. The various contact via structures (75, 78) may comprise source/drain contact via structures 78 contacting a respective one of the metal-semiconductor alloy regions (138, 338, 538), gate contact via structures 75 contacting a respective one of the metallic gate electrodes (168, 568) and the gate metal-semiconductor alloy region 365, and resistor contact via structures 778 contacting a respective one of the contact metal-semiconductor alloy regions 765.

Referring collectively to FIGS. 90A-90D, a semiconductor structure is provided, which comprises: a first field effect transistor 110 comprising first source/drain regions (132, 134) located in a first portion of a semiconductor substrate 2, a first gate dielectric 152 comprising a first metal oxide gate dielectric 152 that comprises a first portion of a dielectric metal oxide material, and a first gate electrode 168 comprising a metallic gate electrode contacting a top surface of the first gate dielectric 152; and a second field effect transistor 310 comprising second source/drain regions (332, 334) located in a second portion of the semiconductor substrate 2, a second gate dielectric (351, 352), a second gate electrode (353, 368) comprising a doped semiconductor gate electrode 353, and a gate metal-semiconductor alloy region 365 comprising an alloy of a first elemental metal and a semiconductor material of the doped semiconductor gate electrode 353.

In one embodiment, the semiconductor structure comprises a planarization dielectric layer 701 laterally surrounding the first gate electrode 168 and the second gate electrode (353, 368) and having a top surface within the horizontal plane (such as the first horizontal plane HP1) containing a top surface of the metallic gate electrode. In one embodiment, the metallic gate electrode comprises at least one gate metallic liner (681, 682, 683) each having a respective horizontally-extending portion and a respective tubular portion that vertically extends upward from a periphery of the respective horizontally-extending portion.

In one embodiment, the second gate dielectric (351, 352) comprises: a first silicon oxide gate dielectric 351; and a second metal oxide gate dielectric 352 that comprises a second portion of the dielectric metal oxide material. In one embodiment, sidewalls of the first metal oxide gate dielectric 152 are vertically coincident with sidewalls of the metallic gate electrode; sidewalls of the second metal oxide gate dielectric 352 are vertically coincident with sidewalls of the doped semiconductor gate electrode 353; and sidewalls of the first silicon oxide gate dielectric 351 are laterally offset outward relative to the sidewalls of the second metal oxide gate dielectric 352.

In one embodiment, the semiconductor structure comprises: a first dielectric gate spacer (62, 63, and/or 64) laterally surrounding the metallic gate electrode and having a first planar dielectric top surface; and a second dielectric gate spacer (62, 63, and/or 64) laterally surrounding the doped semiconductor gate electrode 353 and having a second planar dielectric top surface that is located within a same horizontal plane (such as the first horizontal plane HP1) as the first planar dielectric top surface.

In one embodiment, a topmost surface of the doped semiconductor gate electrode 353 is located within a horizontal plane (such as the first horizontal plane HP1) containing a top surface of the metallic gate electrode. In one embodiment, the semiconductor structure comprises a dielectric material layer (such as a dielectric capping layer 44) contacting a top surface segment of the metallic gate electrode, contacting a top surface segment of the doped semiconductor gate electrode, and laterally surrounding the gate metal-semiconductor alloy region 365, wherein an interface between the dielectric material layer and the top surface segment of the metallic gate electrode is located within a same horizontal plane (such as the first horizontal plane HP1) as an interface between the dielectric material layer and the top surface segment of the doped semiconductor gate electrode.

In one embodiment, a topmost surface of the doped semiconductor gate electrode 353 is located below a horizontal plane (such as the first horizontal plane HP1) containing a top surface of the metallic gate electrode. In one embodiment, the semiconductor structure comprises a gate cap dielectric 341 overlying the doped semiconductor gate electrode 353, wherein a top surface of the metallic gate electrode is located within a horizontal plane (such as the first horizontal plane HP1) including a top surface of the gate cap dielectric.

In one embodiment, the semiconductor structure comprises a pair of source/drain metal-semiconductor alloy regions located on top of the second source/drain regions (332, 334). In one embodiment, the semiconductor structure comprises a resistor structure (752, 742, 753, 741, 765) that overlies an isolation dielectric layer 751 and comprising: a semiconductor material strip 753 having a same thickness as the doped semiconductor gate electrode 353; and a pair of contact electrode metal-semiconductor alloy regions 765 located on end portions of the semiconductor material strip 753.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a first field effect transistor comprising first source/drain regions located in a first portion of a semiconductor substrate, a first gate dielectric comprising a first metal oxide gate dielectric that comprises a first portion of a dielectric metal oxide material, and a first gate electrode consisting essentially of a first metallic gate electrode contacting a top surface of the first gate dielectric; and
a second field effect transistor comprising second source/drain regions located in a second portion of the semiconductor substrate, a second gate dielectric comprising a silicon oxide gate dielectric, and a second gate electrode comprising a vertical stack of a doped semiconductor gate electrode and a second metallic gate electrode.

2. The semiconductor structure of claim 1, wherein:
the first field effect transistor comprises a lower voltage transistor than the second field effect transistor;
the first field effect transistor lacks any doped semiconductor gate electrode portions; and
the first gate dielectric is thinner than the second gate dielectric.

3. The semiconductor structure of claim 1, wherein a topmost surface of the second gate electrode is located within a horizontal plane containing a topmost surface of the first gate electrode.

4. The semiconductor structure of claim 1, wherein the first metallic gate electrode has a greater vertical extent and a smaller lateral extent than the second metallic gate electrode, and a vertical extent of the first metallic gate electrode is not less than a total vertical extent of the vertical stack.

5. The semiconductor structure of claim 1, wherein:
sidewalls of the first gate dielectric are vertically coincident with sidewalls of the first gate electrode; and
the silicon oxide gate dielectric comprises:
first sidewalls that are laterally offset outward relative to the sidewalls of the second metal oxide gate dielectric;
second sidewalls that are vertically coincident with and are adjoined to the sidewalls of the second metal oxide gate dielectric;
a first portion located within an area of the second metal oxide gate dielectric in a plan view and having a first thickness; and
a second portion that does not have any areal overlap in the plan view and having a second thickness that is less than the first thickness.

6. The semiconductor structure of claim 5, wherein:
the second gate dielectric further comprises a second metal oxide gate dielectric; and
sidewalls of the second metal oxide gate dielectric are vertically coincident with sidewalls of the doped semiconductor gate electrode.

7. The semiconductor structure of claim 1, wherein:
the second gate dielectric consists essentially of the silicon oxide gate dielectric;
the doped semiconductor gate electrode directly contacts the silicon oxide gate dielectric; and
a bottom surface of the first metal oxide gate dielectric is in direct contact with a channel region of the first field effect transistor.

8. The semiconductor structure of claim 1, wherein:
the first metallic gate electrode comprises a first portion of at least one metallic material; and
the second metallic gate electrode comprises a second portion of the at least one metallic material, wherein:
for each metallic material portion located within the first metallic gate electrode, a corresponding metallic material portion having a same material composition is present in the second metallic gate electrode; and
for each metallic material portion located within the second metallic gate electrode, a corresponding metallic material portion having a same material composition is present in the first metallic gate electrode.

9. The semiconductor structure of claim 8, wherein:
the first metallic gate electrode further comprises at least one first metallic liner having a respective first horizontally-extending portion and a respective first tubular portion that vertically extends upward from a periphery of the respective first horizontally-extending portion;
the second metallic gate electrode further comprises at least one second metallic liner having a respective second horizontally-extending portion and a respective second tubular portion that vertically extends upward from a periphery of the respective second horizontally-extending portion;
for each first metallic liner located within the first metallic gate electrode, a corresponding second metallic liner having a same material composition and a same thickness is present in the second metallic gate electrode; and
for each second metallic liner located within the second metallic gate electrode, a corresponding first metallic liner having a same material composition and a same thickness is present in the first metallic gate electrode.

10. The semiconductor structure of claim 2, further comprising:
a third field effect transistor comprising third source/drain regions located in a third portion of the semiconductor substrate, a third gate dielectric comprising a second silicon oxide gate dielectric and a second metal oxide gate dielectric that comprises a second portion of a dielectric metal oxide material, and a third gate electrode consisting essentially of a third metallic gate electrode;
wherein:
the third field effect transistor comprises a lower voltage transistor than the second field effect transistor and a higher voltage transistor than the first field effect transistor;
the third field effect transistor lacks any doped semiconductor gate electrode portions; and
the third gate dielectric is thinner than the second gate dielectric and thicker than the first gate dielectric.

11. A method of forming a semiconductor structure, comprising:
forming a silicon oxide gate dielectric on a top surface segment of a semiconductor substrate, wherein the silicon oxide gate dielectric is not present in a first device region and is present in a second device region;
forming a gate dielectric metal oxide layer directly on an additional top surface segment of the semiconductor substrate in the first device region and over the silicon oxide gate dielectric in the second device region;
forming a lower gate semiconductor layer over the silicon oxide gate dielectric in the second device region and over gate dielectric metal oxide layer in the first device region;
forming an etch-stop layer over the lower gate semiconductor layer in the second device region;
forming an upper gate semiconductor layer over the gate dielectric metal oxide layer in the first device region and over the etch-stop layer and the lower gate semiconductor layer in the second device region;
patterning the upper gate semiconductor layer, the etch-stop layer, and the lower gate semiconductor layer into a first gate structure that is formed in the first device region and into a second gate structure that is formed in the second device region;
replacing a first patterned portion of the upper gate semiconductor layer and a patterned portion of the lower gate semiconductor layer in the first gate structure with a first metallic gate electrode; and
replacing a second patterned portion of the upper gate semiconductor layer and a patterned portion of the etch-stop layer with a second metallic gate electrode.

12. The method of claim 11, wherein the second metallic gate electrode is formed directly on a top surface of second patterned portion of the lower gate semiconductor layer that is present within the second gate structure.

13. The method of claim 11, further comprising:
depositing a planarization dielectric layer over and around the first gate structure and the second gate structure; and
planarizing the planarization dielectric layer, wherein a top surface of the first patterned portion of the upper gate semiconductor layer and a top surface of the second patterned portion of the upper gate semiconductor layer are physically exposed.

14. The method of claim 13, wherein:
the gate dielectric metal oxide layer is formed directly on the additional top surface segment of the semiconductor substrate in the first device region and directly on the silicon oxide gate dielectric in the second device region prior to forming the lower gate semiconductor layer; and
the lower gate semiconductor layer is formed over both the gate dielectric metal oxide layer and the silicon oxide gate dielectric in the first device region and over the gate dielectric metal oxide layer in the second device region.

15. The method of claim 14, further comprising:
performing a first selective etch process that etches materials of the upper gate semiconductor layer and the lower gate semiconductor layer selectively to the material of the etch-stop layer to form a first gate cavity over a first remaining portion of the gate dielectric metal oxide layer in the first device region, and to form a second gate cavity over a remaining portion of the etch-stop layer in the second device region; and
performing a second selective etch process that etches the remaining portion of the etch-stop layer selectively to the lower gate semiconductor layer.

16. The method of claim 14, wherein the patterning the upper gate semiconductor layer, the etch-stop layer, and the lower gate semiconductor layer into a first gate structure that is formed in the first device region and into a second gate structure that is formed in the second device region occurs during a same etching step.

17. The method of claim 11, wherein:
the lower gate semiconductor layer is formed in the first device region and in the second device region;
the lower gate semiconductor layer is removed from the first device region prior to patterning the upper gate semiconductor layer;
the patterning the upper gate semiconductor layer, the etch-stop layer, and the lower gate semiconductor layer into a first gate structure that is formed in the first device region and into a second gate structure that is formed in the second device region occurs during different etching steps.

18. The method of claim 17, wherein the gate dielectric metal oxide layer is formed directly on the additional top surface segment of the semiconductor substrate in the first device region and on the etch-stop layer in the second device region after forming the lower gate semiconductor layer and the etch-stop layer and after the lower gate semiconductor layer is removed from the first device region.

19. The method of claim 18, further comprising:
forming an intermediate gate semiconductor layer over the gate dielectric metal oxide layer after the lower gate semiconductor layer is removed from the first device region;
removing a portion of the gate dielectric metal oxide layer and the intermediate gate semiconductor layer in the second device region to expose a top surface of the etch-stop layer; and
patterning the upper gate semiconductor layer and the intermediate gate semiconductor layer into a first gate structure in the first device region and patterning the upper gate semiconductor layer, the etch-stop layer, and the lower gate semiconductor layer into the second gate structure.

20. A method of forming a semiconductor structure, comprising:
forming a silicon oxide gate dielectric on a top surface segment of a semiconductor substrate, wherein the silicon oxide gate dielectric is not present in a first device region and is present in a second device region;
forming a lower gate semiconductor layer over the silicon oxide gate dielectric;
forming a gate dielectric metal oxide layer directly on an additional top surface segment of the semiconductor substrate in the first device region;
forming an intermediate gate semiconductor layer over the gate dielectric metal oxide layer;
forming an upper gate semiconductor layer over the intermediate gate semiconductor layer;
patterning the upper gate semiconductor layer, the intermediate gate semiconductor layer, and the lower gate semiconductor layer into a first gate structure that is formed in the first device region and into a second gate structure that is formed in the second device region;
replacing a first patterned portion of the upper gate semiconductor layer and a patterned portion of the intermediate gate semiconductor layer in the first gate structure with a first metallic gate electrode; and
replacing at least a second patterned portion of the upper gate semiconductor layer with a second metallic gate electrode.
